(19) United States
(12) Patent Application Publication
(10) Pub. No.: US 2023/0279027 A1
(43) Pub. Date: Sep. 7, 2023

(54) LIGHT EMITTING ELEMENT AND POLYCYCLIC COMPOUND FOR LIGHT EMITTING ELEMENT

(71) Applicant: Samsung Display Co., Ltd., Yongin-si (KR)

(72) Inventors: MUN-KI SIM, Seoul (KR); SUN YOUNG PAK, Suwon-si (KR); SERAN KIM, Suwon-si (KR); TAEIL KIM, Hwaseong-si (KR); JUNHA PARK, Gwacheon-si (KR); MINJUNG JUNG, Hongcheon-gun (KR)

(21) Appl. No.: 18/104,683

(22) Filed: Feb. 1, 2023

(30) Foreign Application Priority Data
Mar. 3, 2022 (KR) 10-2022-0027437

(51) Int. Cl. C07F 5/02; H10K 85/60; H10K 50/11

(52) U.S. Cl. CPC C07F 5/027; H10K 85/658; H10K 85/6572; H10K 85/6574; H10K 50/11; C07B 2200/05

(57) ABSTRACT

A light emitting element includes an emission layer. The emission layer includes a polycyclic compound having a fused ring core portion containing at least two boron atoms as ring-forming atoms, and further includes a substituent positioned para to each of the boron atoms, and may thus exhibit high efficiency and long lifespan characteristics.

### CROSS-REFERENCE TO RELATED APPLICATIONS

This application claims priority to and the benefit of Korean Patent Application No. 10-2022-0027437, filed on Mar. 3, 2022, in the Korean Intellectual Property Office, the entire content of which is hereby incorporated by reference.

### BACKGROUND

### 1. Field

The present disclosure herein relates to a light emitting element and a polycyclic compound for the same, and for example, to a light emitting element including a plurality of materials such as a new polycyclic compound utilized as a light emitting material in an emission layer.

### 2. Description of the Related Art

As image display devices, organic electroluminescence display devices and/or the like have been actively developed lately. The organic electroluminescence display devices and/or the like are display devices including so-called self-luminescent light emitting elements in which holes and electrons injected from a first electrode and a second electrode recombine in an emission layer, and thus a luminescent material in the emission layer emits light to accomplish display (e.g., to display an image).

For application of light emitting elements in display devices, there is a demand or desire for light emitting elements having a low driving voltage, high light emitting efficiency, and a long life, and development of materials, for light emitting elements, capable of stably attaining such characteristics is being continuously pursued.

In recent years, in order to implement a highly efficient organic electroluminescence device, technologies pertaining to phosphorescence emission utilizing triplet state energy or delayed fluorescence emission utilizing triplet-triplet annihilation (TTA) (in which singlet excitons are generated by collision of triplet excitons) are being developed, and thermally activated delayed fluorescence (TADF) materials utilizing a delayed fluorescence phenomenon are being developed.

### SUMMARY

Aspects according to embodiments of the present disclosure are directed toward a light emitting element exhibiting high efficiency and long service life characteristics.

Aspects according to embodiments of the present disclosure are directed toward a polycyclic compound exhibiting high light emitting efficiency and increased lifespan characteristics.

Additional aspects will be set forth in part in the description which follows and, in part, will be apparent from the description, or may be learned by practice of the presented embodiments of the disclosure.

According to an embodiment of the present disclosure, a light emitting element includes: a first electrode; a second electrode on the first electrode; and an emission layer between the first electrode and the second electrode, wherein the emission layer includes: a first compound represented by Formula 1; and at least one of a second compound represented by Formula HT, a third compound represented by Formula ET, or a fourth compound represented by Formula M-b.

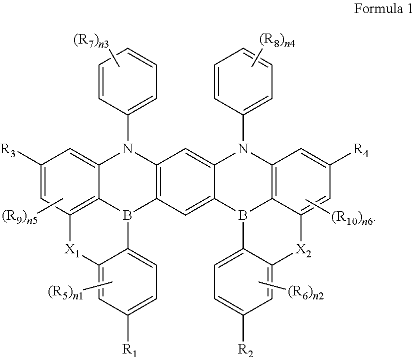

In Formula 1, one of X₁ or X₂ may be O or S and the other one of X₁ or X₂ may be NRₓ, O, or S, Rx may be a substituted or unsubstituted aryl group having 6 to 30 ring-forming carbon atoms, or a substituted or unsubstituted heteroaryl group having 2 to 30 ring-forming carbon atoms, R₁ to R₄ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, wherein when R₃ and/or R₄ are each independently a substituted or unsubstituted carbazole group, the nitrogen atom of the carbazole group is not bonded to a benzene ring (e.g., a case where the nitrogen atom of the carbazole group being bonded to a benzene ring is excluded), R₅ to R₈ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, R₉ and R₁₀ may each independently be a hydrogen atom or a deuterium atom, or bonded to an adjacent group to form a ring, n1 and n2 may each independently be an integer of 0 to 3, n3 and n4 may each independently be an integer of 0 to 5, and n5 and n6 may each independently be an integer of 0 to 2.

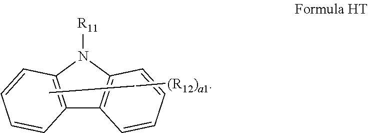

In Formula HT, a1 may be an integer of 0 to 8, and R₁₁ and R₁₂ may each independently be a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms.

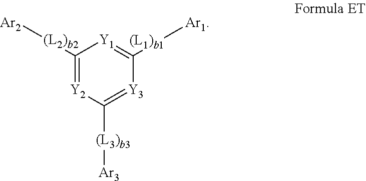

In Formula ET, at least one of Y₁ to Y₃ may be N and any remainder thereof (e.g., the others (Yi to Y₃ which are not N)) may each independently be CRₐ, Rₐ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, b1 to b3 may each independently be an integer of 0 to 10, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms, and Aᵣ₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

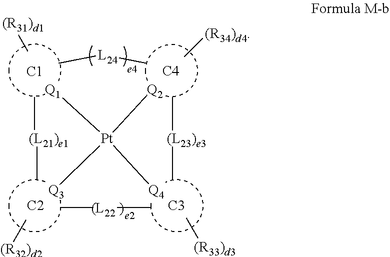

In Formula M-b, Q₁ to Q₄ may each independently be C or N, C1 to C4 may each independently be a substituted or unsubstituted hydrocarbon ring having 5 to 30 ring-forming carbon atoms, or a substituted or unsubstituted heterocycle having 2 to 30 ring-forming carbon atoms, e1 to e4 may each independently be 0 or 1, L₂₁ to L₂₄ may each independently be a direct linkage,

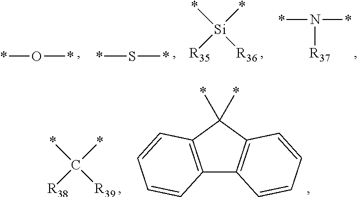

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, d1 to d4 may each independently be an integer of 0 to 4, R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or linked to an adjacent group to form a ring.

In an embodiment, the first compound represented by Formula 1 may be represented by Formula 1-1 or Formula 1-2.

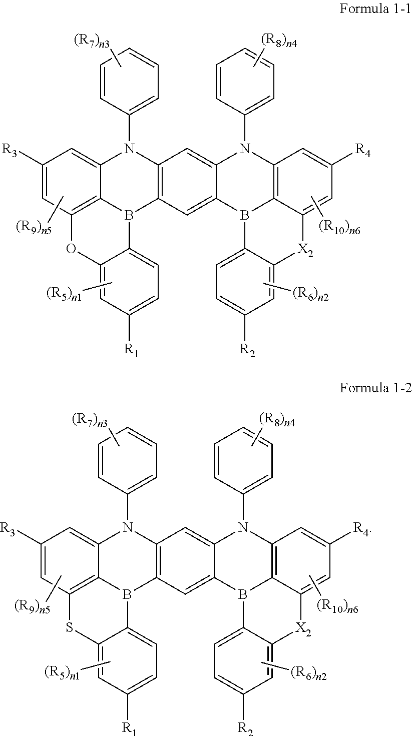

In Formulas 1-1 and 1-2, X₂ may be NRₓ₁, O, or S, Rₓ₁ may be a substituted or unsubstituted aryl group having 6 to 30 ring-forming carbon atoms, or a substituted or unsubstituted heteroaryl group having 2 to 30 ring-forming carbon atoms, and R₁ to R₁₀, and n1 to n6 may each independently be the same as respectively defined in Formula 1.

In an embodiment, the first compound represented by Formula 1 may be represented by Formula 2.

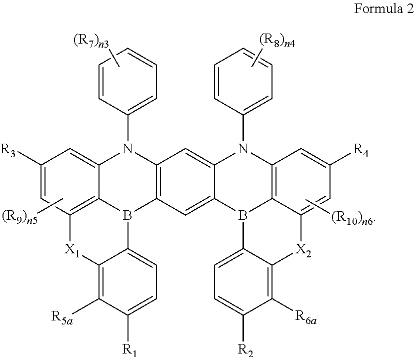

In Formula 2, R₁ₐ may be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to R₅ₐ to form a ring, R₂ₐ may be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to R₆ₐ to form a ring, R₅ₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to R₁ₐ to form a ring, R₆ₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to R₂ₐ to form a ring, and X₁, X₂, R₃, R₄, R₇ to R₁₀, and n3 to n6 may each independently be the same as respectively defined in Formula 1.

In an embodiment, the first compound represented by Formula 1 may be represented by Formula 3.

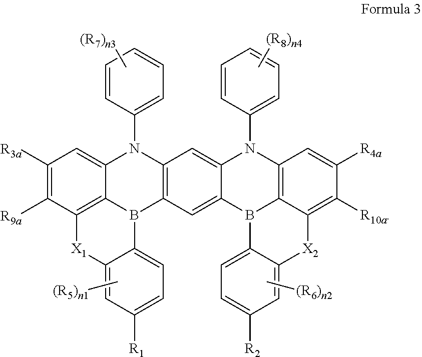

In Formula 3, R₃ₐ may be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to R₉ₐ to form a ring, R₄ₐ may be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to R₁₀ₐ to form a ring, R₉ₐ may be a hydrogen atom or a deuterium atom, and/or bonded to R₃a to form a ring, R₁₀ₐ may be a hydrogen atom or a deuterium atom, and/or bonded to R₄ₐ to form a ring, and X₁, X₂, R₁, R₂, R₅ to R₈, and n1 to n4 may each independently be the same as defined in Formula 1.

In an embodiment, in Formula 1, R₁ and R₂ may each independently be represented by any one from among R-1 to R-7, and/or bonded to an adjacent group to form a ring represented by R-9, and R₃ and R₄ may each independently be represented by any one from among R-1 to R-5, and R-8, and/or bonded to an adjacent group to form a ring represented by R-9.

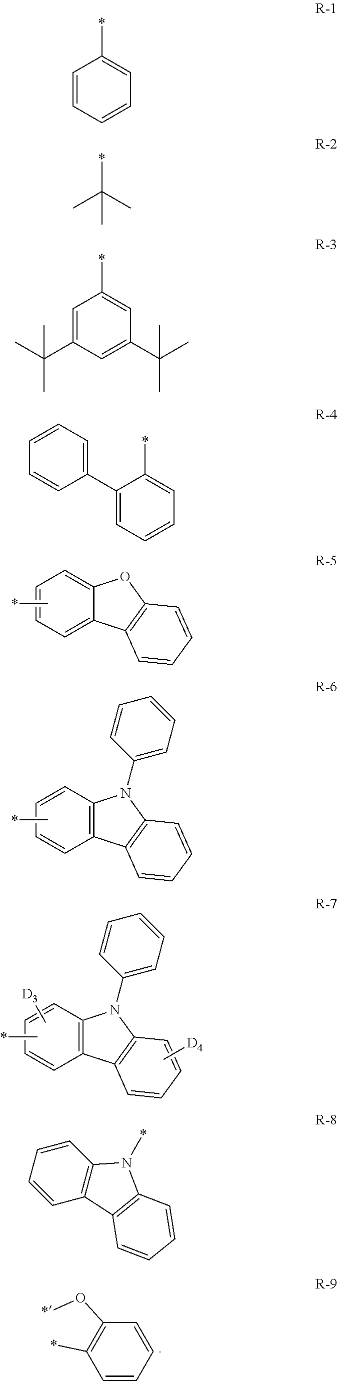

In R-1 to R-9, “*-“is a site where R₁ to R₄ are linked to Formula 1, and in R-9, “*-” is a site where the adjacent group is linked to Formula 1.

In a polycyclic compound of an embodiment, which is represented by Formula 1, R₅ and R₆ may each independently be a hydrogen atom, a deuterium atom, a substituted or unsubstituted t-butyl group, or a substituted or unsubstituted phenyl group, and/or bonded to an adjacent group to form a ring.

In an embodiment, the first compound represented by Formula 1 may be represented by Formula 4.

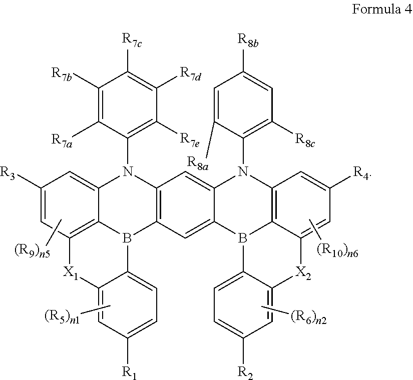

In Formula 4, R₇ₐ to R₇ₑ, and R₈ₐ to R_{8c} may each independently be a hydrogen atom, a deuterium atom, a substituted or unsubstituted alkyl group having 1 to 6 carbon atoms, or a substituted or unsubstituted aryl group having 6 to 20 ring-forming carbon atoms, and X₁, X₂, R₁ to R₆, R₉, R₁₀, n1, n2, n5, and n6 may each independently be the same as respectively defined in Formula 1.

In an embodiment, R₇ₐ to R₇ₑ, and R₈ₐ to R_{8c} may each independently be a hydrogen atom, a deuterium atom, a substituted or unsubstituted t-butyl group, or a substituted or unsubstituted phenyl group.

In an embodiment, Rₓ may be a substituted or unsubstituted phenyl group, or a substituted or unsubstituted biphenyl group.

In an embodiment, the emission layer may be to emit blue light.

In an embodiment, the emission layer may include the first compound, the second compound, and the third compound. In some embodiments, the emission layer may include the first compound, the second compound, the third compound, and the fourth compound.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a plan view showing a display device according to an embodiment;

FIG. 2 is a cross-sectional view showing a portion corresponding to the line I-I′ of FIG. 1;

FIG. 3 is a cross-sectional view schematically showing a light emitting element according to an embodiment;

FIG. 4 is a cross-sectional view schematically showing a light emitting element according to an embodiment;

FIG. 5 is a cross-sectional view schematically showing a light emitting element according to an embodiment;

FIG. 6 is a cross-sectional view schematically showing a light emitting element according to an embodiment;

FIG. 7 is a cross-sectional view showing a display device according to an embodiment;

FIG. 8 is a cross-sectional view showing a display device according to an embodiment;

FIG. 9 is a cross-sectional view showing a display device according to an embodiment; and

FIG. 10 is a cross-sectional view showing a display device according to an embodiment.

### DETAILED DESCRIPTION

The subject matter of the present disclosure may be modified in many alternate forms, and thus specific embodiments will be exemplified in the drawings and described in more detail. It should be understood, however, that it is not intended to limit the present disclosure to the particular forms disclosed, but rather, is intended to cover all modifications, equivalents, and alternatives falling within the spirit and scope of the present disclosure.

In describing the drawings, like reference numerals are used for like elements. In the drawings, the sizes of elements may be exaggerated for clarity. It will be understood that, although the terms “first”, “second”, etc. may be used herein to describe one or more suitable elements, these elements should not be limited by these terms. These terms are only used to distinguish one element from another. For example, a first element could be termed a second element, and, similarly, a second element could be termed a first element, without departing from the scope of example embodiments of the present disclosure. The terms of a singular form may include plural forms unless the context clearly indicates otherwise.

In the present description, it should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

In the present description, it should be understood that when an element such as a layer, a film, a region, or a substrate is referred to as being “on” or “above” another element, it may be “directly on” the other element or intervening elements may also be present. In contrast, it should be understood that when an element such as a layer, a film, a region, or a substrate is referred to as being “beneath” or “under” another element, it may be “directly under” the other element or intervening elements may also be present. In addition, in the present description, it should be understood that when an element is referred to as being “on” another element, it may be “above” or “under” the other element.

In the present description, the term “substituted or unsubstituted” may indicate that a functional group is substituted or unsubstituted with at least one substituent selected from the group consisting of a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. In addition, each of the substituents provided as examples above may be substituted or unsubstituted. For example, a biphenyl group may be interpreted as an aryl group or as a phenyl group substituted with a phenyl group.

In the present description, the term “linked to an adjacent group to form a ring” may indicate that a group is linked to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle.

The hydrocarbon ring and the heterocycle may be monocyclic or polycyclic. In addition, the rings formed via the combination with an adjacent group may be connected to another ring to form a spiro structure.

In the present description, the term “an adjacent group” may refer to a substituent substituted for an atom which is directly connected to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as mutually “adjacent groups” and two ethyl groups in 1,1-diethylcyclopentane may be interpreted as mutually “adjacent groups”. In addition, two methyl groups in 4,5-dimethylphenanthrene may be interpreted as mutually “adjacent groups”.

In the present description, examples of a halogen atom may include a fluorine atom, a chlorine atom, a bromine atom, and an iodine atom.

In the present description, an alkyl group may be a linear, branched or cyclic alkyl group. The number of carbon atoms in the alkyl group is 1 to 50, 1 to 30, 1 to 20, 1 to 10, or 1 to 6. Non-limiting examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-a dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc.

In the present description, an alkenyl group refers to a hydrocarbon group including at least one carbon-carbon double bond in the middle and/or at the terminal end of an alkyl group having 2 or more carbon atoms. The alkenyl group may be linear or branched. The number of carbon atoms is not particularly limited, but may be 2 to 30, 2 to 20, or 2 to 10. Non-limiting examples of the alkenyl group may include a vinyl group, a 1-butenyl group, a 1-pentenyl group, a 1,3-butadienyl aryl group, a styrenyl group, a styryl vinyl group, etc.

In the present description, an alkynyl group refers to a hydrocarbon group including at least one carbon-carbon triple bond in the middle and/or at the terminal end of an alkyl group having 2 or more carbon atoms. The alkynyl group may be linear or branched. The number of carbon atoms is not particularly limited, but may be 2 to 30, 2 to 20, or 2 to 10. Non-limiting examples of the alkynyl group may include an ethynyl group, a propynyl group, etc.

In the present description, a hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the present description, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 60, 6 to 30, 6 to 20, or 6 to 15. Non-limiting examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc.

In the present description, a fluorenyl group may be substituted, and two substituents may be bonded to each other to form a spiro structure. Examples of a substituted fluorenyl group are as follows. However, the embodiment of the present disclosure is not limited thereto.

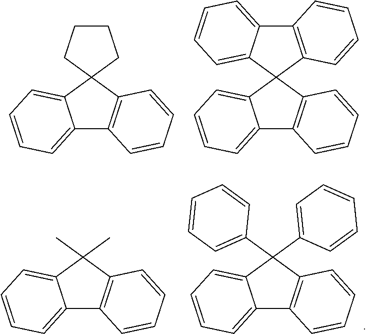

In the present description, a heterocyclic group refers to any functional group or substituent derived from a ring containing at least one of B, O, N, P, Si, or S as a hetero atom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the present description, the heterocyclic group may contain at least one of B, O, N, P, Si or S as a hetero atom. When the heterocyclic group contains two or more hetero atoms, the two or more hetero atoms may be the same as or different from each other. In the present description, the heterocyclic group may be a monocyclic heterocyclic group or a polycyclic heterocyclic group, and may include a heteroaryl group. The number of ring-forming carbon atoms in the heterocyclic group may be 2 to 30, 2 to 20, or 2 to 10.

In the present description, the aliphatic heterocyclic group may contain at least one of B, O, N, P, Si or S as a hetero atom. The number of ring-forming carbon atoms in the aliphatic heterocyclic group may be 2 to 30, 2 to 20, or 2 to 10. Non-limiting examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc.

In the present description, a heteroaryl group may include at least one of B, O, N, P, Si, or S as a hetero atom. When the heteroaryl group contains two or more hetero atoms, the two or more hetero atoms may be the same as or different from each other. The heteroaryl group may be a monocyclic heteroaryl group or a polycyclic heteroaryl group. The number of ring-forming carbon atoms in the heteroaryl group may be 2 to 60, 2 to 30, 2 to 20, or 2 to 10. Non-limiting examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc.

In the present description, the above description of the aryl group may be applied to an arylene group, except that the arylene group is a divalent group. The above description of the heteroaryl group may be applied to a heteroarylene group, except that the heteroarylene group is a divalent group.

In the present description, a boron (e.g., boryl) group may refer to one that a boron atom is bonded to an alkyl group or aryl group as defined above. The boron group includes an alkyl boron group and an aryl boron group. Non-limiting examples of the boron group may include a dimethyl boron group, a diethyl boron group, a t-butylmethyl boron group, a diphenyl boron group, a phenyl boron group, etc.

In the present description, a silyl group includes an alkyl silyl group and an aryl silyl group. Non-limiting examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc.

In the present description, the number of carbon atoms in a carbonyl group is not particularly limited, but may be 1 to 40, 1 to 30, or 1 to 20. For example, the carbonyl group may have the following structures, but is not limited thereto.

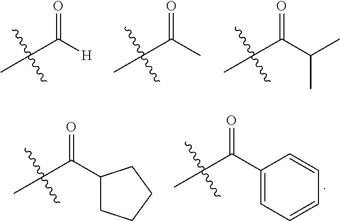

In the present description, the number of carbon atoms in a sulfinyl group and a sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the present description, a thio group may include an alkyl thio group and an aryl thio group. The thio group may include a sulfur atom bonded to an alkyl group or an aryl group defined above. Non-limiting examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc.

In the present description, an oxy group may include an oxygen atom bonded to an alkyl group or aryl group defined above. The oxy group may include an alkoxy group and an aryl oxy group. The alkoxy group may be linear, branched or cyclic. The number of carbon atoms in the alkoxy group is not particularly limited, but may be, for example, 1 to 20, or 1 to 10. Non-limiting examples of the oxy group may include a methoxy group, an ethoxy group, an n-propoxy group, an isopropoxy group, a butoxy group, a pentyloxy group, a hexyloxy group, an octyloxygroup, a nonyloxy group, a decyloxy group, a benzyloxy group, etc.,

In the present description, the number of carbon atoms in an amine group is not particularly limited, but may be 1 to 30. The amine group may include an alkyl amine group and an aryl amine group. Non-limiting examples of the amine group may include a methylamine group, a dimethylamine group, a phenylamine group, a diphenylamine group, a naphthylamine group, a 9-methyl-anthracenylamine group, etc.

In the present description, the alkyl group included in an alkylthio group, an alkyl sulfoxy group, an alkylaryl group, an alkylamino group, an alkyl boron group, an alkyl silyl group, and an alkyl amine group may be the same as the examples of the above-described alkyl group.

In the present description, the aryl group included in an aryloxy group, an arylthio group, an aryl sulfoxy group, an arylamino group, an aryl boron group, an aryl silyl group, and an aryl amine group may be the same as the examples of the above-described aryl group.

In the present description, a direct linkage may refer to a single bond.

In the present description,

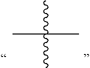

or “*-” refers to a site to be connected.

Hereinafter, embodiments of the present disclosure will be described with reference to the accompanying drawings.

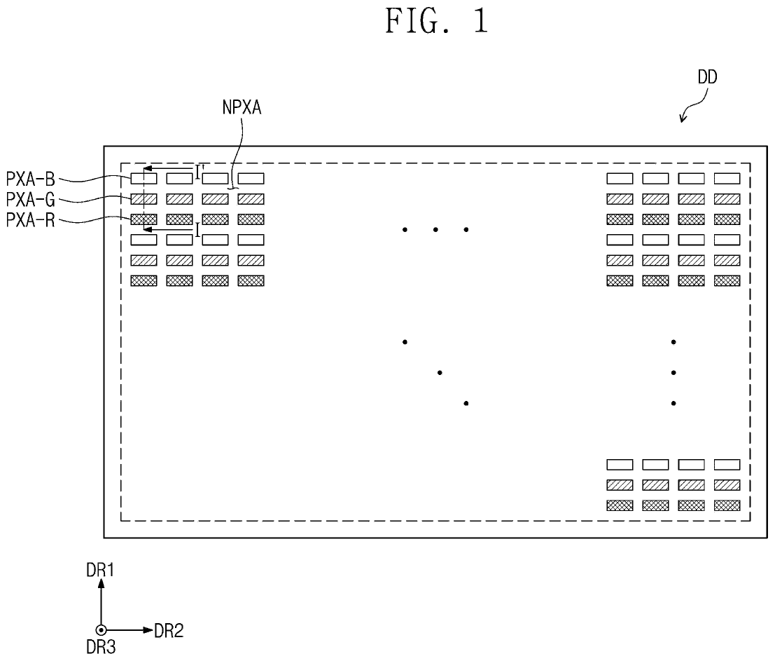

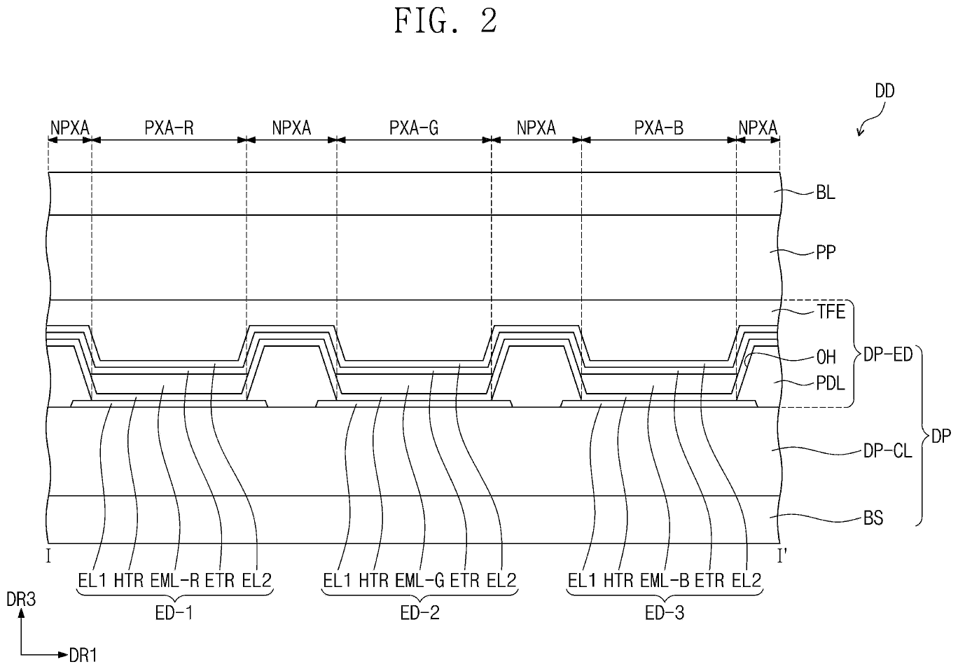

FIG. 1 is a plan view showing an embodiment of a display device DD. FIG. 2 is a cross-sectional view of a display device DD of an embodiment. FIG. 2 is a cross-sectional view showing a portion corresponding to the line I-I′ of FIG. 1.

The display device DD may include a display panel DP and an optical layer PP disposed on the display panel DP. The display panel DP may include light emitting elements ED-1, ED-2, and ED-3. The display device DD may include a plurality of light emitting elements ED-1, ED-2, and ED-3. The optical layer PP may be disposed on the display panel DP to control reflection of external light at the display panel DP. The optical layer PP may include, for example, a polarizing layer and/or a color filter layer. In some embodiments, unlike what is shown in the drawings, the optical layer PP may not be provided in the display device DD of an embodiment.

A base substrate BL may be disposed on the optical layer PP. The base substrate BL may be a member providing a base surface on which the optical layer PP is disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, unlike what is shown, the base substrate BL may not be provided in an embodiment.

The display device DD according to an embodiment may further include a filling layer. The filling layer may be disposed between a display element layer DP-ED and the base substrate BL. The filling layer may be an organic material layer. The filling layer may include at least one selected from among an acrylic resin, a silicone-based resin, and an epoxy-based resin.

The display panel DP may include a base layer BS, a circuit layer DP-CL provided on the base layer BS, and a display element layer DP-ED. The display element layer DP-ED may include pixel defining films PDL, a plurality of light emitting elements ED-1, ED-2, and ED-3 disposed between the pixel defining films PDL, and an encapsulation layer TFE disposed on the plurality of light emitting elements ED-1, ED-2, and ED-3.

The base layer BS may be a member providing a base surface on which the display element layer DP-ED is disposed. The base layer BS may be a glass substrate, a metal substrate, a plastic substrate, etc. However, the embodiment of the present disclosure is not limited thereto, and the base layer BS may be an inorganic layer, an organic layer, or a composite material layer.

In an embodiment, the circuit layer DP-CL may be disposed on the base layer BS, and the circuit layer DP-CL may include a plurality of transistors. The transistors may each include a control electrode, an input electrode, and an output electrode. For example, the circuit layer DP-CL may include a switching transistor and a driving transistor for driving the plurality of light emitting elements ED-1, ED-2 and ED-3 of the display element layer DP-ED.

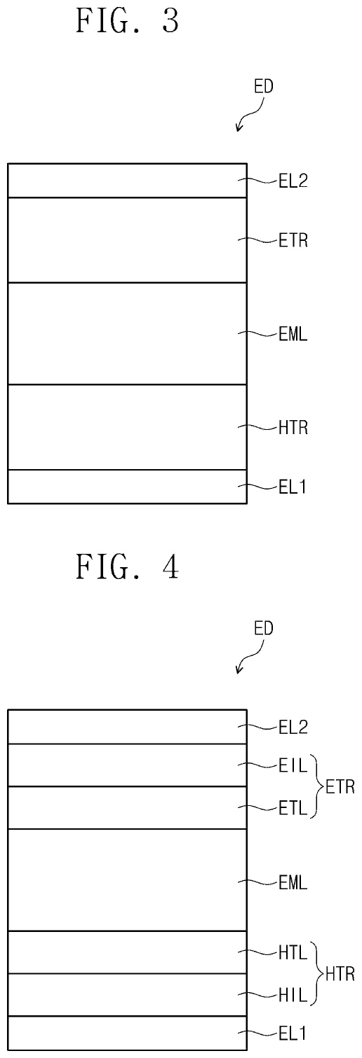

The light emitting elements ED-1, ED-2, and ED-3 may each have a structure of a light emitting element ED of an embodiment shown in FIGS. 3 to 6, which will be described in more detail later. The light emitting elements ED-1, ED-2, and ED-3 may each include a first electrode EL1, a hole transport region HTR, emission layers EML-R, EML-G, and EML-B (e.g., a corresponding one of the emission layer EML-R, the emission layer EML-G, or the emission layer EML-B), an electron transport region ETR, and a second electrode EL2.

FIG. 2 shows an embodiment in which the emission layers EML-R, EML-G, and EML-B of the light emitting elements ED-1, ED-2, and ED-3 are disposed in openings OH defined in the pixel defining films PDL, and the hole transport region HTR, the electron transport region ETR, and the second electrode EL2 are provided as common layers throughout the light emitting elements ED-1, ED-2, and ED-3. However, the embodiment of the present disclosure is not limited thereto, and unlike what is shown in FIG. 2, in an embodiment, the hole transport region HTR and the electron transport region ETR may be provided to be patterned inside the openings OH defined in the pixel defining films PDL. For example, in an embodiment, the hole transport region HTR, the emission layers EML-R, EML-G, and EML-B, and the electron transport region ETR, etc., of the light emitting elements ED-1, ED-2, and ED-3 may be patterned and provided through an inkjet printing method.

An encapsulation layer TFE may cover the light emitting elements ED-1, ED-2 and ED-3. The encapsulation layer TFE may seal the display element layer DP-ED. The encapsulation layer TFE may be a thin film encapsulation layer. The encapsulation layer TFE may be a single layer or a laminated layer of a plurality of layers. The encapsulation layer may include at least one insulating layer. The encapsulation layer TFE according to an embodiment may include at least one inorganic film (hereinafter, an encapsulation inorganic film). In some embodiments, the encapsulation layer TFE according to an embodiment may include at least one organic film (hereinafter, an encapsulation organic film) and at least one encapsulation inorganic film.

The encapsulation inorganic film may protect the display element layer DP-ED from moisture/oxygen, and the encapsulation organic film may protect the display element layer DP-ED from foreign substances such as dust particles. The encapsulation inorganic film may include silicon nitride, silicon oxy nitride, silicon oxide, titanium oxide, aluminum oxide, etc., but is not particularly limited thereto. The encapsulation organic layer may include an acrylic compound, an epoxy-based compound, etc. The encapsulation organic layer may include a photopolymerizable organic material, and is not particularly limited.

The encapsulation layer TFE may be disposed on the second electrode EL2, and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region emitting light generated from a corresponding one of the light emitting elements ED-1, ED-2, and ED-3. The light emitting regions PXA-R, PXA-G, and PXA-B may be spaced apart from each other when viewed on a plane (e.g., in a plan view).

The light emitting regions PXA-R, PXA-G, and PXA-B may each be a region separated by the pixel defining films PDL. The non-light emitting regions NPXA may be regions between neighboring light emitting regions PXA-R, PXA-G, and PXA-B, and may correspond to the pixel defining films PDL. In some embodiments, in the present description, the light emitting regions PXA-R, PXA-G, and PXA-B may each correspond to a pixel. The pixel defining films PDL may separate the light emitting elements ED-1, ED-2 and ED-3. The emission layers EML-R, EML-G, and EML-B of the light emitting elements ED-1, ED-2 and ED-3 may be disposed and separated in openings OH defined by the pixel defining films PDL.

The light emitting regions PXA-R, PXA-G, and PXA-B may be divided into a plurality of groups according to the color of light generated from the light emitting elements ED-1, ED-2, and ED-3. In the display device DD of an embodiment shown in FIGS. 1 and 2, three light emitting regions PXA-R, PXA-G, and PXA-B which emit red light, green light, and blue light, are illustrated as an example. For example, the display device DD of an embodiment may include a red light emitting region PXA-R, a green light emitting region PXA-G, and a blue light emitting region PXA-B, which are distinct from one another.

In the display device DD according to an embodiment, the plurality of light emitting elements ED-1, ED-2, and ED-3 may be to emit light having different wavelength ranges. For example, in an embodiment, the display device DD may include a first light emitting element ED-1 emitting red light, a second light emitting element ED-2 emitting green light, and a third light emitting element ED-3 emitting blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, the embodiment of the present disclosure is not limited thereto, and the first to third light emitting elements ED-1, ED-2 and ED-3 may be to emit light in substantially the same wavelength range or emit light in at least one different wavelength range. For example, the first to third light emitting elements ED-1, ED-2, and ED-3 may all emit blue light.

The light emitting regions PXA-R, PXA-G, and PXA-B in the display device DD according to an embodiment may be arranged in the form of a stripe. Referring to FIG. 1, a plurality of red light emitting regions PXA-R may be arranged with each other along a second directional axis DR2, a plurality of green light emitting regions PXA-G may be arranged with each other along the second directional axis DR2, and a plurality of blue light emitting regions PXA-B may each be arranged with each other along the second directional axis DR2. In some embodiments, the red light emitting region PXA-R, the green light emitting region PXA-G, and the blue light emitting region PXA-B may be alternately arranged in this stated order along a first directional axis DR1.

FIGS. 1 and 2 illustrate that the light emitting regions PXA-R, PXA-G, and PXA-B are all similar in size, but the embodiment of the present disclosure is not limited thereto, and the light emitting regions PXA-R, PXA-G and PXA-B may be different in size from each other according to the wavelength range of emitted light. The areas of the light emitting regions PXA-R, PXA-G, and PXA-B may refer to areas when viewed on a plane defined by the first directional axis DR1 and the second directional axis DR2 (e.g., in a plan view).

In some embodiments, the arrangement of the light emitting regions PXA-R, PXA-G, and PXA-B is not limited to what is shown in FIG. 1, and the red light emitting region PXA-R, the green light emitting region PXA-G, and the blue light emitting region PXA-B may be arranged in one or more suitable combinations according to display quality characteristics required or desired for the display device DD. For example, the light emitting regions PXA-R, PXA-G, and PXA-B may be arranged in the form of a pentile (PENTILE®) or a diamond (Diamond Pixel™). PENTILE® and Diamond Pixel™ are trademarks of Samsung Display Co., Ltd.

In some embodiments, the areas (e.g., size) of each of the light emitting regions PXA-R, PXA-G, and PXA-B may be different from one another. For example, in an embodiment, the green light emitting region PXA-G may be smaller than the blue light emitting region PXA-B in size, but the embodiment of the present disclosure is not limited thereto.

In the display device DD according to an embodiment which is shown in FIG. 2, at least one of the first to third light emitting elements ED-1, ED-2, and ED-3 may include a polycyclic compound according to an embodiment.

Hereinafter, FIGS. 3 to 6 are cross-sectional views schematically showing a light emitting element according to an embodiment. A light emitting element ED according to an embodiment may include a first electrode EL1, a second electrode EL2 facing the first electrode EL1, and an emission layer EML disposed between the first electrode EL1 and the second electrode EL2. The light emitting element ED according to an embodiment may include a first compound of an embodiment, which will be described in more detail later, in the emission layer EML. In some embodiments, the polycyclic compound of an embodiment may be referred to as a first compound herein.

The light emitting element ED may include a hole transport region HTR, an emission layer EML, and an electron transport region ETR, which are sequentially stacked in the stated order, as the at least one functional layer. Referring to FIG. 3, the light emitting element ED according to an embodiment may include a first electrode EL1, a hole transport region HTR, an emission layer EML, an electron transport region ETR, and a second electrode EL2. In some embodiments, the light emitting element ED according to an embodiment may include a polycyclic compound of an embodiment, which will be described in more detail later, in the emission layer EML.

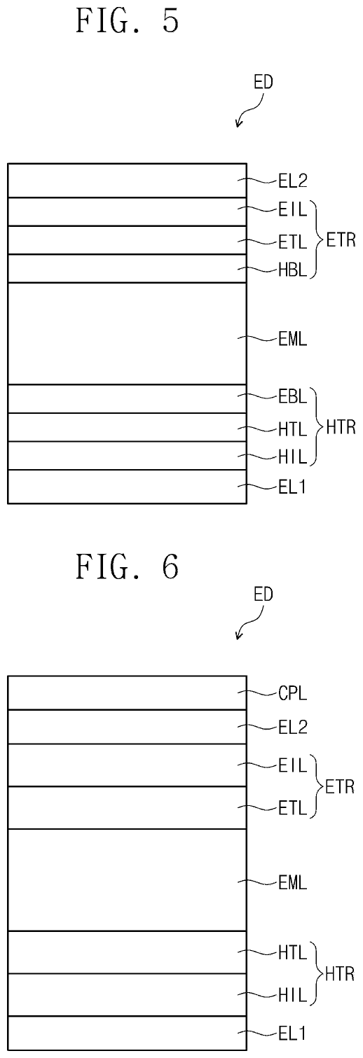

FIG. 4 shows, compared with FIG. 3, a cross-sectional view of a light emitting element ED of an embodiment in which the hole transport region HTR includes a hole injection layer HIL and a hole transport layer HTL, and the electron transport region ETR includes an electron injection layer EIL and an electron transport layer ETL. In addition, FIG. 5 shows, compared with FIG. 3, a cross-sectional view of a light emitting element ED of an embodiment in which the hole transport region HTR includes a hole injection layer HIL, a hole transport layer HTL, and an electron blocking layer EBL, and the electron transport region ETR includes an electron injection layer EIL, an electron transport layer ETL, and a hole blocking layer HBL. FIG. 6 shows, compared with FIG. 4, a cross-sectional view of a light emitting element ED of an embodiment, in which a capping layer CPL disposed on the second electrode EL2 is provided.

In an embodiment, the emission layer EML may include a first compound that contains a core portion having at least two boron atoms as ring-forming atoms and having a broad plate-shaped skeleton, and substituents substituted in the core portion and each positioned para to the boron atoms (e.g., each of the boron atoms has a substituent substituted in the core portion positioned para to the respective boron atom).

In an embodiment, the emission layer may include at least one of a second compound, a third compound, or a fourth compound. The second compound may include a substituted or unsubstituted carbazole. The third compound may include a hexagonal ring containing at least one nitrogen atom as a ring-forming atom. The fourth compound may be an organometallic complex compound. The fourth compound may be an organometallic complex compound containing platinum (Pt) or iridium (Ir) as a central metal.

In the light emitting element ED according to an embodiment, the first electrode EL1 has conductivity (e.g., is a conductor). The first electrode EL1 may be formed of a metal material, a metal alloy or a conductive compound. The first electrode EL1 may be an anode or a cathode. However, the embodiment of the present disclosure is not limited thereto. In some embodiments, the first electrode EL1 may be a pixel electrode. The first electrode EL1 may be a transmissive electrode, a transflective electrode, or a reflective electrode. The first electrode may include at least one selected from Ag, Mg, Cu, Al, Pt, Pd, Au, Ni, Nd, Ir, Cr, Li, Ca, LiF, Mo, Ti, W, In, Sn, Zn, compounds of two or more selected therefrom, mixtures of two or more selected therefrom, and an oxide thereof.

When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/AI (a stacked structure of LiF and Al), Mo, Ti, W, a compound thereof, or a mixture thereof (e.g., a mixture of Ag and Mg). In some embodiments, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, the first electrode EL1 may have a three-layer structure of ITO/Ag/ITO, but the present disclosure is not limited thereto, and the first electrode EL1 may include one or more of the above-described metal materials, a combination of two or more metal materials selected from the above-described metal materials, and/or one or more of oxides of the above-described metal materials. The first electrode EL1 may have a thickness of about 700 A to about 10000 A. For example, the first electrode EL1 may have a thickness of 1000 A to about 3000 A.

The hole transport region HTR is provided on the first electrode EL1. The hole transport region HTR may have a single layer formed of a single material, a single layer formed of a plurality of different materials, or a multilayer structure having a plurality of layers formed of a plurality of different materials.

The hole transport region HTR may include at least one selected from among a hole injection layer HIL, a hole transport layer HTL, a buffer layer, a light emitting auxiliary layer, and an electron blocking layer EBL. In some embodiments, although not shown, the hole transport region HTR may include a plurality of hole transport layers that are stacked over one another.

In some embodiments, alternatively, the hole transport region HTR may have a single-layer structure formed of the hole injection layer HIL or the hole transport layer HTL, or a single-layer structure formed of a hole injection material or a hole transport material. For example, the hole transport region HTR may have a single-layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in the respective stated order from the first electrode EL1, but the embodiment of the present disclosure is not limited thereto.

The hole transport region HTR may have, for example, a thickness of about 50 A to about 15000 A. The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1.

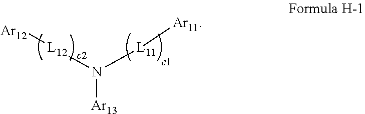

In Formula H-1 above, L₁₁ and L₁₂ may each independently be a direct linkage, a substituted or unsubstituted arylene group having 6 to 30 ring-forming carbon atoms, or a substituted or unsubstituted heteroarylene group having 2 to 30 ring-forming carbon atoms. c1 and c2 may each independently be an integer of 0 to 10. When c1 or c2 is an integer of 2 or greater, a plurality of L₁₁'s and L₁₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁₁ and Ar₁₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₁₃ may each independently be a substituted or unsubstituted aryl group having 6 to 30 ring-forming carbon atoms.

A compound represented by Formula H-1 above may be a monoamine compound (e.g., a compound including a single amine group). In some embodiments, the compound represented by Formula H-1 may be a diamine compound in which at least one of Ar₁₁ to Ar₁₃ includes an amine group as a substituent. In some embodiments, the compound represented by Formula H-1 may be a carbazole-based compound in which Ar₁ and/or Ar₂ includes a substituted or unsubstituted carbazole group or a fluorene-based compound in which Ar₁ and/or Ar₂ includes a substituted or unsubstituted fluorene-based group.

The compound represented by Formula H-1 may be any one of the compounds from Compound Group H. However, the compounds listed in Compound Group H are presented as an example, and the compound represented by Formula H-1 is not limited to the those listed in Compound Group H.

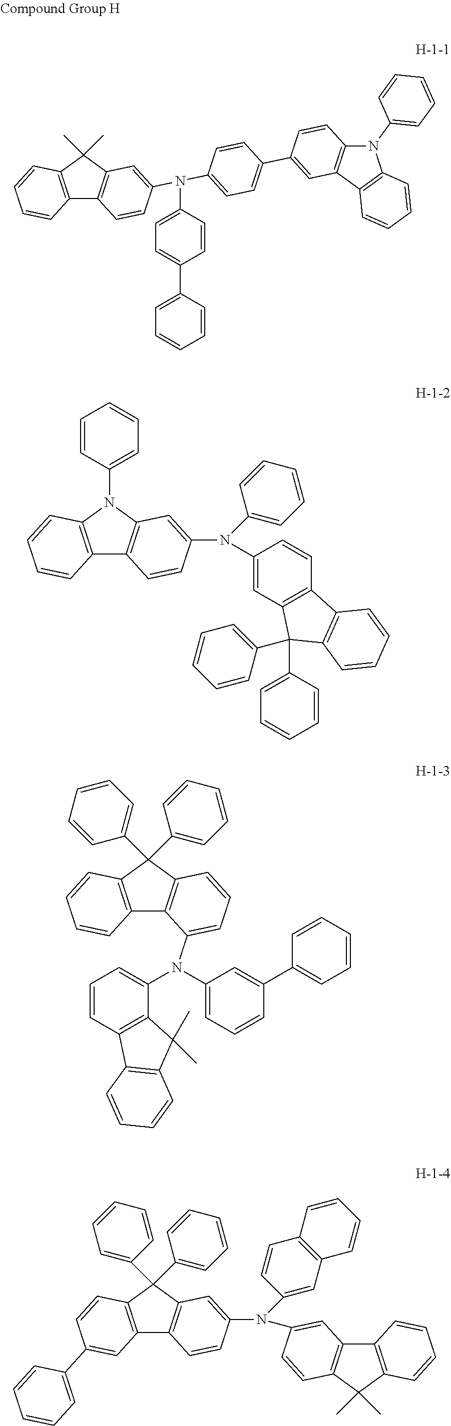 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

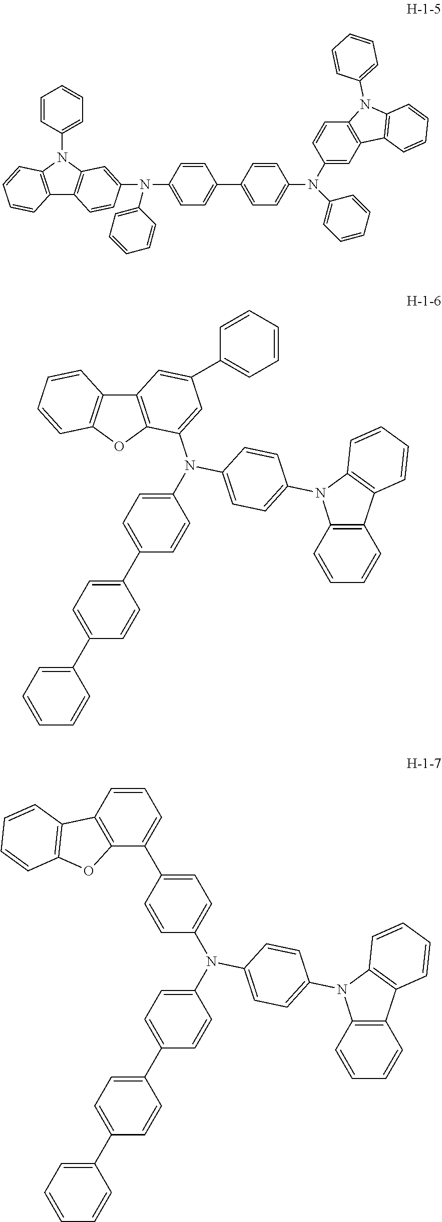 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

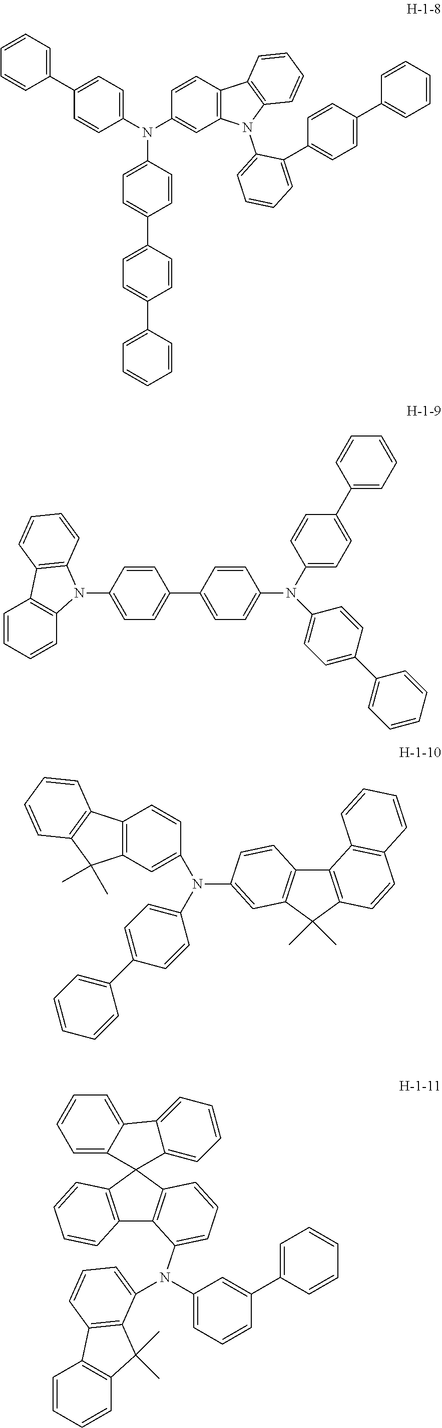 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21]

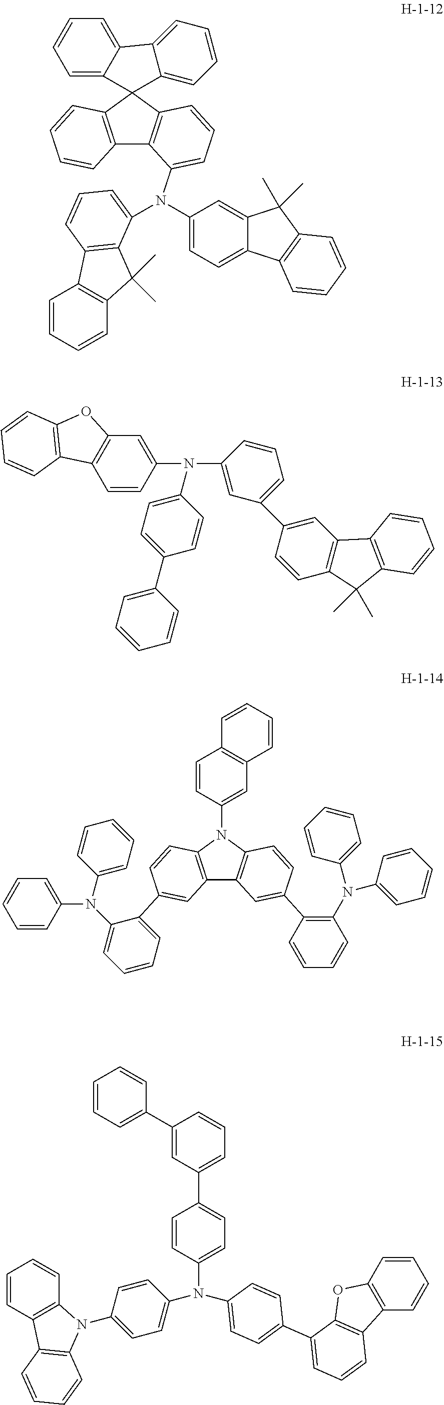 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

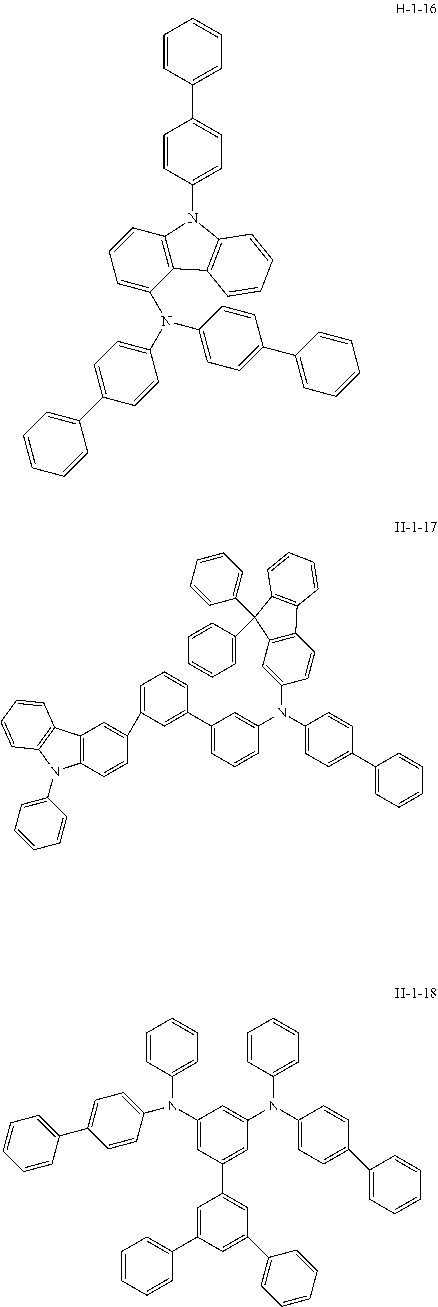 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

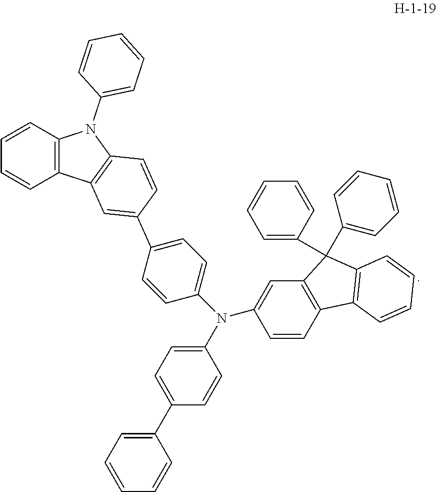 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine] (m-MTDATA), 4,4′,4′-tris(N,N-diphenylamino)triphenylamine (TDATA), 4,4′,4″-tris[N(1-naphthyl)-N-phenylamino]-triphenylamine (1-TNATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-I-yl)-N,N′-diphenyl-benzidine (NPB or NPD, a-NPD), triphenylamine-containing polyetherketone (TPAPEK), 4-isopropyl-4′-methyldiphenyliodonium tetrakis(pentafluorophenyl)borate, dipyrazino[2,3-f: 2′,3′-h]quinoxaline-2,3,6,7,10,11-hexacarbonitrile (HATCN), etc.

The hole transport region HTR may include carbazole-based derivatives such as N-phenyl carbazole and/or polyvinyl carbazole, fluorene-based derivatives, triphenylamine-based derivatives such as 4,4′,4″-tris(N-carbazolyl)triphenylamine (TCTA), N,N′-bis(3-methylphenyl)-N,N′-diphenyl-[1,1′-biphenyl]-4,4′-diamine (TPD), N,N′-di(naphthalen-1-yl)-N,N′-diphenyl-benzidine (NPB), 4,4′-Cyclohexylidene bis[N,N-bis(4-methylphenyl)benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-Butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the compounds of the hole transport region described above in at least one selected from among the hole injection layer HIL, the hole transport layer HTL, and the electron blocking layer EBL.

The hole transport region HTR may have a thickness of about 100 A to about 10000 A, for example, about 100 A to about 5000 A. When the hole transport region HTR includes the hole injection layer HIL, the hole injection layer HIL may have a thickness of, for example, about 30 A to about 1000 A. When the hole transport region HTR includes the hole transport layer HTL, the hole transport layer HTL may have a thickness of about 30 A to about 1000 A. When the hole transport region HTR includes the electron blocking layer EBL, the electron blocking layer EBL may have a thickness of, for example, about 10 A to about 1000 A. When the thicknesses of the hole transport region HTR, the hole injection layer HIL, the hole transport layer HTL, and the electron blocking layer EBL satisfy the above-described ranges, satisfactory hole transport properties may be obtained without a substantial increase in driving voltage.

The hole transport region HTR may further include, in addition to the above-described materials, a charge generation material to increase conductivity. The charge generation material may be uniformly or non-uniformly dispersed in the hole transport region HTR. The charge generation material may be, for example, a p-dopant. The p-dopant may include one or more of halogenated metal (e.g., metal halide) compounds, quinone derivatives, metal oxides, and cyano group-containing compounds, but the embodiment of the present disclosure is not limited thereto. For example, non-limiting examples of the p-dopant may include one or more halogenated metal compounds such as Cul and/or Rbl, quinone derivatives such as tetracyanoquinodimethane (TCNQ) and/or 2,3,5,6-tetrafluoro-7,7,8,8-tetracyanoquinodimethane (F4-TCNQ), metal oxides such as tungsten oxides and/or molybdenum oxides, cyano group-containing compounds such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc.

As described above, the hole transport region HTR may further include a buffer layer and/or an electron blocking layer EBL in addition to the hole injection layer HIL and the hole transport layer HTL. The buffer layer may compensate a resonance distance according to wavelengths of light emitted from an emission layer EML, and may thus increase light emitting efficiency. Materials which may be included in the hole transport region HTR may be utilized as materials included in the buffer layer. The electron blocking layer EBL is a layer that serves to prevent or reduce the injection of electrons from the electron transport region ETR to the hole transport region HTR. The light emitting auxiliary layer may improve charge balance between holes and electrons. When the hole transport region HTR includes the electron blocking layer EBL, the electron blocking layer EBL may function as a light emitting auxiliary layer.

The emission layer EML is provided on the hole transport region HTR. The emission layer EML may have, for example, a thickness of about 100 A to about 1000 A or about 100 A to about 300 A. The emission layer EML may have a single layer formed of a single material, a single layer formed of a plurality of different materials, or a multilayer structure having a plurality of layers formed of a plurality of different materials.

In the light emitting element ED according to an embodiment, the emission layer EML may include a plurality of light emitting materials. In an embodiment, the emission layer may include a first compound, and at least one of a second compound, a third compound, or a fourth compound. In the light emitting element ED according to an embodiment, the emission layer EML may include at least one host and at least one dopant. For example, the emission layer EML according to an embodiment may include a first dopant and may include a first host and a second host that are different from each other.

In an embodiment, the emission layer EML may include a first compound represented by Formula 1. The first compound corresponds to a polycyclic compound according to an embodiment.

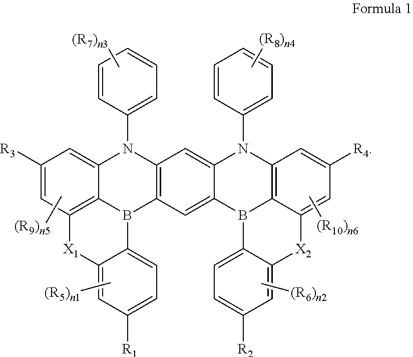

In Formula 1, one of X₁ or X₂ may be O or S and the other one of X₁ or X₂ may be NRₓ, O, or S. In the polycyclic compound according to an embodiment, X₁ and X₂ may be the same or different. For example, in an embodiment, one of X₁ or X₂ may be O and the other of X₁ or X₂ may be NRₓ, O, or S. In some embodiments, one of X₁ or X₂ may be S and the other of X₁ or X₂ may be NRₓ, O, or S.

In an embodiment, Rₓ may be a substituted or unsubstituted aryl group having 6 to 30 ring-forming carbon atoms, or a substituted or unsubstituted heteroaryl group having 2 to 30 ring-forming carbon atoms. For example, Rₓ may be a substituted or unsubstituted phenyl group, or a substituted or unsubstituted biphenyl group. However, the embodiment of the present disclosure is not limited thereto.

In Formula 1, R₁ to R₄ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. In some embodiments, when each of R₁ to R₄ is a heteroaryl group, a hetero atom of O, S, or N may be included as a ring-forming atom.

In an embodiment, R₁ to R₄ may each independently be a substituted or unsubstituted alkyl group having 1 to 6 carbon atoms, a substituted or unsubstituted aryl group having 6 to 20 ring-forming carbon atoms, or a substituted or unsubstituted heteroaryl group having 2 to 15 ring-forming carbon atoms, and/or bonded to an adjacent group to form a ring. For example, R₁ to R₄ may each independently be a substituted or unsubstituted t-butyl group, a substituted or unsubstituted phenyl group, a substituted or unsubstituted biphenyl group, a substituted or unsubstituted carbazole group, or a substituted or unsubstituted dibenzofuran group, and/or R₃ and/or R₄ may be bonded to an adjacent R₉ or R₁₀ to form a heterocycle of dihydrobenzofuran. However, in the polycyclic compound of an embodiment, when R₃ and R₄ are a substituted or unsubstituted carbazole group, the nitrogen atom of the carbazole group is not bonded to a benzene ring (e.g., a case in which the nitrogen atom of the carbazole group being bonded to a benzene ring is excluded).

In the polycyclic compound of an embodiment, R₁ and R₂ may each independently be represented by any one from among R-1 to R-7, and/or bonded to an adjacent group to form a ring represented by R-9. In some embodiments, R₃ and R₄ may each independently be represented by any one from among R-1 to R-5, and R-8, and/or bonded to an adjacent group to form a ring represented by R-9. In R-1 to R-9, “*-” may be a site where R₁ to R₄ are linked to Formula 1 above. In R-9, “*′-” may be a site where a group adjacent to each of R₁ to R₄ (e.g., the adjacent group bonded with a corresponding one of R₁ to R₄) is linked to Formula 1.

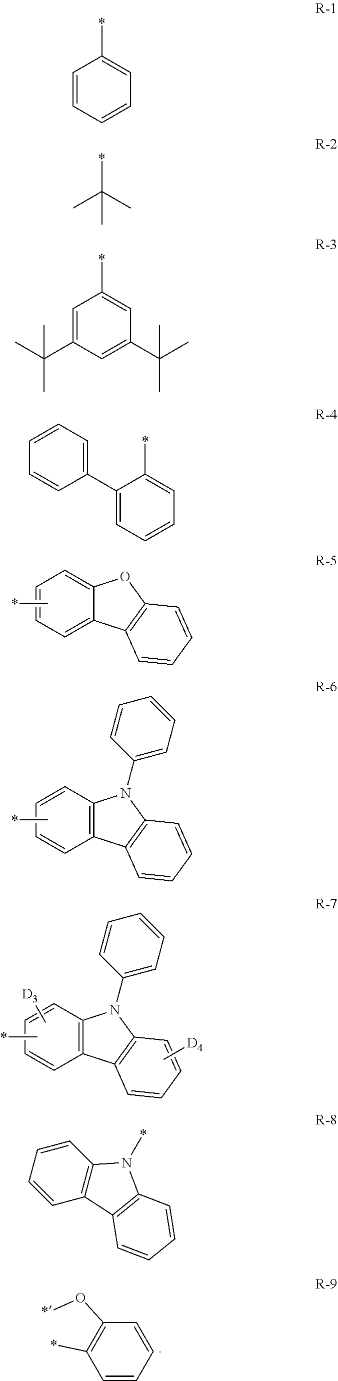

In Formula 1, R₅ to R₈ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In an embodiment, R₅ to R₈ may each independently be a hydrogen atom, a deuterium atom, a substituted or unsubstituted alkyl group having 1 to 6 carbon atoms, a substituted or unsubstituted aryl group having 6 to 20 ring-forming carbon atoms, or a substituted or unsubstituted heteroaryl group having 2 to 15 ring-forming carbon atoms, and/or bonded to an adjacent group to form a ring. For example, R₅ and R₆ may each independently be a hydrogen atom, a deuterium atom, a substituted or unsubstituted t-butyl group, or a substituted or unsubstituted phenyl group, and/or bonded to an adjacent group to form a ring. In some embodiments, R₇ to R₈ may each independently be a hydrogen atom, a deuterium atom, an unsubstituted t-butyl group, or a substituted or unsubstituted phenyl group.

In Formula 1, R₉ and R₁₀ may each independently be a hydrogen atom or a deuterium atom, or bonded to an adjacent group to form a ring. For example, R₉ and R₁₀ may each independently be a hydrogen atom or a deuterium atom, or R₉ and/or R₁₀ may each be bonded to adjacent R₃ or R₄ to form a heterocycle of dihydrobenzofuran. That is, in an embodiment, R₉ and R₃ may be bonded to each other to form a dihydrobenzofuran, and/or R₁₀ and R₄ may be bonded to each other to form a dihydrobenzofuran.

In Formula 1, n1 and n2 may each independently be an integer of 0 to 3. When n1 is an integer of 2 or greater, a plurality of R₅'s may all be the same or at least one may be different from the others. In addition, when n2 is an integer of 2 or greater, a plurality of R₆'s may all be the same or at least one may be different from the others. For example, n1 and n2 may each independently be 0, 1, or 3. The case where n1 is 0 may be the same as the case where n1 is 3 and R₅ is a hydrogen atom. When n1 is 0, it may be understood that R₅ is not substituted in the polycyclic compound represented by Formula 1. The case where n2 is 0 may be the same as the case where n2 is 3 and R₆ is a hydrogen atom. When n2 is 0, it may be understood that R₆ is not substituted in the polycyclic compound represented by Formula 1.

In Formula 1, n3 and n4 may each independently be an integer of 0 to 5. When n3 is an integer of 2 or greater, a plurality of R₇'s may all be the same or at least one may be different from the others. In addition, when n4 is an integer of 2 or greater, a plurality of R₈'s may all be the same or at least one may be different from the others. For example, n3 and n4 may each independently be 0, 1, 2, or 3. The case where n3 is 0 may be the same as the case where n3 is 5 and R₇ is a hydrogen atom. When n3 is 0, it may be understood that R₇ is not substituted in the polycyclic compound represented by Formula 1. The case where n4 is 0 may be the same as the case where n4 is 5 and R₈ is a hydrogen atom. When n4 is 0, it may be understood that R₈ is not substituted in the polycyclic compound represented by Formula 1.

In Formula 1, n5 and n6 may each independently be an integer of 0 to 2. When n5 is 2, two R₉'s may be the same or different. In addition, when n6 is 2, two R₁₀'s may be the same or different. For example, n5 and n6 may each independently be 0 or 1. The case where n5 is 0 may be the same as the case where n5 is 2 and R₉ is a hydrogen atom. When n5 is 0, it may be understood that R₉ is not substituted in the polycyclic compound represented by Formula 1. The case where n6 is 0 may be the same as the case where n6 is 2 and R₁₀ is a hydrogen atom. When n6 is 0, it may be understood that R₁₀ is not substituted in the polycyclic compound represented by Formula 1.

In some embodiments, the polycyclic compound according to an embodiment may include at least one deuterium atom as a substituent. For example, in an embodiment, at least one selected from among X1, X₂, and R₁ to R₁₀ in Formula 1 may include a deuterium atom or a substituent containing a deuterium atom. For example, in the polycyclic compound of an embodiment, which is represented by Formula 1, at least one of Rₓ, R₁ to R₄, R₉, or R₁₀ may be a substituent containing a deuterium atom, and at least one of R₅ to R₈ may be a deuterium atom or a substituent containing a deuterium atom.

The polycyclic compound of an embodiment, which is represented by Formula 1, may include a core portion of a fused ring, containing at least two boron atoms (B) as ring-forming atoms, and include substituents positioned para to the boron atoms at the core portion (e.g., each of the boron atoms at the core portion has a substituent positioned para to the respective boron atom). In the polycyclic compound of an embodiment, substituents are positioned para to the boron atoms to allow pi (Π) electrons to be stably supplied to the boron atoms by conjugation or hyper conjugation, resulting in reduced electron deficiency, and accordingly, the boron atoms are less likely to be unstable. In the polycyclic compound of an embodiment, as hyper conjugation is prolonged, radicals may be stabilized in a wider space, thereby contributing to increased lifespan of a light emitting element.

In the polycyclic compound of an embodiment, a benzene ring is further bonded and/or fused in the molecular structure, and the core portion includes a structure in which at least one oxygen atom or one sulfur atom is introduced. Accordingly, the polycyclic compound of an embodiment has a deep HOMO (Highest Occupied Molecular Orbital) energy level to prevent or reduce trouble caused by hole traps that restrict and obstruct hole movement, thereby contributing to increased lifespan of a light emitting element. In some embodiments, the polycyclic compound of an embodiment may contribute to shortening the wavelength of a light emitting element. As used herein, “shallow” in relation to energy level may indicate that the absolute value of the energy level decreases in a negative direction from a vacuum level. As used herein, “deep” in relation to energy level may indicate that the absolute value of the energy level increases in a negative direction from a vacuum level.

In some embodiments, due to the nature of polycyclic compounds utilizing multiple resonance of boron/nitrogen atoms, a pattern with high/low electron density is repeated for each atom up to the range of a benzene ring directly linked to the boron atoms. Given that degradation products and decomposition products in an element are mostly present in the form of radicals, the high or low electron density of the benzene ring directly linked to the boron atoms may likely cause side reactions with radicals. Accordingly, in the polycyclic compound of an embodiment, which is represented by Formula 1, substituents R₁, R₂, R₃, and R₄ substituted on four benzene rings directly linked to the boron atoms also serve as sterically hindered substituents that prevent or reduce the side reactions.

For example, the polycyclic compound of an embodiment has a structure including a core portion of a boron-containing fused ring, and including substituents, such as an oxygen atom, a sulfur atom, an alkyl group, an aryl group, a heteroaryl group, and/or the like, positioned para to the boron atoms, and may thus exhibit increased stability, light extraction efficiency, and delayed fluorescence of the compound. Accordingly, the polycyclic compound of an embodiment may contribute to increased light emitting efficiency and lifespan.

In an embodiment, the polycyclic compound represented by Formula 1 may be represented by Formula 1-1 or Formula 1-2. In Formulas 1-1 and 1-2, the same descriptions as those described above in Formula 1 may be applied to R₁ to R₁₀, and n1 to n6.

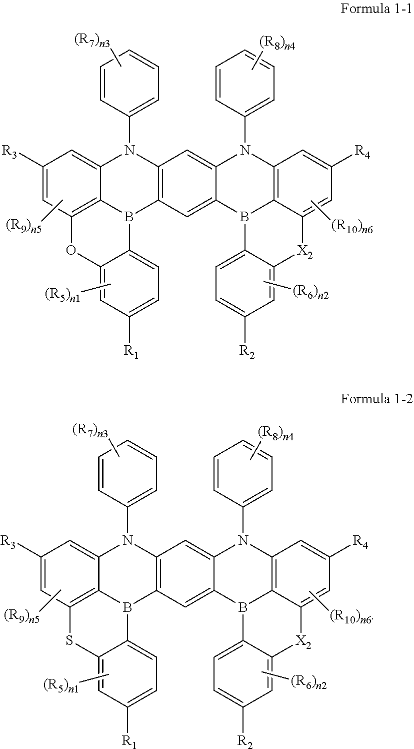

In Formulas 1-1 and 1-2, X₂ may be NRₓ₁, O, or S. Rₓ₁ may be a substituted or unsubstituted aryl group having 6 to 30 ring-forming carbon atoms, or a substituted or unsubstituted heteroaryl group having 2 to 30 ring-forming carbon atoms. For example, the polycyclic compound of an embodiment, which is represented by Formula 1-1 or Formula 1-2, may contain one oxygen atom (O) and one sulfur atom (S) as ring-forming atoms, may contain two oxygen atoms or two sulfur atoms as ring-forming atoms, or may contain one oxygen atom or one sulfur atom as ring-forming atoms.

In an embodiment, the polycyclic compound represented by Formula 1 may be represented by Formula 2. Formula 2 may specify a bonding position of R₅ and R₆ in Formula 1. In Formula 2, the same descriptions as those described above in Formula 1 may be applied to X₁, X₂, R₃, R₄, R₇ to R₁₀, and n3 to n6.

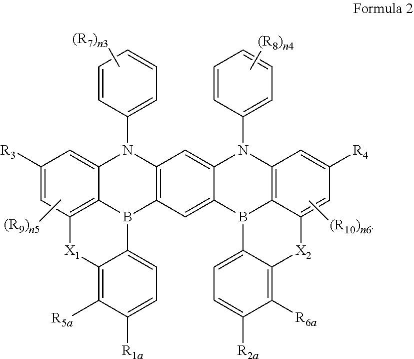

In Formula 2, R₁ₐ and R₂ₐ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. For example, when R₁ₐ and/or R₂ₐ are bonded to an adjacent group to form a ring, R₁ₐ may be bonded to adjacent R₅ₐ to form a ring, and/or R₂ₐ may be bonded to adjacent R₆ₐ to form a ring.

In Formula 2, R₅ₐ and R₆ₐ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. For example, when R₅ₐ and/or R₆ₐ are bonded to an adjacent group to form a ring, R₅ₐ may be bonded to adjacent R₁ₐ to form a ring, and/or R₆ₐ may be bonded to adjacent R₂ₐ to form a ring.

In an embodiment, the polycyclic compound represented by Formula 1 may be represented by Formula 3. Formula 3 may specify a bonding position of R₉ and R₁₀ in Formula 1. In Formula 3, the same descriptions as those described above in Formula 1 may be applied to X₁, X₂, R₁, R₂, R₅ to R₈, and n1 to n4.

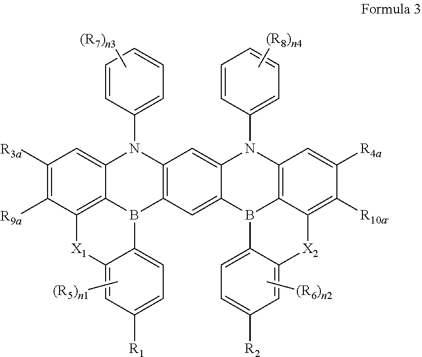

In Formula 3, R₃a and R₄ₐ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. For example, when R₃a and/or R₄a are bonded to an adjacent group to form a ring, R₃ₐ may be bonded to adjacent R₉ₐ to form a ring, and/or R₄ₐ may be bonded to adjacent R₁₀ₐ to form a ring.

In Formula 3, R₉ₐ and R₁₀ₐ may each independently be a hydrogen atom or a deuterium atom, or bonded to an adjacent group to form a ring. For example, when R₉a and/or R₁₀a are bonded to an adjacent group to form a ring, R₉ₐ may be bonded to adjacent R₃a to form a ring, and/or R₁₀ₐ may be bonded to adjacent R₄ₐ to form a ring.

In an embodiment, the polycyclic compound according to an embodiment, which is represented by Formula 1, may be represented by Formula 4. Formula 4 may specify a bonding position of R₇ and R₈ in Formula 1. In Formula 4, the same descriptions as those described above in Formula 1 may be applied to X₁, X₂, R₁ to R₆, R₉, R₁₀, n1, n2, n5, and n6.

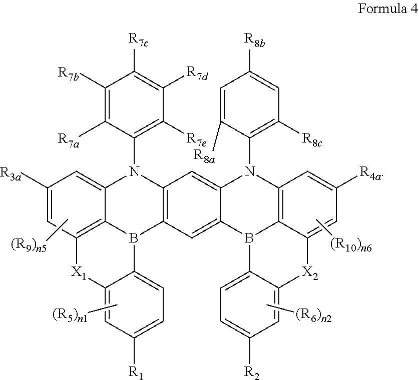

In Formula 4, R₇ₐ to R₇ₑ, and R₈ₐ to R_{8c} may each independently be a hydrogen atom, a deuterium atom, a substituted or unsubstituted alkyl group having 1 to 6 carbon atoms, or a substituted or unsubstituted aryl group having 6 to 20 ring-forming carbon atoms. For example, R₇ₐ to R₇ₑ, and R₈ₐ to R_{8c} may each independently be a hydrogen atom, a deuterium atom, a substituted or unsubstituted t-butyl group, or a substituted or unsubstituted phenyl group.

The first compound of an embodiment may be any of the compounds shown in Compound Group 1. The light emitting element ED according to an embodiment may include at least one of the compounds shown in Compound Group 1 in the emission layer EML.

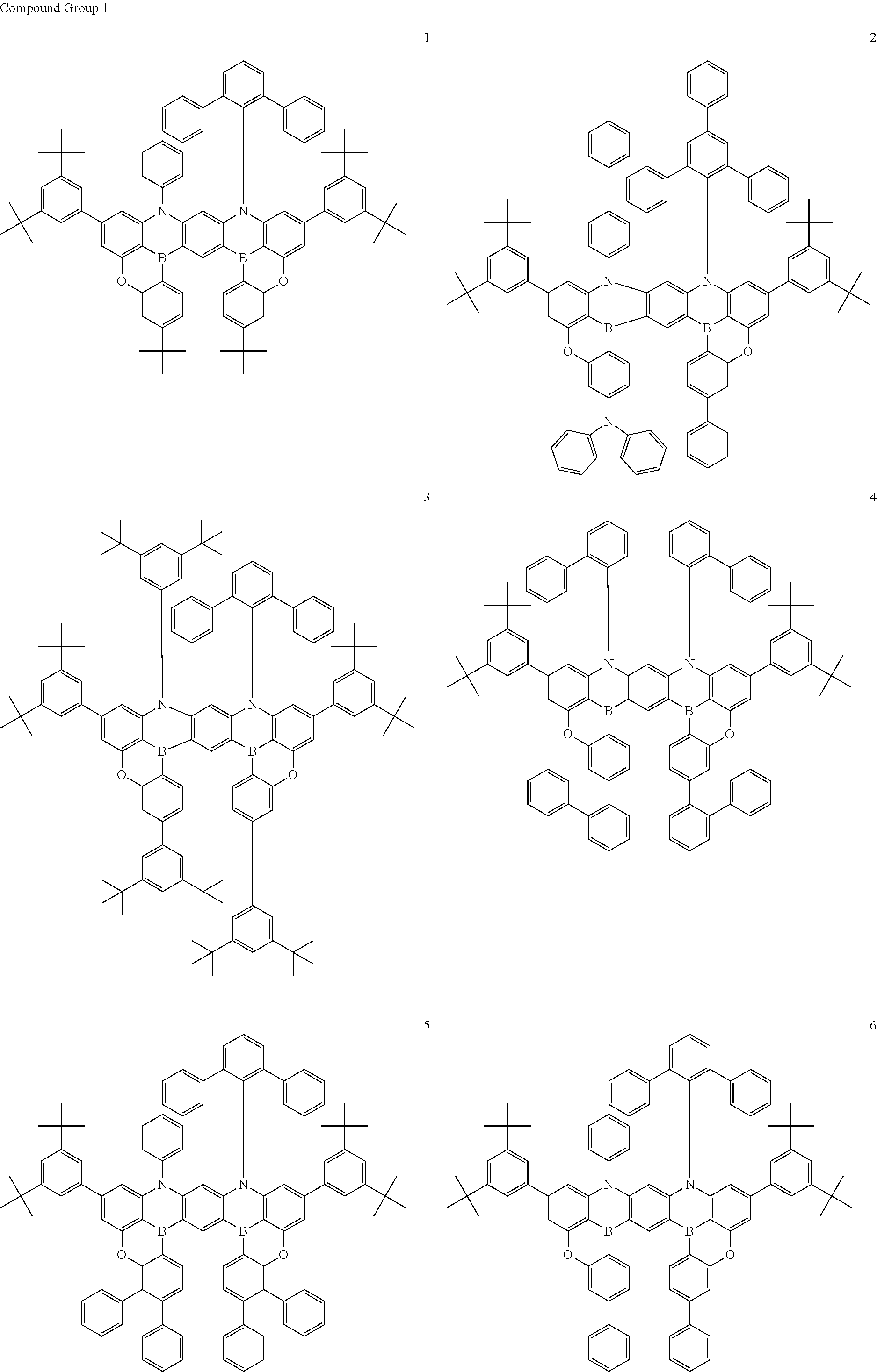

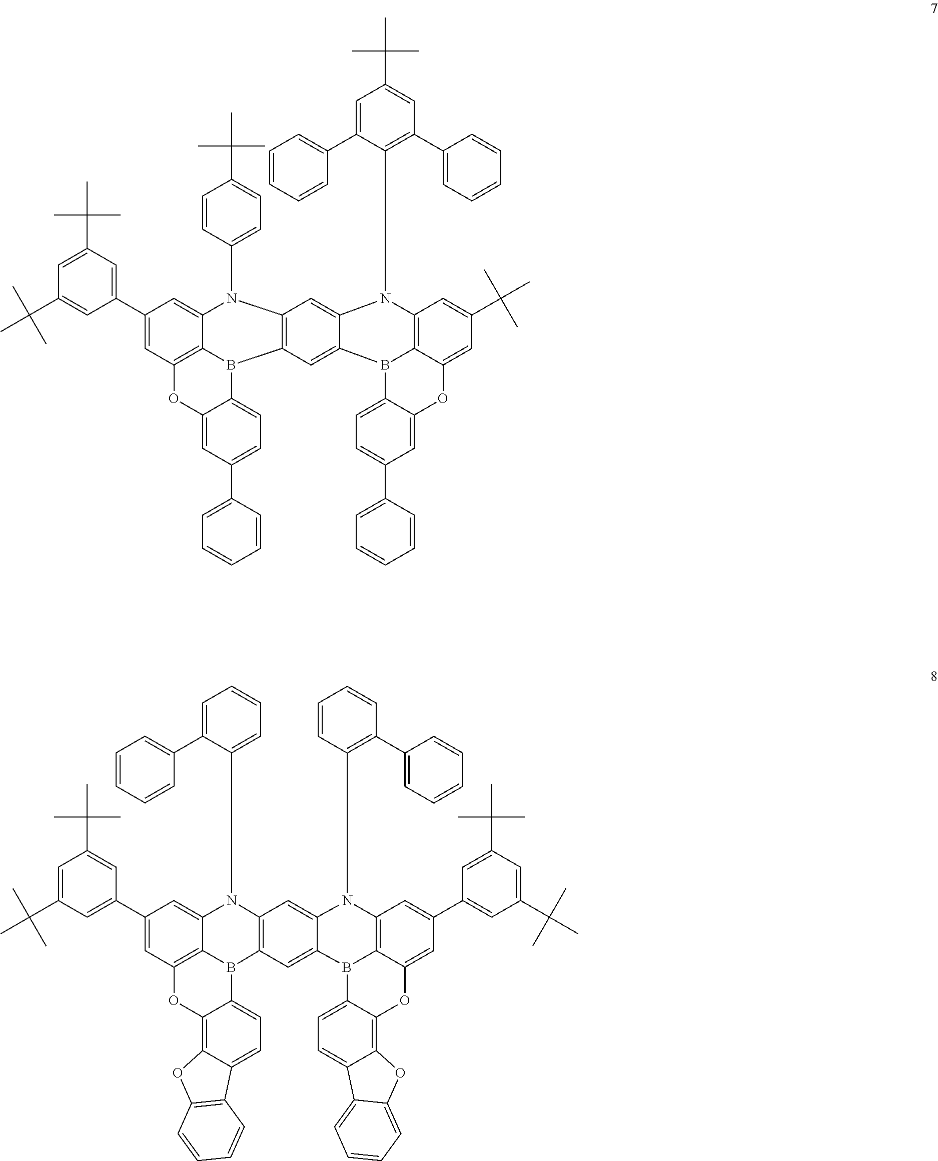

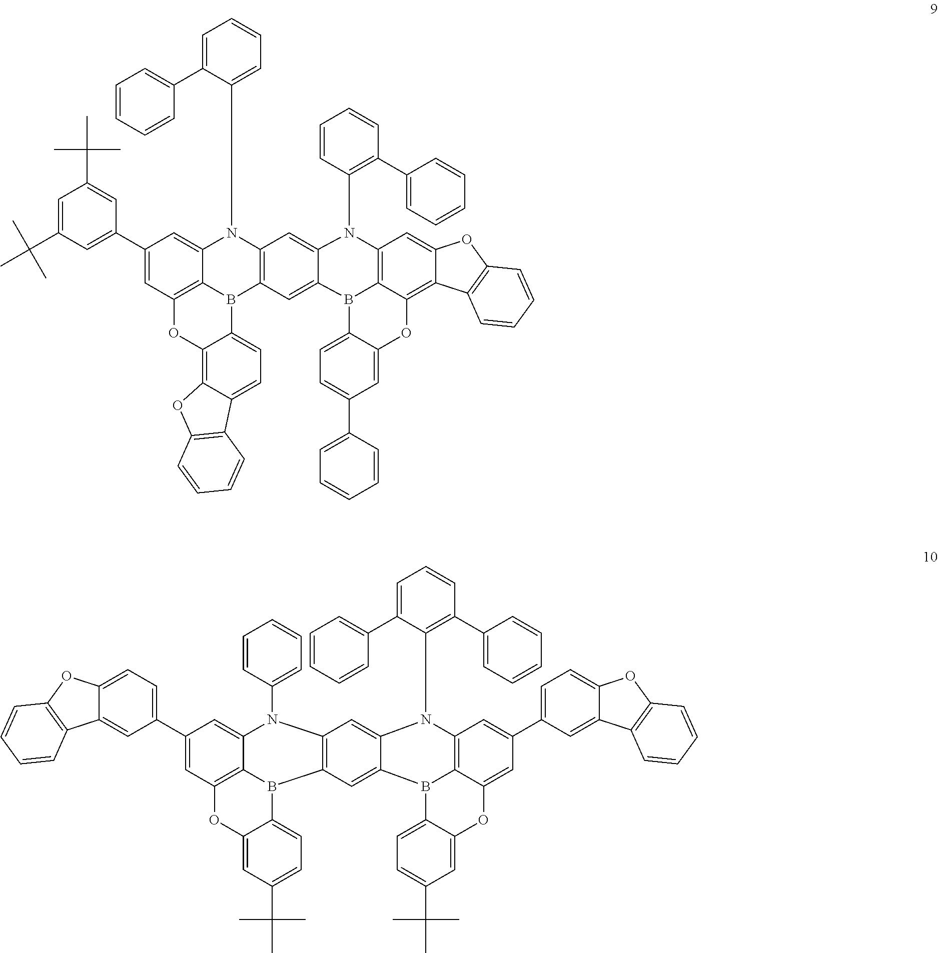 [SMILES: CC(C)(C)c1cc(-c2cc3c4c(c2)N(c2ccccc2-c2ccccc2)c2cc5c(cc2B4c2ccc4c(oc6ccccc64)c2O3)B2c3ccc(-c4ccccc4)cc3Oc3c2c(cc2oc4ccccc4c32)N5c2ccccc2-c2ccccc2)cc(C(C)(C)C)c1 ; CC(C)(C)c1ccc2c(c1)Oc1cc(-c3ccc4oc5ccccc5c4c3)cc3c1B2c1cc2c(cc1N3c1ccccc1)N(c1c(-c3ccccc3)cccc1-c1ccccc1)c1cc(-c3ccc4oc5ccccc5c4c3)cc3c1B2c1ccc(C(C)(C)C)cc1O3]

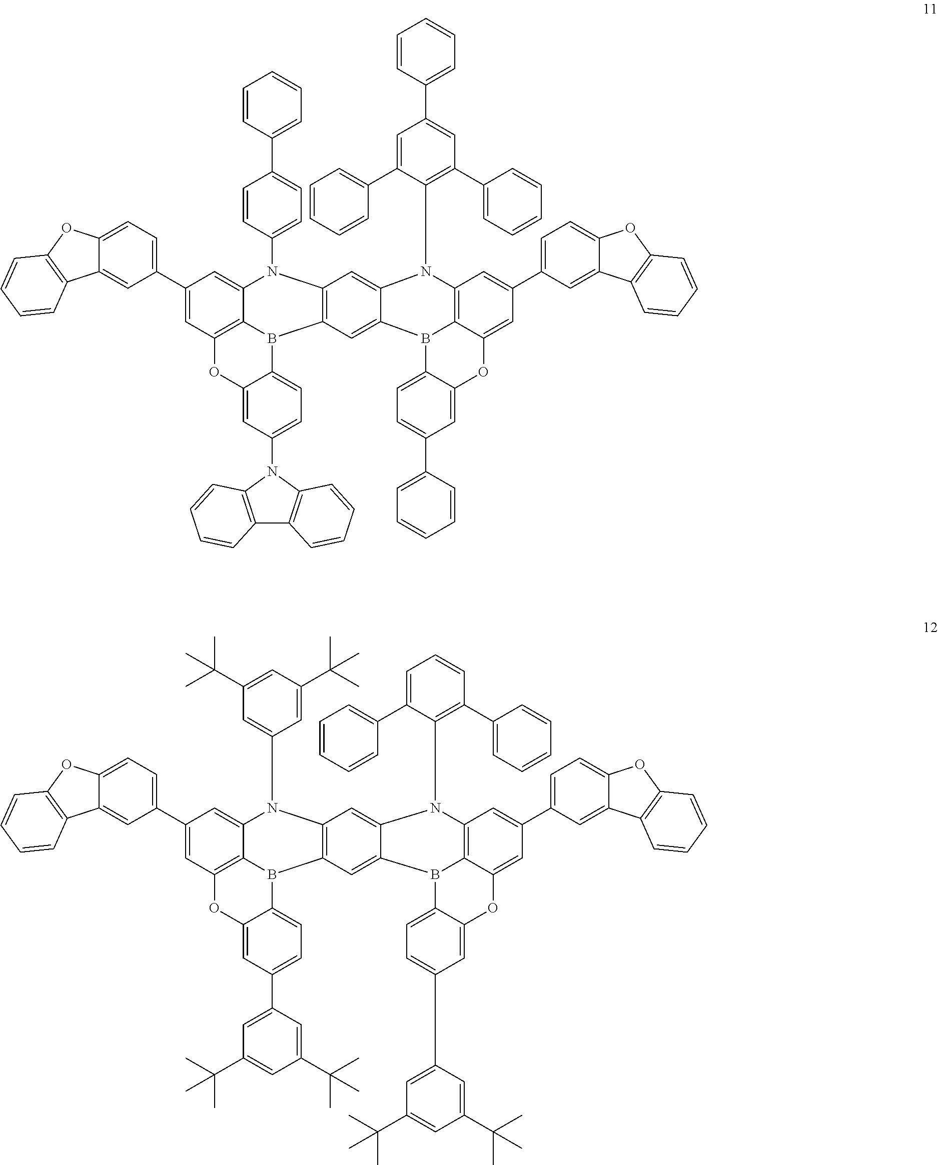 [SMILES: c1ccc(-c2ccc(N3c4cc5c(cc4B4c6ccc(-n7c8ccccc8c8ccccc87)cc6Oc6cc(-c7ccc8oc9ccccc9c8c7)cc3c64)B3c4ccc(-c6ccccc6)cc4Oc4cc(-c6ccc7oc8ccccc8c7c6)cc(c43)N5c3c(-c4ccccc4)cc(-c4ccccc4)cc3-c3ccccc3)cc2)cc1 ; CC(C)(C)c1cc(-c2ccc3c(c2)Oc2cc(-c4ccc5oc6ccccc6c5c4)cc4c2B3c2cc3c(cc2N4c2cc(C(C)(C)C)cc(C(C)(C)C)c2)N(c2c(-c4ccccc4)cccc2-c2ccccc2)c2cc(-c4ccc5oc6ccccc6c5c4)cc4c2B3c2ccc(-c3cc(C(C)(C)C)cc(C(C)(C)C)c3)cc2O4)cc(C(C)(C)C)c1]

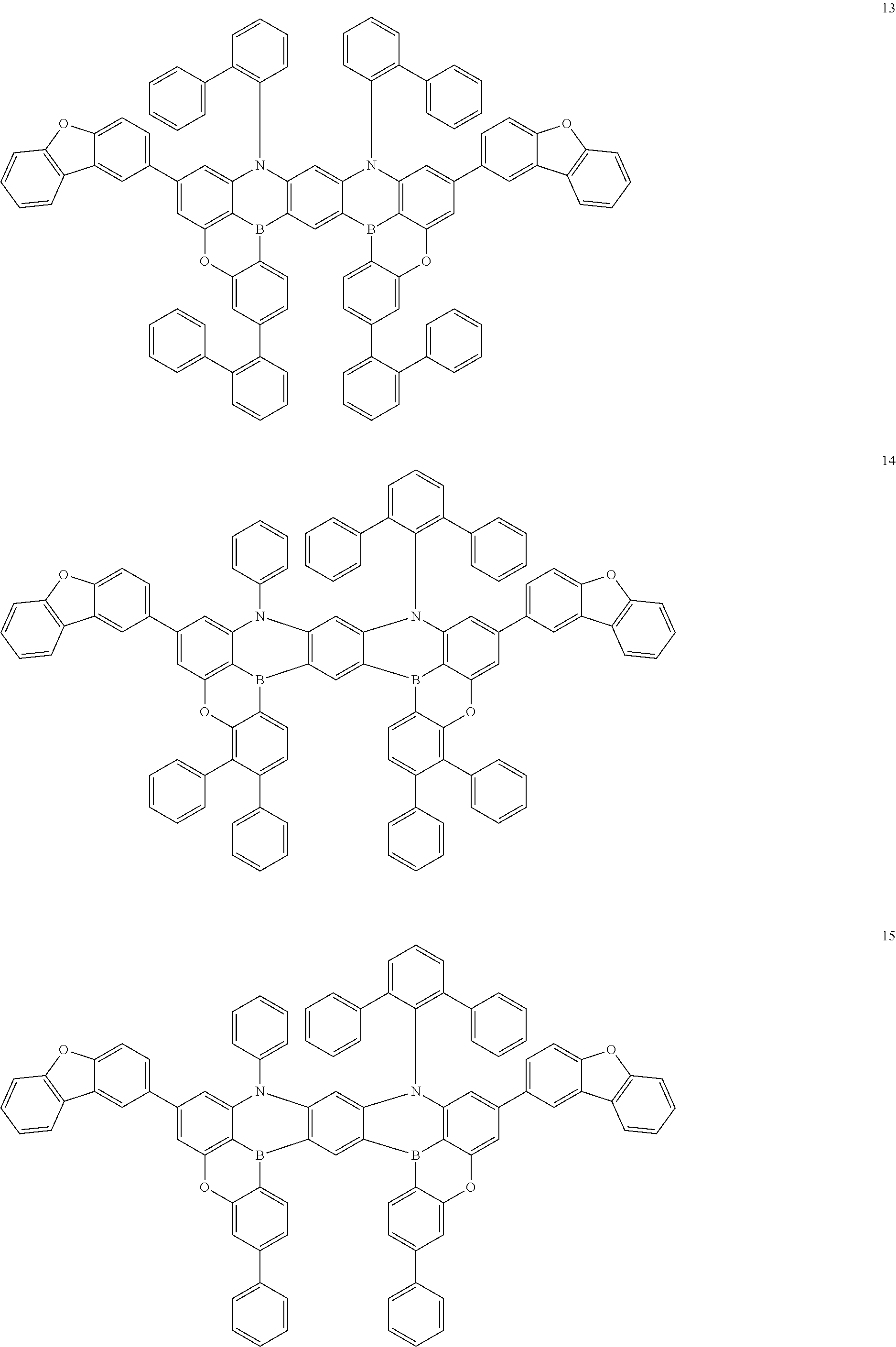

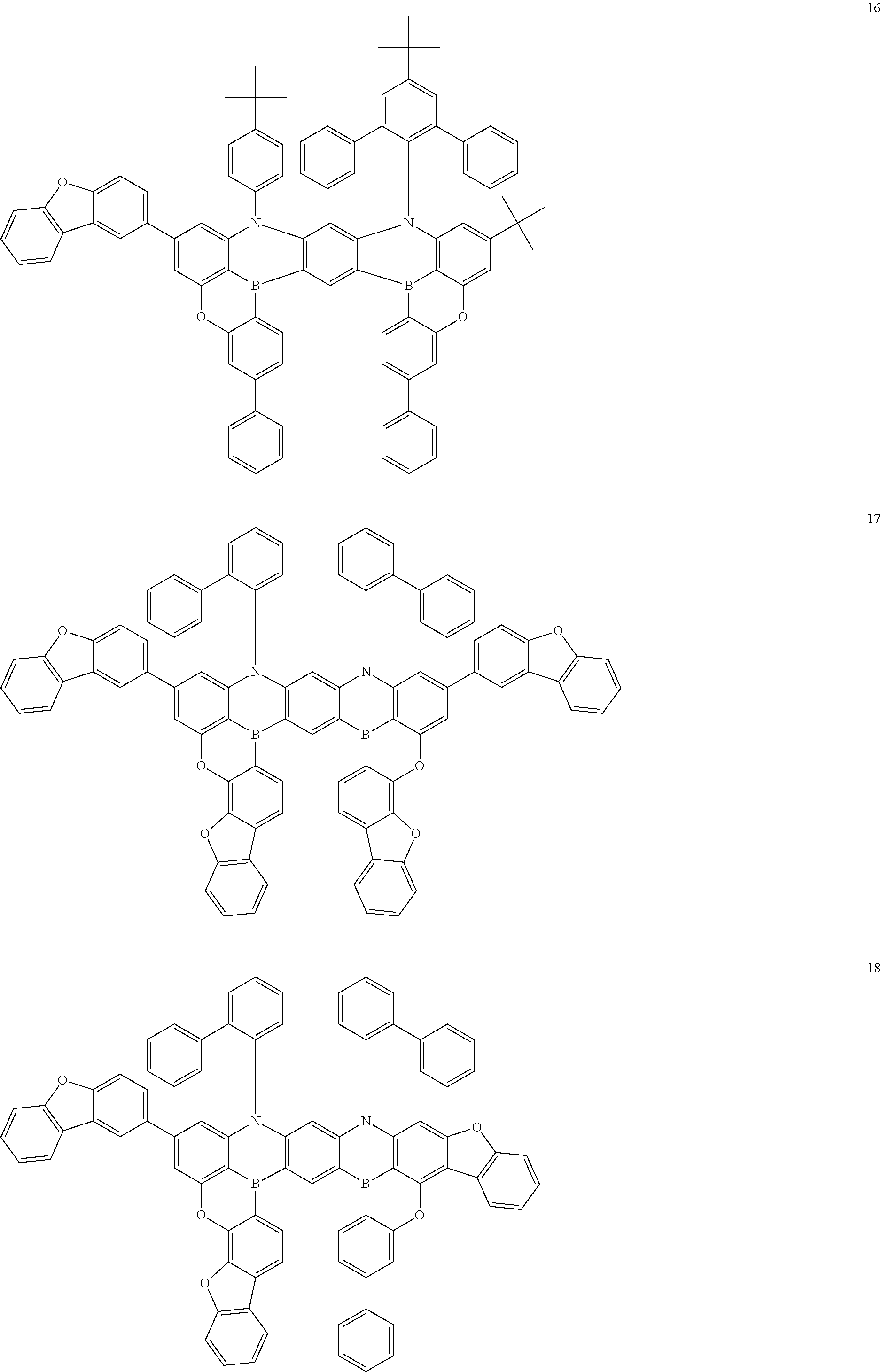 [SMILES: CC(C)(C)c1ccc(N2c3cc4c(cc3B3c5ccc(-c6ccccc6)cc5Oc5cc(-c6ccc7oc8ccccc8c7c6)cc2c53)B2c3ccc(-c5ccccc5)cc3Oc3cc(C(C)(C)C)cc(c32)N4c2c(-c3ccccc3)cc(C(C)(C)C)cc2-c2ccccc2)cc1 ; c1ccc(-c2ccccc2N2c3cc4c(cc3B3c5ccc6c(oc7ccccc76)c5Oc5cc(-c6ccc7oc8ccccc8c7c6)cc2c53)B2c3ccc5c(oc6ccccc65)c3Oc3cc(-c5ccc6oc7ccccc7c6c5)cc(c32)N4c2ccccc2-c2ccccc2)cc1 ; c1ccc(-c2ccc3c(c2)Oc2c4c(cc5oc6ccccc6c25)N(c2ccccc2-c2ccccc2)c2cc5c(cc2B34)B2c3ccc4c(oc6ccccc64)c3Oc3cc(-c4ccc6oc7ccccc7c6c4)cc(c32)N5c2ccccc2-c2ccccc2)cc1]

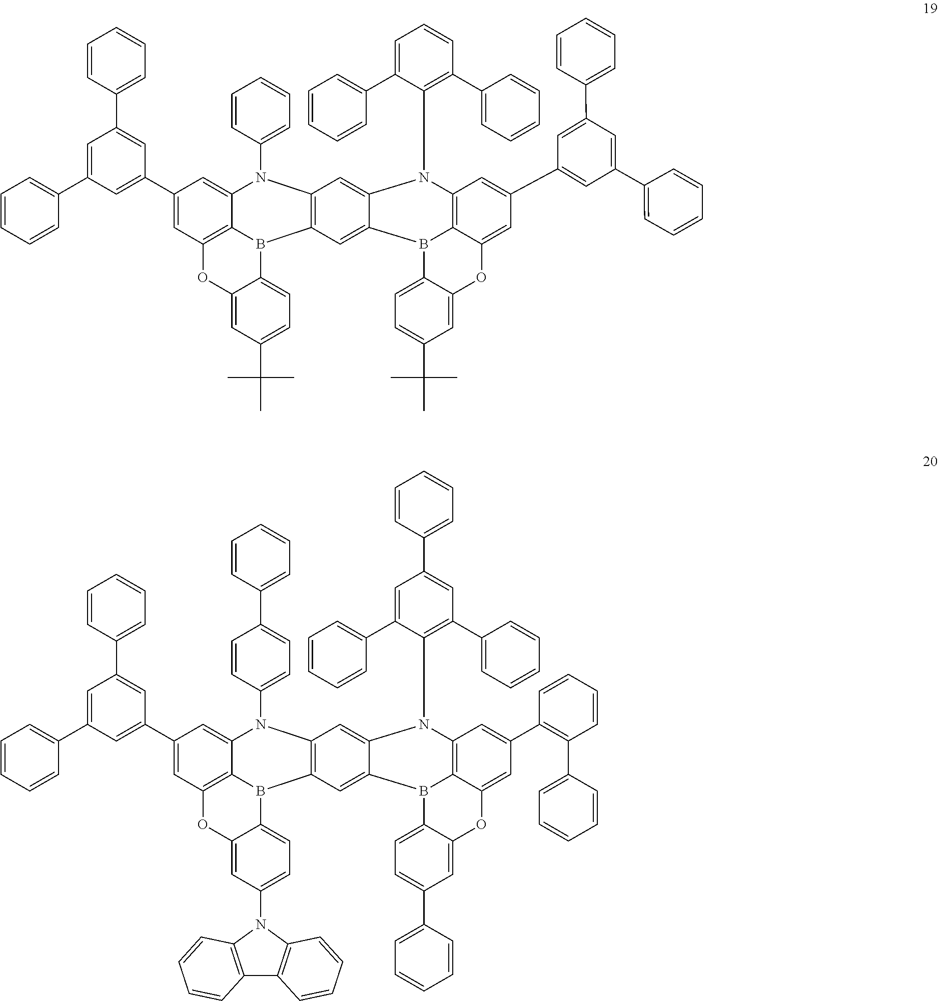 [SMILES: CC(C)(C)c1ccc2c(c1)Oc1cc(-c3cc(-c4ccccc4)cc(-c4ccccc4)c3)cc3c1B2c1cc2c(cc1N3c1ccccc1)N(c1c(-c3ccccc3)cccc1-c1ccccc1)c1cc(-c3cc(-c4ccccc4)cc(-c4ccccc4)c3)cc3c1B2c1ccc(C(C)(C)C)cc1O3 ; c1ccc(-c2ccc(N3c4cc5c(cc4B4c6ccc(-n7c8ccccc8c8ccccc87)cc6Oc6cc(-c7cc(-c8ccccc8)cc(-c8ccccc8)c7)cc3c64)B3c4ccc(-c6ccccc6)cc4Oc4cc(-c6ccccc6-c6ccccc6)cc(c43)N5c3c(-c4ccccc4)cc(-c4ccccc4)cc3-c3ccccc3)cc2)cc1]

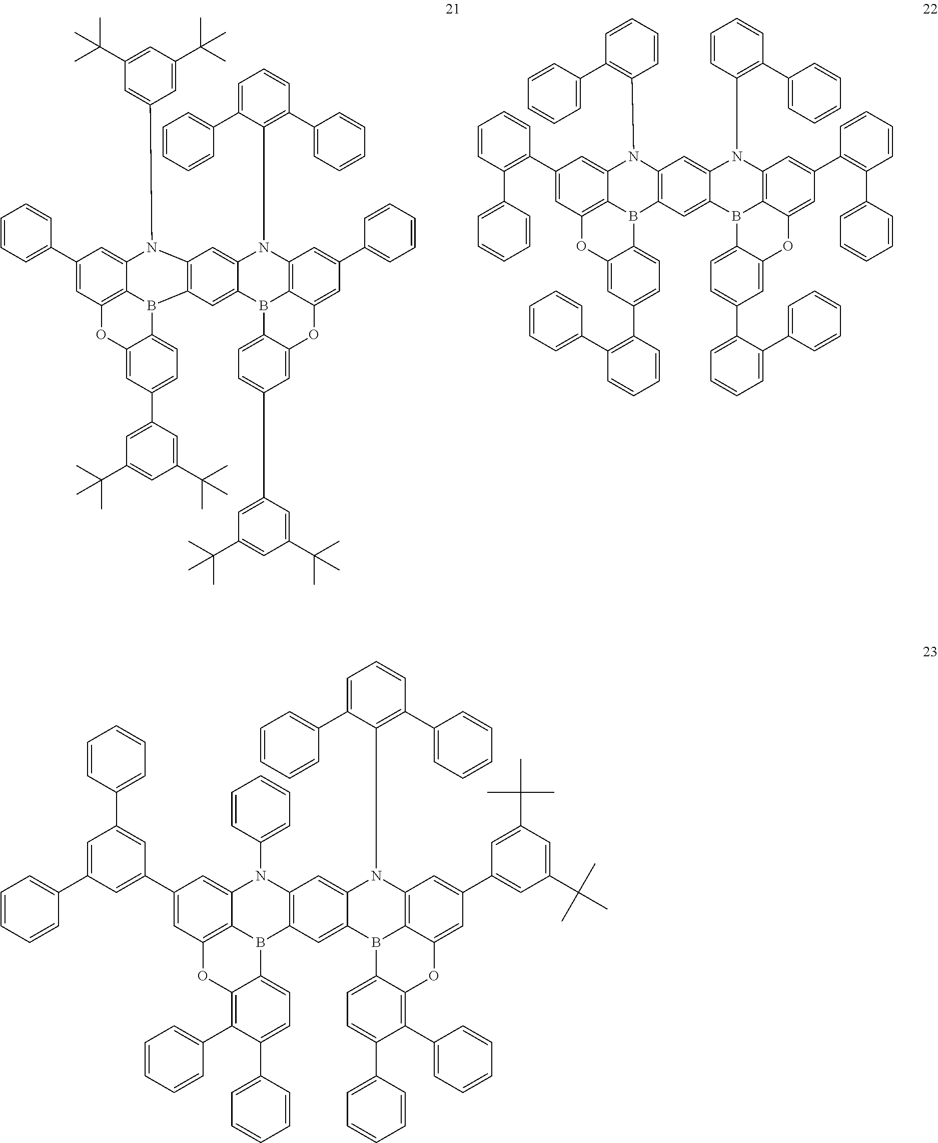

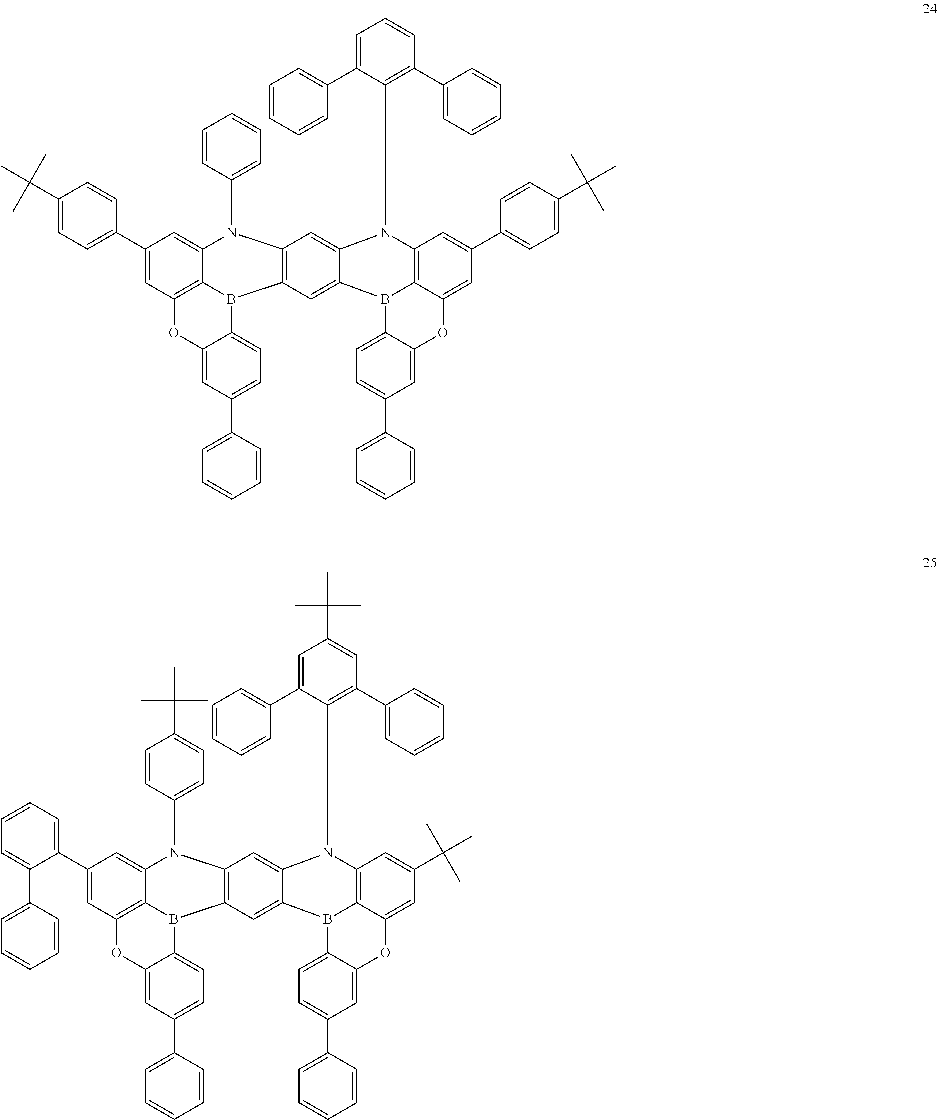 [SMILES: CC(C)(C)c1ccc(-c2cc3c4c(c2)N(c2ccccc2)c2cc5c(cc2B4c2ccc(-c4ccccc4)cc2O3)B2c3ccc(-c4ccccc4)cc3Oc3cc(-c4ccc(C(C)(C)C)cc4)cc(c32)N5c2c(-c3ccccc3)cccc2-c2ccccc2)cc1 ; CC(C)(C)c1ccc(N2c3cc4c(cc3B3c5ccc(-c6ccccc6)cc5Oc5cc(-c6ccccc6-c6ccccc6)cc2c53)B2c3ccc(-c5ccccc5)cc3Oc3cc(C(C)(C)C)cc(c32)N4c2c(-c3ccccc3)cc(C(C)(C)C)cc2-c2ccccc2)cc1]

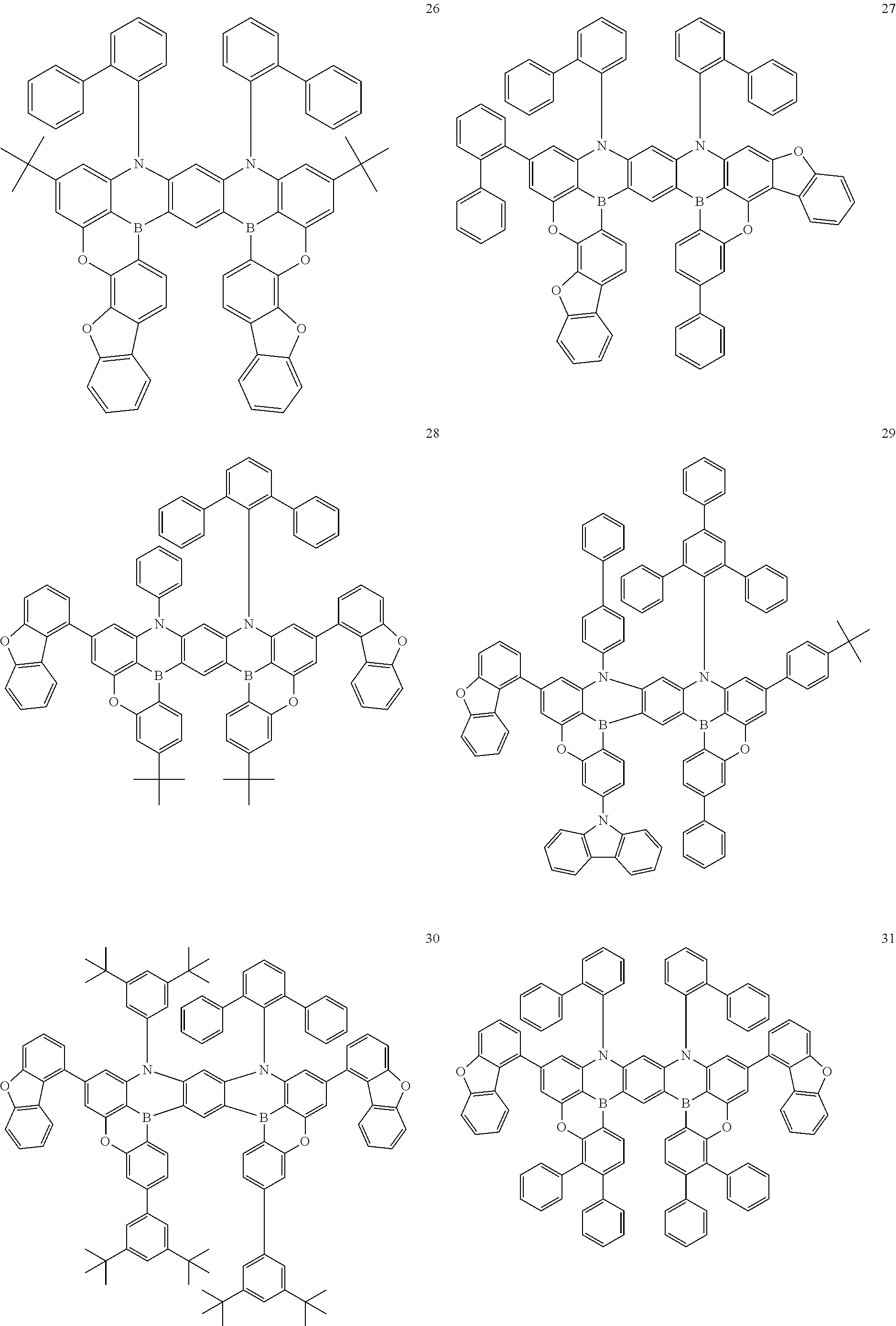

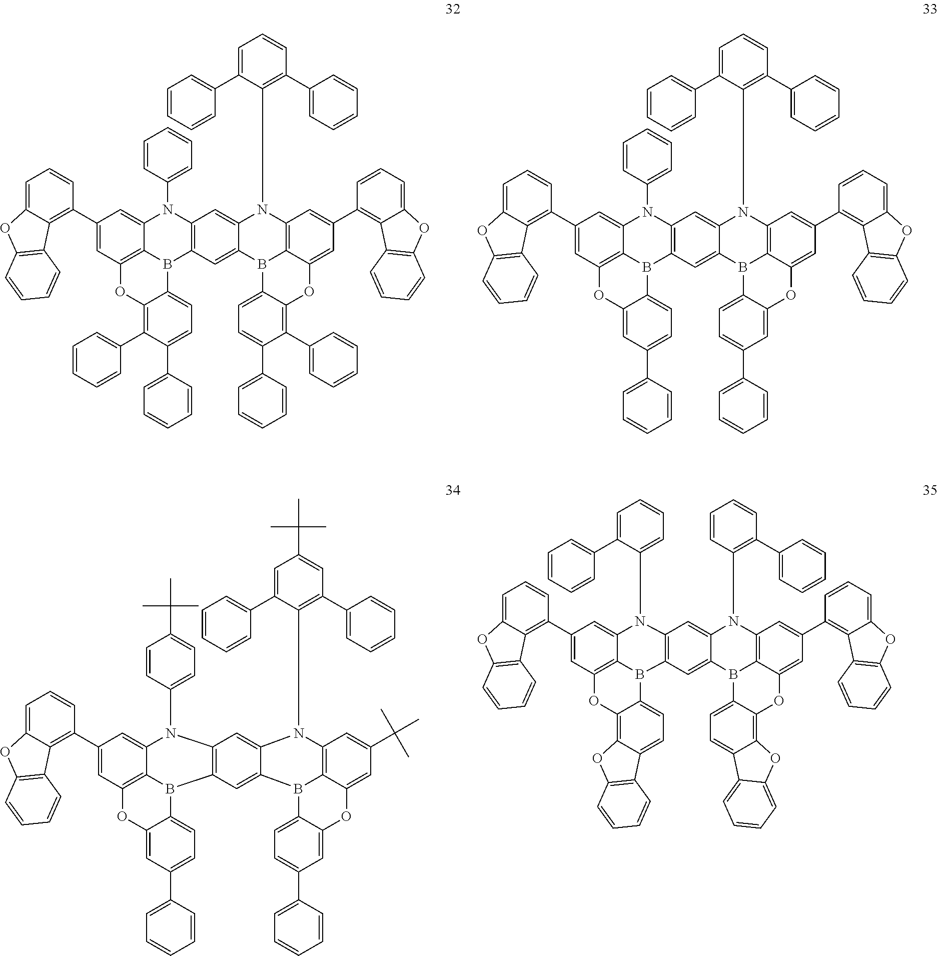

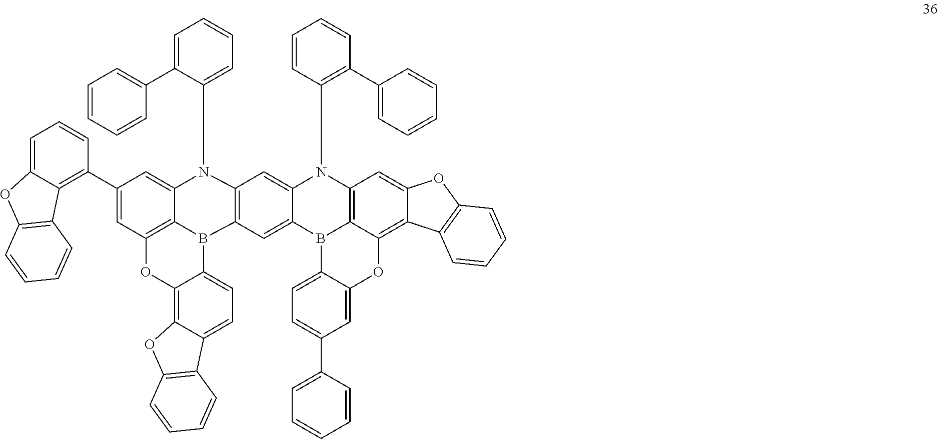 [SMILES: c1ccc(-c2ccc3c(c2)Oc2c4c(cc5oc6ccccc6c25)N(c2ccccc2-c2ccccc2)c2cc5c(cc2B34)B2c3ccc4c(oc6ccccc64)c3Oc3cc(-c4cccc6oc7ccccc7c46)cc(c32)N5c2ccccc2-c2ccccc2)cc1]

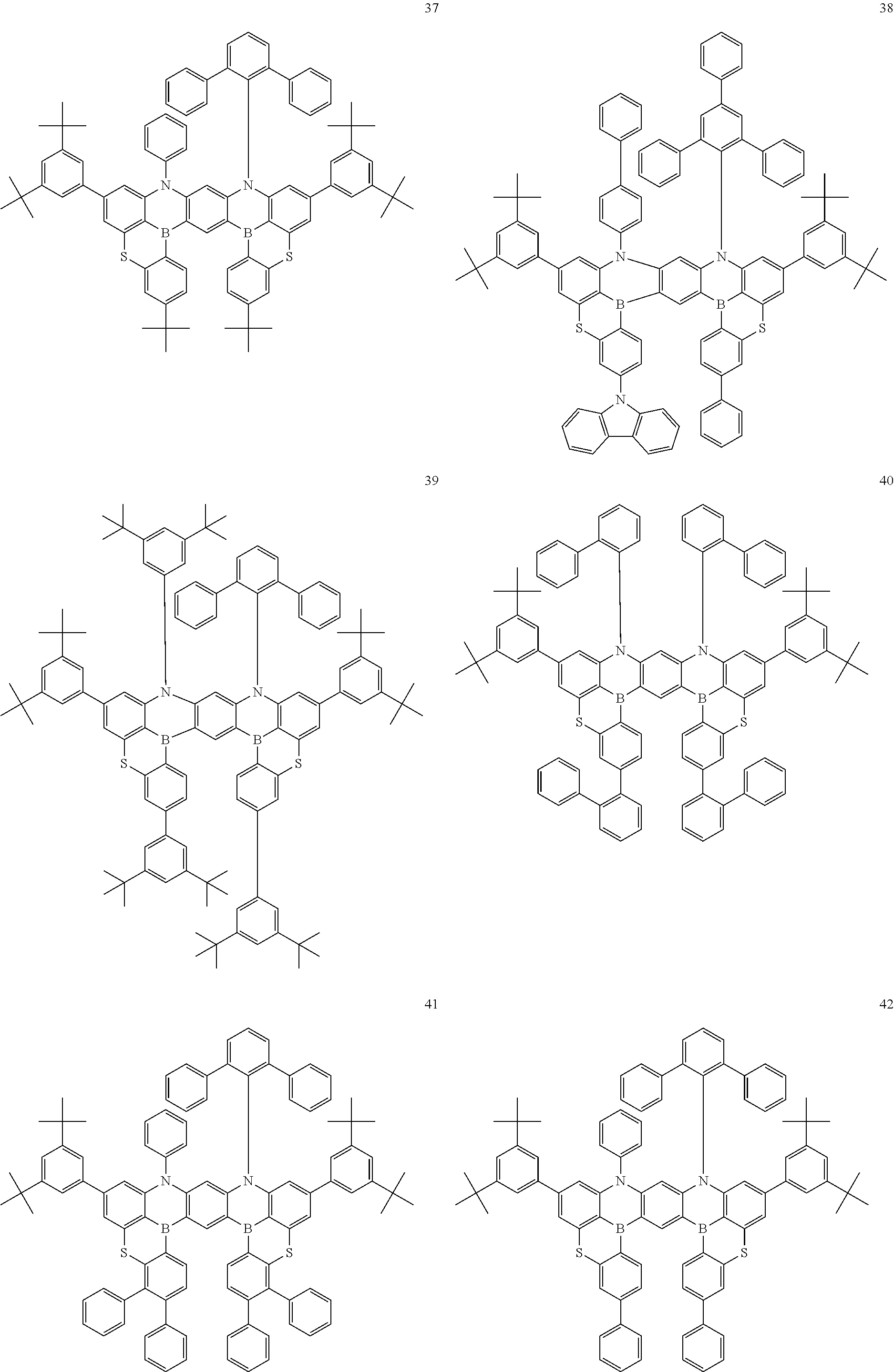

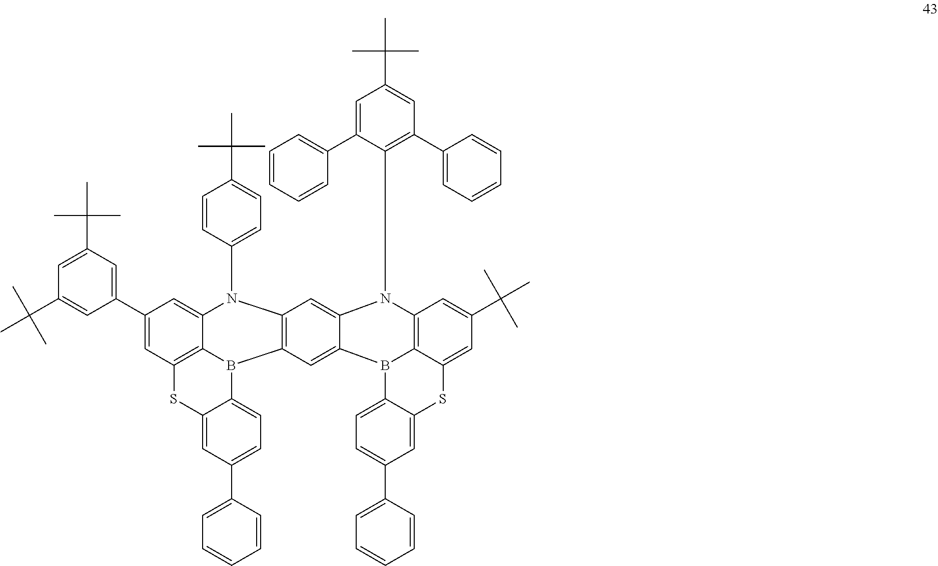 [SMILES: CC(C)(C)c1ccc(N2c3cc4c(cc3B3c5ccc(-c6ccccc6)cc5Sc5cc(-c6cc(C(C)(C)C)cc(C(C)(C)C)c6)cc2c53)B2c3ccc(-c5ccccc5)cc3Sc3cc(C(C)(C)C)cc(c32)N4c2c(-c3ccccc3)cc(C(C)(C)C)cc2-c2ccccc2)cc1]

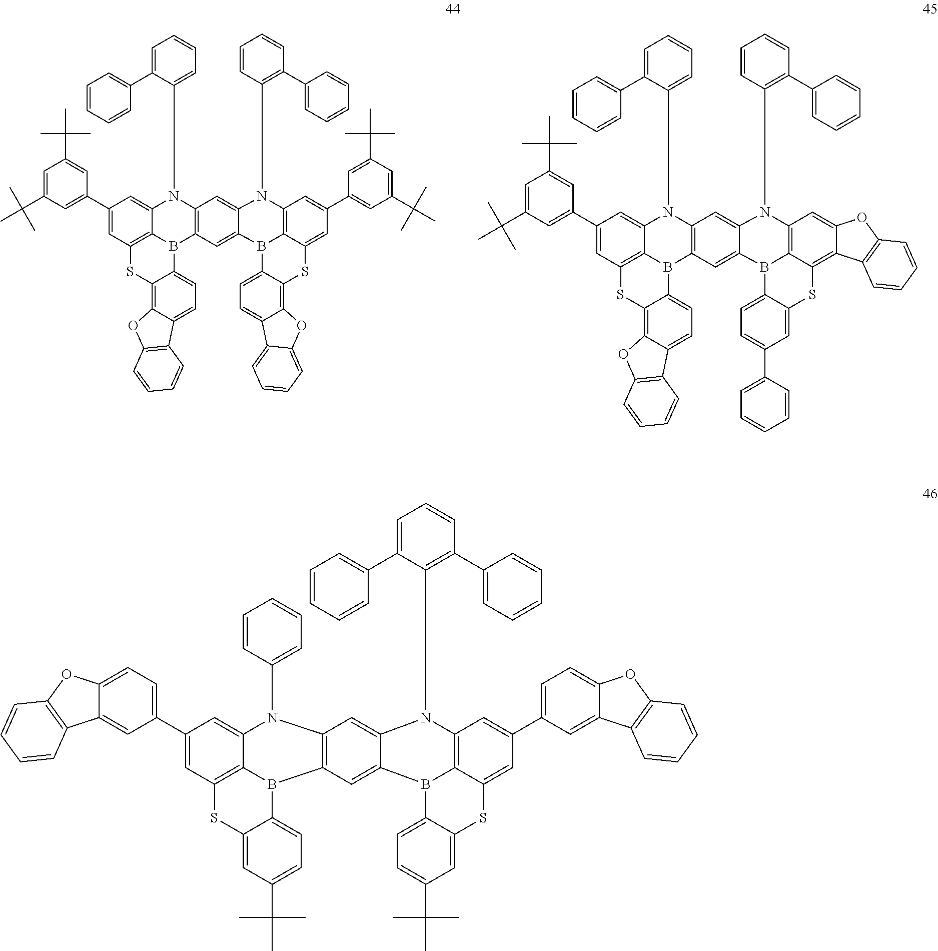

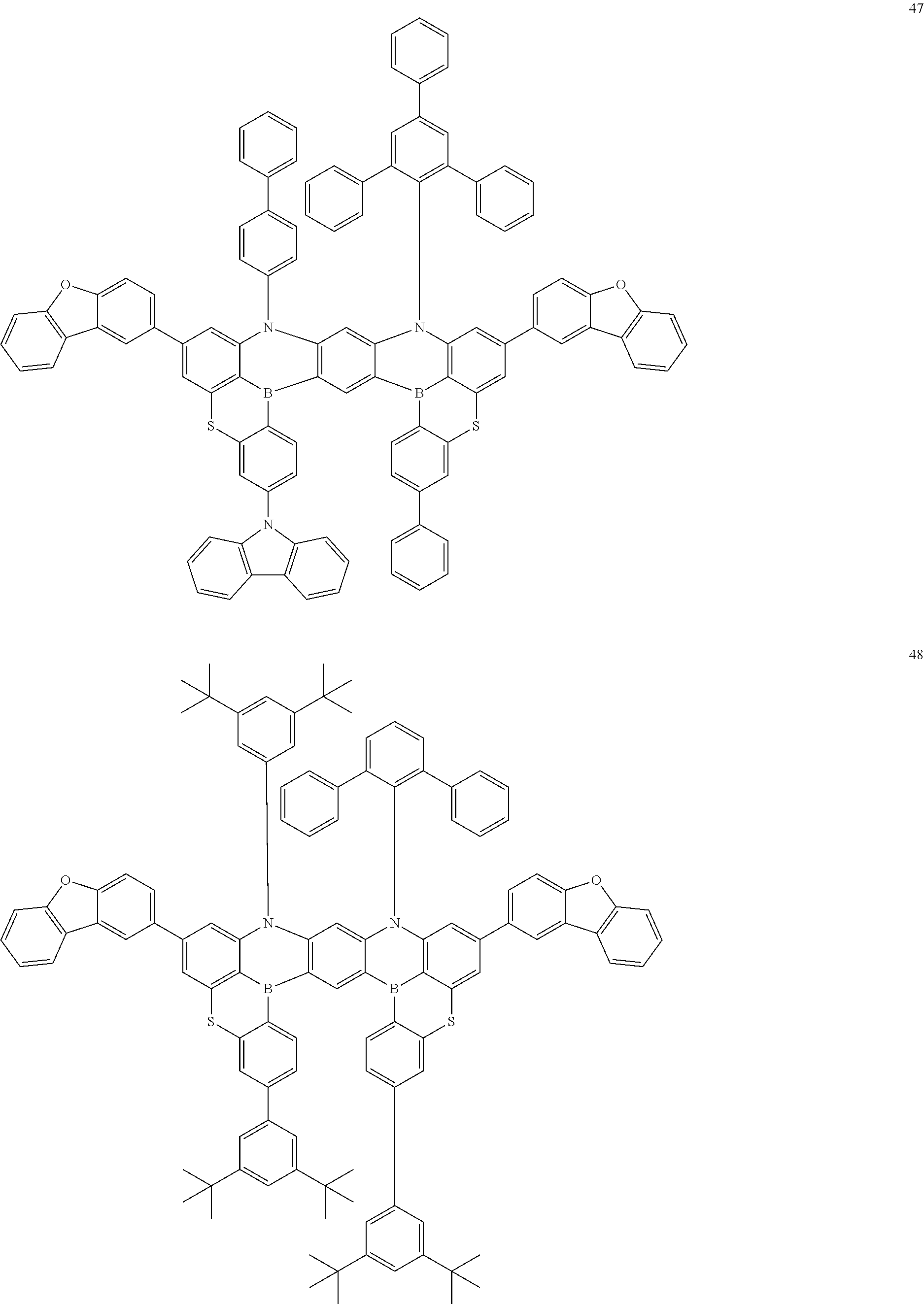 [SMILES: c1ccc(-c2ccc(N3c4cc5c(cc4B4c6ccc(-n7c8ccccc8c8ccccc87)cc6Sc6cc(-c7ccc8oc9ccccc9c8c7)cc3c64)B3c4ccc(-c6ccccc6)cc4Sc4cc(-c6ccc7oc8ccccc8c7c6)cc(c43)N5c3c(-c4ccccc4)cc(-c4ccccc4)cc3-c3ccccc3)cc2)cc1 ; CC(C)(C)c1cc(-c2ccc3c(c2)Sc2cc(-c4ccc5oc6ccccc6c5c4)cc4c2B3c2cc3c(cc2N4c2cc(C(C)(C)C)cc(C(C)(C)C)c2)N(c2c(-c4ccccc4)cccc2-c2ccccc2)c2cc(-c4ccc5oc6ccccc6c5c4)cc4c2B3c2ccc(-c3cc(C(C)(C)C)cc(C(C)(C)C)c3)cc2S4)cc(C(C)(C)C)c1]

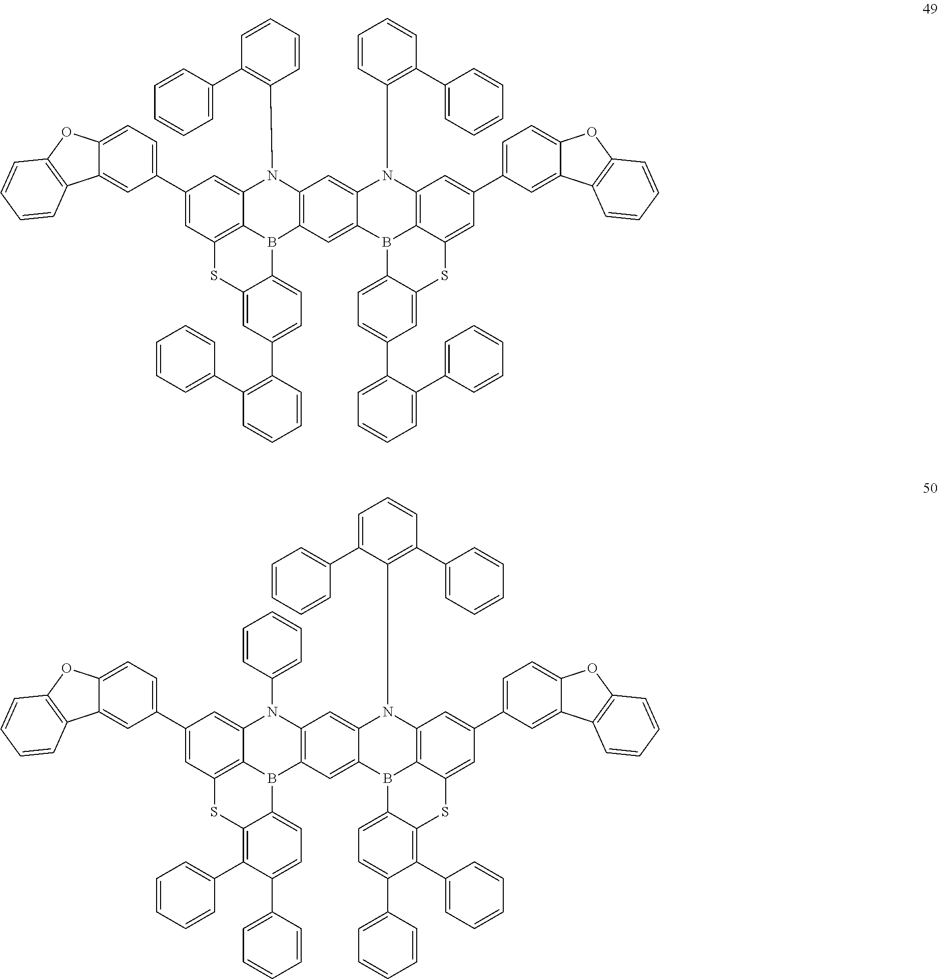 [SMILES: c1ccc(-c2ccccc2-c2ccc3c(c2)Sc2cc(-c4ccc5oc6ccccc6c5c4)cc4c2B3c2cc3c(cc2N4c2ccccc2-c2ccccc2)N(c2ccccc2-c2ccccc2)c2cc(-c4ccc5oc6ccccc6c5c4)cc4c2B3c2ccc(-c3ccccc3-c3ccccc3)cc2S4)cc1 ; c1ccc(-c2ccc3c(c2-c2ccccc2)Sc2cc(-c4ccc5oc6ccccc6c5c4)cc4c2B3c2cc3c(cc2N4c2ccccc2)N(c2c(-c4ccccc4)cccc2-c2ccccc2)c2cc(-c4ccc5oc6ccccc6c5c4)cc4c2B3c2ccc(-c3ccccc3)c(-c3ccccc3)c2S4)cc1]

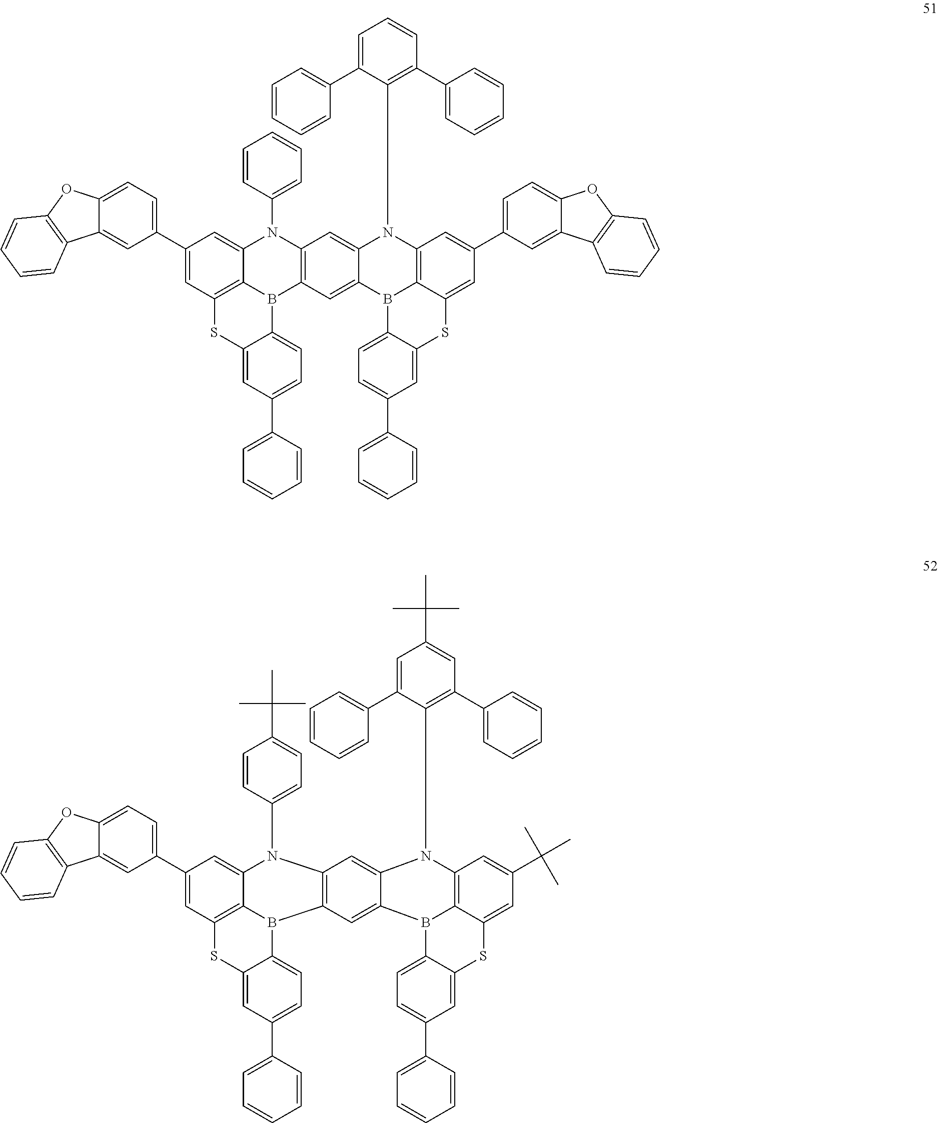 [SMILES: c1ccc(-c2ccc3c(c2)Sc2cc(-c4ccc5oc6ccccc6c5c4)cc4c2B3c2cc3c(cc2N4c2ccccc2)N(c2c(-c4ccccc4)cccc2-c2ccccc2)c2cc(-c4ccc5oc6ccccc6c5c4)cc4c2B3c2ccc(-c3ccccc3)cc2S4)cc1 ; CC(C)(C)c1ccc(N2c3cc4c(cc3B3c5ccc(-c6ccccc6)cc5Sc5cc(-c6ccc7oc8ccccc8c7c6)cc2c53)B2c3ccc(-c5ccccc5)cc3Sc3cc(C(C)(C)C)cc(c32)N4c2c(-c3ccccc3)cc(C(C)(C)C)cc2-c2ccccc2)cc1]

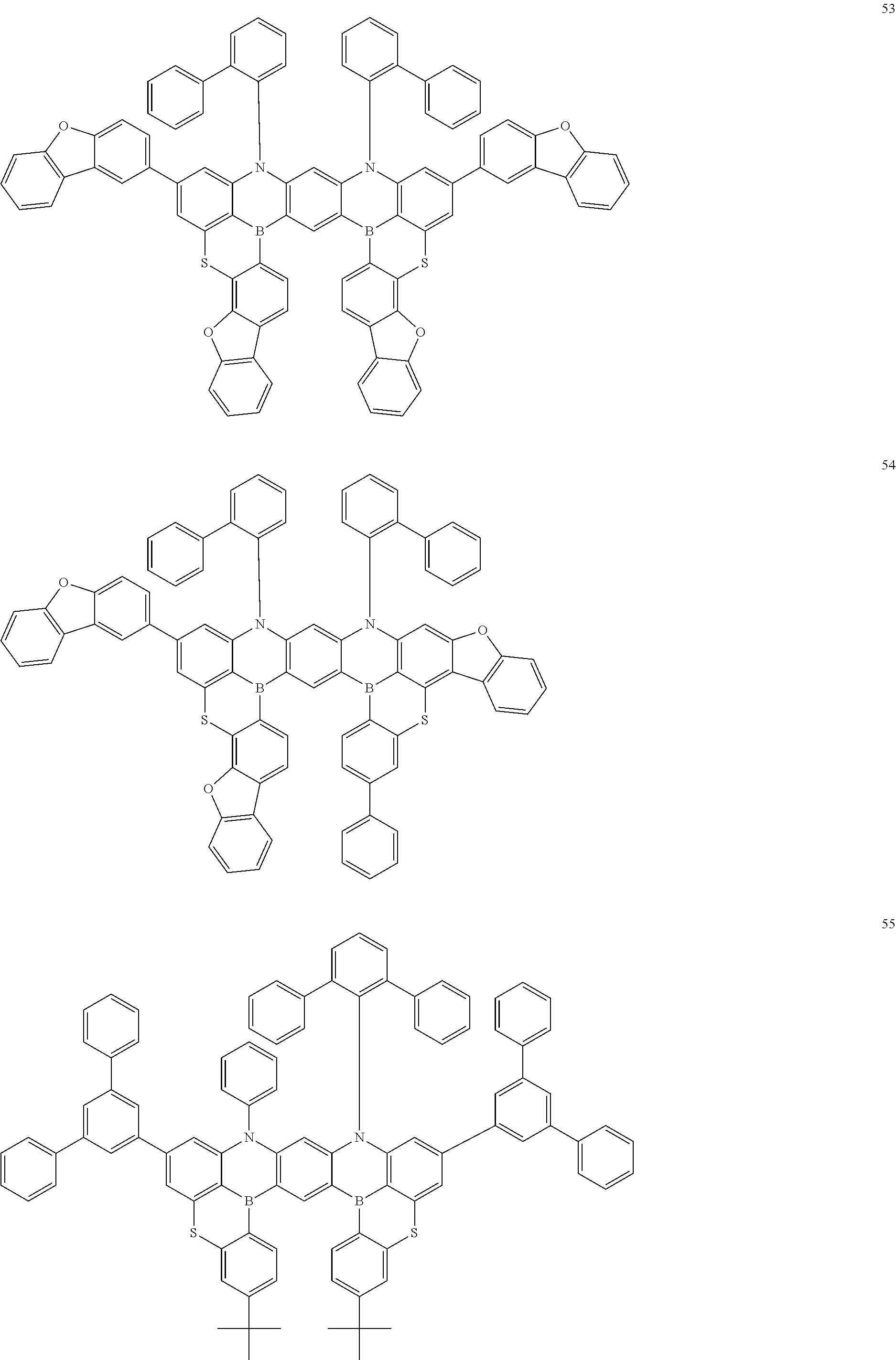

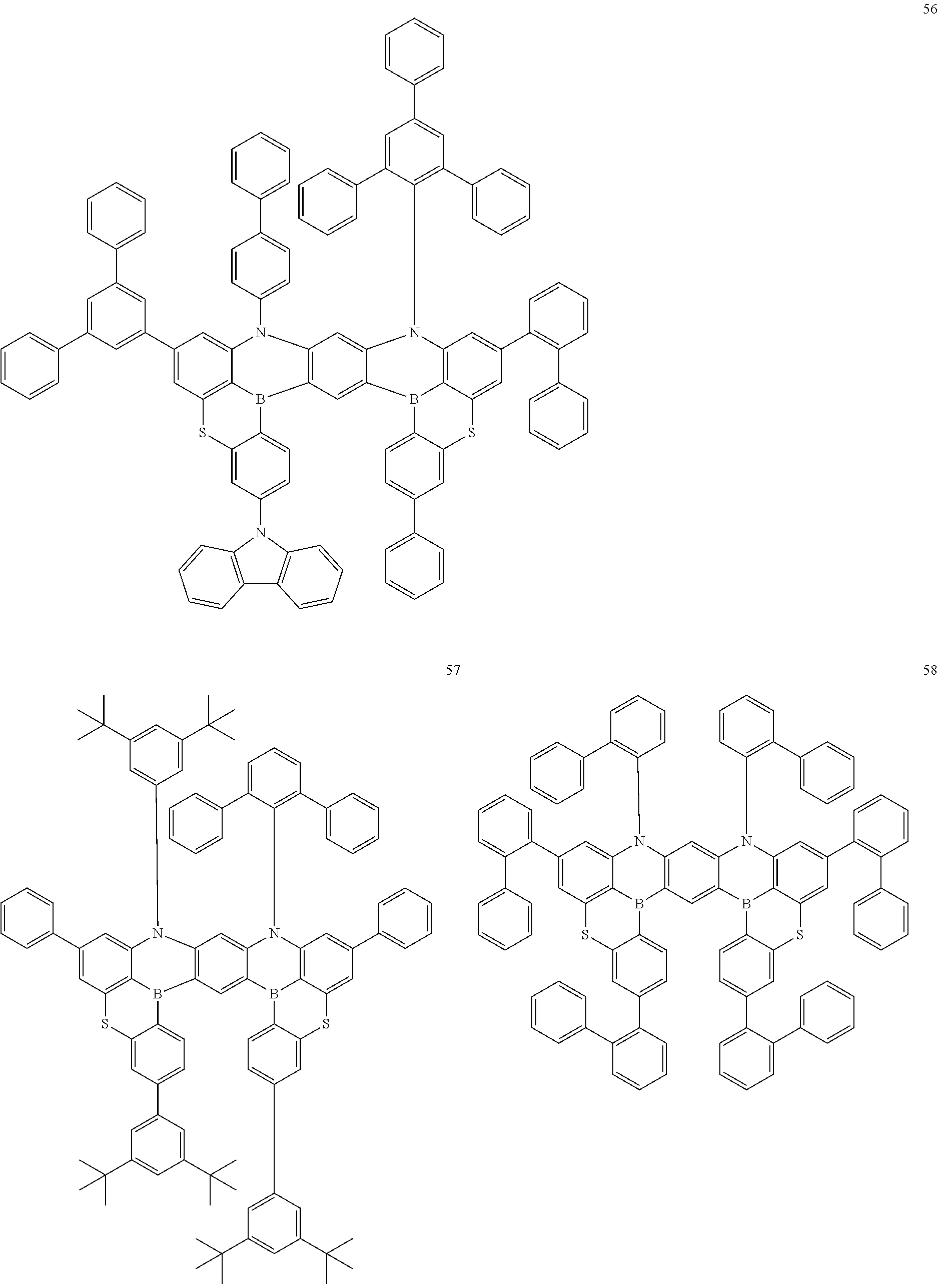

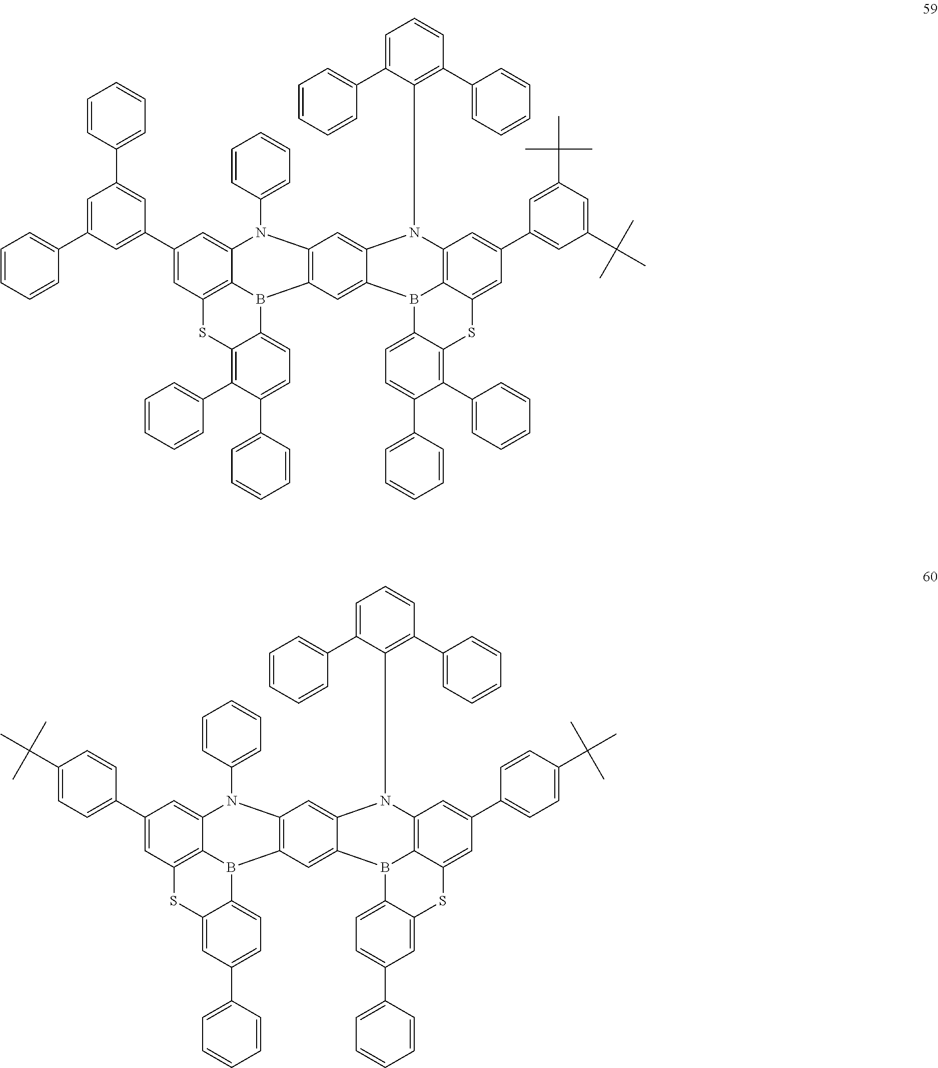

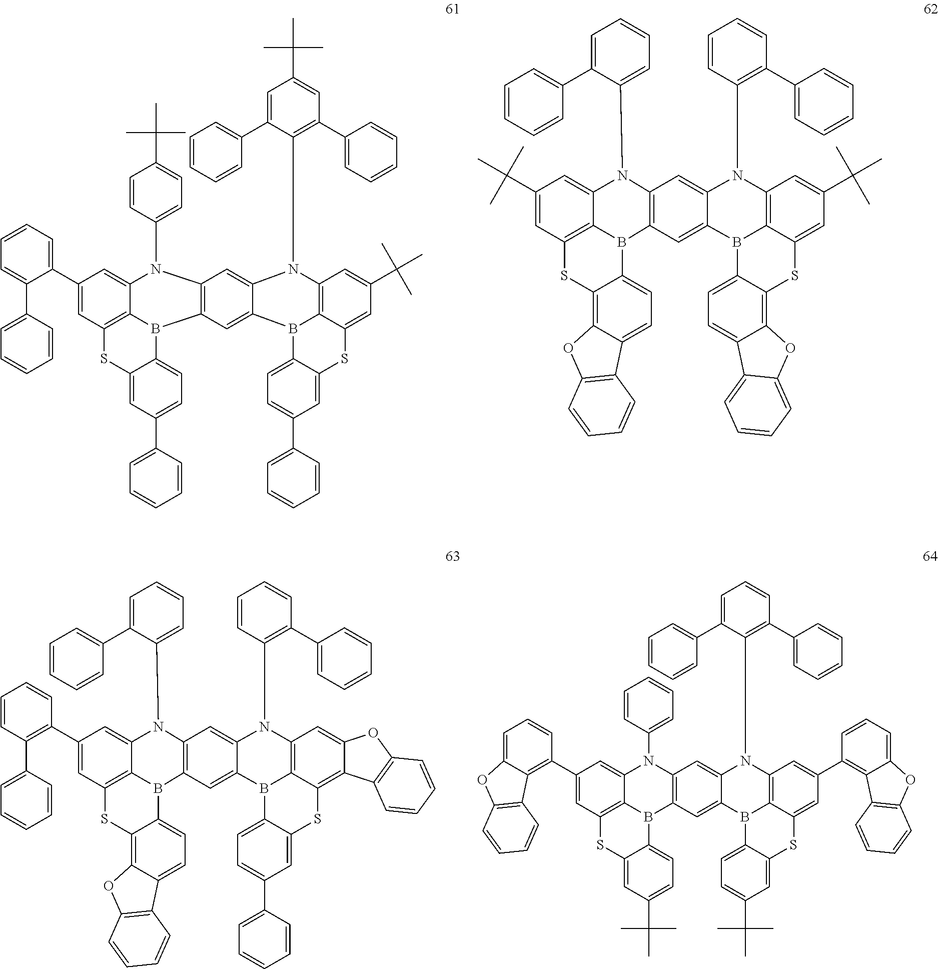

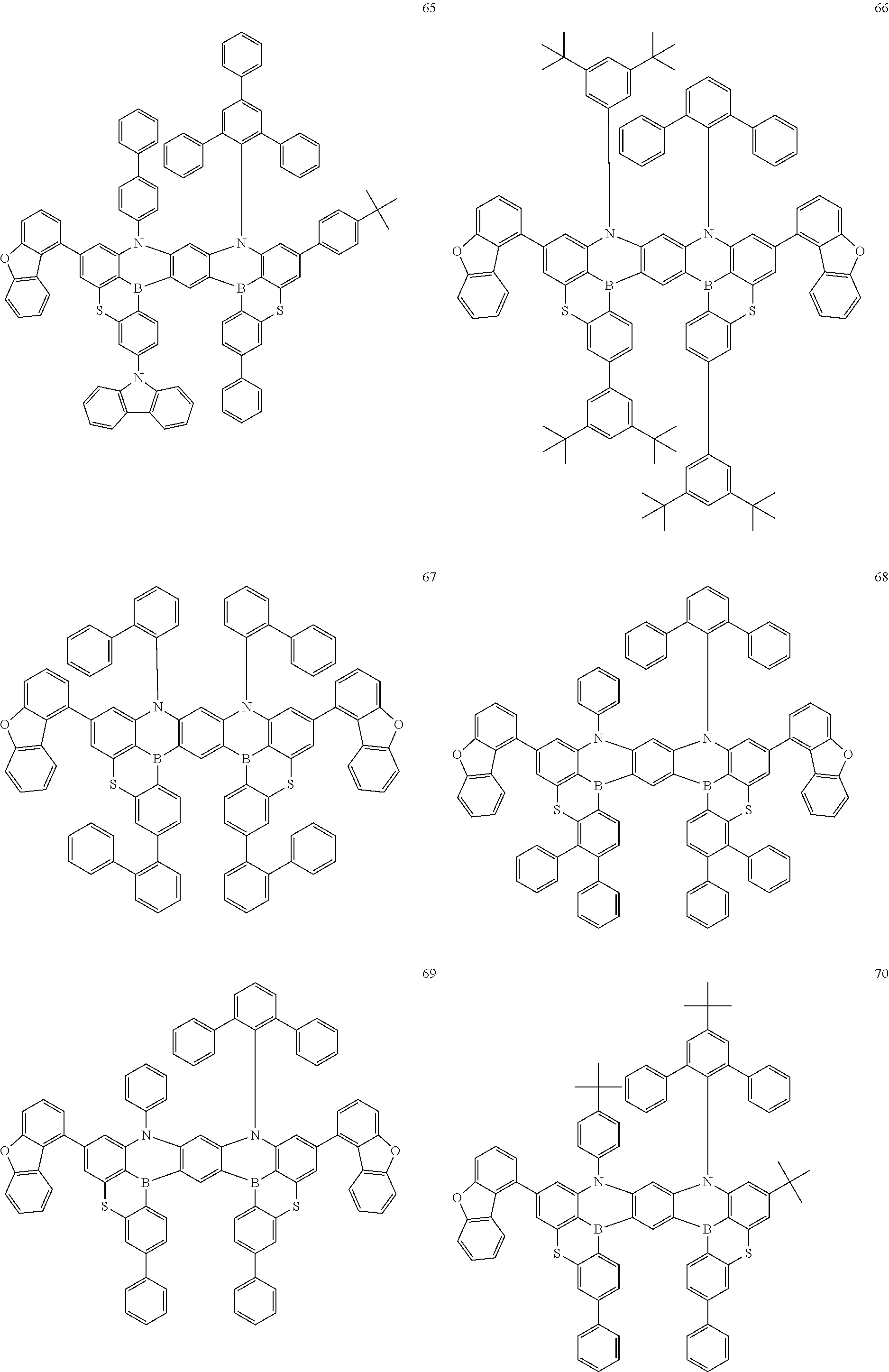

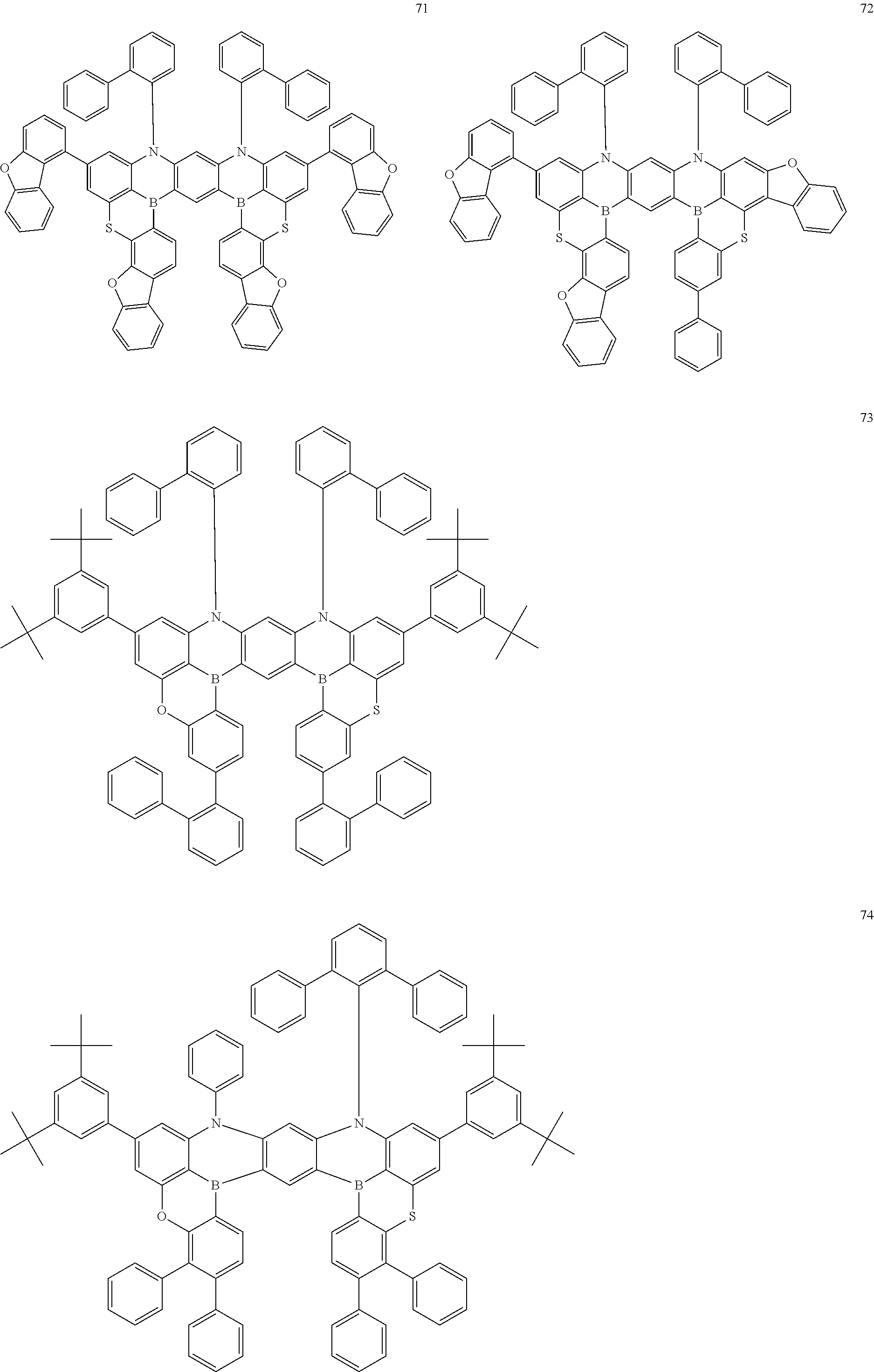

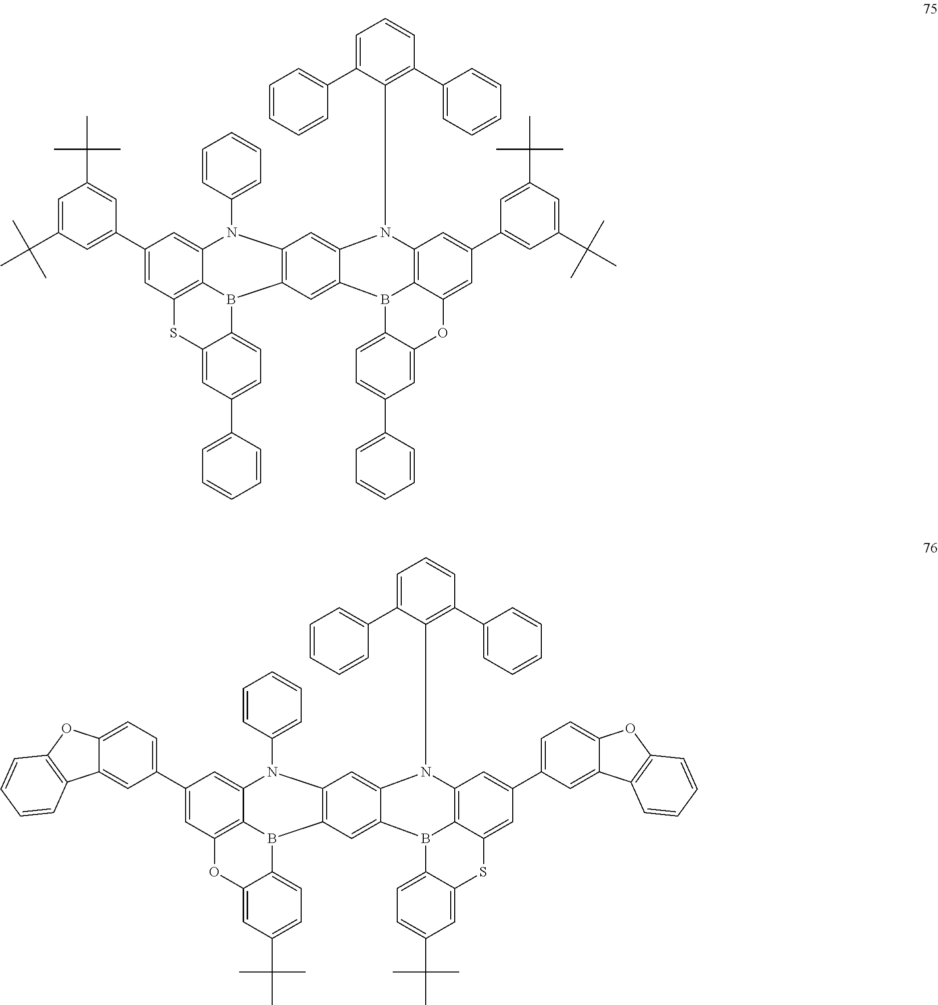 [SMILES: CC(C)(C)c1cc(-c2cc3c4c(c2)N(c2c(-c5ccccc5)cccc2-c2ccccc2)c2cc5c(cc2B4c2ccc(-c4ccccc4)cc2O3)B2c3ccc(-c4ccccc4)cc3Sc3cc(-c4cc(C(C)(C)C)cc(C(C)(C)C)c4)cc(c32)N5c2ccccc2)cc(C(C)(C)C)c1 ; CC(C)(C)c1ccc2c(c1)Oc1cc(-c3ccc4oc5ccccc5c4c3)cc3c1B2c1cc2c(cc1N3c1ccccc1)N(c1c(-c3ccccc3)cccc1-c1ccccc1)c1cc(-c3ccc4oc5ccccc5c4c3)cc3c1B2c1ccc(C(C)(C)C)cc1S3]

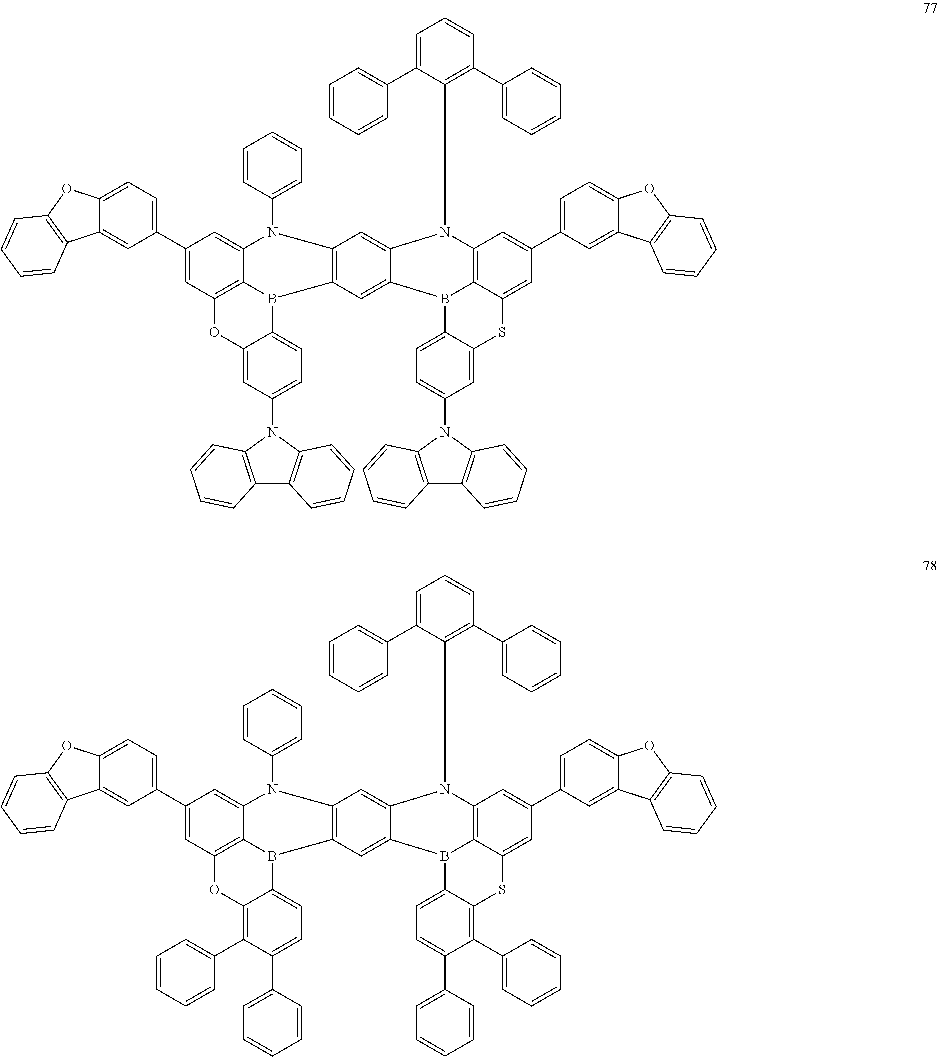 [SMILES: c1ccc(-c2cccc(-c3ccccc3)c2N2c3cc4c(cc3B3c5ccc(-n6c7ccccc7c7ccccc76)cc5Sc5cc(-c6ccc7oc8ccccc8c7c6)cc2c53)B2c3ccc(-n5c6ccccc6c6ccccc65)cc3Oc3cc(-c5ccc6oc7ccccc7c6c5)cc(c32)N4c2ccccc2)cc1 ; c1ccc(-c2ccc3c(c2-c2ccccc2)Oc2cc(-c4ccc5oc6ccccc6c5c4)cc4c2B3c2cc3c(cc2N4c2ccccc2)N(c2c(-c4ccccc4)cccc2-c2ccccc2)c2cc(-c4ccc5oc6ccccc6c5c4)cc4c2B3c2ccc(-c3ccccc3)c(-c3ccccc3)c2S4)cc1]

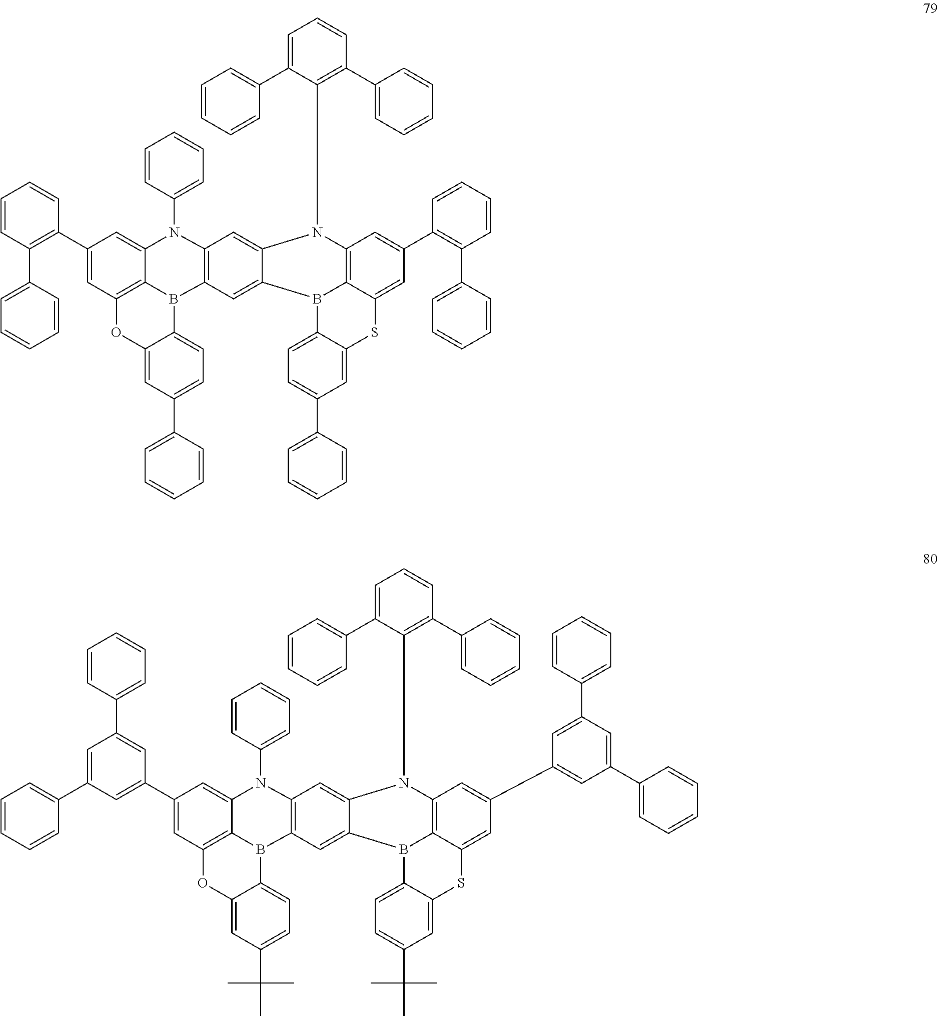 [SMILES: c1ccc(-c2ccc3c(c2)Oc2cc(-c4ccccc4-c4ccccc4)cc4c2B3c2cc3c(cc2N4c2ccccc2)N(c2c(-c4ccccc4)cccc2-c2ccccc2)c2cc(-c4ccccc4-c4ccccc4)cc4c2B3c2ccc(-c3ccccc3)cc2S4)cc1 ; CC(C)(C)c1ccc2c(c1)Oc1cc(-c3cc(-c4ccccc4)cc(-c4ccccc4)c3)cc3c1B2c1cc2c(cc1N3c1ccccc1)N(c1c(-c3ccccc3)cccc1-c1ccccc1)c1cc(-c3cc(-c4ccccc4)cc(-c4ccccc4)c3)cc3c1B2c1ccc(C(C)(C)C)cc1S3]

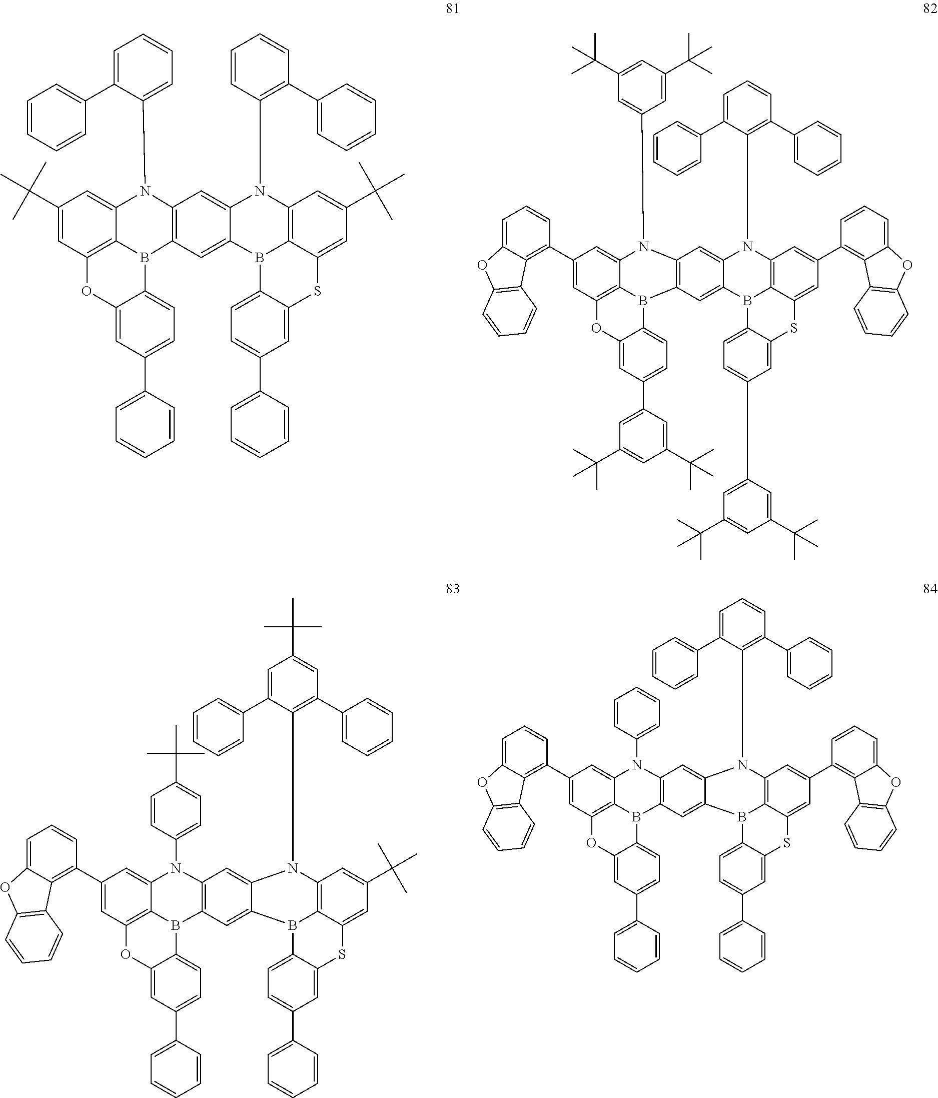

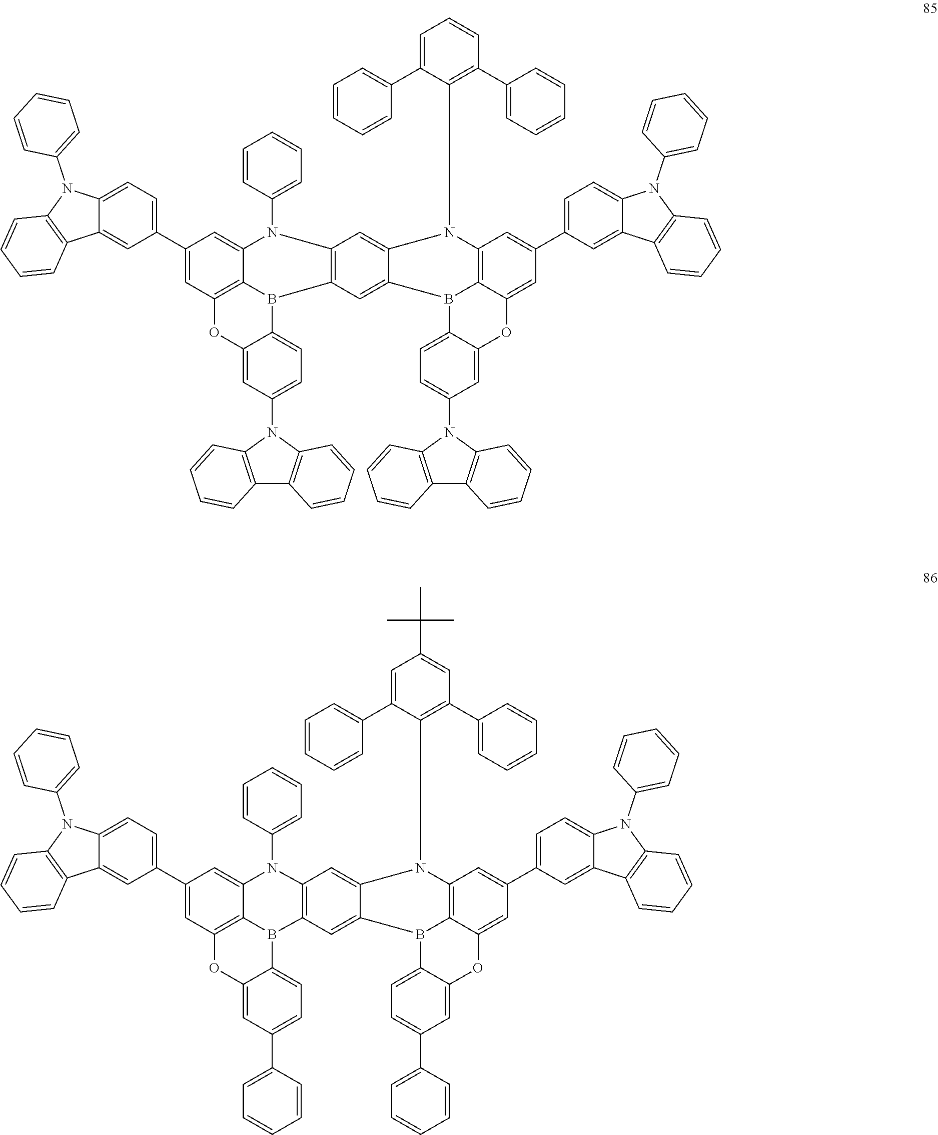 [SMILES: c1ccc(-c2cccc(-c3ccccc3)c2N2c3cc4c(cc3B3c5ccc(-n6c7ccccc7c7ccccc76)cc5Oc5cc(-c6ccc7c(c6)c6ccccc6n7-c6ccccc6)cc2c53)B2c3ccc(-n5c6ccccc6c6ccccc65)cc3Oc3cc(-c5ccc6c(c5)c5ccccc5n6-c5ccccc5)cc(c32)N4c2ccccc2)cc1 ; CC(C)(C)c1cc(-c2ccccc2)c(N2c3cc4c(cc3B3c5ccc(-c6ccccc6)cc5Oc5cc(-c6ccc7c(c6)c6ccccc6n7-c6ccccc6)cc2c53)B2c3ccc(-c5ccccc5)cc3Oc3cc(-c5ccc6c(c5)c5ccccc5n6-c5ccccc5)cc(c32)N4c2ccccc2)c(-c2ccccc2)c1]

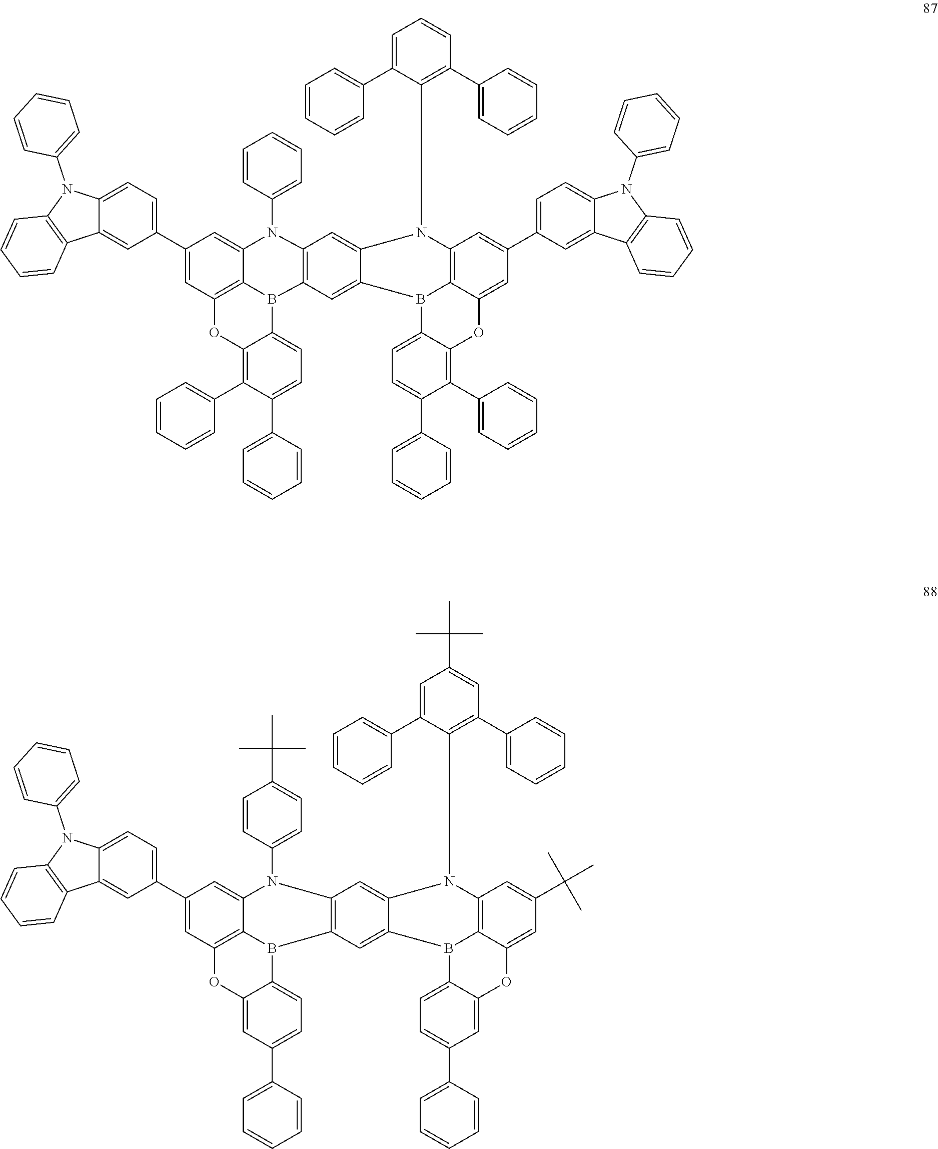 [SMILES: c1ccc(-c2ccc3c(c2-c2ccccc2)Oc2cc(-c4ccc5c(c4)c4ccccc4n5-c4ccccc4)cc4c2B3c2cc3c(cc2N4c2ccccc2)N(c2c(-c4ccccc4)cccc2-c2ccccc2)c2cc(-c4ccc5c(c4)c4ccccc4n5-c4ccccc4)cc4c2B3c2ccc(-c3ccccc3)c(-c3ccccc3)c2O4)cc1 ; CC(C)(C)c1ccc(N2c3cc4c(cc3B3c5ccc(-c6ccccc6)cc5Oc5cc(-c6ccc7c(c6)c6ccccc6n7-c6ccccc6)cc2c53)B2c3ccc(-c5ccccc5)cc3Oc3cc(C(C)(C)C)cc(c32)N4c2c(-c3ccccc3)cc(C(C)(C)C)cc2-c2ccccc2)cc1]

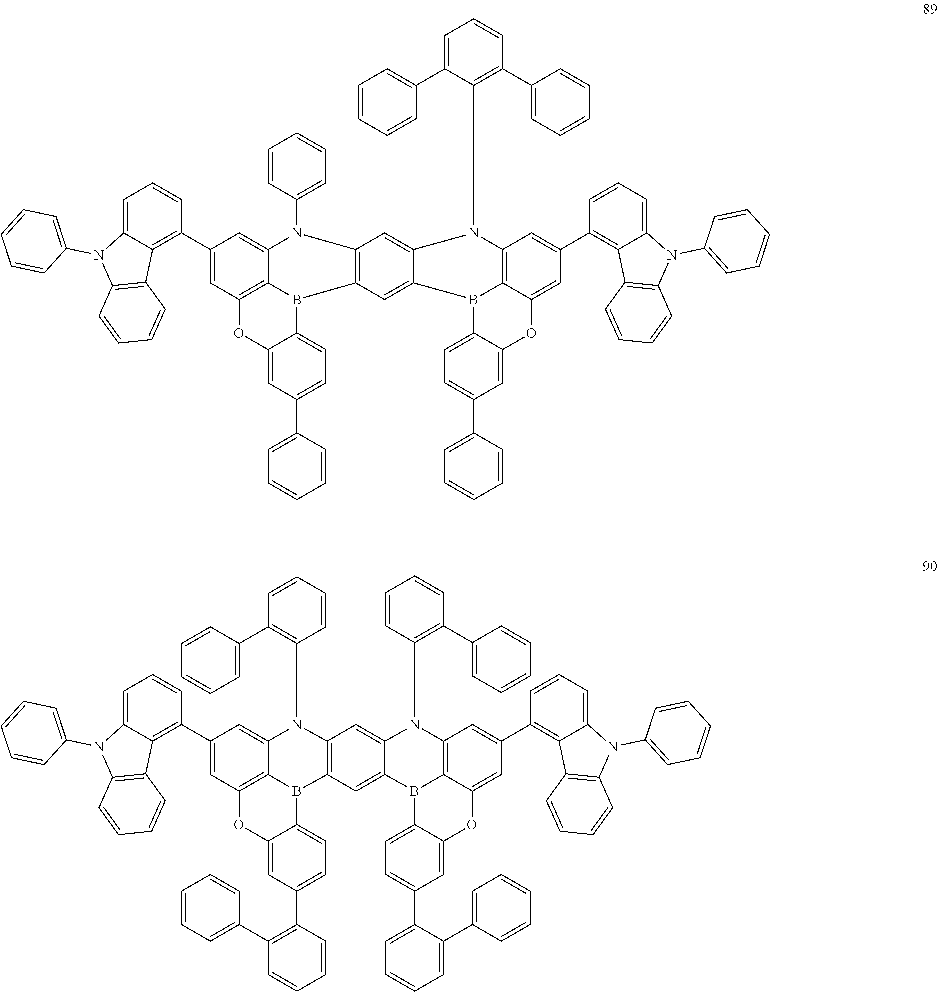 [SMILES: c1ccc(-c2ccc3c(c2)Oc2cc(-c4cccc5c4c4ccccc4n5-c4ccccc4)cc4c2B3c2cc3c(cc2N4c2ccccc2)N(c2c(-c4ccccc4)cccc2-c2ccccc2)c2cc(-c4cccc5c4c4ccccc4n5-c4ccccc4)cc4c2B3c2ccc(-c3ccccc3)cc2O4)cc1 ; c1ccc(-c2ccccc2-c2ccc3c(c2)Oc2cc(-c4cccc5c4c4ccccc4n5-c4ccccc4)cc4c2B3c2cc3c(cc2N4c2ccccc2-c2ccccc2)N(c2ccccc2-c2ccccc2)c2cc(-c4cccc5c4c4ccccc4n5-c4ccccc4)cc4c2B3c2ccc(-c3ccccc3-c3ccccc3)cc2O4)cc1]

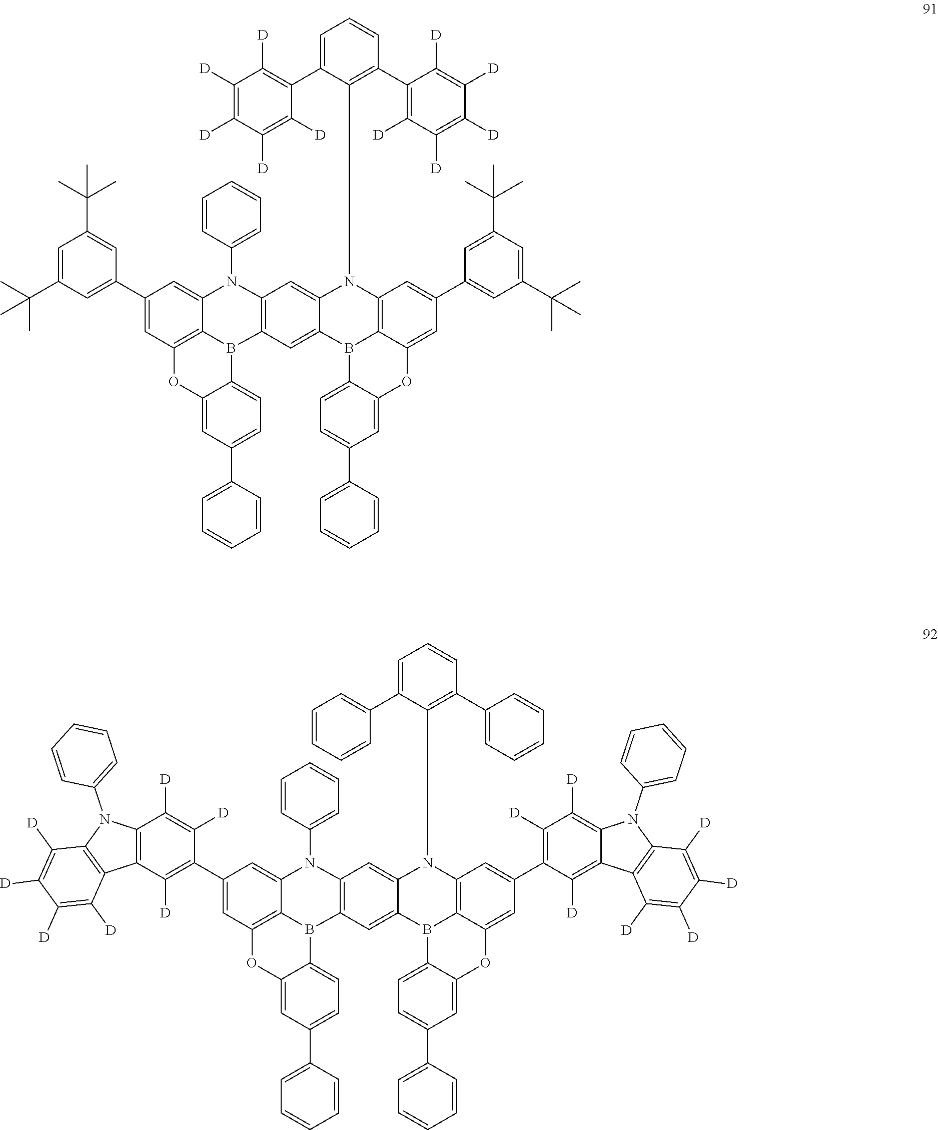

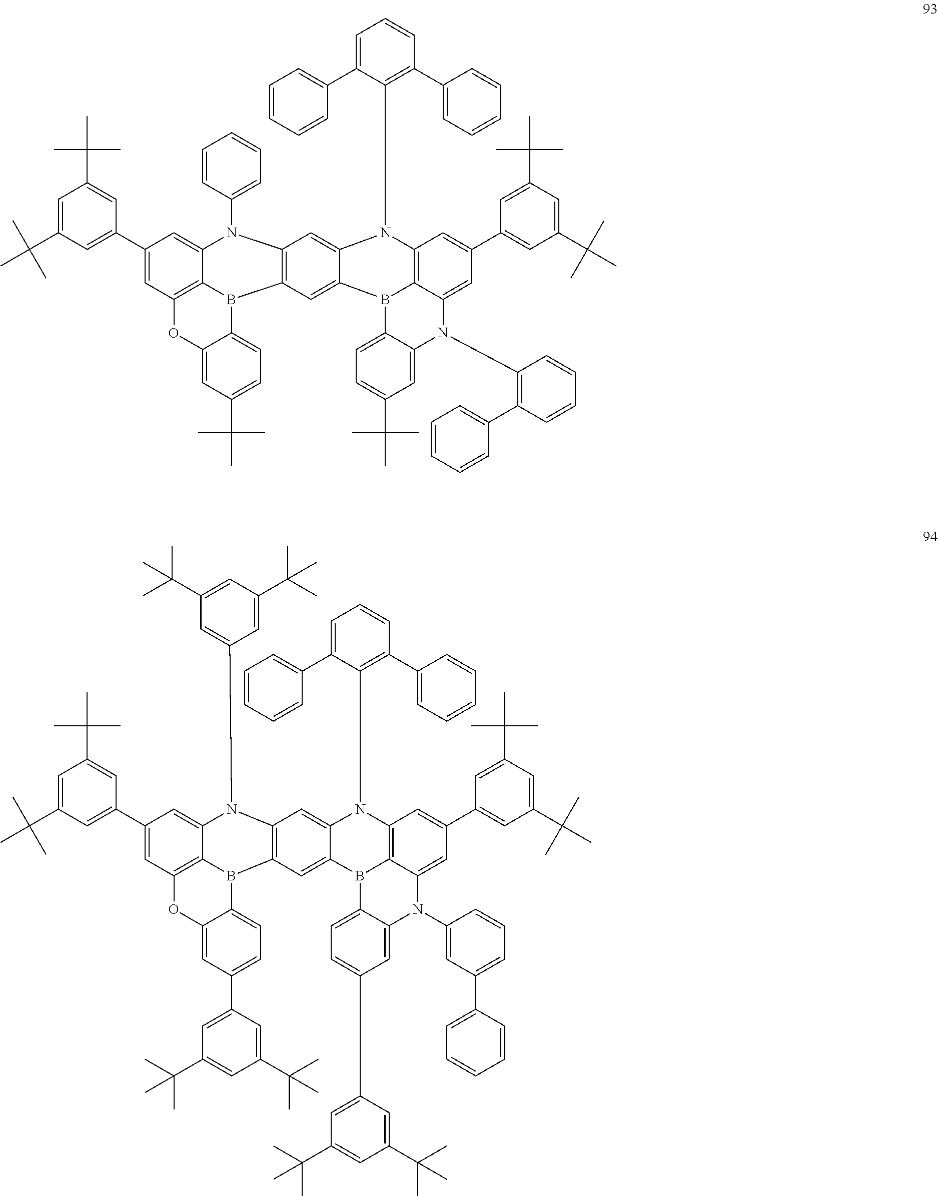

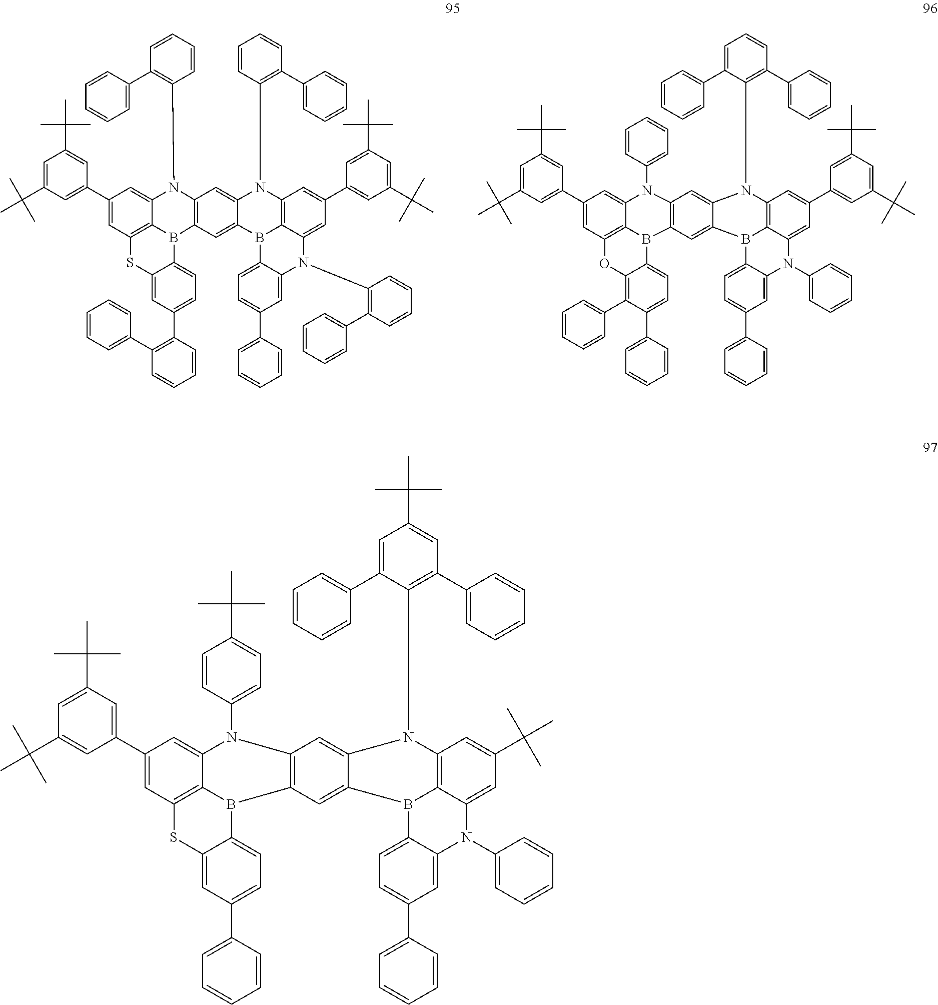

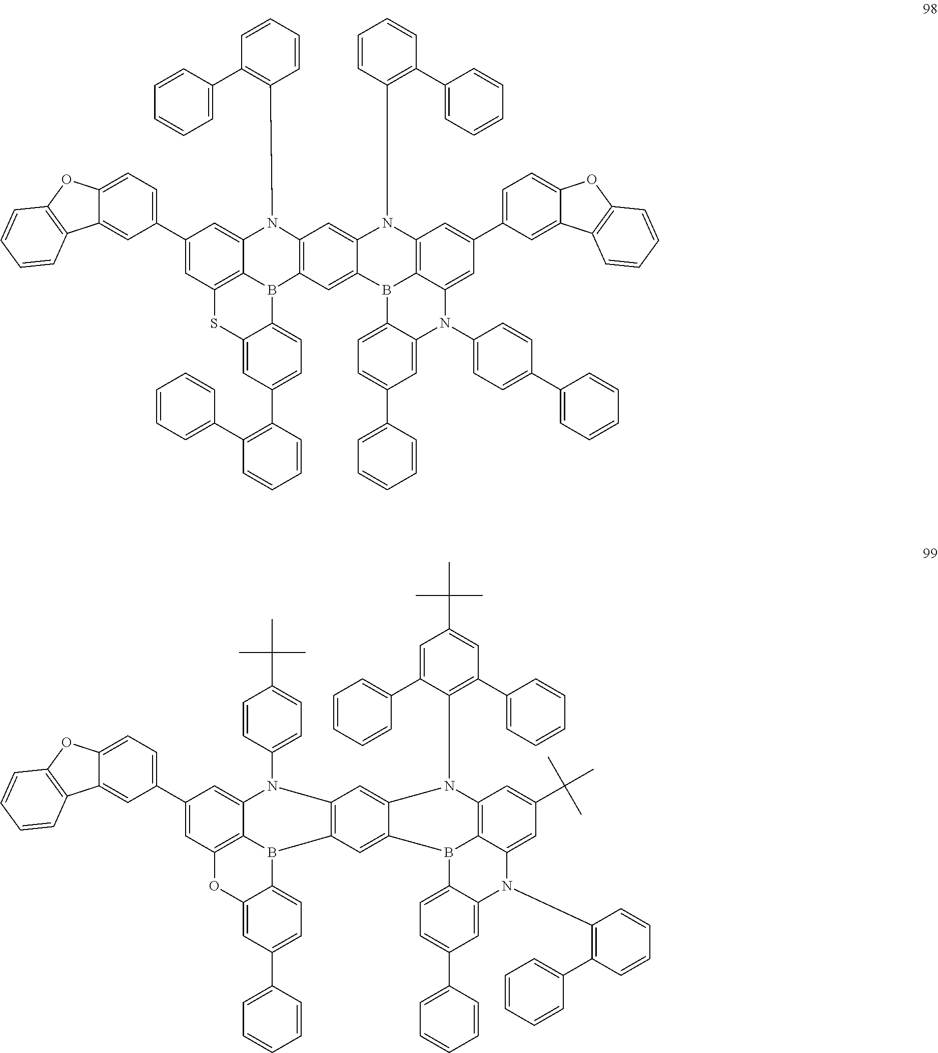 [SMILES: c1ccc(-c2ccc(N3c4cc(-c5ccccc5)ccc4B4c5cc6c(cc5N(c5ccccc5-c5ccccc5)c5cc(-c7ccc8oc9ccccc9c8c7)cc3c54)N(c3ccccc3-c3ccccc3)c3cc(-c4ccc5oc7ccccc7c5c4)cc4c3B6c3ccc(-c5ccccc5-c5ccccc5)cc3S4)cc2)cc1 ; CC(C)(C)c1ccc(N2c3cc4c(cc3B3c5ccc(-c6ccccc6)cc5Oc5cc(-c6ccc7oc8ccccc8c7c6)cc2c53)B2c3ccc(-c5ccccc5)cc3N(c3ccccc3-c3ccccc3)c3cc(C(C)(C)C)cc(c32)N4c2c(-c3ccccc3)cc(C(C)(C)C)cc2-c2ccccc2)cc1]

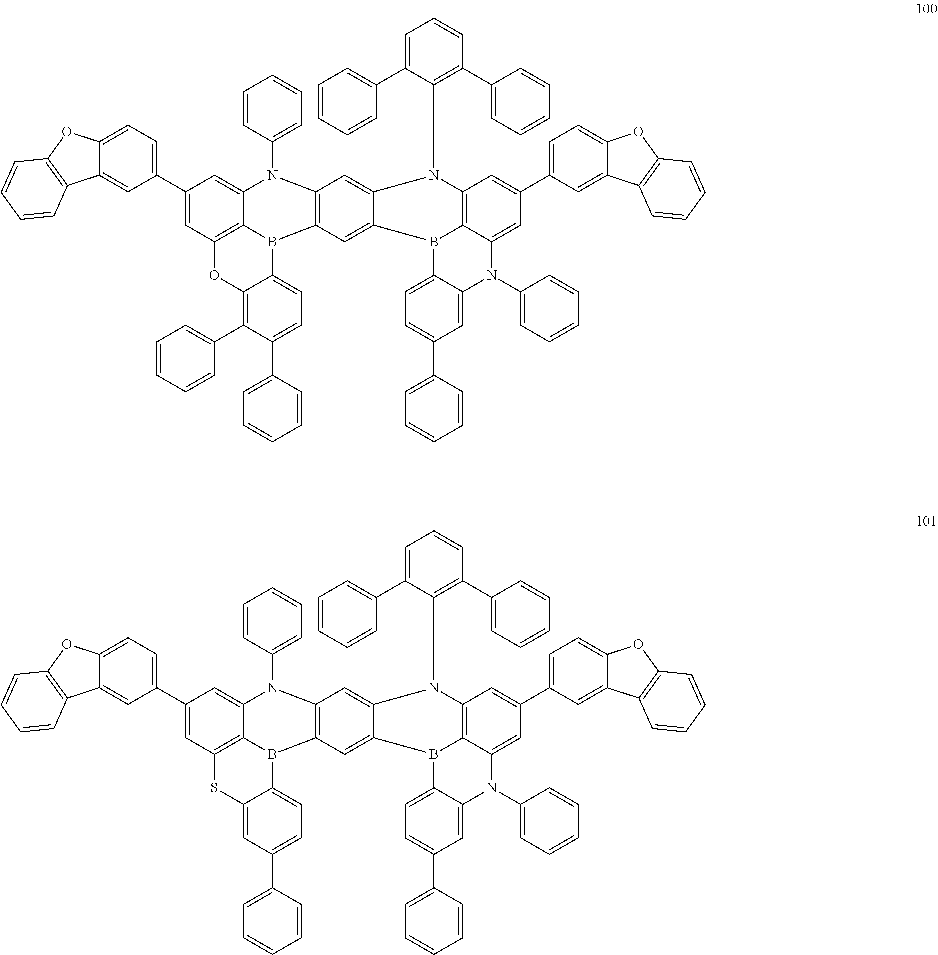 [SMILES: c1ccc(-c2ccc3c(c2)N(c2ccccc2)c2cc(-c4ccc5oc6ccccc6c5c4)cc4c2B3c2cc3c(cc2N4c2c(-c4ccccc4)cccc2-c2ccccc2)N(c2ccccc2)c2cc(-c4ccc5oc6ccccc6c5c4)cc4c2B3c2ccc(-c3ccccc3)c(-c3ccccc3)c2O4)cc1 ; c1ccc(-c2ccc3c(c2)Sc2cc(-c4ccc5oc6ccccc6c5c4)cc4c2B3c2cc3c(cc2N4c2ccccc2)N(c2c(-c4ccccc4)cccc2-c2ccccc2)c2cc(-c4ccc5oc6ccccc6c5c4)cc4c2B3c2ccc(-c3ccccc3)cc2N4c2ccccc2)cc1]

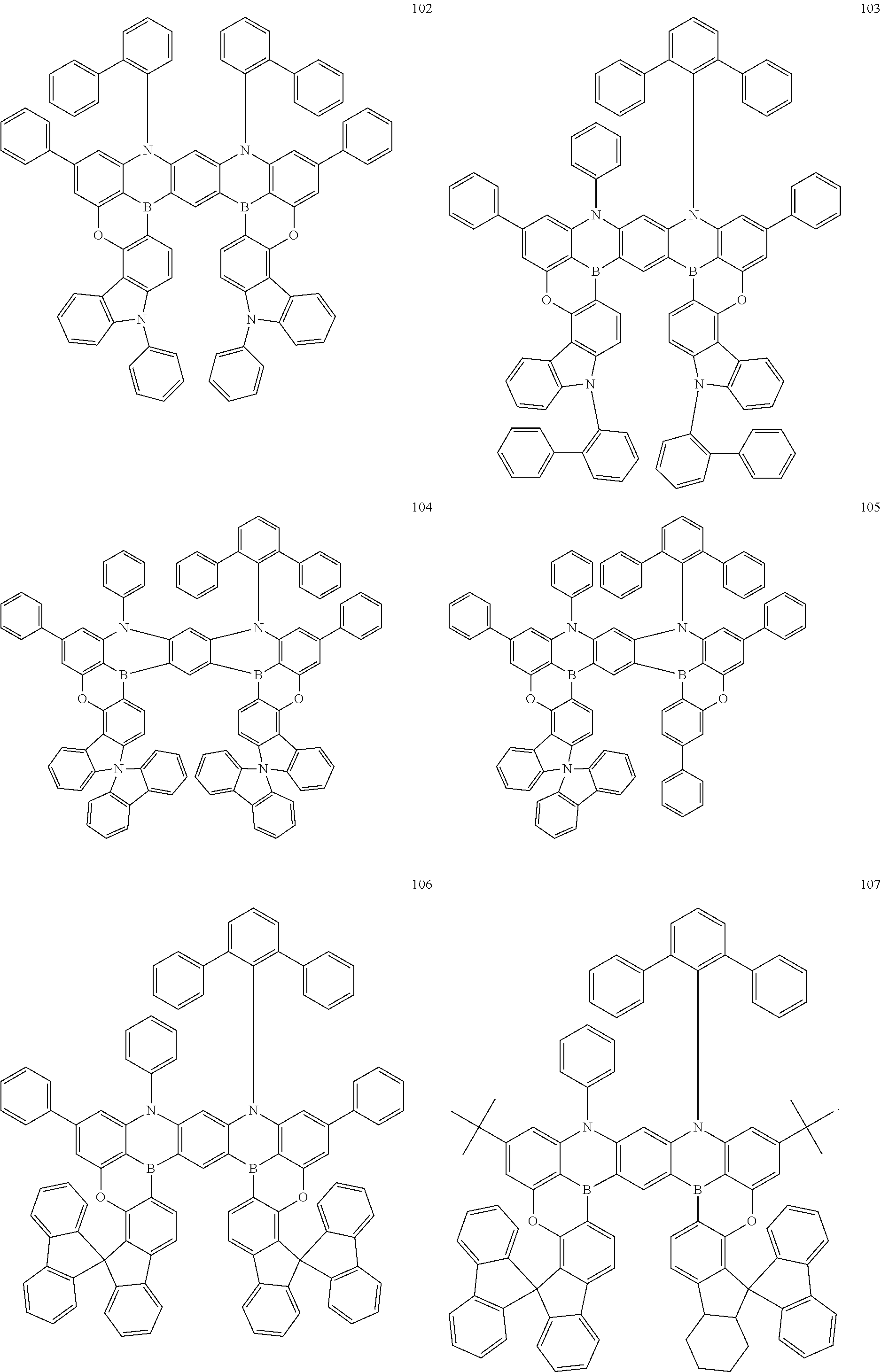

In the structures of the compounds of Compound Group 1, D indicates a deuterium atom.

The polycyclic compound of an embodiment may include a core portion of a fused ring containing at least two boron atoms and at least one oxygen atom and/or at least one sulfur atom as ring-forming atoms, and include substituents positioned para to the boron atoms of the core portion to prevent or reduce steric effect between bonds in molecules, thereby exhibiting high stability. In addition, the substituents positioned para to the boron atoms allow the polycyclic compound of an embodiment to have a deep HOMO level, and a light emitting device may thus have increased lifespan. In addition, the polycyclic compound according to an embodiment may shorten light emitting wavelength due to an oxygen atom and/or a sulfur atom introduced into the core portion. Accordingly, the polycyclic compound of an embodiment may be utilized as a material of a light emitting element to increase light emitting efficiency and lifespan of the light emitting element.

In some embodiments, the polycyclic compound according to an embodiment may be included in the emission layer EML. The polycyclic compound according to an embodiment may be included in the emission layer EML as a dopant material. The polycyclic compound according to an embodiment may be a thermally activated delayed fluorescent material. The polycyclic compound according to an embodiment may be utilized as a thermally activated delayed fluorescent dopant. For example, in the light emitting element ED of an embodiment, the emission layer EML may include at least one of the polycyclic compounds shown in Compound Group 1 above as a thermally activated delayed fluorescent dopant. However, the usage of the polycyclic compound according to an embodiment is not limited thereto.

The polycyclic compound according to an embodiment may be to emit blue light. However, the embodiment of the present disclosure is not limited thereto.

In an embodiment, the emission layer EML may include a first compound represented by Formula 1, and further include at least one of a second compound represented by Formula HT, a third compound represented by Formula ET, or a fourth compound represented by Formula M-b.

For example, in an embodiment, the second compound may be utilized as a hole transporting host material of the emission layer EML.

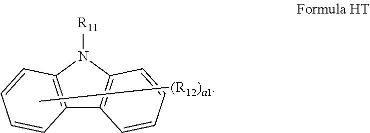

In Formula HT, a1 may be an integer of 0 to 8. When a1 is an integer of 2 or greater, a plurality of R₁₂'s may all be the same or at least one may be different from the others. R₁₁ and R₁₂ may each independently be a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms. For example, R₁₁ may be a substituted phenyl group, an unsubstituted dibenzofuran group, or a substituted fluorenyl group. R₁₂ may be a substituted or unsubstituted carbazole group.

The second compound may be any of the compounds of Compound Group 2. The light emitting element ED of an embodiment may include any one from among compounds of Compound Group 2. In Compound Group 2, D is a deuterium atom.

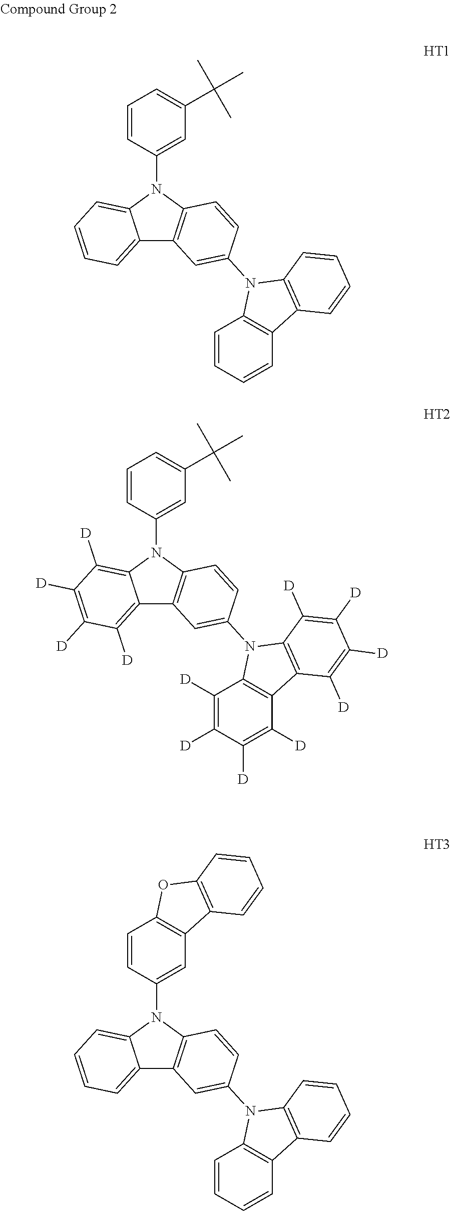 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

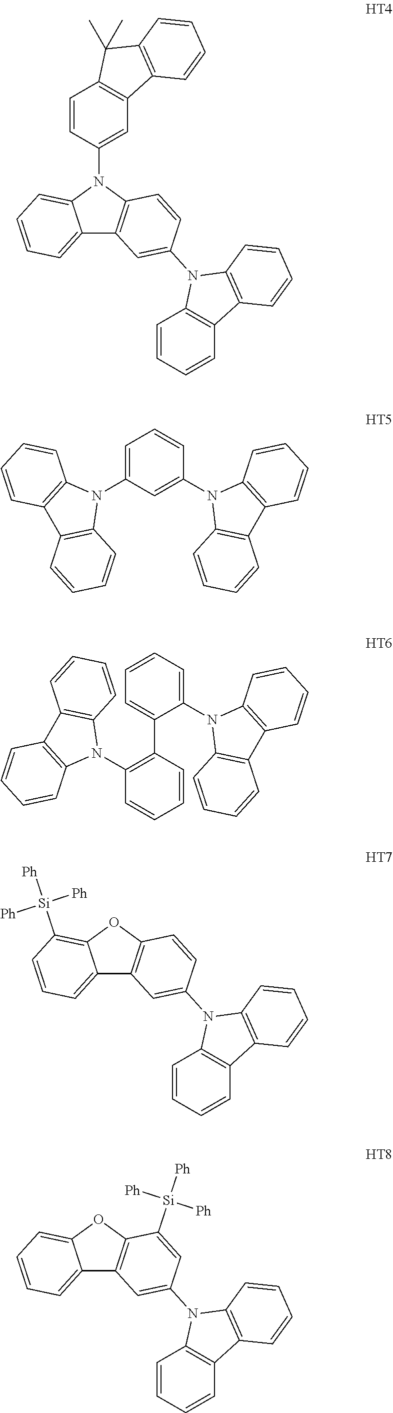 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

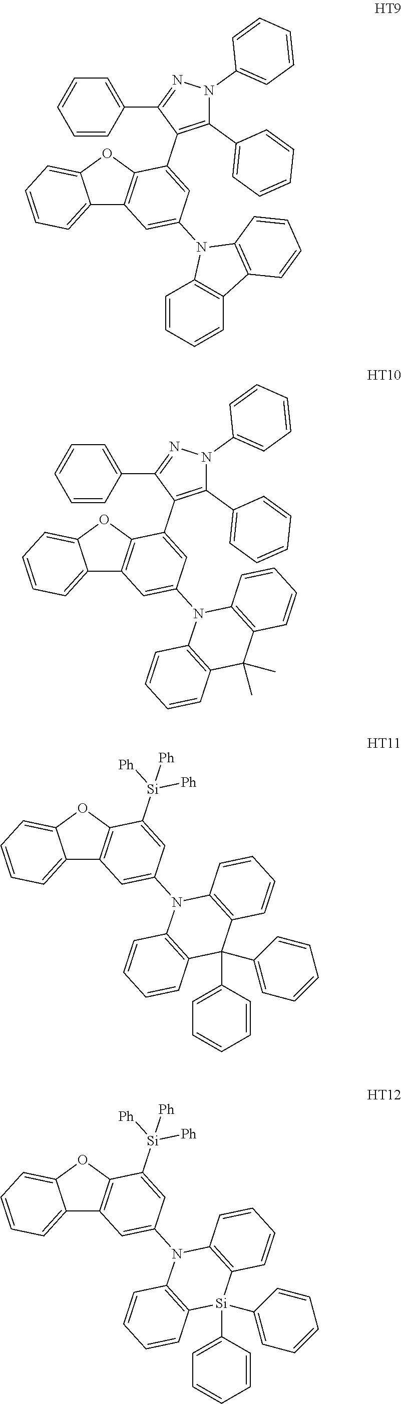 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

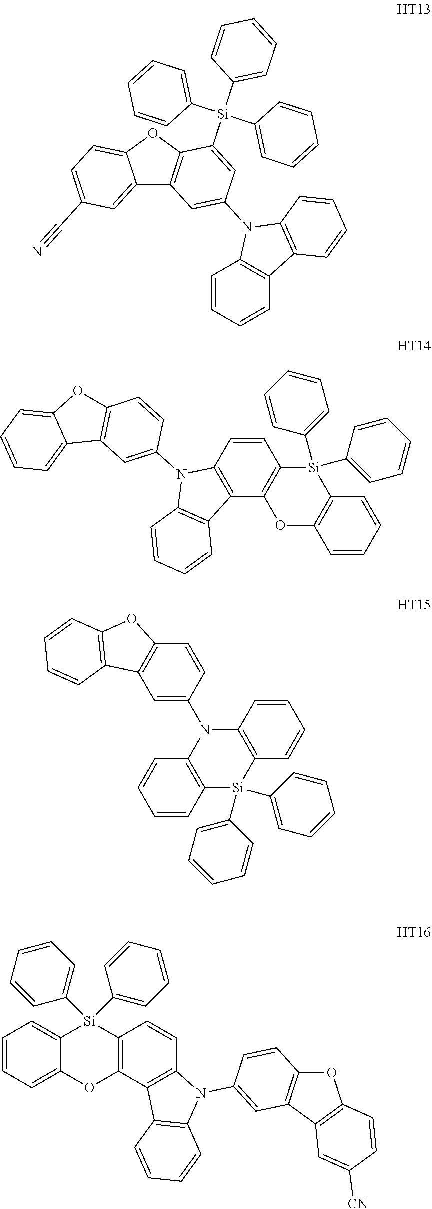 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

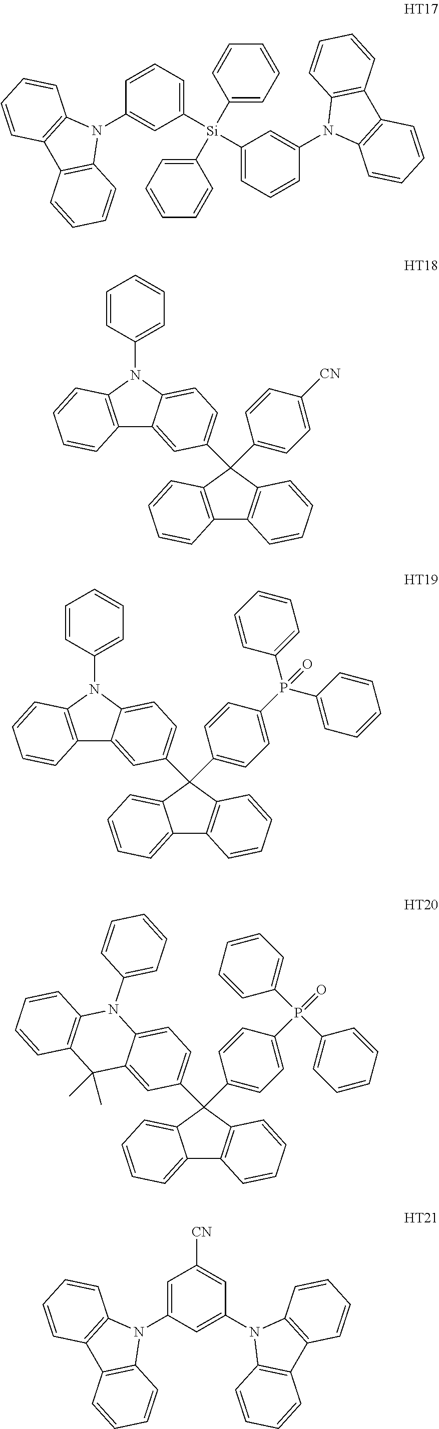 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1]

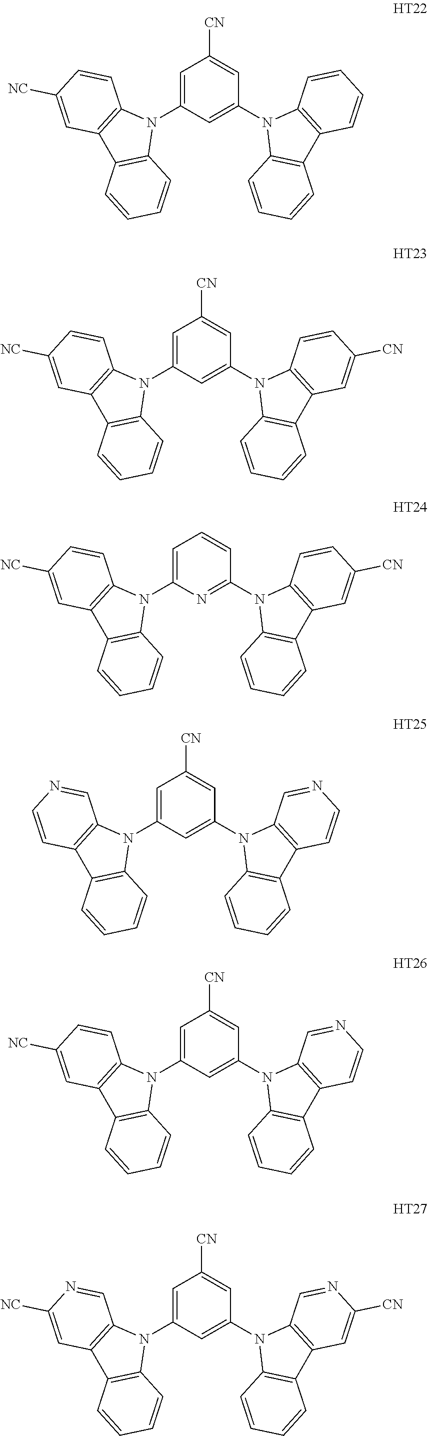 [SMILES: N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1]

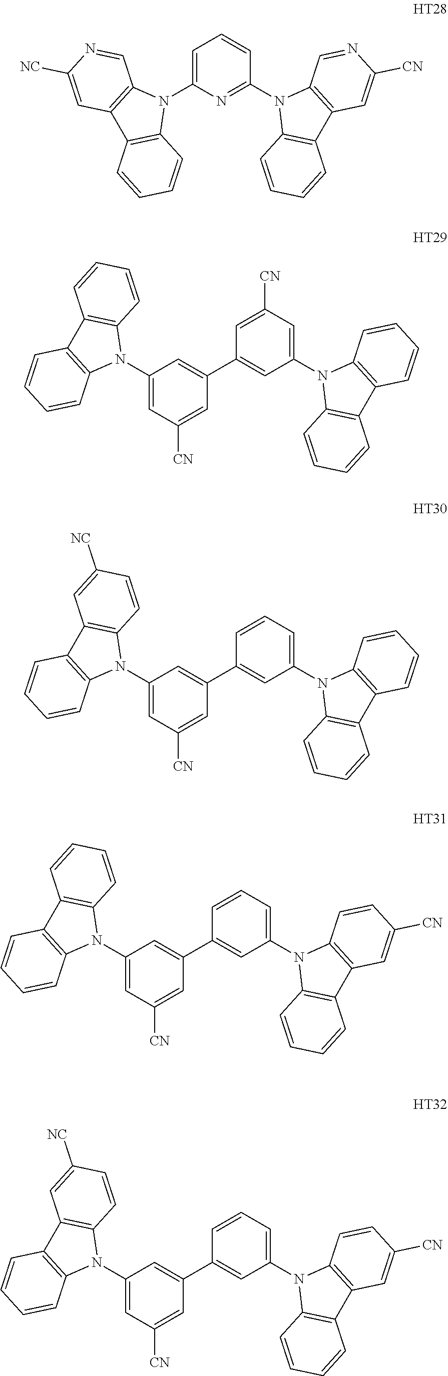 [SMILES: N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

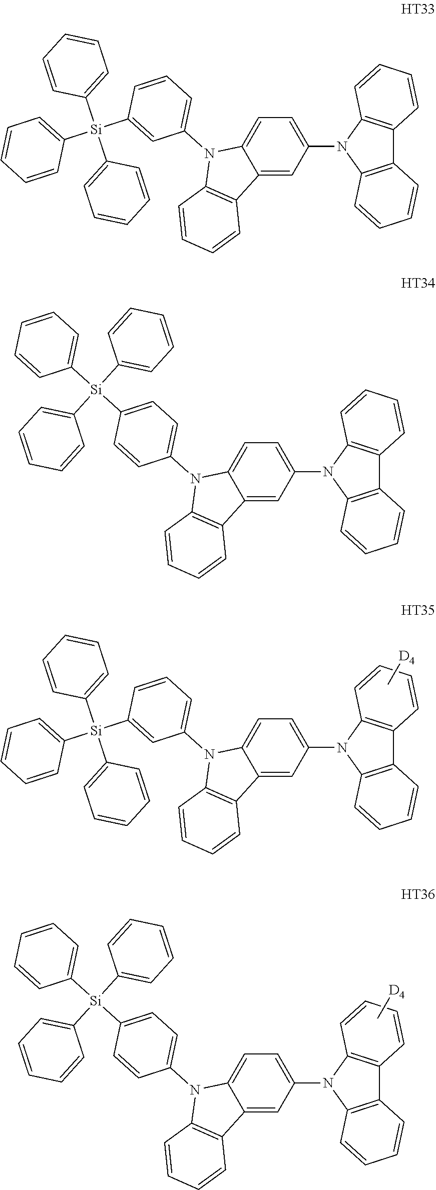

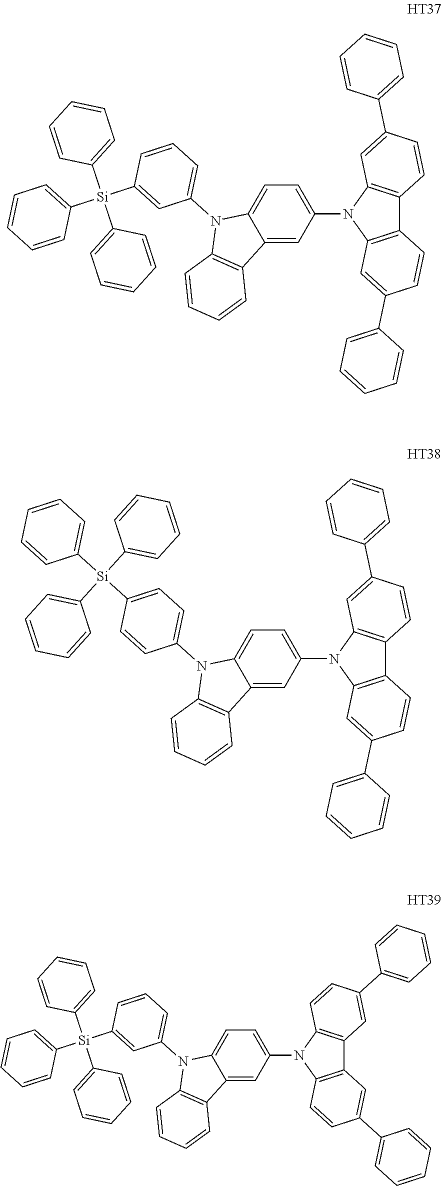 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1]

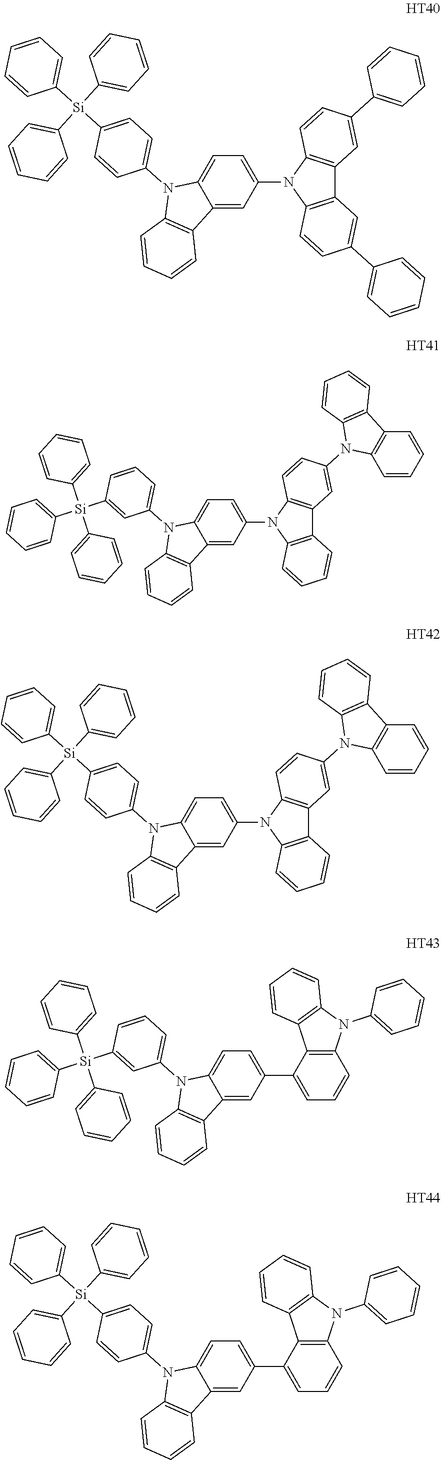

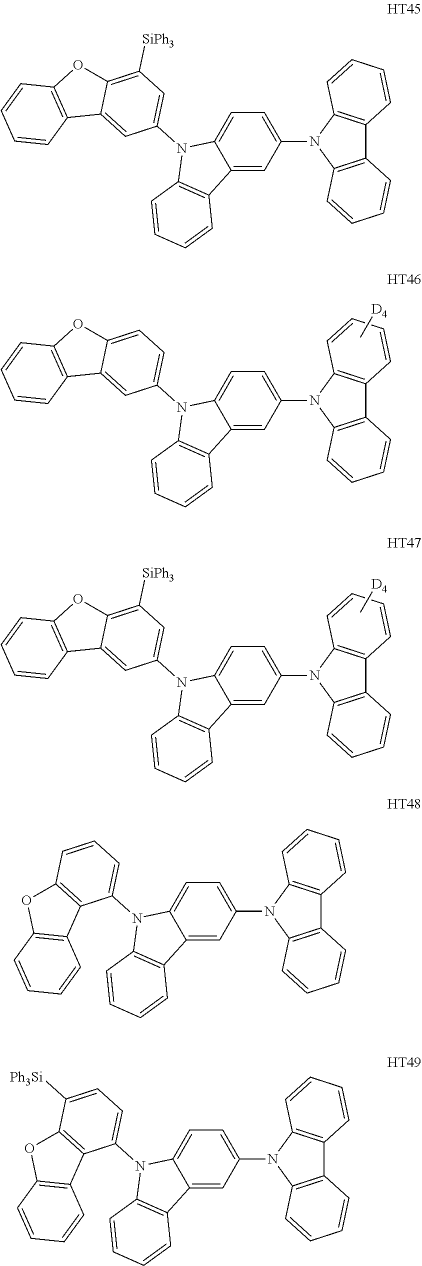

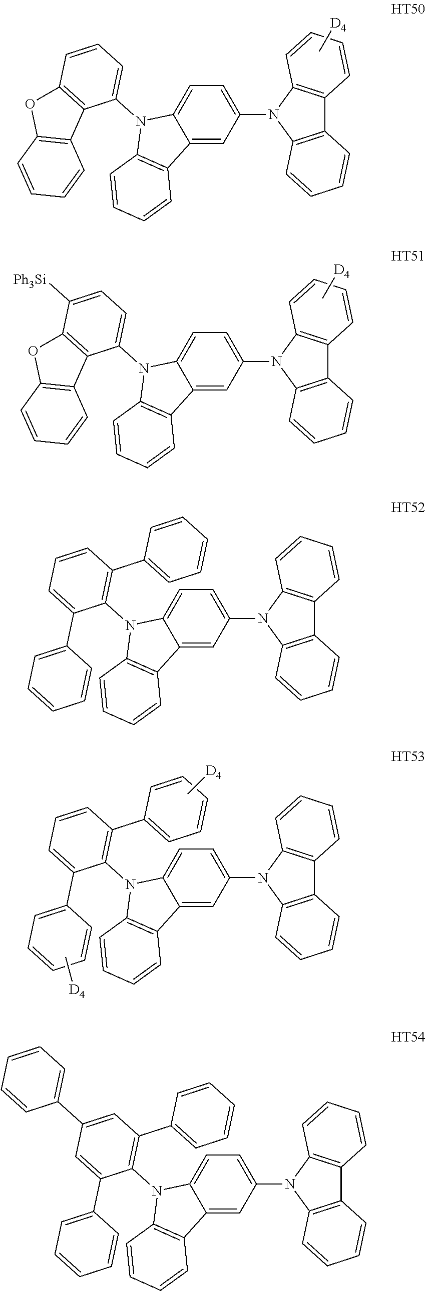

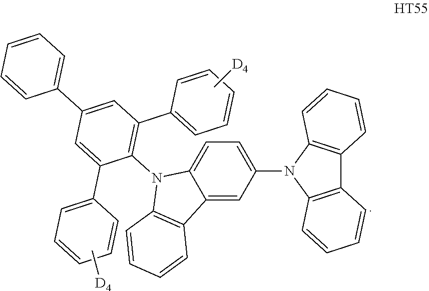

In an embodiment, the emission layer EML may include the third compound represented by Formula ET. For example, the third compound may be utilized as an electron transporting host material of the emission layer EML

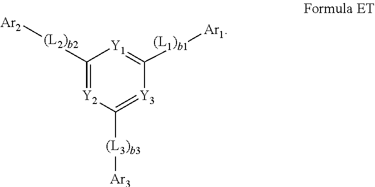

In Formula ET, at least one of Y₁ to Y₃ may be N, and the others may each be CRₐ, and Rₐ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

b1 to b3 may each independently be an integer of 0 to 10. L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms.

Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₁ to Ar₃ may each independently be a substituted or unsubstituted phenyl group or a substituted or unsubstituted carbazole group.

The third compound may be any of the compounds of Compound Group 3. The light emitting element ED of an embodiment may include any one from among compounds of Compound Group 3. In Compound Group 3, D is a deuterium atom.

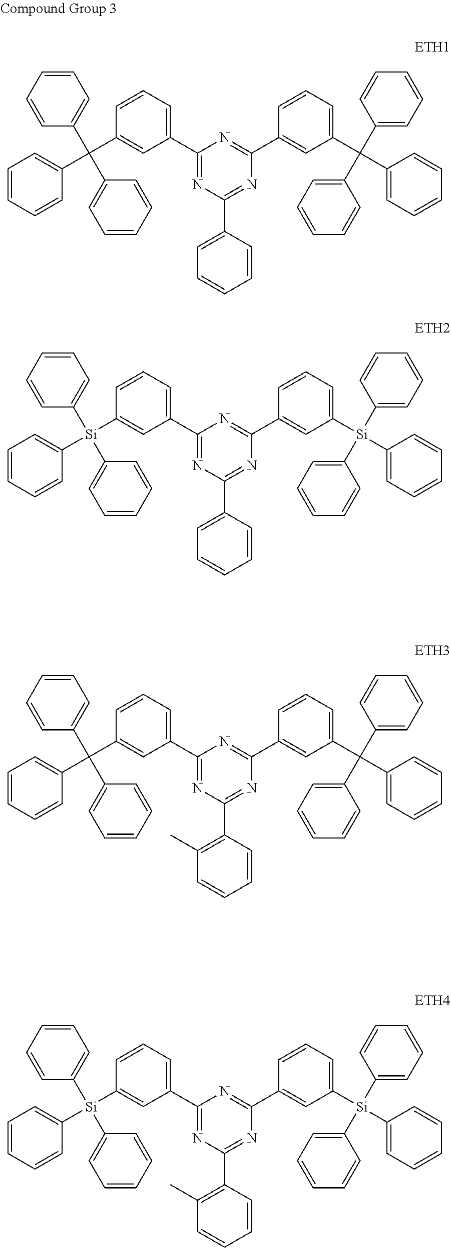 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

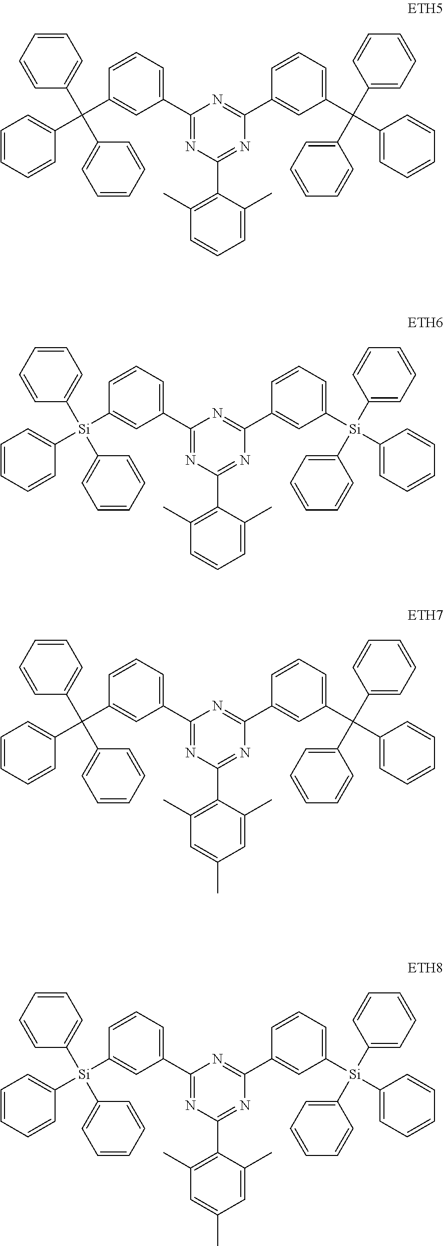 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

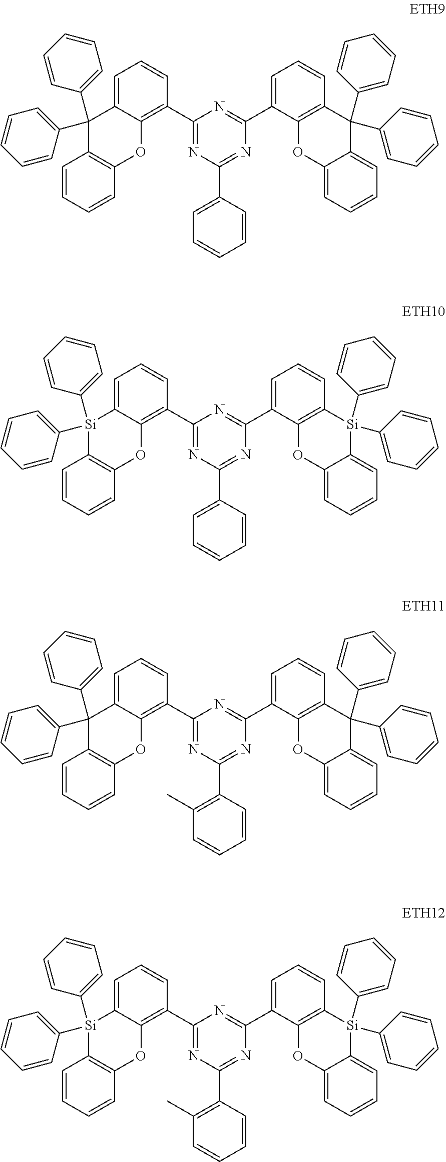 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

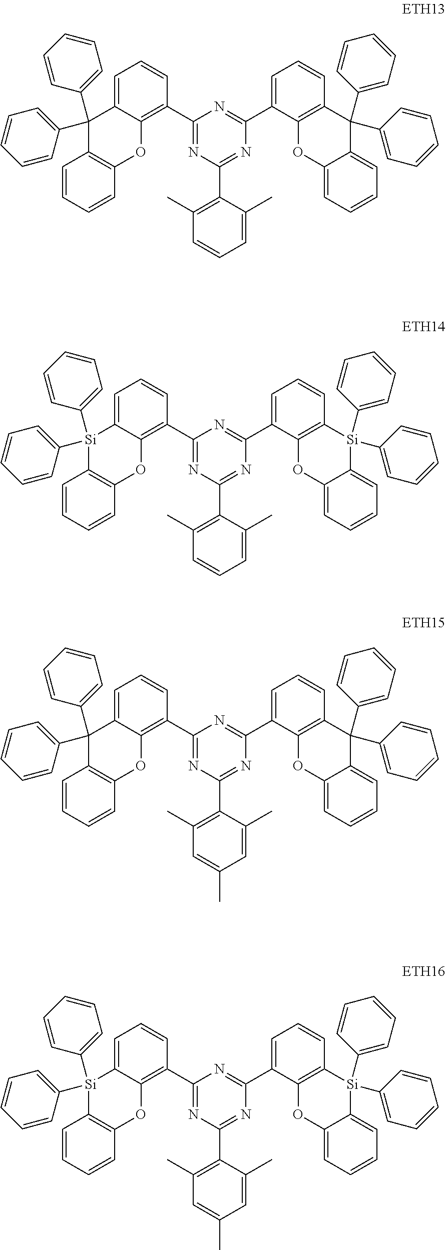 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

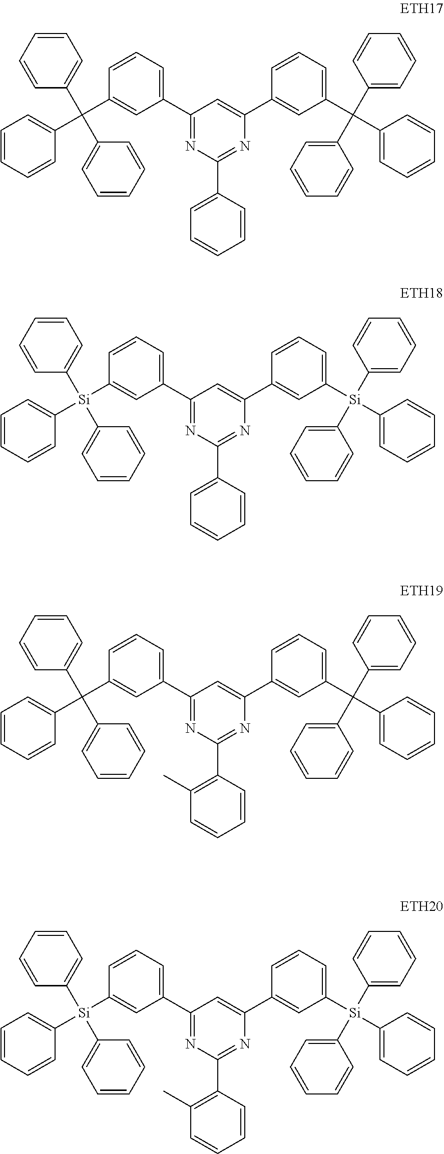 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

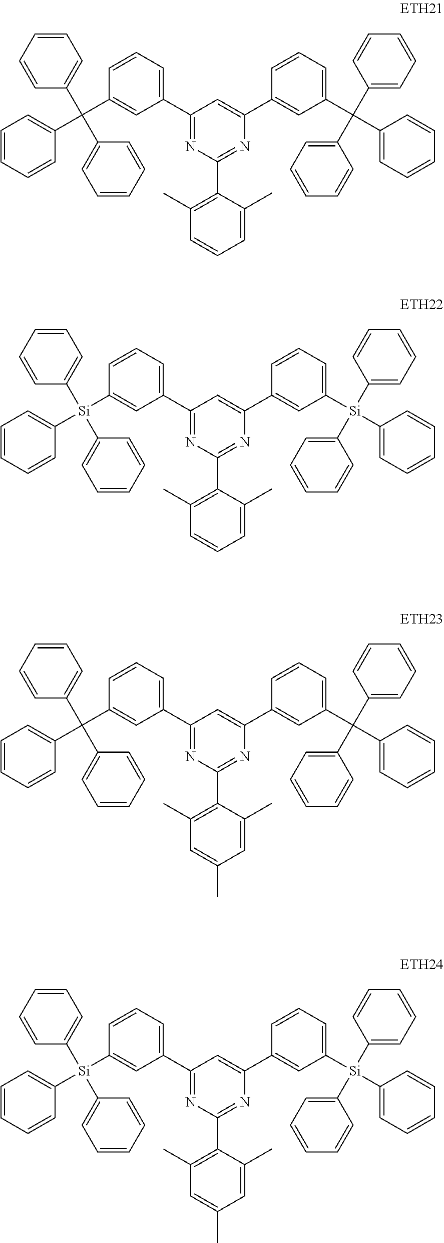 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

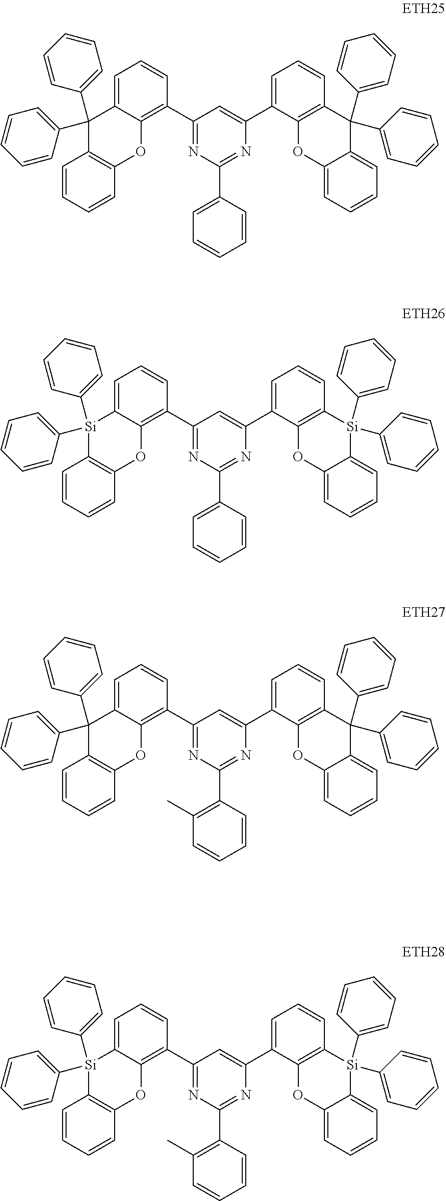 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

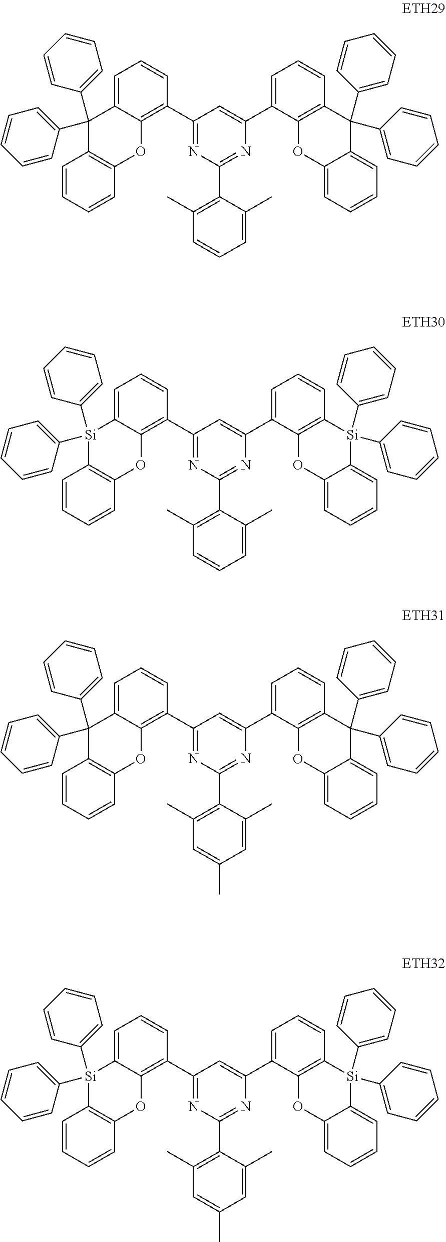 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

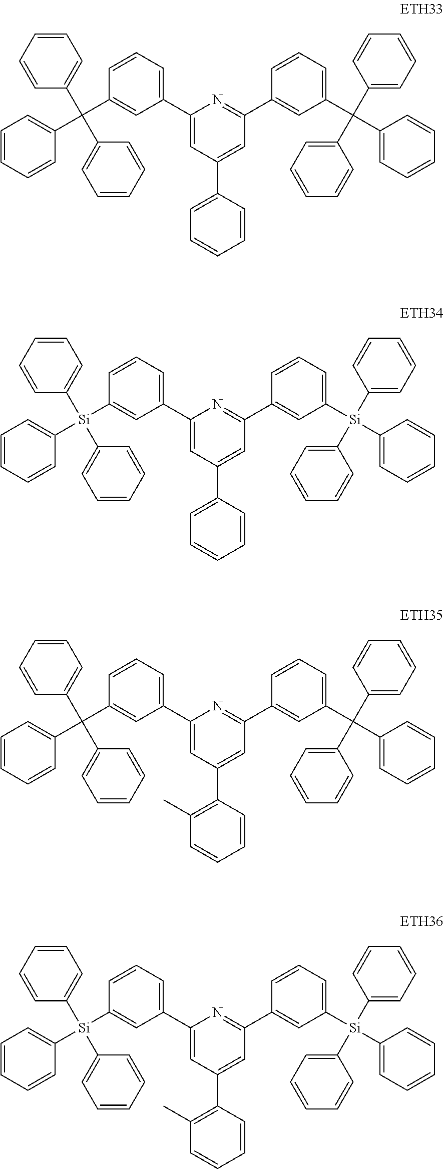 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

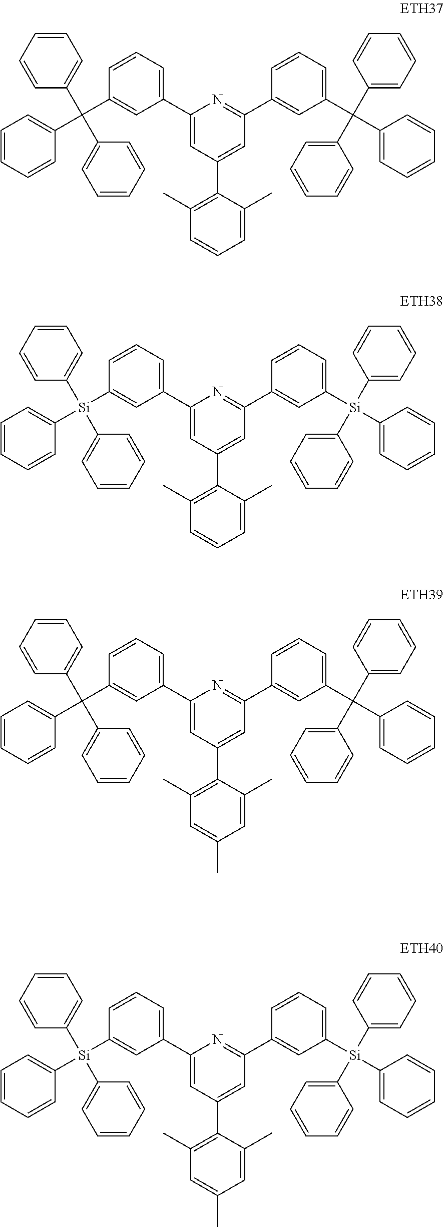 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

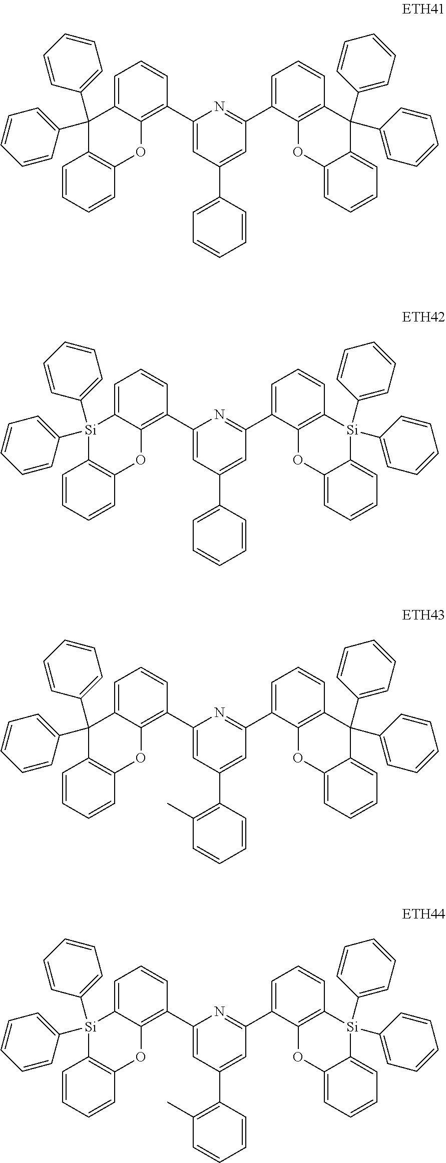 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

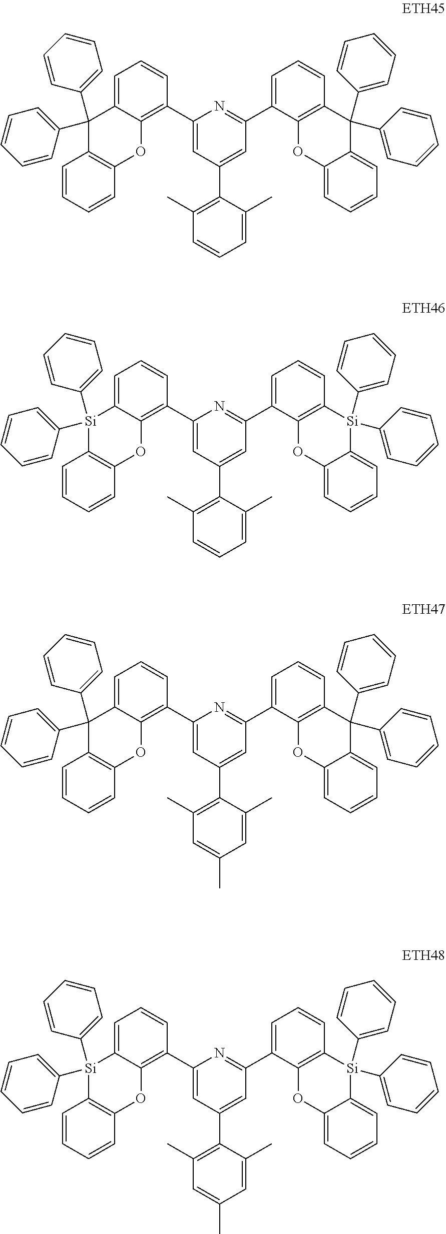 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

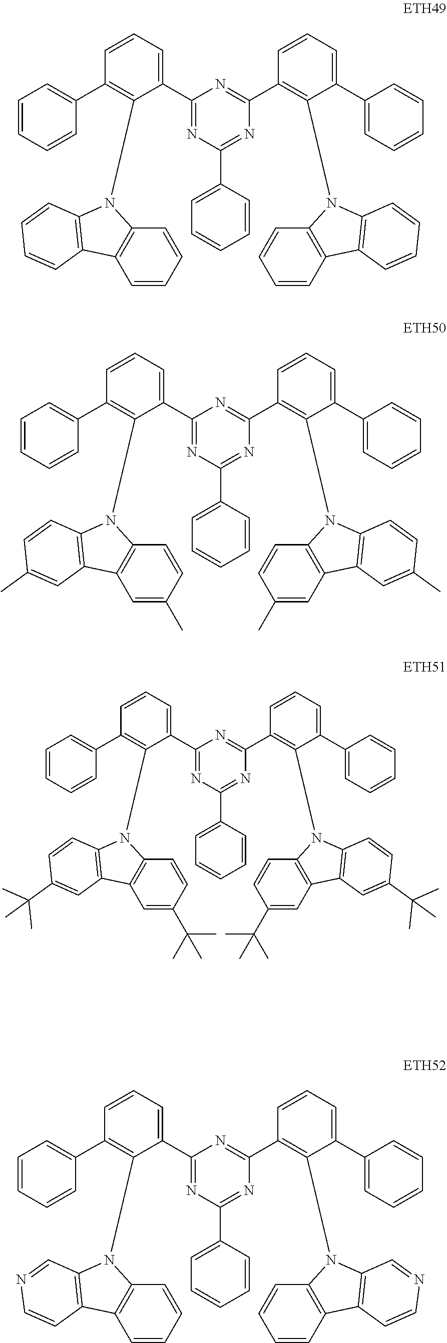

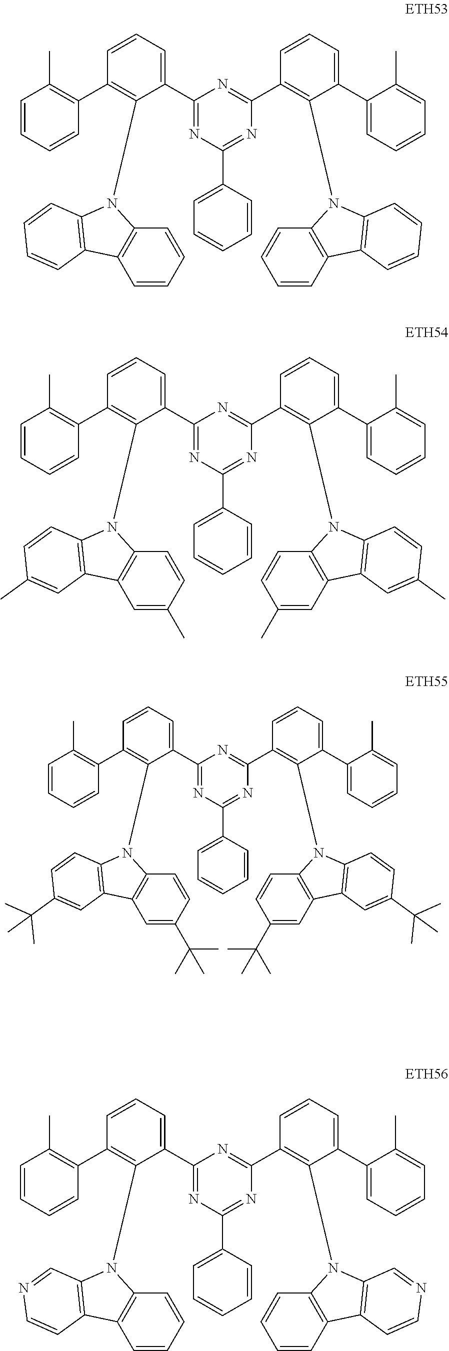

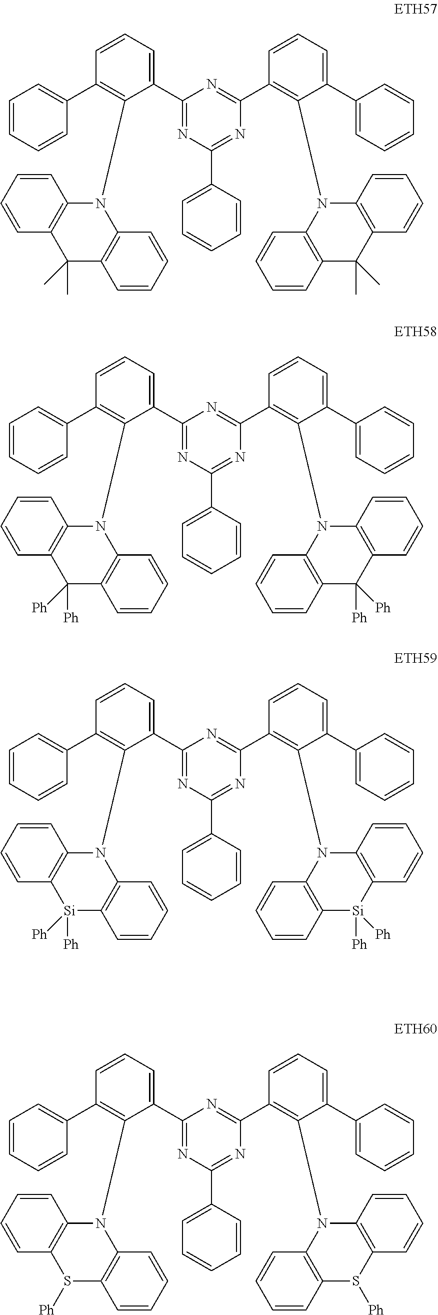

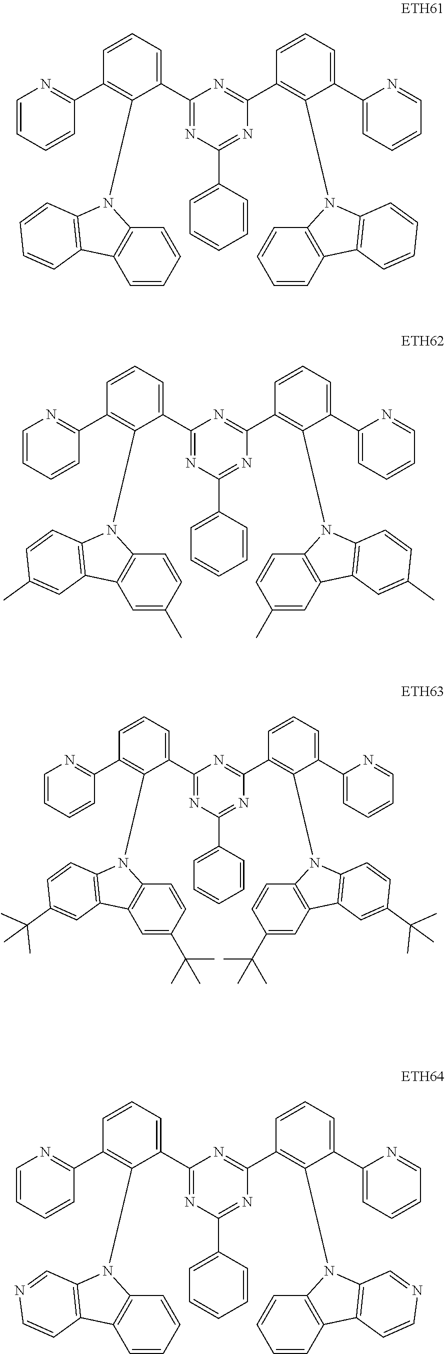

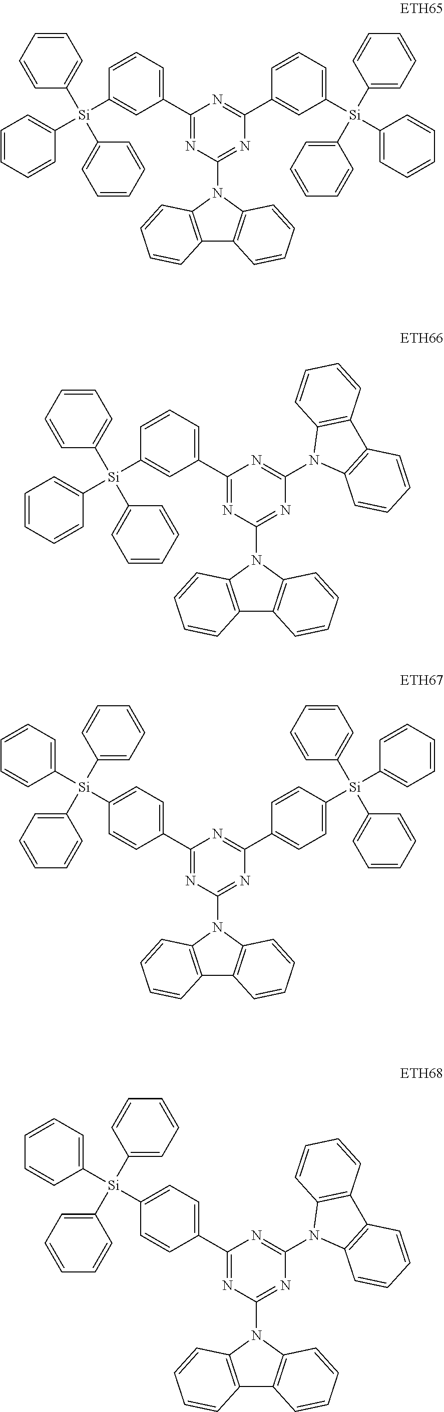 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

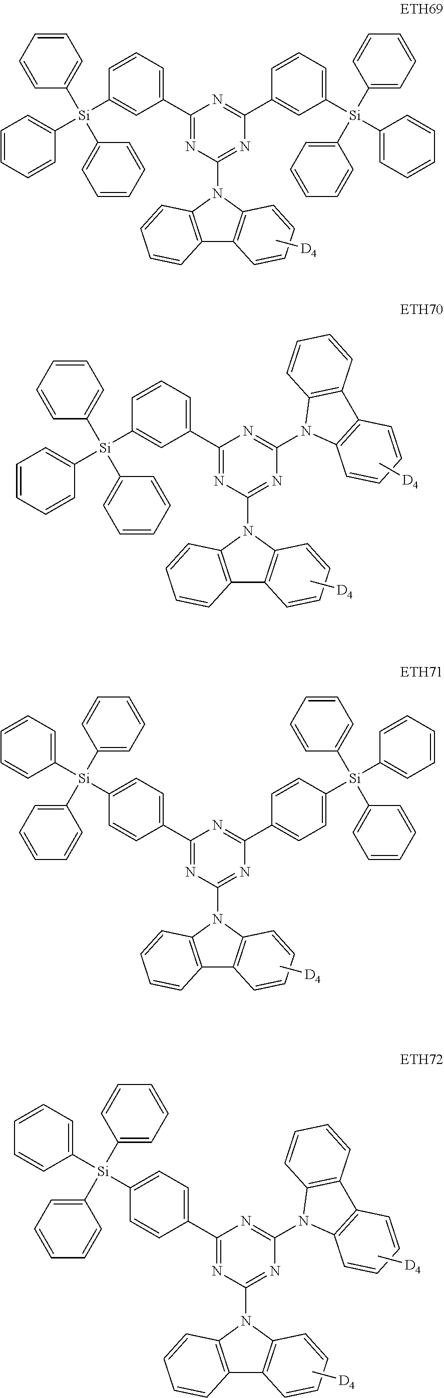

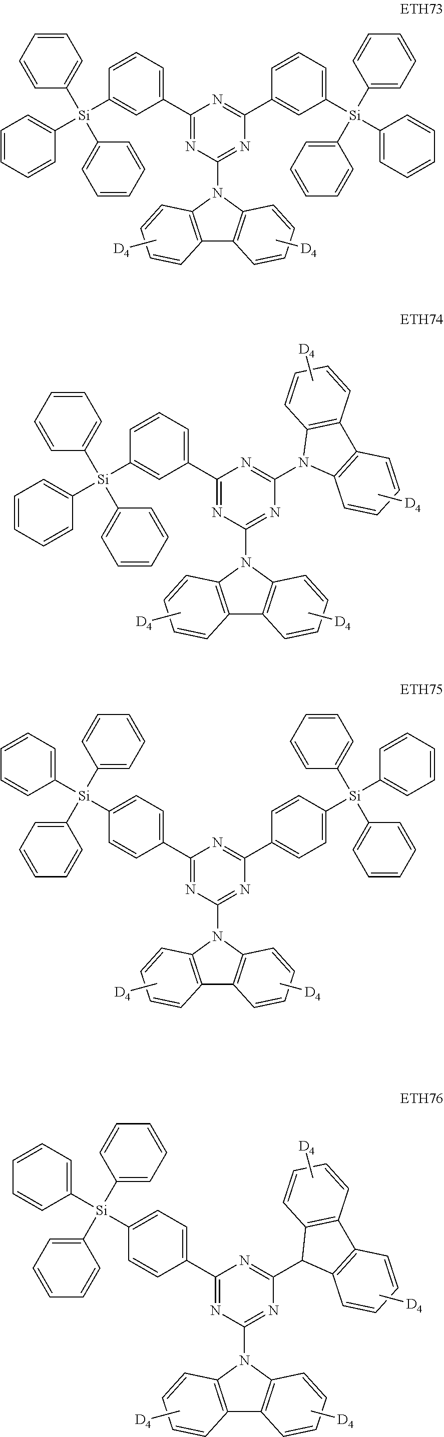

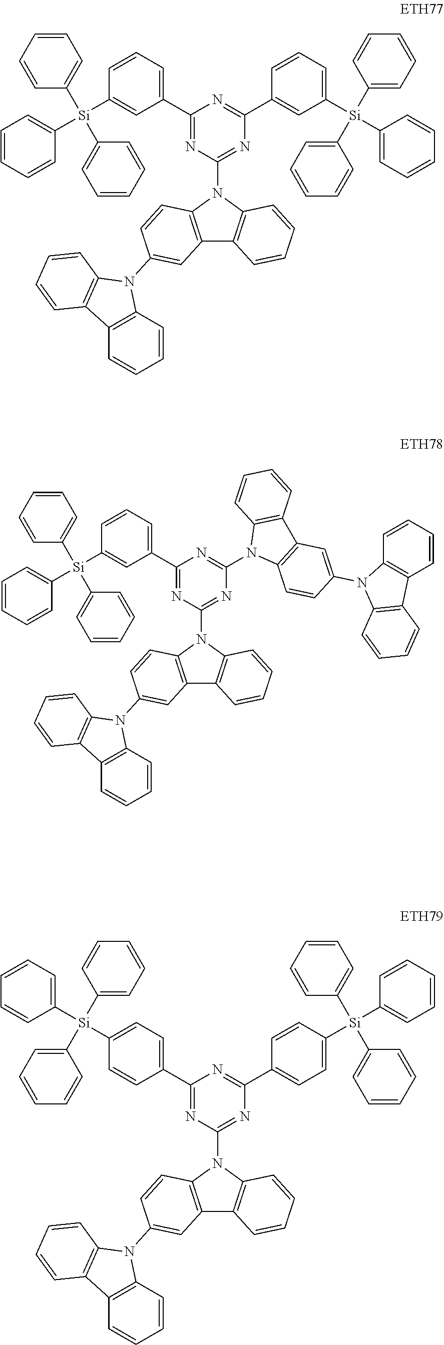 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

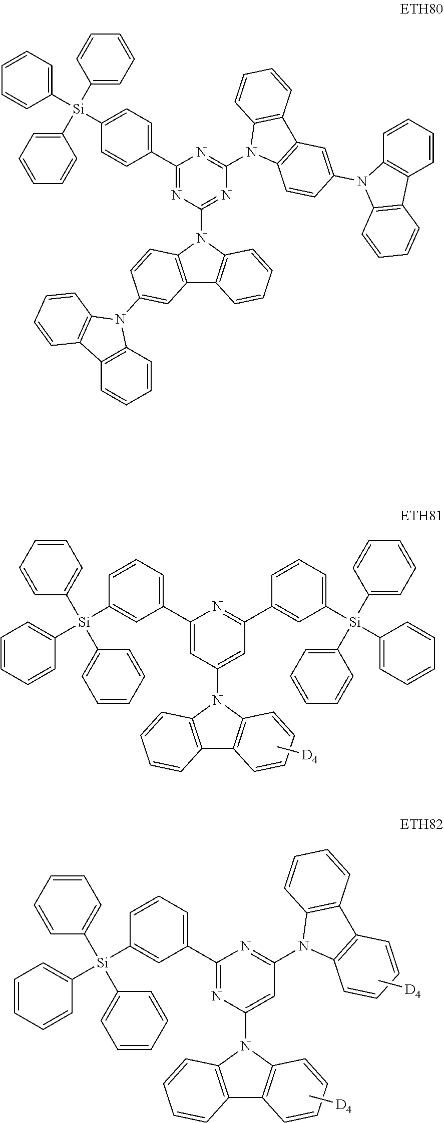

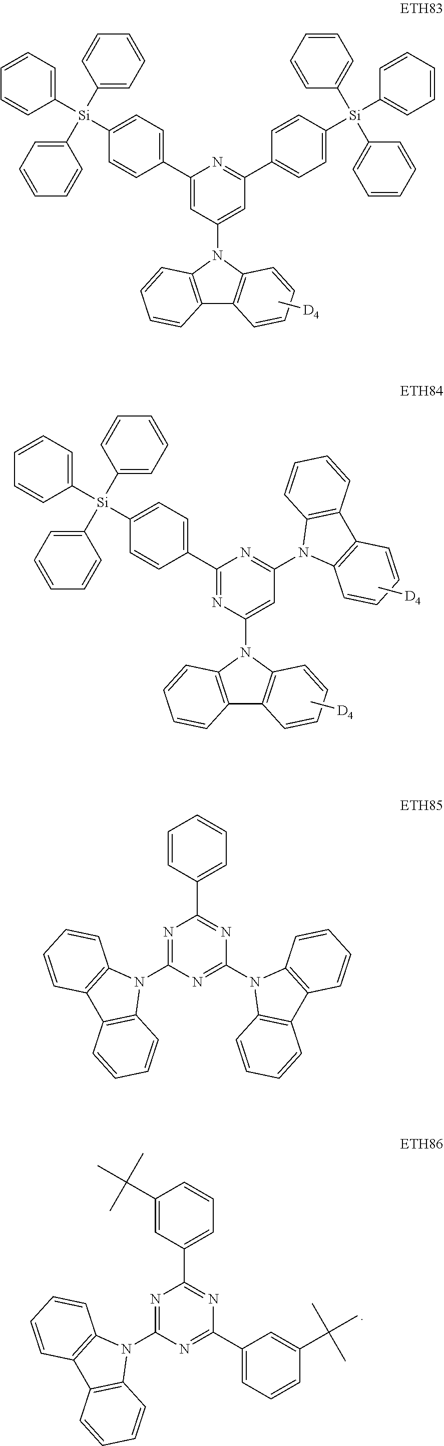

For example, the emission layer EML may include a second compound and a third compound, and the second compound and the third compound may form an exciplex. In the emission layer EML, the hole transporting host and the electron transporting host may form an exciplex. At this point, the triplet energy of the exciplex formed by the hole transporting host and the electron transporting host corresponds to a difference between the Lowest Unoccupied Molecular Orbital (LUMO) energy level of the electron transporting host and the Highest Occupied Molecular Orbital (HOMO) energy level of the hole transporting host.

For example, the triplet energy level (T1) of the exciplex formed by the hole transporting host and the electron transporting host may have an absolute value of about 2.4 eV to about 3.0 eV. In some embodiments, the triplet energy of the exciplex may have a value smaller than the energy gap of each host material. The exciplex may have a triplet energy of 3.0 eV or less, which is an energy gap between the hole transporting host and the electron transporting host.

In an embodiment, the emission layer EML may include the fourth compound represented by Formula M-b. For example, the fourth compound may be utilized as a phosphorescent sensitizer of the emission layer EML. Energy may be transferred from the fourth compound to the first compound to emit light.

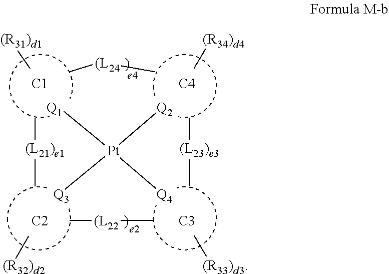

In Formula M-b, Q₁ to Q₄ may each independently be C or N, and C1 to C4 may each independently be a substituted or unsubstituted hydrocarbon ring group having 5 to 30 ring-forming carbon atoms, or a substituted or unsubstituted heterocyclic group having 2 to 30 ring-forming carbon atoms.

e1 to e4 may each independently be 0 or 1, and L₂₁ to L₂₄ may each independently be a direct linkage,

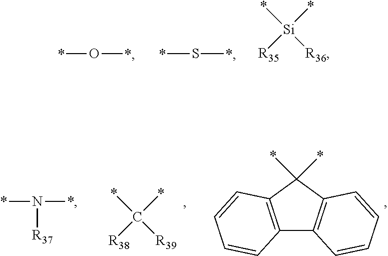

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms.

d1 to d4 may each independently be an integer of 0 to 4. When d1 is an integer of 2 or greater, a plurality of R₃₁'s may all be the same or at least one may be different from the others. When d2 is an integer of 2 or greater, a plurality of R₃₂'s may all be the same or at least one may be different from the others. When d3 is an integer of 2 or greater, a plurality of R₃₃'s may all be the same or at least one may be different from the others. When d4 is an integer of 2 or greater, a plurality of R₃₄'s may all be the same or at least one may be different from the others.

R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or linked to an adjacent group to form a ring.

The fourth compound may be any of the compounds of Compound Group 4. The light emitting element ED of an embodiment may include any one from among compounds of Compound Group 4.

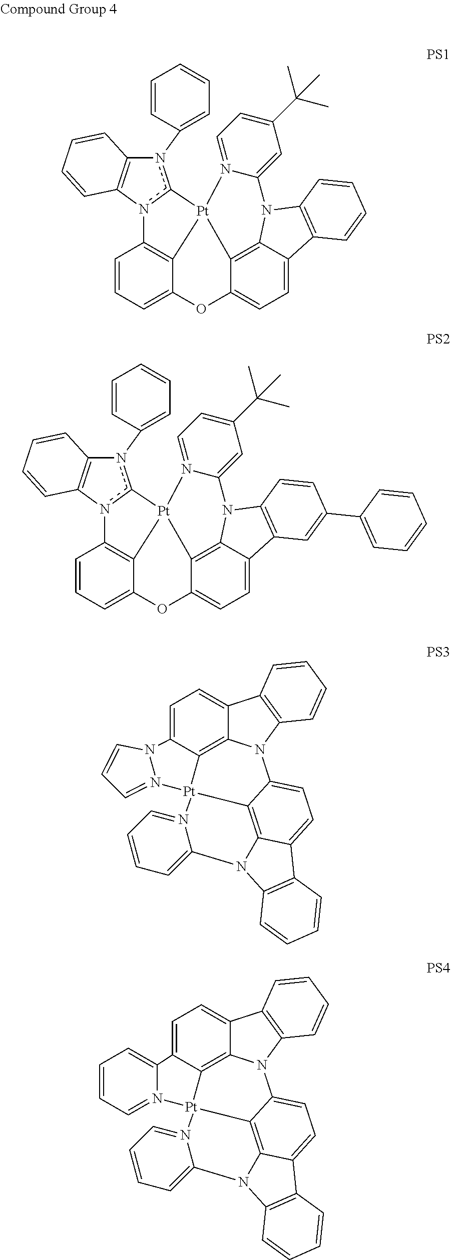

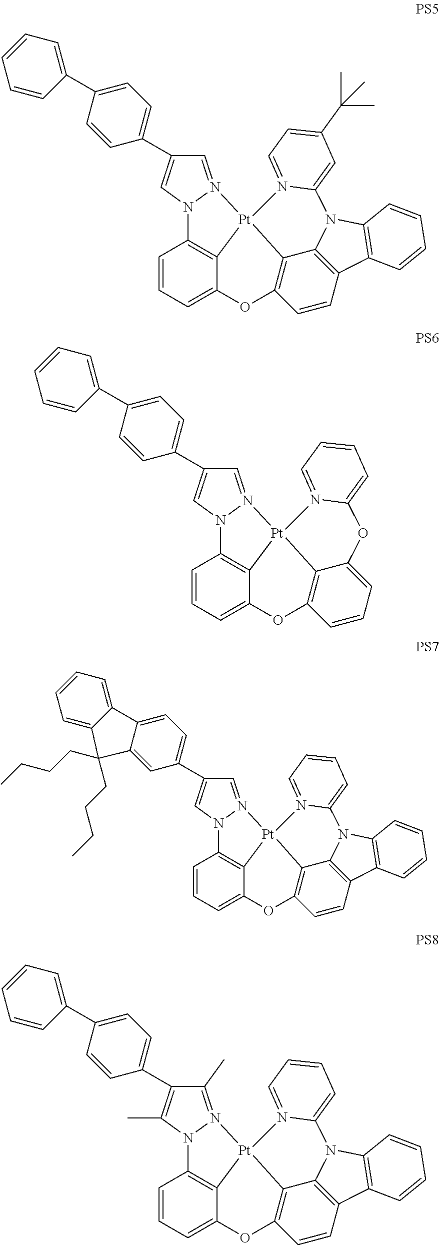

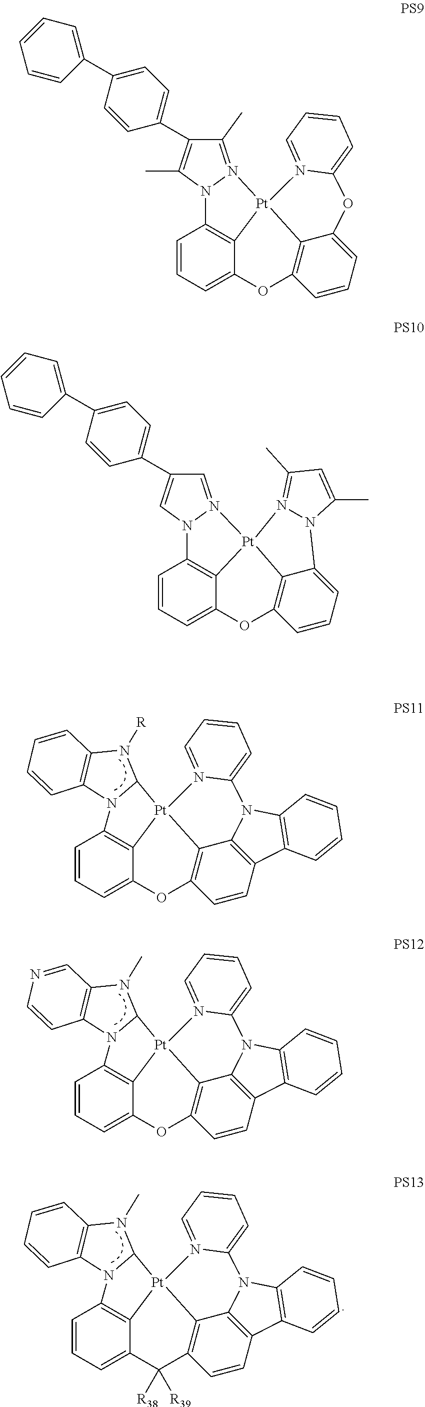

In the compounds above, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

The emission layer EML according to an embodiment may include the first compound which is the polycyclic compound, and at least one of the second to fourth compounds. For example, the emission layer EML may include the first compound, the second compound, and the third compound. In the emission layer EML, the second compound and the third compound form an exciplex, and energy may be transferred from the exciplex to the first compound to emit light.

In some embodiments, the emission layer EML may include the first compound, the second compound, the third compound, and the fourth compound. In the emission layer EML, the second compound and the third compound form an exciplex, and energy may be transferred from the exciplex to the fourth compound and the first compound to emit light. The fourth compound may be referred to as a phosphorescent sensitizer. For example, the fourth compound may be to emit phosphorescence light or transfer energy to the first compound as an auxiliary dopant. However, this is presented as an example, and the embodiment of the present disclosure is not limited thereto.

In some embodiments, the emission layer EML may further include suitable light emitting materials in addition to the first to fourth compounds. In the light emitting element ED of an embodiment, the emission layer EML may further include an anthracene derivative, a pyrene derivative, a fluoranthene derivative, a chrysene derivative, a dihydrobenzanthracene derivative, and/or a triphenylene derivative. For example, the emission layer EML may further include an anthracene derivative and/or a pyrene derivative.

In the light emitting element ED of an embodiment shown in FIGS. 3 to 6, the emission layer EML may include a compound represented by Formula E-1. The compound represented by Formula E-1 may be utilized as a fluorescent host material.

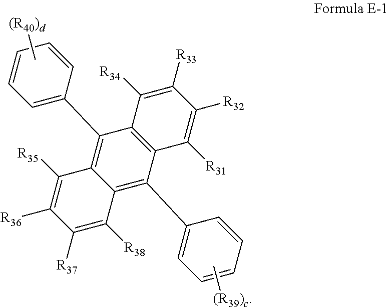

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. In some embodiments, R₃₁ to R₄₀ may be linked to an adjacent group to form a saturated hydrocarbon ring, an unsaturated hydrocarbon ring, a saturated heterocycle, or an unsaturated heterocycle.

In Formula E-1, c and d may each independently be an integer of 0 to 5.

The compound represented by Formula E-1 may be represented by any one of compounds E1 to E19.

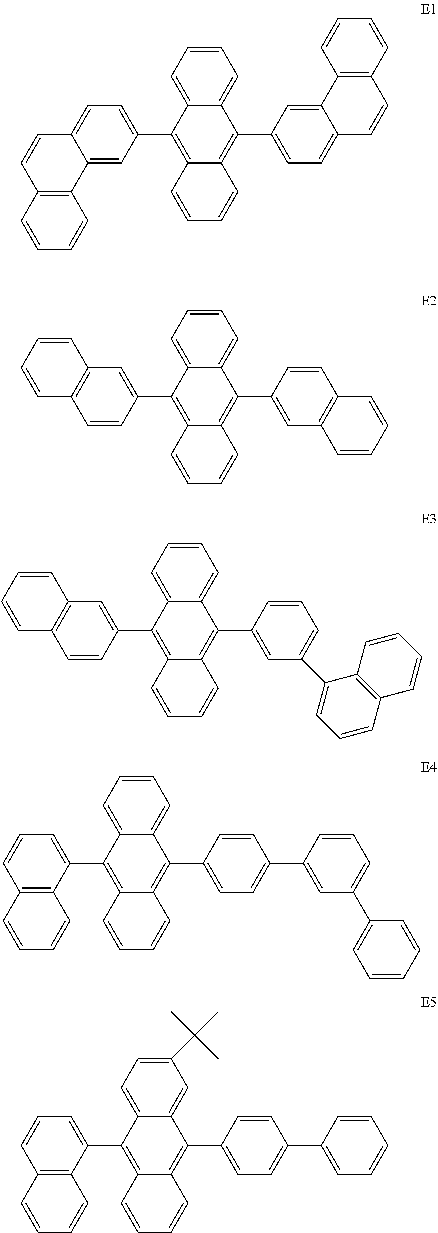

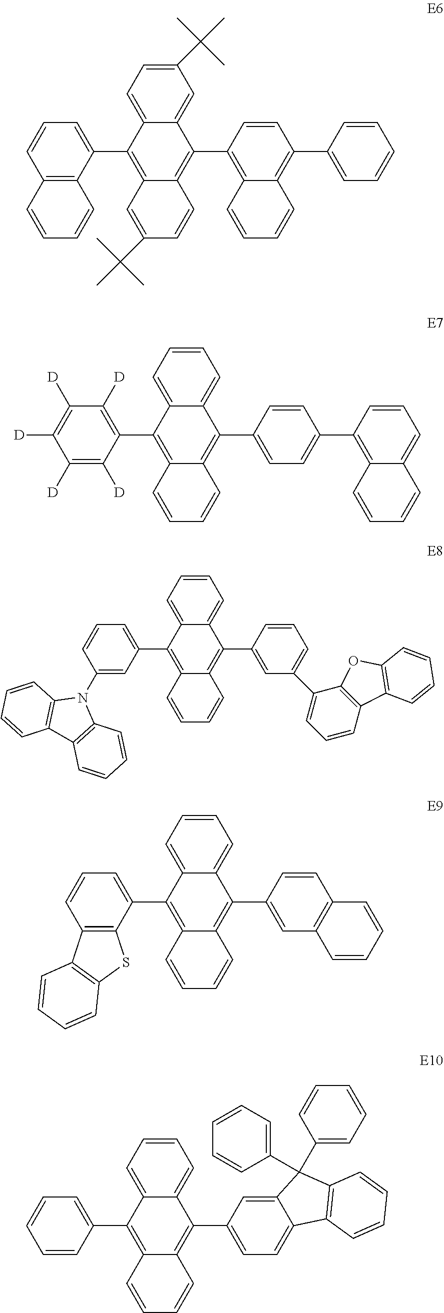

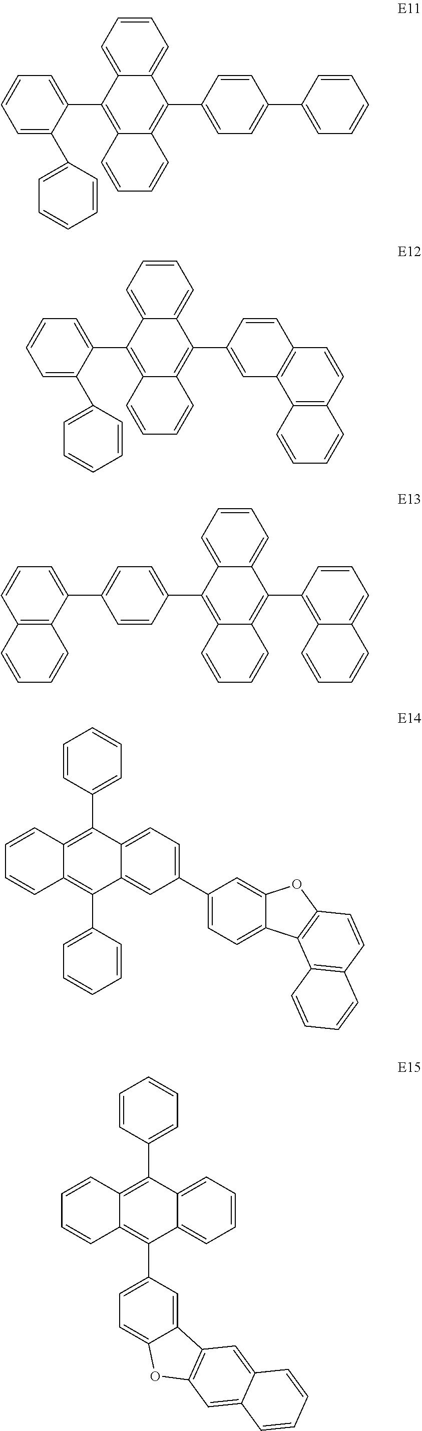

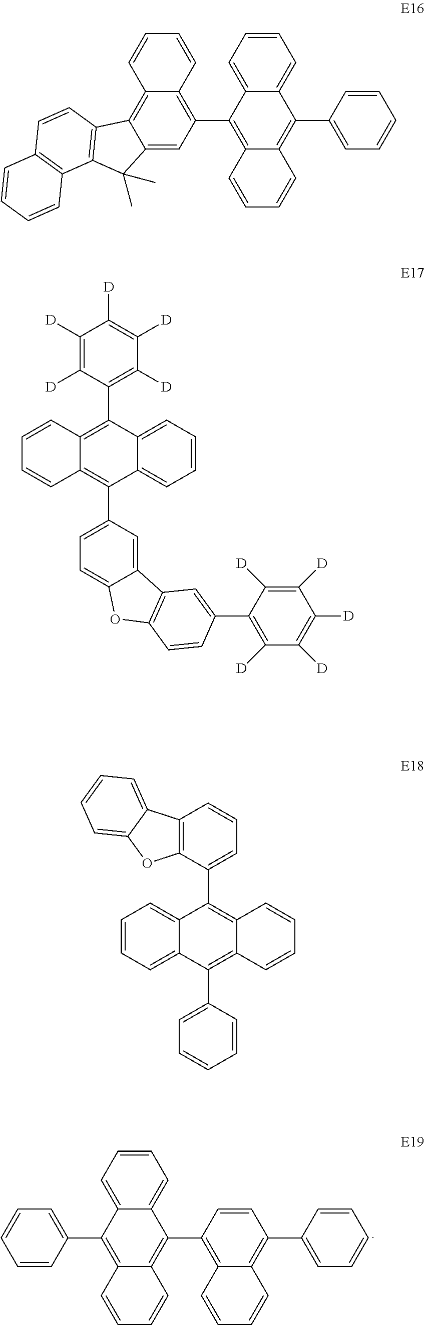

In an embodiment, the emission layer EML may include a compound represented by Formula E-2a or Formula E-2b. The compound represented by Formula E-2a or Formula E-2b may be utilized as a phosphorescent host material.

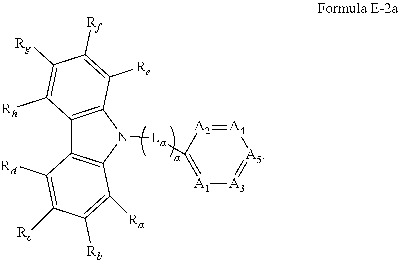

In Formula E-2a, a may be an integer of 0 to 10, and La may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or greater, a plurality of La's may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRᵢ. Rₐ to R₁ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or linked to an adjacent group to form a ring. In an embodiment, Rₐ to R₁ may be linked to an adjacent group to form a hydrocarbon ring or a heterocycle containing N, O, S, etc. as a ring-forming atom.

In some embodiments, in Formula E-2a, two or three selected from A₁ to A₅ may be N, and the rest (e.g., any remainder thereof) may be CRᵢ.

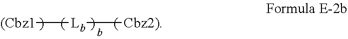

In Formula E-2b, Cbz1 and Cbz2 may each independently be an unsubstituted carbazole group or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms, b may be an integer of 0 to 10, and when b is an integer of 2 or greater, a plurality of L_{b}'s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be any one of the compounds from Compound Group E-2. However, the compounds listed in Compound Group E-2 are presented as an example, and the compound represented by Formula E-2a or Formula E-2b is not limited to those listed in Compound Group E-2.

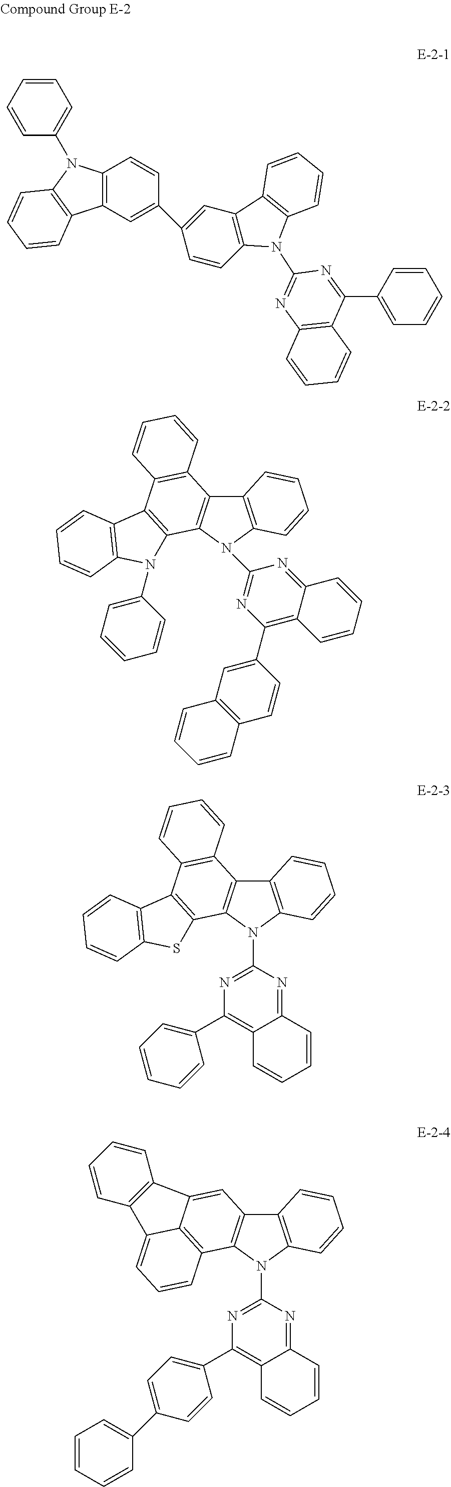

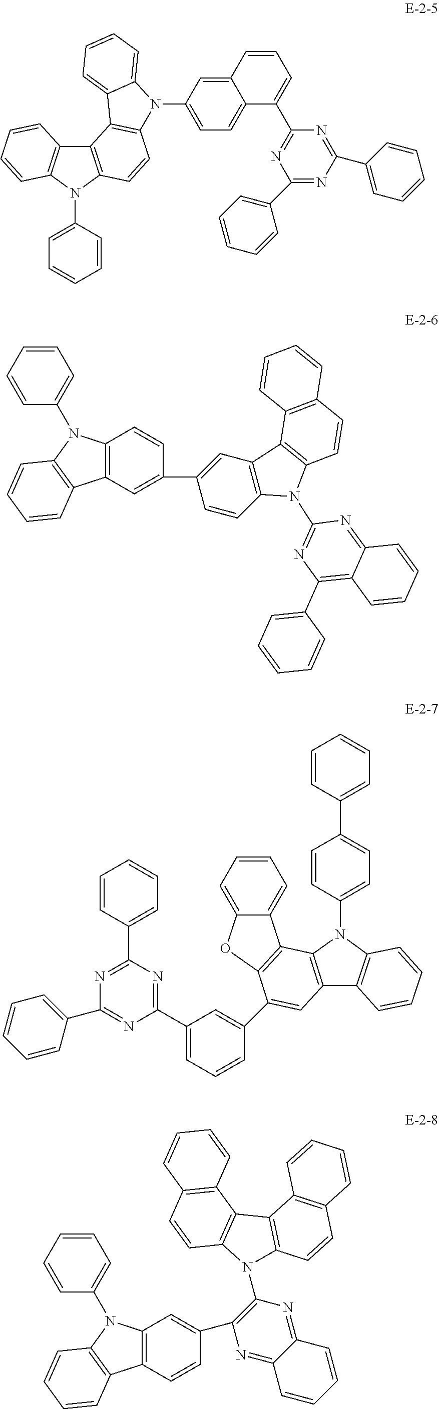 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

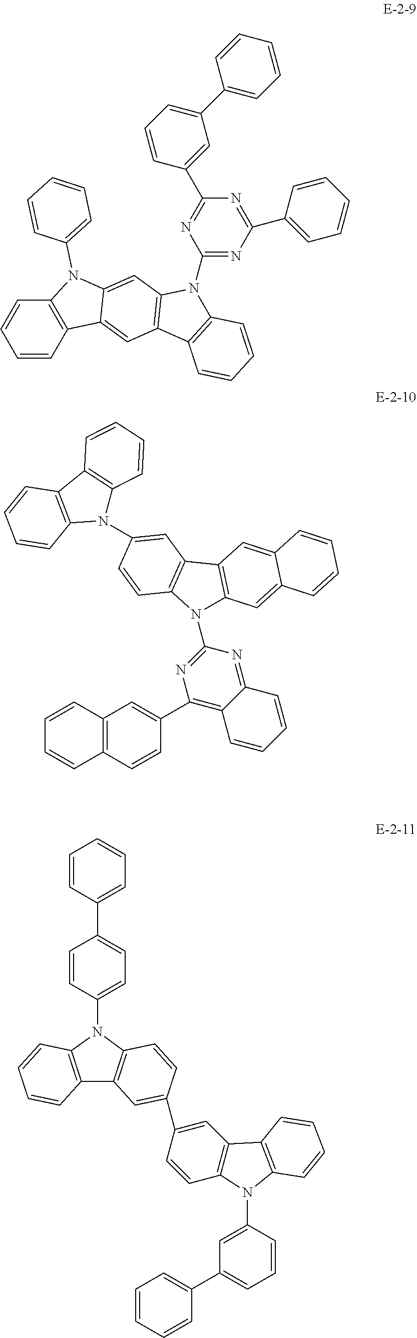 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

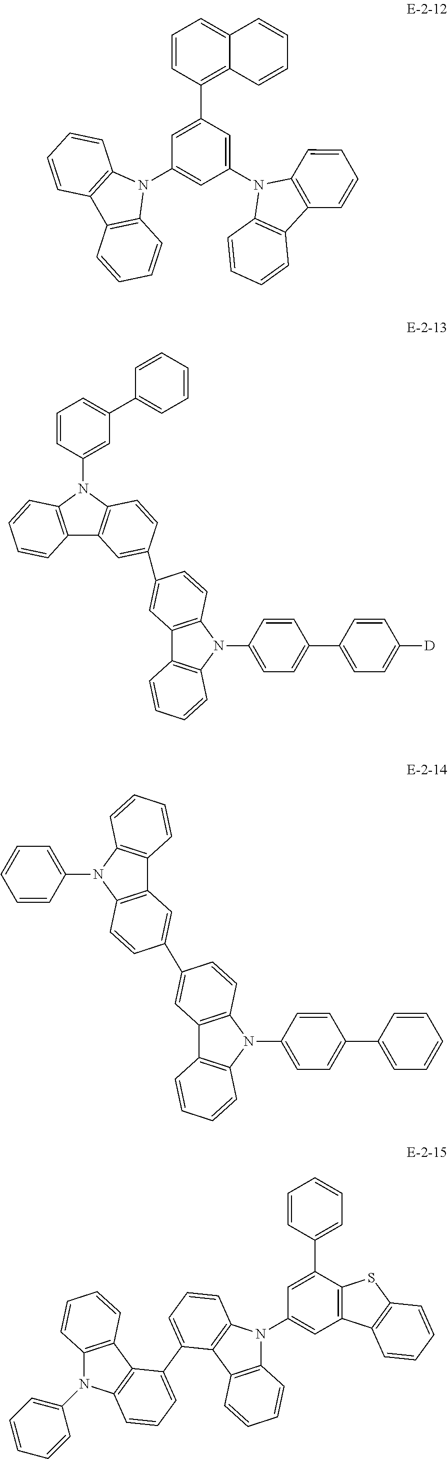 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

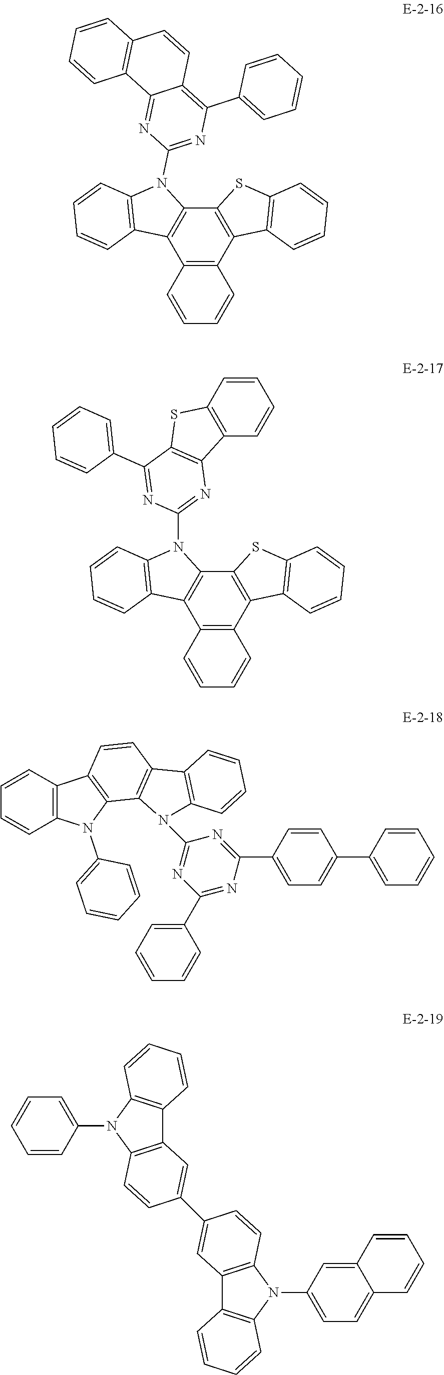 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1]

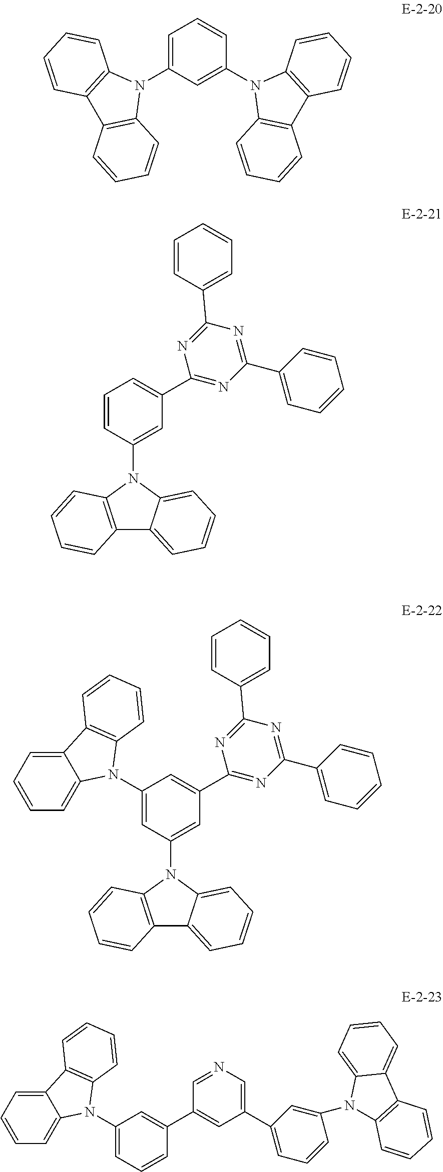 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

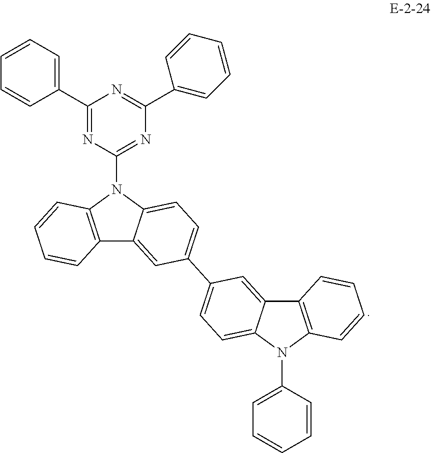 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a general material suitable in the art as a host material. For example, the emission layer EML may include, as a host material, at least one selected from among bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 3,3′-Di(9H-carbazol-9-yl)-1,1′-biphenyl (mCBP), 4,4′-bis(N-carbazolyl)-1,1′-biphenyl (CBP), 1,3-bis(carbazolyl-9-yl)benzene (mCP), 2,8-bis(diphenylphosphoryl)dibenzofuran (PPF), 4,4′,4″-tris(carbazol-9-yl)-triphenylamine (TCTA), and 1,3,5-tris(1-phenyl-1H-benzo[d]imidazol-2-yl)benzene (TPBi). However, the embodiment of the present disclosure is not limited thereto, and for example, tris(8-hydroxyquinolinato)aluminum (Alq₃), 9,10-di(naphthalene-2-yl)anthracene (ADN), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be utilized as a host material.

The emission layer EML may include a compound represented by Formula M-a. The compound represented by Formula M-a may be utilized as a phosphorescent dopant material. In an embodiment, the compound represented by Formula M-a may be utilized an assistant dopant material.

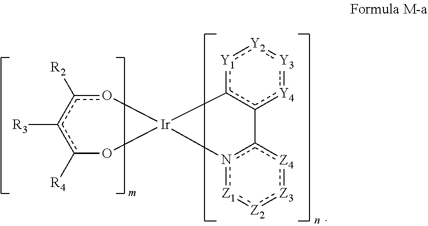

In Formula M-a above, Y₁ to Y₄, and Z₁ to Z₄ may each independently be CR₁or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. In Formula M-a, m is 0 or 1, and n is 2 or 3. In Formula M-a, when m is 0, n is 3, and when m is 1, n is 2.

The compound represented by Formula M-a may be represented by any one from among compounds M-a1 to M-a25. However, the compounds M-a1 to M-a25 are presented as an example, and the compound represented by Formula M-a is not limited to those represented by the compounds M-a1 to M-a25.

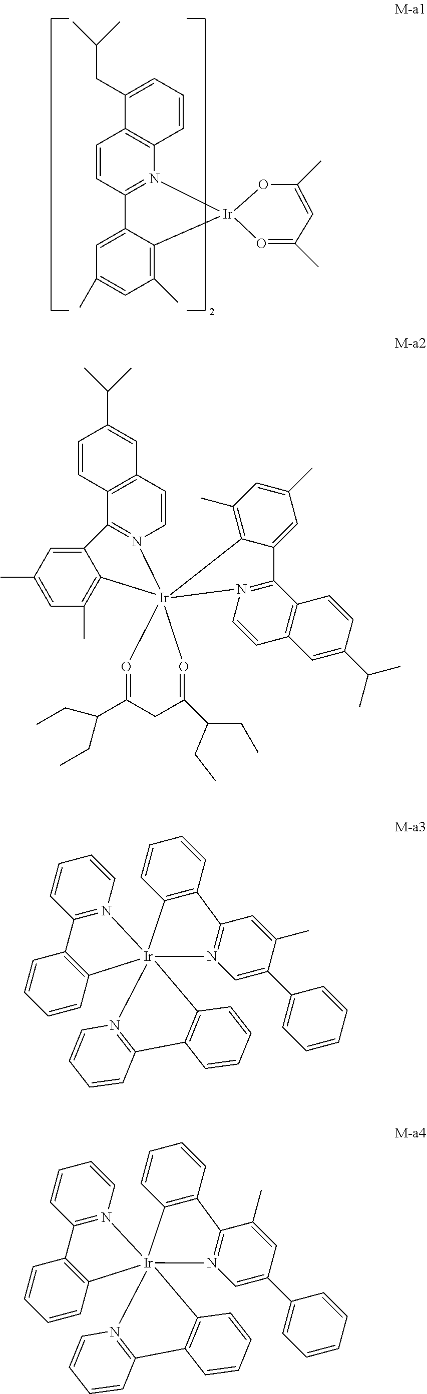

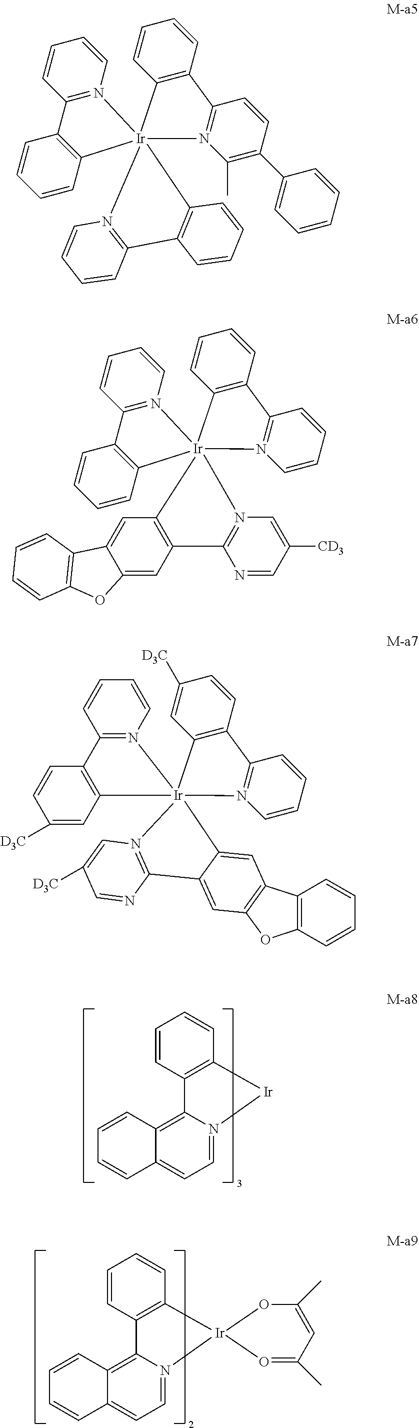

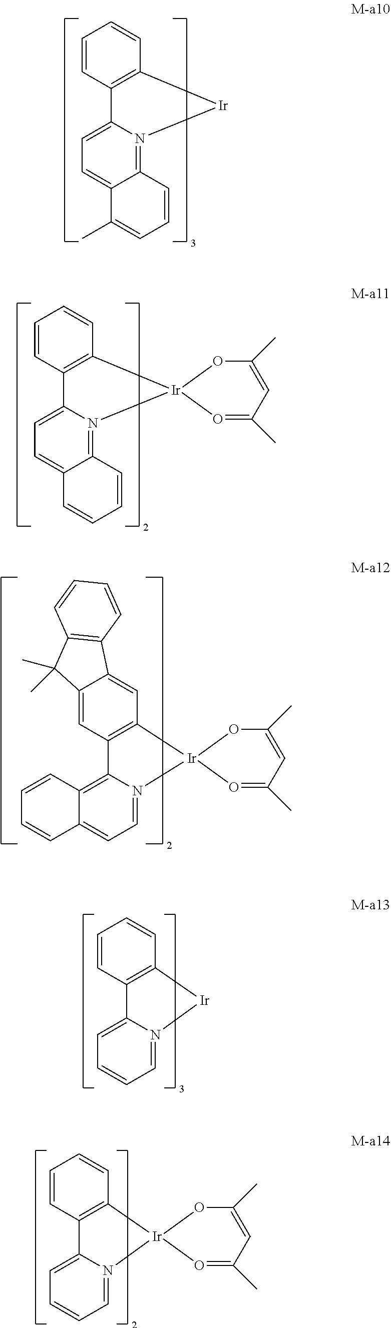

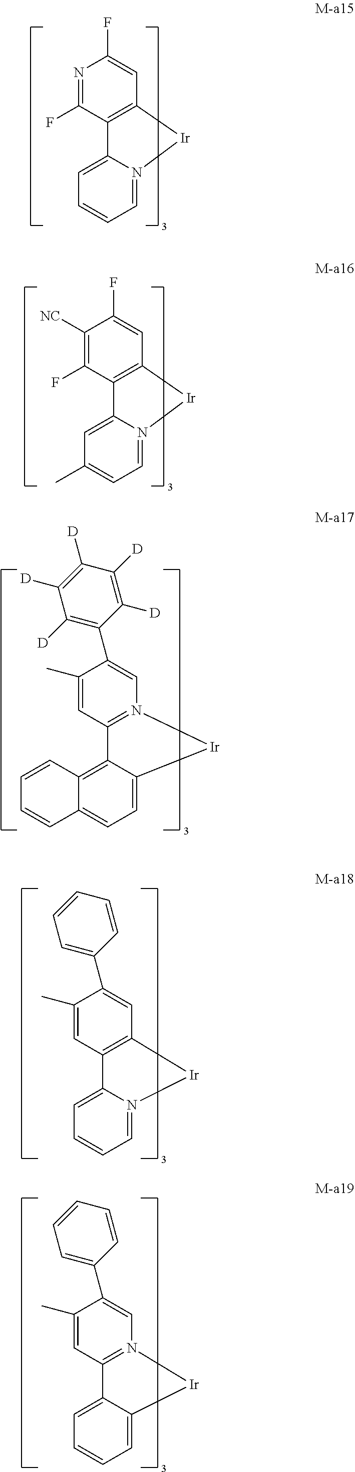

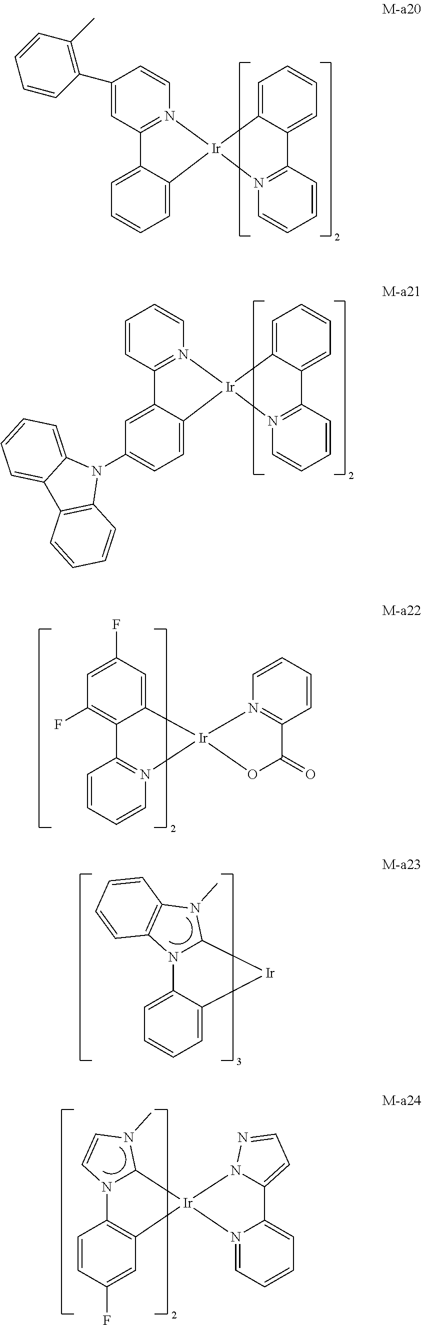

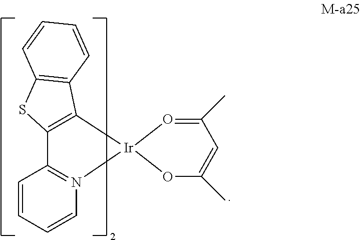

The compounds M-a1 and M-a2 may be utilized as a red dopant material, and the compounds M-a3 to M-a7 may be utilized as a green dopant material.

The emission layer EML may further include a compound represented by any one of Formulas F-a to F-c. The compounds represented by Formulas F-a to F-c may be utilized as a fluorescent dopant material.

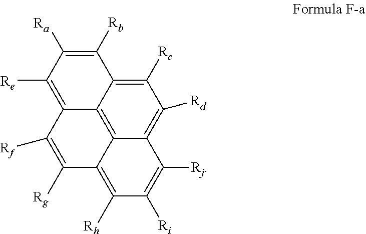

In Formula F-a above, two selected from Rₐ to R; may each independently be substituted with •—NA₁Ar₂. The others from among Rₐ to R; (e.g., any remainder thereof) which are not substituted with •—NAr₁,Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In *—NAr₁Ar₂, An and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of An or Ar₂ may be a heteroaryl group containing O or S as a ring-forming atom.

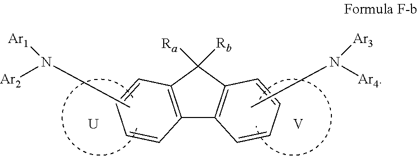

In Formula F-b above, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or linked to an adjacent group to form a ring. An to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. For example, in Formula F-b, when the number of U or V is 1, one ring indicated by U or V forms a fused ring at the designated part (e.g., a portion indicated by U or V), and when the number of U or V is 0, it refers to that no ring indicated by U or V is present. For example, when the number of U is 0 and the number of V is 1, or when the number of U is 1 and the number of V is 0, a fused ring having a fluorene core of Formula F-b may be a cyclic compound having four rings. In some embodiments, when the number of U and the number of V are both (e.g., simultaneously) 0, the fused ring of Formula F-b may be a cyclic compound having three rings. In some embodiments, when the number of U and the number of V are both (e.g., simultaneously) 1, the fused ring having a fluorene core of Formula F-b may be a cyclic compound having five rings.

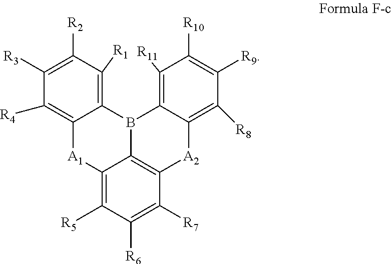

In Formula F-c, A₁ and A₂ may each independently be O, S, Se, or NRₘ, and Rm may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In Formula F-c, A₁ and A₂ may each independently be bonded to substituents of neighboring rings to form a fused ring. For example, when A₁ and A₂ may each independently be NRₘ, A₁ may be bonded to R₄ or R₅ to form a ring. In some embodiments, A₂ may be bonded to R₇ or R₈ to form a ring.

The emission layer EML may include, as a suitable dopant material, one or more styryl derivatives (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi)), perylene and derivatives thereof (e.g., 2,5,8,11-tetra-t-butylperylene (TBP)), pyrene and derivatives thereof (e.g., 1,1′-dipyrene, 1,4-dipyrenylbenzene, 1,4-bis(N,N-diphenylamino)pyrene), etc.

In an embodiment, when a plurality of emission layers EML are included, at least one emission layer EML may include a suitable phosphorescent dopant material. For example, as a phosphorescent dopant, a metal complex including iridium (Ir), platinum (Pt), osmium (Os), gold (Au), titanium (Ti), zirconium (Zr), hafnium (Hf), europium (Eu), and terbium (Tb), or thulium (Tm) may be utilized. For example, iridium(III) bis(4,6-difluorophenylpyridinato-N,C2′)picolinate (Flrpic), bis(2,4-difluorophenylpyridinato)-tetrakis(1-pyrazolyl)borate iridium(III) (Fir₆), platinum octaethyl porphyrin (PtOEP), etc. may be utilized as a phosphorescent dopant.

However, the embodiment of the present disclosure is not limited thereto.

In some embodiments, at least one emission layer EML may include a quantum dot material. The core of a quantum dot may be selected from a Group II-VI compound, a Group III-VI compound, a Group I-III-VI compound, a Group III-V compound, a Group III-II-V compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may include a binary compound such as In₂S₃ and/or In₂Se₃, a ternary compound such as InGaS₃ and/or InGaSe₃, or any combination thereof.

The Group I—III-VI compound may include a ternary compound selected from the group consisting of AgInS, AgInS₂, CulnS, CuInS₂, AgGaS₂, CuGaS2 CuGaO2, AgGaO₂, AgAIO₂, or any mixture thereof, and/or a quaternary compound such as AgInGaS₂ and/or CuInGaS2.

The Group III-V compound may be selected from the group consisting of a binary compound selected from the group consisting of GaN, GaP, GaAs, GaSb, AlN, AlP, AlAs, AlSb, lnN, lnP, lnAs, lnSb, and a mixture thereof, a ternary compound selected from the group consisting of GaNP, GaNAs, GaNSb, GaPAs, GaPSb, AINP, AlNAs, AlNSb, AlPAs, AlPSb, lnGaP, lnAlP, lnNP, lnNAs, lnNSb, lnPAs, lnPSb, and a mixture thereof, and a quaternary compound selected from the group consisting of GaAlNP, GaAlNAs, GaAlNSb, GaAlPAs, GaAlPSb, GalnNP, GalnNAs, GalnNSb, GalnPAs, GalnPSb, lnAlNP, lnAlNAs, lnAlNSb, lnAlPAs, lnAlPSb, and a mixture thereof. In some embodiments, the Group III-V compound may further include a Group II metal. For example, InZnP, etc. may be selected as a Group III—II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

In this case, the binary compound, the ternary compound, or the quaternary compound may be present in particles having a substantially uniform concentration distribution, or may be present in the same particles having a partially different concentration distribution. In some embodiments, the quantum dot may have a core/shell structure in which one quantum dot surrounds another quantum dot. The core/shell structure may have a concentration gradient in which the concentration of an element present in the shell becomes lower towards the core.

In some embodiments, a quantum dot may have the core/shell structure including a core having nano-crystals, and a shell around (e.g., surrounding) the core, which are described above. The shell of the quantum dot may serve as a protection layer to prevent or reduce the chemical deformation of the core so as to keep (e.g., maintain) semiconductor properties, and/or as a charging layer to impart electrophoresis properties to the quantum dot. The shell may be a single layer or multiple layers. Examples of the shell of the quantum dot may be a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, CO₃O₄, and/or NiO, and/or a ternary compound such as MgAl₂O₄, CoFe₂O₄, NiFe₂O₄, and/or CoMn₂O₄, but the embodiment of the present disclosure is not limited thereto.

In some embodiments, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, lnGaP, InSb, AlAs, AlP, AlSb, etc., but the embodiment of the present disclosure is not limited thereto.

A quantum dot may have a full width of half maximum (FWHM) of a light emitting wavelength spectrum of about 45 nm or less, about 40 nm or less, or about 30 nm or less, and color purity or color reproducibility may be enhanced in the above ranges. In some embodiments, light emitted through such a quantum dot is emitted in all directions, and thus a wide viewing angle may be improved.

In some embodiments, the form of a quantum dot is not particularly limited as long as it is a form commonly utilized in the art, for example, a quantum dot in the form of spherical, pyramidal, multi-arm, or cubic nanoparticles, nanotubes, nanowires, nanofibers, nanoplatelets, etc. may be utilized.

The quantum dot may control the color of emitted light according to the particle size thereof, and thus the quantum dot may have one or more suitable light emission colors such as blue, red, green, etc.

In the light emitting element ED of an embodiment illustrated in FIGS. 3 to 6, an electron transport region ETR is provided on the emission layer EML. The electron transport region ETR may include at least one selected from among a hole blocking layer HBL, an electron transport layer ETL, and an electron injection layer EIL, but the embodiment of the present disclosure is not limited thereto.

The electron transport region ETR may have a single layer formed of a single material, a single layer formed of a plurality of different materials, or a multilayer structure having a plurality of layers formed of a plurality of different materials.

For example, the electron transport region ETR may have a single layer structure of an electron injection layer EIL or an electron transport layer ETL, or may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL, or an electron transport layer ETL/buffer layer/electron injection layer EIL are stacked in the respective stated order from the emission layer EML, but the embodiment of the present disclosure is not limited thereto. The electron transport region ETR may have a thickness of, for example, about 1000 A to about 1500 A.

The electron transport region ETR may be formed utilizing one or more suitable methods such as a vacuum deposition method, a spin coating method, a cast method, a Langmuir-Blodgett (LB) method, an inkjet printing method, a laser printing method, a laser induced thermal imaging (LITI) method, etc.

The electron transport region ETR may include a compound represented by Formula ET-1.

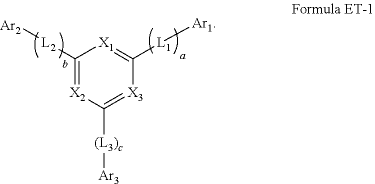

In Formula ET-1, at least one of X₁ to X₃ may be N and the rest (e.g., any remainder thereof) may be CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. An to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer of 0 to 10. In Formula ET-i, Li to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c are each independently an integer of 2 or greater, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1, 10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), berylliumbis(benzoquinolin-10-olate) (Bebq₂), 9,10-di(naphthalen-2-yl)anthracene (ADN), 1,3-bis[3,5-di(pyridin-3-yl)phenyl]benzene (BmPyPhB), diphenyl(4-(triphenylsilyl)phenyl)phosphine oxide (TSPO1), or a mixture thereof.

The electron transport region ETR may include at least one of compounds ET1 to ET36.

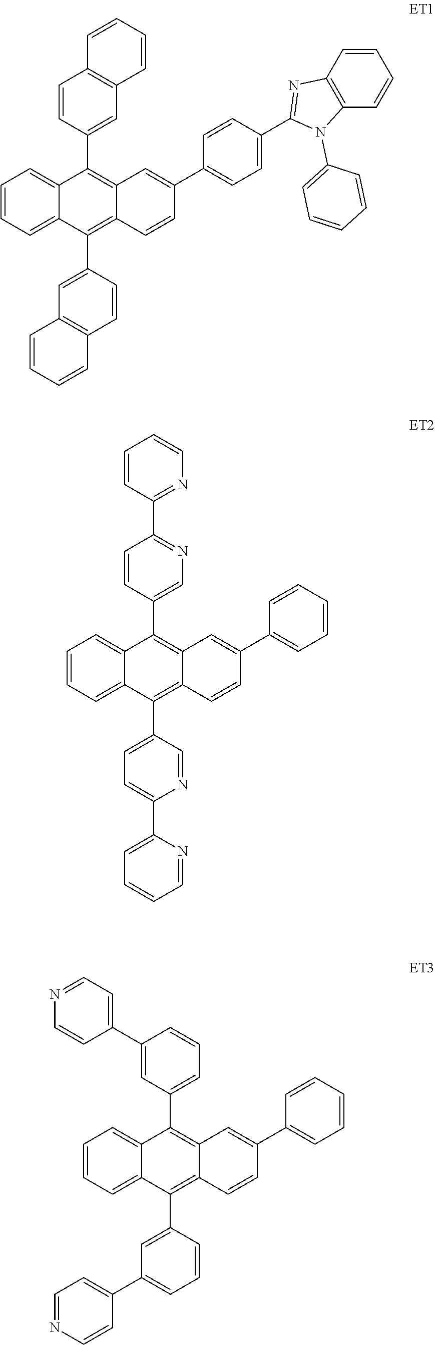 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

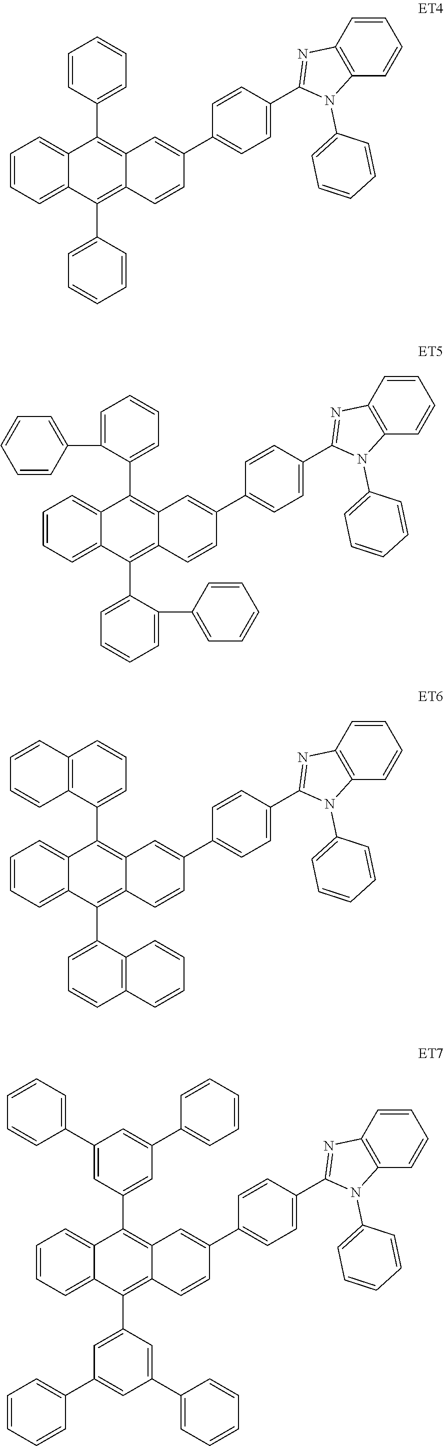 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

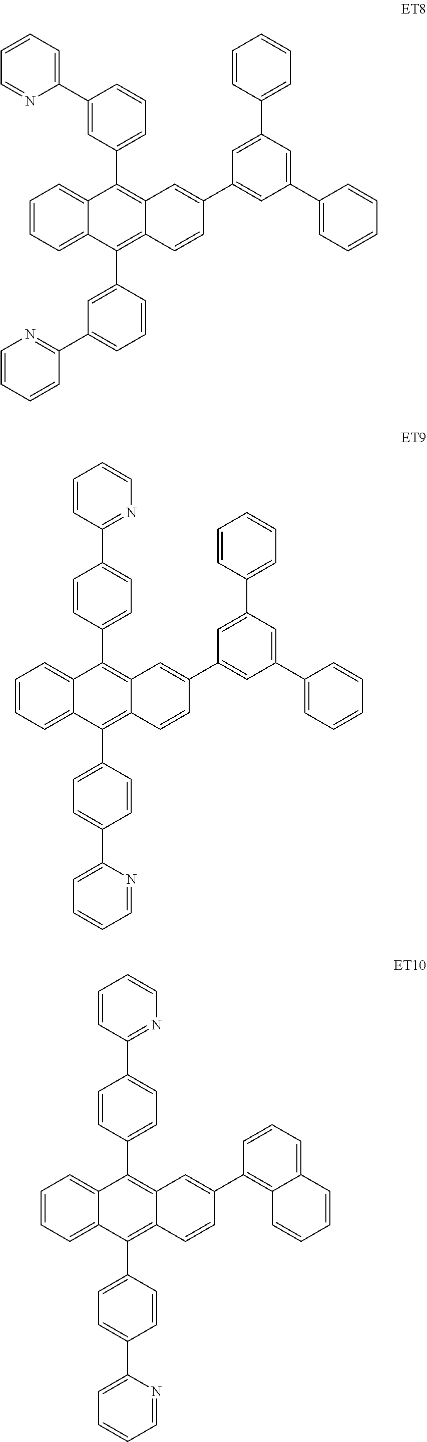 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

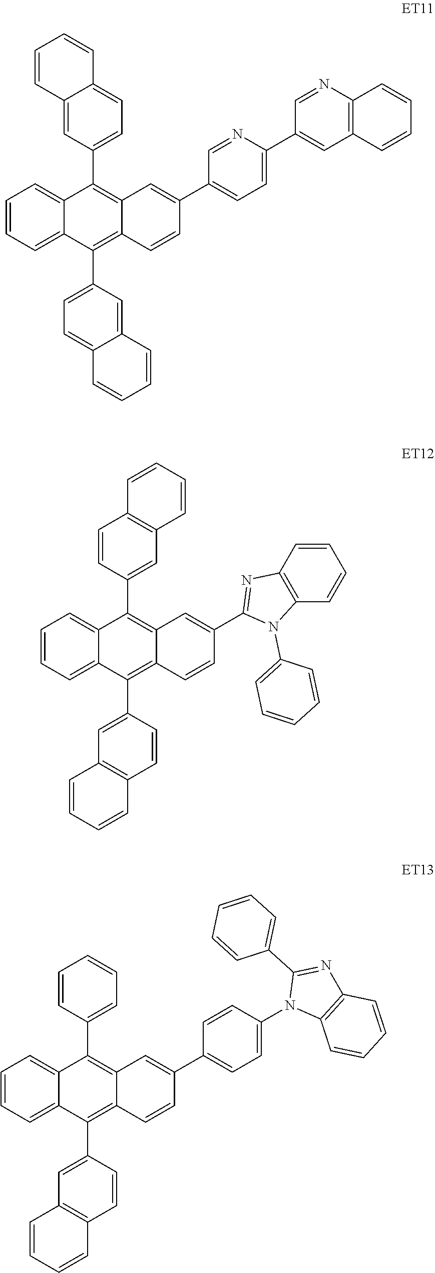 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

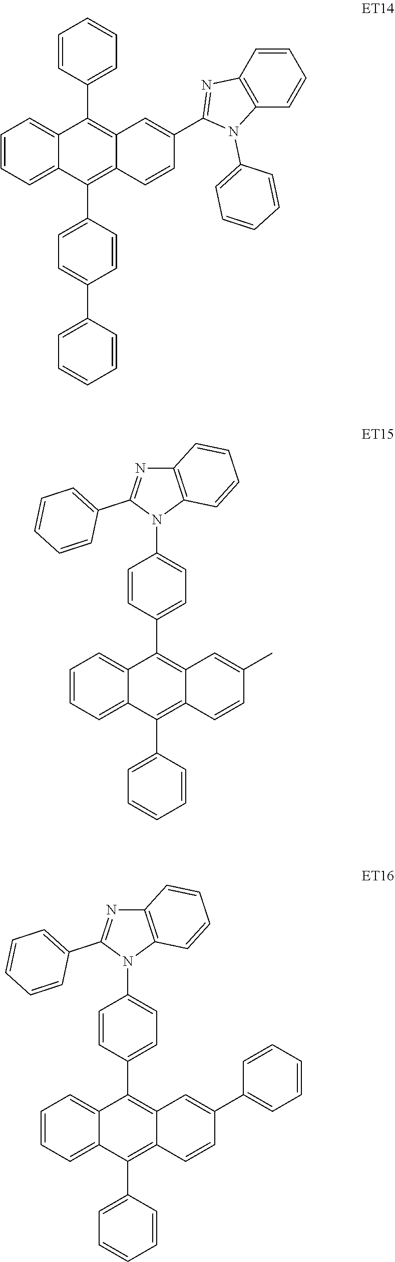 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

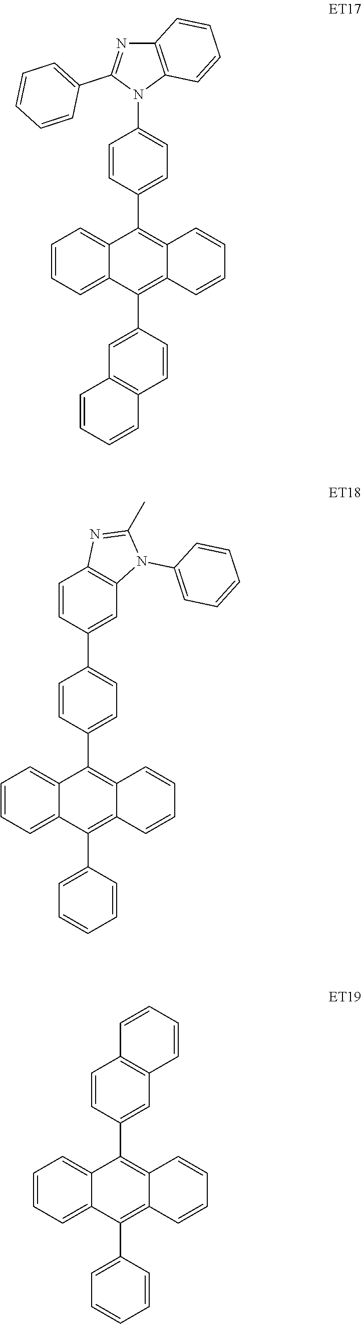

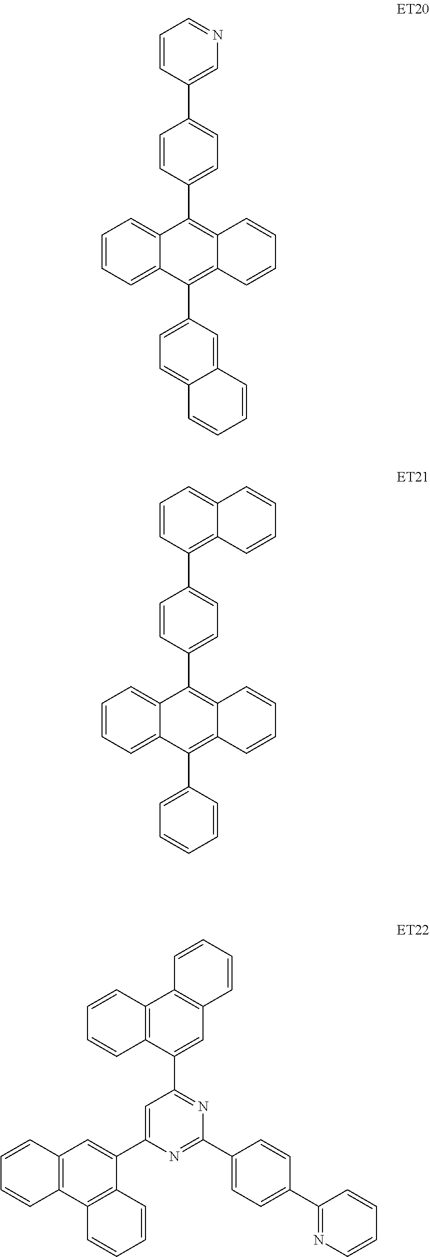

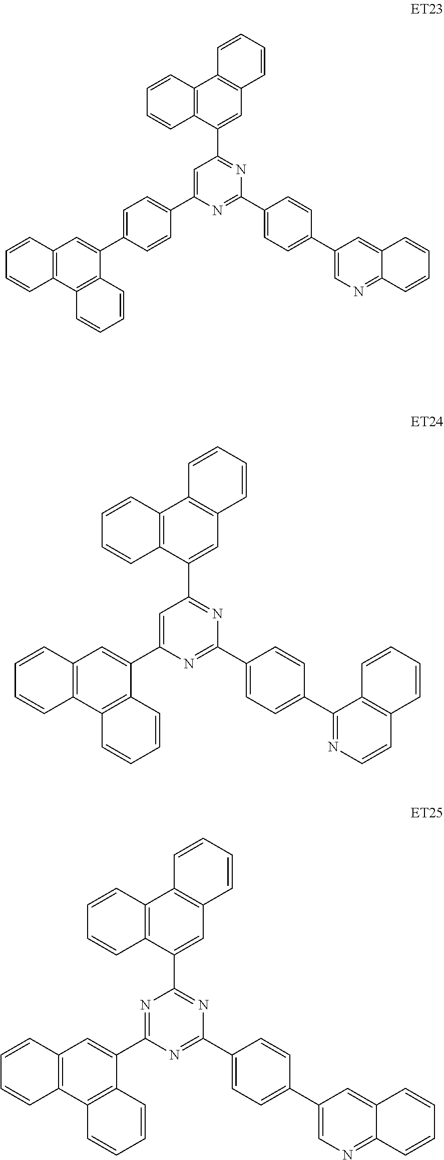 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

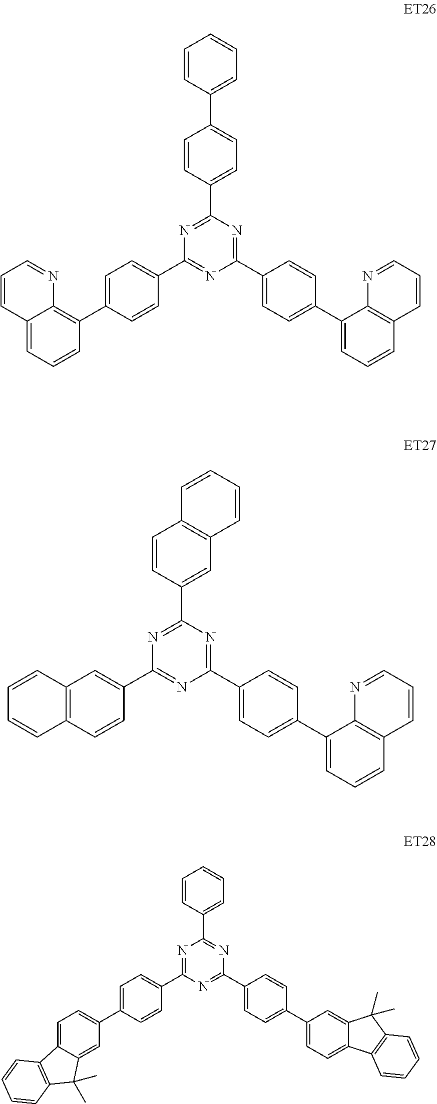 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

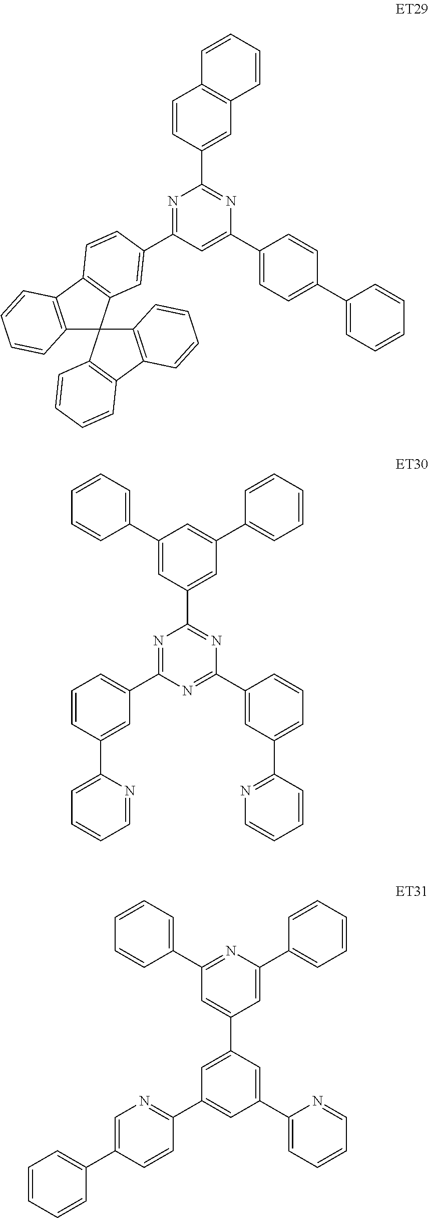 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

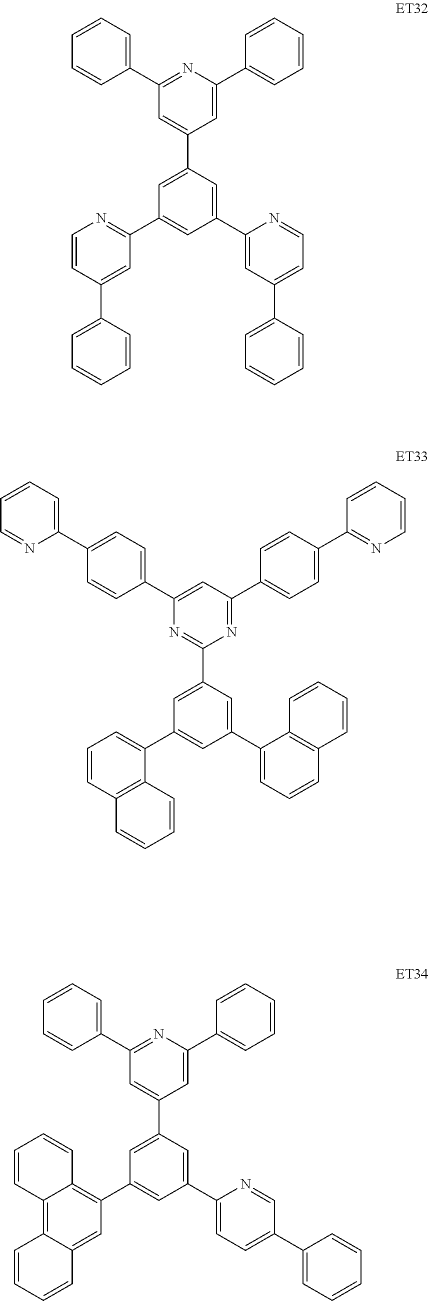 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

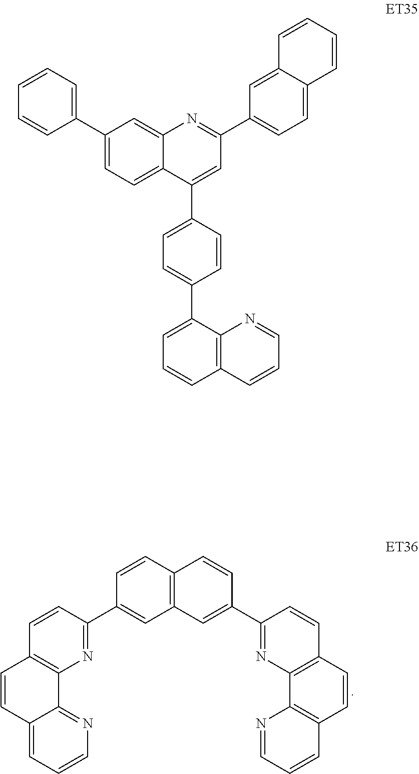 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In some embodiments, the electron transport region ETR may include one or more halogenated metals (e.g., metal halides) such as LiF, NaCl, CsF, RbCl, Rbl, Cul, and/or KI, lanthanide metals such as Yb, and/or co-deposition materials of a halogenated metal and a lanthanide metal. For example, the electron transport region ETR may include Kl:Yb, Rbl:Yb, LiF:Yb, etc., as a co-deposition material. In some embodiments, for the electron transport region ETR, a metal oxide such as Li₂O and/or BaO, 8-hydroxyl-lithium quinolate (Liq), etc. may be utilized, but the embodiment of the present disclosure is limited thereto. The electron transport region ETR may also be formed of a mixture material of an electron transport material and an insulating organo-metal salt. The organo-metal salt may be a material having an energy band gap of about 4 eV or greater. For example, the organo-metal salt may include, for example, one or more metal acetates, metal benzoates, metal acetoacetates, metal acetylacetonates, and/or metal stearates.

The electron transport region ETR may further include, for example, at least one of 2,9-dimethyl-4,7-diphenyl-1, 10-phenanthroline (BCP), diphenyl(4-(triphenylsilyl)phenyl)phosphine oxide (TSPO1), or 4,7-diphenyl-1, 10-phenanthroline (Bphen) in addition to the materials described above, but the embodiment of the present disclosure is not limited thereto.

The electron transport region ETR may include the compounds of the electron transport region described above in at least one selected from among the electron injection layer EIL, the electron transport layer ETL, and the hole blocking layer HBL.

When the electron transport region ETR includes the electron transport layer ETL, the electron transport layer ETL may have a thickness of about 100 A to about 1000 A, for example, about 150 A to about 500 A. When the thickness of the electron transport layer ETL satisfies the above-described range, satisfactory electron transport properties may be obtained without a substantial increase in driving voltage. When the electron transport region ETR includes the electron injection layer EIL, the electron injection layer EIL may have a thickness of about 1 A to about 100 A, for example, about 3 A to about 90 A. When the thickness of the electron injection layer EIL satisfies the above-described ranges, satisfactory electron injection properties may be obtained without a substantial increase in driving voltage.

The second electrode EL2 is provided on the electron transport region ETR.

The second electrode EL2 may be a common electrode. The second electrode EL2 may be a cathode or an anode but the embodiment of the present disclosure is not limited thereto. For example, when the first electrode EL1 is an anode, the second electrode EL2 may be a cathode, and when the first electrode EL1 is a cathode, the second electrode EL2 may be an anode. The second electrode may include at least one selected from Ag, Mg, Cu, Al, Pt, Pd, Au, Ni, Nd, Ir, Cr, Li, Ca, LiF, Mo, T1, W, In, Sn, and Zn, compounds of two or more selected therefrom, mixtures of two or more selected therefrom, and an oxide thereof.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca (a stacked structure of LiF and Ca), LiF/AI (a stacked structure of LiF and Al), Mo, T1, W, a compound thereof, or a mixture thereof (e.g., AgMg, AgYb, and/or MgYb). In some embodiments, the second electrode EL2 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, the second electrode EL2 may include one or more of the above-described metal materials, a combination of two or more metal materials selected from the above-described metal materials, and/or one or more oxides of the above-described metal materials.

In some embodiments, the second electrode EL2 may be connected with an auxiliary electrode. When the second electrode EL2 is connected with the auxiliary electrode, the resistance of the second electrode EL2 may decrease.

In some embodiments, a capping layer CPL may be further disposed on the second electrode EL2 of the light emitting element ED of an embodiment. The capping layer CPL may include a multilayer or a single layer.

In an embodiment, the capping layer CPL may be an organic layer or an inorganic layer. For example, when the capping layer CPL includes an inorganic material, the inorganic material may include an alkali metal compound such as LiF, an alkaline earth metal compound such as MgF₂, SiON, SiNₓ, SiO_{y}, etc.

For example, when the capping layer CPL includes an organic material, the organic material may include a-NPD, NPB, TPD, m-MTDATA, Alq₃ CuPc, N4,N4,N4′,N4′-tetra(biphenyl-4-yl) biphenyl-4,4′-diamine (TPD15), 4,4′,4″-tris(carbazol-9-yl)triphenylamine (TCTA), etc., and/or may include one or more epoxy resins and/or acrylates such as methacrylates. However, the embodiment of the present disclosure is not limited thereto. In some embodiments, the capping layer CPL may include compounds P1 to P5.

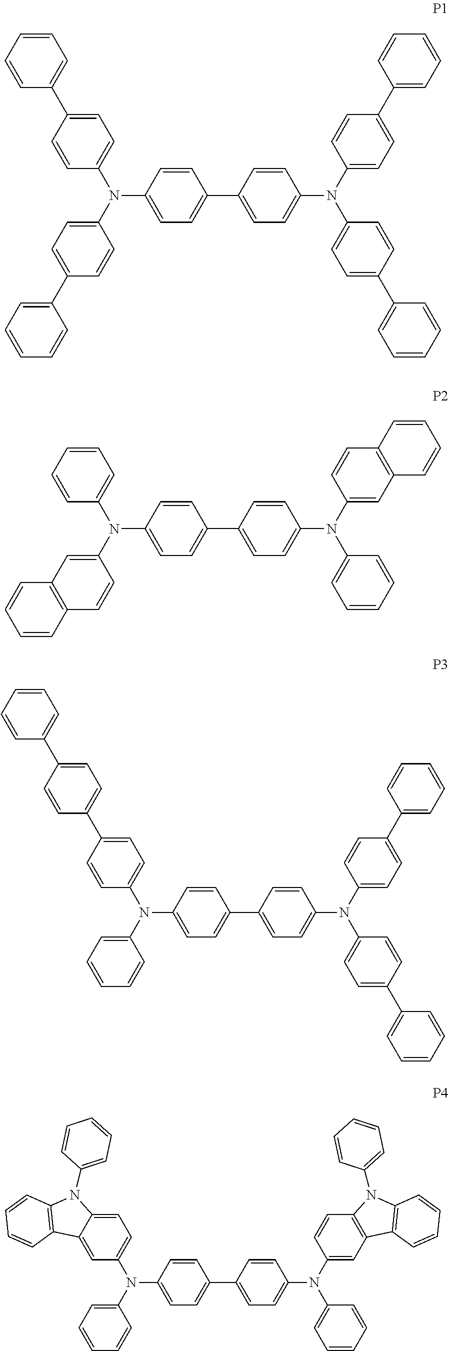 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

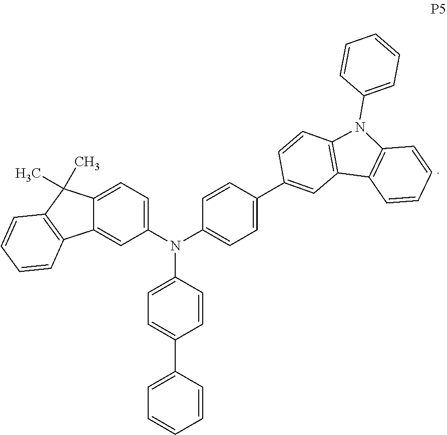 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the capping layer GPL may have a refractive index of about 1.6 or greater. For example, the capping layer GPL may have a refractive index of about 1.6 or greater in a wavelength range of about 550 nm to about 660 nm.

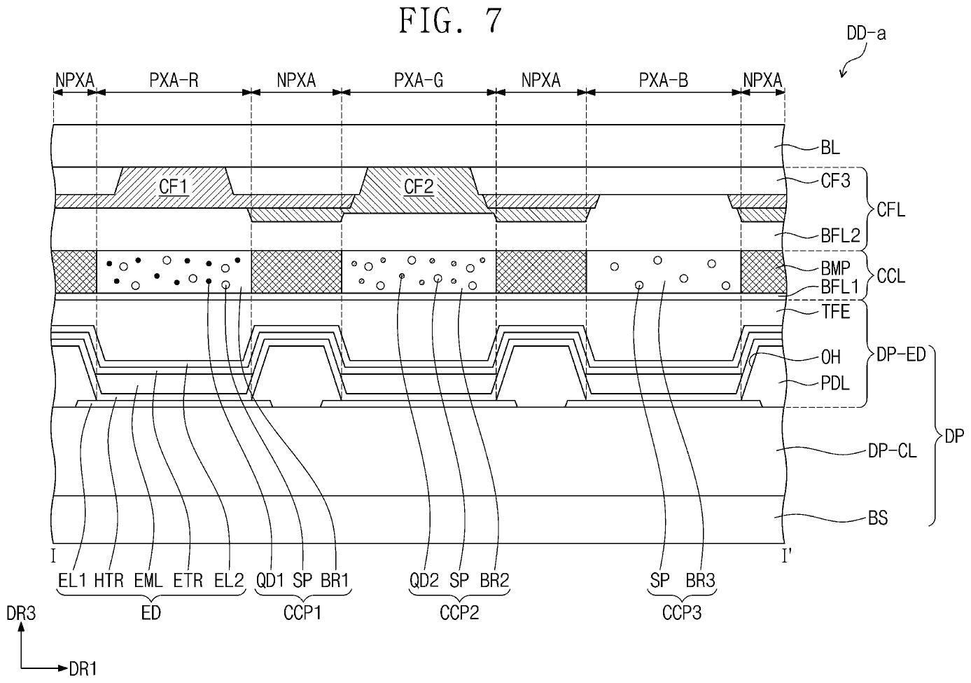

FIGS. 7 to 10 are each a cross-sectional view of a display device according to an embodiment. Hereinafter, in the description of the display device according to an embodiment with reference to FIGS. 7 and 10, content overlapping the one described above with reference to FIGS. 1 to 6 will not be described again, and the differences will be mainly described.

Referring to FIG. 7, a display device DD-a according to an embodiment may include a display panel DP having a display element layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and a display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In some embodiments, a structure of the light emitting element ED shown in FIG. 7 may be the same as the structure of the light emitting element of FIGS. 3 to 6 described above.

The emission layer EML of the light emitting element ED included in a display device DD-a according to an embodiment may include the polycyclic compound of an embodiment, which is described above.

Referring to FIG. 7, the emission layer EML may be disposed in the openings OH defined in the pixel defining films PDL. For example, the emission layer EML separated by the pixel defining films PDL and provided corresponding to each of light emitting regions PXA-R, PXA-G, and PXA-B may be to emit light in substantially the same wavelength ranges. In the display device DD-a of an embodiment, the emission layer EML may be to emit blue light. In some embodiments, unlike the one illustrated, in an embodiment, the emission layer EML may be provided as a common layer throughout the light emitting regions PXA-R, PXA-G, and PXA-B.

The light control layer CCL may be disposed on the display panel DP. The light control layer CCL may include a light converter. The light converter may be a quantum dot or a phosphor. The light converter may convert (e.g., transform) the wavelength of the provided light and then emit light with the converted wavelength. For example, the light control layer CCL may be a layer containing quantum dots or phosphors.

The light control layer CCL may include a plurality of light control units CCP1, CCP2, and CCP3. The light control units CCP1, CCP2, and CCP3 may be spaced apart from each other.

Referring to FIG. 7, a division pattern BMP may be disposed between the light control units CCP1, CCP2, and CCP3 spaced apart from each other, but the embodiment of the present disclosure is not limited thereto. In FIG. 7, the division pattern BMP is shown to not overlap with the light control units CCP1, CCP2, and CCP3, but in some embodiments, the edges of the light control units CCP1, CCP2, and CCP3 may overlap at least a portion of the division pattern BMP.

The light control layer CCL may include a first light control unit CCP1 including a first quantum dot QD1 for converting a first color light provided from the light emitting element ED into a second color light, a second light control unit CCP2 including a second quantum dot QD2 for converting the first color light into a third color light, and a third light control unit CCP3 transmitting the first color light.

In an embodiment, the first light control unit CCP1 may provide red light, which is the second color light, and the second light control unit CCP2 may provide green light, which is the third color light. The third light control unit CCP3 may be to transmit and provide blue light, which is the first color light provided from the light emitting element ED. For example, the first quantum dot QD1 may be a red quantum dot and the second quantum dot QD2 may be a green quantum dot. The quantum dots QD1 and QD2 may be the same as those described above.

In some embodiments, the light control layer CCL may further include scatterers SP. The first light control unit CCP1 may include the first quantum dot QD1 and the scatterers SP, the second light control unit CCP2 may include the second quantum dot QD2 and the scatterers SP, and the third light control unit CCP3 may not include (e.g., may exclude) any quantum dot but may include the scatterers SP.

The scatterers SP may be inorganic particles. For example, the scatterers SP may include at least one selected from among TiO₂, ZnO, Al₂O₃, SiO₂, and hollow silica. The scatterers SP may include any one from among TiO₂, ZnO, Al₂O₃, SiO₂, and hollow silica, or may be a mixture of two or more materials selected from TiO₂, ZnO, Al₂O₃, SiO₂, and hollow silica.

The first light control unit CCP1, the second light control unit CCP2, and the third light control unit CCP3 may each include a corresponding one of the base resins BR1, BR2, and BR3 for dispersing the quantum dots QD1 and QD2 and the scatterers SP. In an embodiment, the first light control unit CCP1 may include the first quantum dot QD1 and the scatterers SP dispersed in the first base resin BR1, the second light control unit CCP2 may include the second quantum dot QD2 and the scatterers SP dispersed in the second base resin BR2, and the third light control unit CCP3 may include the scatterers SP dispersed in the third base resin BR3. The base resins BR1, BR2, and BR3 are a medium in which the quantum dots QD1 and QD2 and the scatterers SP are dispersed, and may be formed of one or more suitable resin compositions, which may be generally referred to as a binder. For example, the base resins BR1, BR2, and BR3 may each be an acrylic resin, a urethane-based resin, a silicone-based resin, an epoxy-based resin, etc. The base resins BR1, BR2, and BR3 may each be a transparent resin. In an embodiment, the first base resin BR1, the second base resin BR2, and the third base resin BR3 may each be the same as or different from each other.

The light control layer CCL may include a barrier layer BFL1. The barrier layer BFL1 may serve to prevent or reduce moisture and/or oxygen (hereinafter referred to as “moisture/oxygen”) from being introduced. The barrier layer BFL1 may be disposed on the light control units CCP1, CCP2, and CCP3 to prevent or reduce the light control units CCP1, CCP2, and CCP3 from being exposed to moisture/oxygen. In some embodiments, the barrier layer BFL1 may cover the light control units CCP1, CCP2, and CCP3. In some embodiments, a barrier layer BFL2 may be provided between the light control units CCP1, CCP2, and CCP3 and the color filter layer CFL (e.g., along the thickness direction).

The barrier layers BFL1 and BFL2 may include at least one inorganic layer. For example, the barrier layers BFL1 and BFL2 may be formed of an inorganic material. For example, the barrier layers BFL1 and BFL2 may be formed utilizing silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and/or a metal thin film in which light transmittance is secured, etc. In some embodiments, the barrier layers BFL1 and BFL2 may further include an organic film. The barrier layers BFL1 and BFL2 may be formed of a single layer or a plurality of layers.

In the display device DD-a of an embodiment, the color filter layer CFL may be disposed on the light control layer CCL. For example, the color filter layer CFL may be directly disposed on the light control layer CCL. In this case, the barrier layer BFL2 may not be provided.

The color filter layer CFL may include filters CF1, CF2, and CF3. For example, the color filter layer CFL may include a first filter CF1 for transmitting the second color light, a second filter CF2 for transmitting the third color light, and a third filter CF3 for transmitting the first color light. For example, the first filter CF1 may be a red filter, the second filter CF2 may be a green filter, and the third filter CF3 may be a blue filter. The filters CF1, CF2, and CF3 may each include a polymer photosensitive resin, a pigment and/or a dye. The first filter CF1 may include a red pigment and/or a red dye, the second filter CF2 may include a green pigment and/or a green dye, and the third filter CF3 may include a blue pigment and/or a blue dye. The embodiment of the present disclosure is not limited thereto, and the third filter CF3 may not include (e.g., may exclude) any pigment or dye. The third filter CF3 may include a polymer photosensitive resin, but may not include any pigment or dye. The third filter CF3 may be transparent. The third filter CF3 may be formed of a transparent photosensitive resin.

In an embodiment, the first filter CF1 and the second filter CF2 may be yellow filters. The first filter CF1 and the second filter CF2 may not be separated and may be provided as a single body. The first to third filters CF1, CF2, and CF3 may be disposed corresponding to the red light emitting region PXA-R, the green light emitting region PXA-G, and the blue light emitting region PXA-B, respectively.

In some embodiments, the color filter layer CFL may further include a light blocking unit. The color filter layer CFL may include the light blocking unit disposed to overlap the boundaries of the neighboring filters CF1, CF2, and CF3. The light blocking unit may be a black matrix. The light blocking unit may be formed including an organic light blocking material and/or an inorganic light blocking material, both (e.g., simultaneously) including a black pigment and/or a black dye. The light blocking unit may separate or define boundaries between the adjacent filters CF1, CF2, and CF3. In an embodiment, the light blocking unit may be formed of a blue filter.

The base substrate BL may be disposed on the color filter layer CFL. The base substrate BL may be a member providing a base surface on which the color filter layer CFL and the light control layer CCL are disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, the base substrate BL may not be provided in an embodiment.

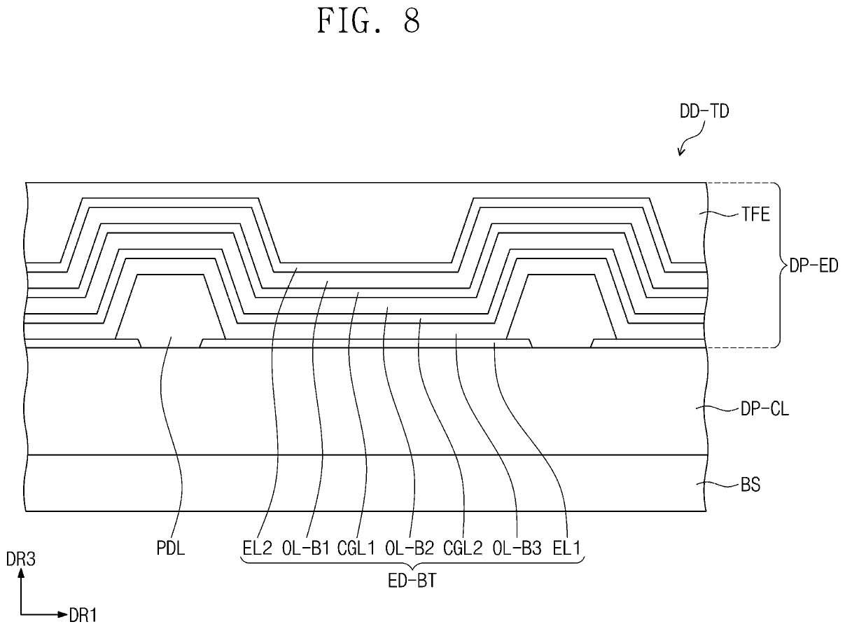

FIG. 8 is a cross-sectional view showing a portion of a display device according to an embodiment. FIG. 8 shows a cross-sectional view of a portion corresponding to the display panel DP of FIG. 7. In a display device DD-TD of an embodiment, a light emitting element ED-BT may include a plurality of light emitting structures OL-B1, OL-B2, and OL-B3. The light emitting element ED-BT may include the first electrode EL1 and the second electrode EL2 facing each other, and the plurality of light emitting structures OL-B1, OL-B2, and OL-B3 provided by being sequentially stacked in a thickness direction between the first electrode EL1 and the second electrode EL2. The light emitting structures OL-B1, OL-B2, and OL-B3 may each include the emission layer EML (FIG. 7), a hole transport region HTR and an electron transport region ETR disposed with the emission layer EML (FIG. 7) therebetween.

For example, the light emitting element ED-BT included in the display device DD-TD of an embodiment may be a light emitting element having a tandem structure including a plurality of emission layers.

In an embodiment illustrated in FIG. 8, light emitted from each of the light emitting structures OL-B1, OL-B2, and OL-B3 may all be blue light. However, the embodiment of the present disclosure is not limited thereto, and wavelength ranges of light emitted from each of the light emitting structures OL-B1, OL-B2, and OL-B3 may be different from each other. For example, the light emitting element ED-BT including the plurality of light emitting structures OL-B1, OL-B2, and OL-B3 emitting light in different wavelength ranges may be to emit white light.

Charge generation layers CGL1 and CGL2 may be disposed between neighboring light emitting structures OL-B1, OL-B2, and OL-B3. The charge generation layers CGL1 and CGL2 may include a p-type or kind charge generation layer (e.g., a P-charge generation layer) and/or an n-type or kind charge generation layer (e.g., a N-charge generation layer).

At least one of the light emitting structures OL-B1, OL-B2, and OL-B3 included in the display device DD-TD of an embodiment may include the polycyclic compound of an embodiment described above. For example, at least one of the plurality of emission layers included in the light emitting element ED-BT may include a polycyclic compound according to an embodiment.

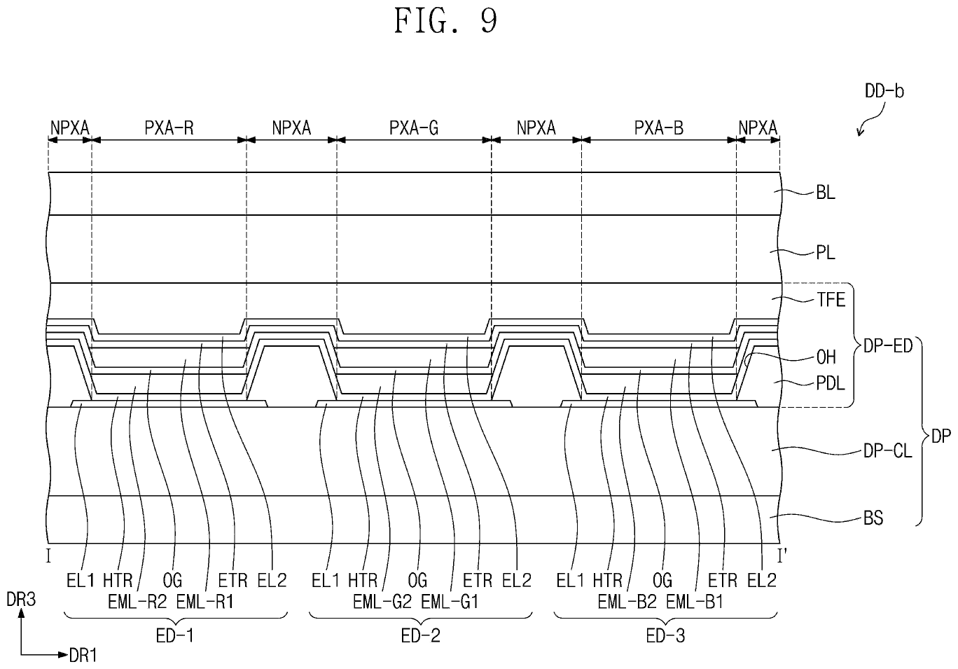

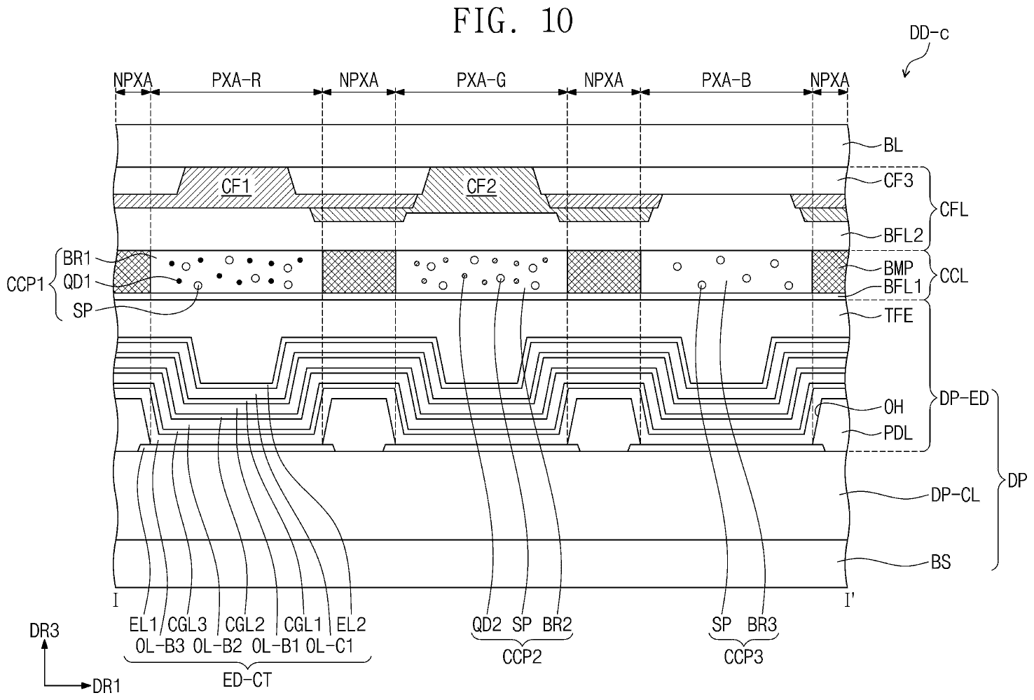

Referring to FIG. 9, a display device DD-b according to an embodiment may include light emitting elements ED-1, ED-2, and ED-3 in which two emission layers are stacked over each other. Compared to the display device DD according to an embodiment shown in FIG. 2, in an embodiment shown in FIG. 9, the first to third light emitting elements ED-1, ED-2, and ED-3 each include two emission layers stacked in a thickness direction. In each of the first to third light emitting elements ED-1, ED-2, and ED-3, the two emission layers may be to emit light in substantially the same wavelength range.

The first light emitting element ED-1 may include a first red emission layer EML-R₁ and a second red emission layer EML-R₂. The second light emitting element ED-2 may include a first green emission layer EML-G1 and a second green emission layer EML-G2. In some embodiments, the third light emitting element ED-3 may include a first blue emission layer EML-B1 and a second blue emission layer EML-B2. A light emitting auxiliary portion OG may be disposed between the first red emission layer EML-R₁ and the second red emission layer EML-R₂, between the first green emission layer EML-G1 and the second green emission layer EML-G2, and between the first blue emission layer EML-B1 and the second blue emission layer EML-B2.

The light emitting auxiliary portion OG may include a single layer or multiple layers. The light emitting auxiliary portion OG may include a charge generation layer. For example, the light emitting auxiliary portion OG may include an electron transport region, a charge generation layer, and a hole transport region that are sequentially stacked. The light emitting auxiliary portion OG may be provided as a common layer throughout the first to third light emitting elements ED-1, ED-2, and ED-3. However, the embodiment of the present disclosure is not limited thereto, and the light emitting auxiliary portion OG may be provided to be patterned inside the openings OH defined in the pixel defining films PDL.

The first red emission layer EML-R₁, the first green emission layer EML-G1, and the first blue emission layer EML-B1 may be disposed between the electron transport region ETR and the emission auxiliary portion OG. The second red emission layer EML-R₂, the second green emission layer EML-G2, and the second blue emission layer EML-B2 may be disposed between the emission auxiliary portion OG and the hole transport region HTR.

For example, the first light emitting element ED-1 may include the first electrode EL1, the hole transport region HTR, the second red emission layer EML-R₂, the emission auxiliary portion OG, the first red emission layer EML-R₁, the electron transport region ETR, and the second electrode EL2, which are sequentially stacked in the stated order. The second light emitting element ED-2 may include the first electrode EL1, the hole transport region HTR, the second green emission layer EML-G2, the emission auxiliary portion OG, the first green emission layer EML-G1, the electron transport region ETR, and the second electrode EL2, which are sequentially stacked in the stated order. The third light emitting element ED-3 may include the first electrode EL1, the hole transport region HTR, the second blue emission layer EML-B2, the emission auxiliary portion OG, the first blue emission layer EML-B1, the electron transport region ETR, and the second electrode EL2, which are sequentially stacked in the stated order.

In some embodiments, an optical auxiliary layer PL may be disposed on the display element layer DP-ED. The optical auxiliary layer PL may include a polarizing layer. The optical auxiliary layer PL may be disposed on the display panel DP to control reflection of external light in the display panel DP. In some embodiments, unlike what is illustrated, the optical auxiliary layer PL may not be provided in the display device according to an embodiment.

At least one emission layer included in a display device DD-b according to an embodiment shown in FIG. 9 may include the polycyclic compound according to an embodiment, which is described above. For example, at least one of the first blue emission layer EML-B1 or the second blue emission layer EML-B2 may include the polycyclic compound according to an embodiment.

Unlike FIGS. 8 and 9, the display device DD-c of FIG. 10 is illustrated to include four light emitting structures OL-B1, OL-B2, OL-B3, and OL-C1. The light emitting element ED-CT may include the first electrode EL1 and the second electrode EL2 facing each other, and the first to fourth light emitting structures OL-B1, OL-B2, OL-B3, and OL-C1 sequentially stacked in a thickness direction between the first electrode EL1 and the second electrode EL2. Charge generation layers CGL1, CGL2, and CGL3 may be disposed between the first to fourth light emitting structures OL-B1, OL-B2, OL-B3, and OL-C1. From among the four light emitting structures, the first to third light emitting structures OL-B1, OL-B2, and OL-B3 may be to emit blue light, and the fourth light emitting structure OL-C1 may be to emit green light. However, the embodiment of the present disclosure is not limited thereto, and the first to fourth light emitting structures OL-B1, OL-B2, OL-B3, and OL-C1 may be to emit light having different wavelength ranges.

The charge generation layers CGL1, CGL2 and CGL3 disposed between the neighboring light emitting structures OL-B1, OL-B2, OL-B3, and OL-C1 may include a p-type or kind charge generation layer (e.g., a P-charge generation layer) and/or an n-type or kind charge generation layer (e.g., a N-charge generation layer).

At least one of the light emitting structures OL-B1, OL-B2, OL-B3, and OL-C1 included in the display device DD-c of an embodiment may include the polycyclic compound of an embodiment described above. For example, in an embodiment, at least one of the first to third light emitting structures OL-B1, OL-B2, and OL-B3 may include a polycyclic compound according to an embodiment, which is described above.

The light emitting element ED according to an embodiment of the present disclosure includes the polycyclic compound of an embodiment described above in at least one functional layer disposed between the first electrode EL1 and the second electrode EL2, and may thus exhibit excellent or suitable light emitting efficiency and improved lifespan characteristics. For example, the polycyclic compound according to an embodiment may be included in the emission layer EML of the light emitting element ED according to an embodiment, and the light emitting element according to an embodiment may exhibit both (e.g., simultaneously) high efficiency and long lifespan characteristics.

The polycyclic compound according to an embodiment, which is described above, may include a core portion of a fused ring containing two boron atoms, and substituents positioned para to each of the boron atoms, thereby becoming highly stable. In some embodiments, the polycyclic compound of an embodiment may include at least one oxygen atom or at least one sulfur atom at the core portion along with boron atoms to shorten light emitting wavelength, and has a deep HOMO level to increase lifespan of a light emitting element.

Hereinafter, with reference to Examples and Comparative Examples, a polycyclic compound and a light emitting element of an embodiment of the present disclosure will be described in more detail. In addition, Examples shown below are illustrated only for the understanding of the present disclosure, and the scope of the present disclosure is not limited thereto.

### EXAMPLES

1. Synthesis of Polycyclic Compounds of Examples

First, a process of synthesizing polycyclic compounds according to an embodiment of the present disclosure will be described in more detail by presenting a process of synthesizing Compounds 6, 14, 29, 58, 82, 105, and 107 as an example. In addition, a process of synthesizing polycyclic compounds, which will be described hereinafter, is provided as an example, and thus a process of synthesizing polycyclic compounds according to an embodiment of the present disclosure is not limited to Examples.

(1) Synthesis of Compound 6

Polycyclic compound 6 according to an embodiment may be synthesized by, for example, a process of Reaction Formula 1.

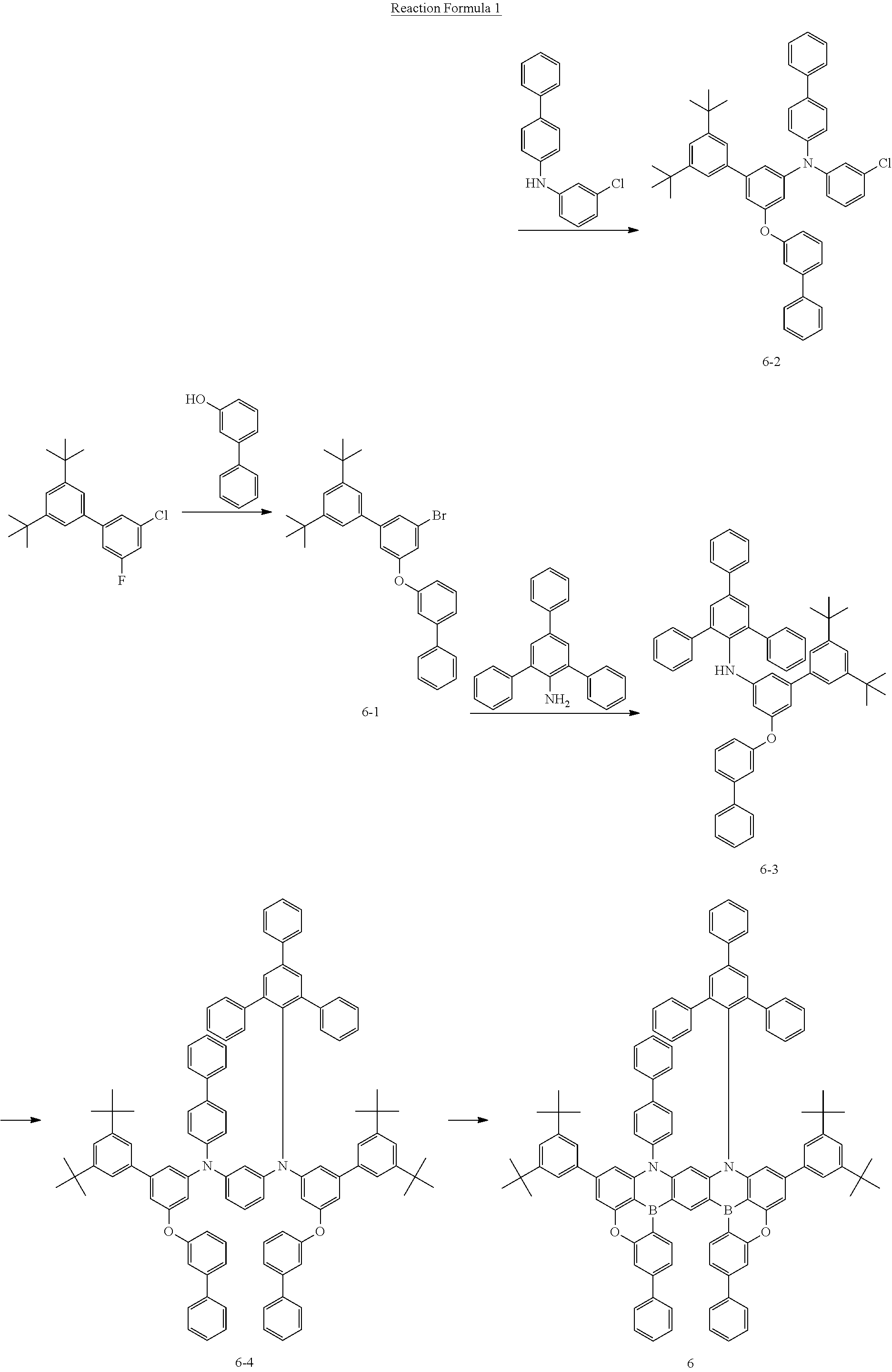

3) Synthesis of Intermediate Compound 6-3

Intermediate Compound 6-1 (1 eq), 5′-phenyl-[1,1′:3′,1″-terphenyl]-2′-amine (1 eq), tris(dibenzylideneacetone)dipalladium(0) (0.05 eq), tri-tert-butylphosphine (0.1 eq), and sodium tert-butoxide (3 eq) were dissolved in o-xylene and then stirred at 150° C. for 10 hours. After cooling, the resultant product was washed three times with ethyl acetate and water, and an organic layer obtained by separation was dried utilizing MgSO₄ and dried under reduced pressure. Intermediate Compound 6-3 was obtained by purification through column chromatography with MC and n-hexane (Yield: 65%).

4) Synthesis of Intermediate Compound 6-4

Intermediate Compound 6-2 (1 eq), Intermediate Compound 6-3 (1 eq), tris(dibenzylideneacetone)dipalladium(0) (0.2 eq), tri-tert-butylphosphine (0.4 eq), and sodium tert-butoxide (3 eq) were dissolved in o-xylene and then stirred at 150° C. for 40 hours. After cooling, the resultant product was washed three times with ethyl acetate and water, and an organic layer obtained by separation was dried utilizing MgSO₄ and dried under reduced pressure. Intermediate Compound 6-4 was obtained by purification through column chromatography with MC and n-hexane. (Yield: 33%)

5) Synthesis of Compound 6

Intermediate Compound 6-4 (1 eq) was dissolved in ortho dichlorobenzene, cooled to 0° C., and then BBr₃ (5 eq) was slowly injected thereto dropwise in a nitrogen atmosphere. After completion of adding BBr₃, the temperature was raised to 150° C. and the resultant mixture was stirred for 24 hours. After cooling, triethylamine was slowly added dropwise to a flask containing the reactants to terminate the reaction, and ethyl alcohol was added to the reactants to cause precipitation and a solid was obtained therefrom by filtration. The obtained solid was purified through column chromatography with MC and n-hexane and then recrystallized utilizing toluene and acetone to obtain Compound 6 (Yield: 19%).

(2) Synthesis of Compound 14

Polycyclic Compound 14 according to an embodiment may be synthesized by, for example, a process of Reaction Formula 2.

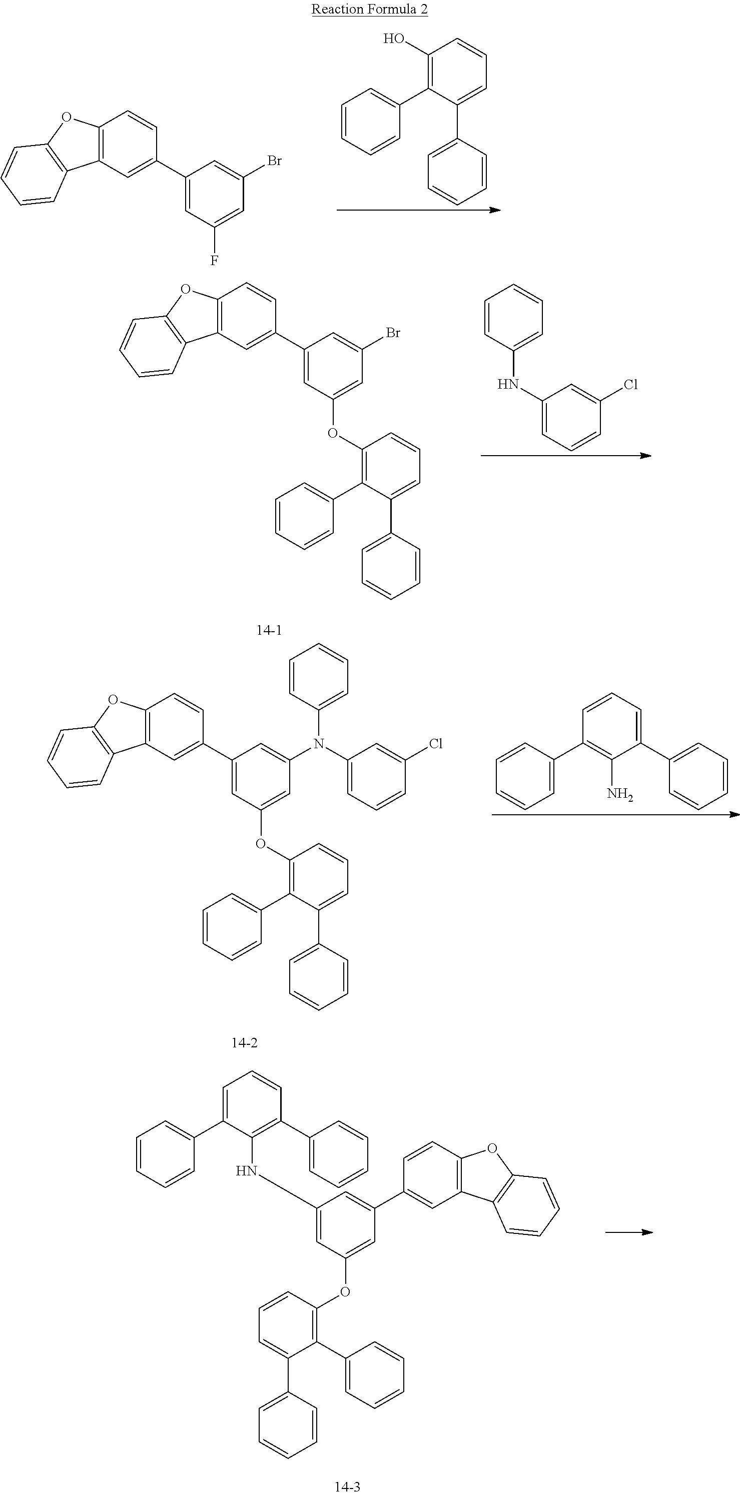

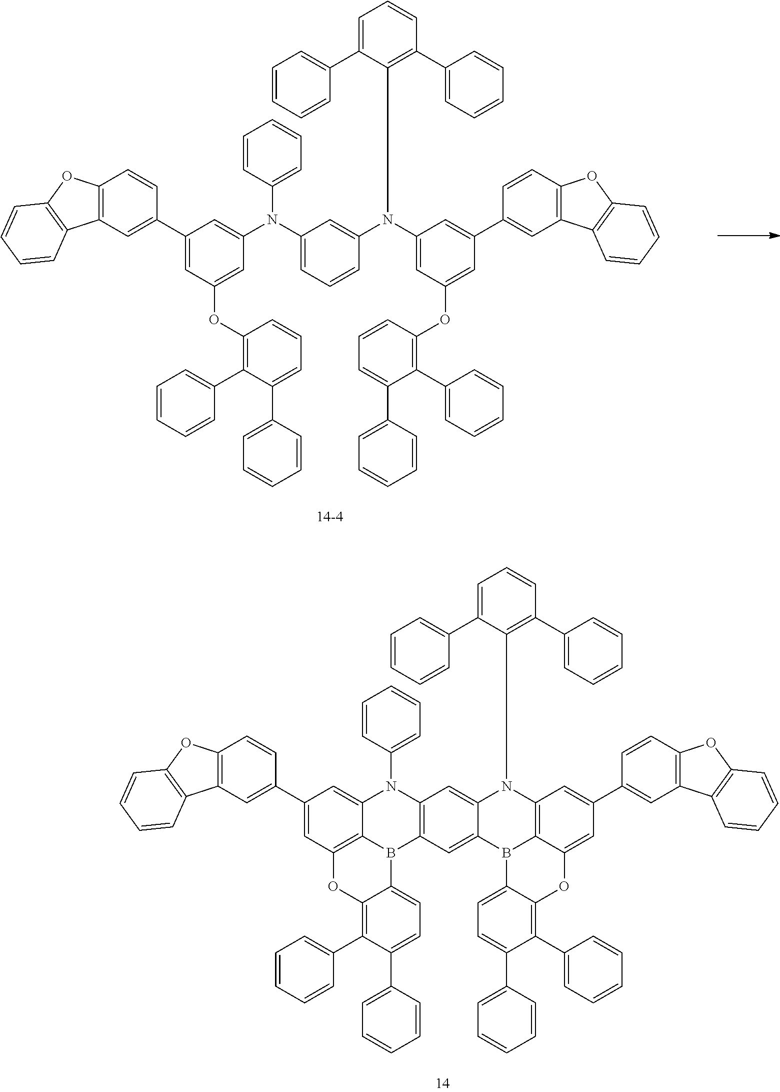 [SMILES: c1ccc(-c2cccc(Oc3cc(-c4ccc5oc6ccccc6c5c4)cc(N(c4ccccc4)c4cccc(N(c5cc(Oc6cccc(-c7ccccc7)c6-c6ccccc6)cc(-c6ccc7oc8ccccc8c7c6)c5)c5c(-c6ccccc6)cccc5-c5ccccc5)c4)c3)c2-c2ccccc2)cc1 ; c1ccc(-c2ccc3c(c2-c2ccccc2)Oc2cc(-c4ccc5oc6ccccc6c5c4)cc4c2B3c2cc3c(cc2N4c2ccccc2)N(c2c(-c4ccccc4)cccc2-c2ccccc2)c2cc(-c4ccc5oc6ccccc6c5c4)cc4c2B3c2ccc(-c3ccccc3)c(-c3ccccc3)c2O4)cc1]

1) Synthesis of Intermediate Compound 14-1

2-(3-bromo-5-fluorophenyl)dibenzo[b,d]furan (1 eq), [1,1′:2′,1″-terphenyl]-3′-ol (1.2 eq), and K₃PO₄ (2 eq) were dissolved in DMF and then stirred at 160° C. for 12 hours. After cooling, a solvent was removed therefrom under reduced pressure, and the resultant product was washed three times with ethyl acetate and water, and an organic layer obtained by separation was dried utilizing MgSO₄ and dried under reduced pressure. Intermediate Compound 14-1 was obtained by purification through column chromatography with MC and n-hexane. (Yield: 80%)

2) Synthesis of Intermediate Compound 14-2

Intermediate Compound 14-1 (1 eq), 3-chloro-N-phenylaniline (1 eq), tris(dibenzylideneacetone)dipalladium(0) (0.05 eq), tri-tert-butylphosphine (0.1 eq), and sodium tert-butoxide (3 eq) were dissolved in toluene and then stirred at 100° C. for 1 hour. After cooling, the resultant product was washed three times with ethyl acetate and water, and an organic layer obtained by separation was dried utilizing MgSO₄ and dried under reduced pressure. Intermediate Compound 14-2 was obtained by purification through column chromatography with MC and n-hexane. (Yield: 35%)

3) Synthesis of Intermediate Compound 14-3

Intermediate Compound 14-1 (1 eq), [1,1′:3′,1″-terphenyl]-2′-amine (1eq), tris(dibenzylideneacetone)dipalladium(0) (0.05 eq), tri-tert-butylphosphine (0.1 eq), and sodium tert-butoxide (3 eq) were dissolved in o-xylene and then stirred at 150° C. for 10 hours. After cooling, the resultant product was washed three times with ethyl acetate and water, and an organic layer obtained by separation was dried utilizing MgSO₄ and dried under reduced pressure. Intermediate Compound 14-3 was obtained by purification through column chromatography with MC and n-hexane. (Yield: 77%)

4) Synthesis of Intermediate Compound 14-4

Intermediate Compound 14-2 (1 eq), Intermediate Compound 14-3 (1 eq), tris(dibenzylideneacetone)dipalladium(0) (0.2 eq), tri-tert-butylphosphine (0.4 eq), and sodium tert-butoxide (3 eq) were dissolved in o-xylene and then stirred at 150° C. for 36 hours. After cooling, the resultant product was washed three times with ethyl acetate and water, and an organic layer obtained by separation was dried utilizing MgSO₄ and dried under reduced pressure. Intermediate Compound 14-4 was obtained by purification through column chromatography with MC and n-hexane. (Yield: 40%)

5) Synthesis of Compound 14

Intermediate Compound 14-4 (1 eq) was dissolved in ortho dichlorobenzene, cooled to 0° C., and then BBr₃ (5 eq) was slowly injected thereto dropwise in a nitrogen atmosphere. After completion of adding BBr₃, the temperature was raised to 150° C. and the resultant mixture was stirred for 24 hours. After cooling, triethylamine was slowly added dropwise to a flask containing the reactants to terminate the reaction, and ethyl alcohol was added to the reactants to cause precipitation and a solid was obtained therefrom by filtration. The obtained solid was purified through column chromatography with MC and n-hexane and then recrystallized utilizing toluene and acetone to obtain Compound 14. (Yield: 21%)

(3) Synthesis of Compound 29

Polycyclic compound 29 according to an embodiment may be synthesized by, for example, a process of Reaction Formula 3.

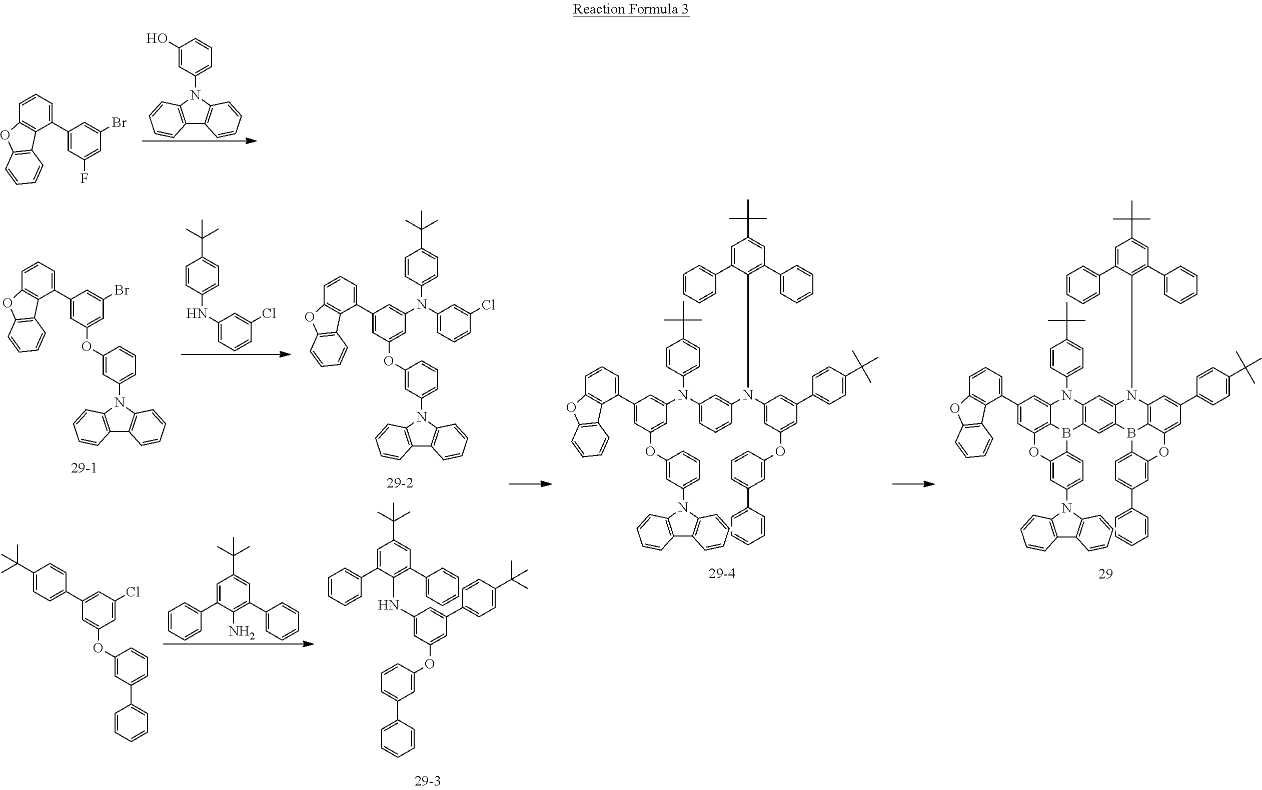

1) Synthesis of Intermediate Compound 29-1

1-(3-bromo-5-fluorophenyl)dibenzo[b,d]furan (1 eq), 3-(9H-carbazol-9-yl)phenol (1.4 eq), and K₃PO₄ (2 eq) were dissolved in DMF and then stirred at 160° C. for 12 hours. After cooling, a solvent was removed therefrom under reduced pressure, and the resultant product was washed three times with ethyl acetate and water, and an organic layer obtained by separation was dried utilizing MgSO₄ and dried under reduced pressure. Intermediate Compound 29-1 was obtained by purification through column chromatography with MC and n-hexane. (Yield: 64%)

2) Synthesis of Intermediate Compound 29-2

Intermediate Compound 29-1 (1 eq), N-(4-(tert-butyl)phenyl)-3-chloroaniline (1 eq), tris(dibenzylideneacetone)dipalladium(0) (0.05 eq), tri-tert-butylphosphine (0.1 eq), and sodium tert-butoxide (3 eq) were dissolved in toluene and then stirred at 100° C. for 1 hour. After cooling, the resultant product was washed three times with ethyl acetate and water, and an organic layer obtained by separation was dried utilizing MgSO₄ and dried under reduced pressure. Intermediate Compound 29-2 was obtained by purification through column chromatography with MC and n-hexane. (Yield: 40%)

3) Synthesis of Intermediate Compound 29-3

Intermediate Compound 29-1 (1 eq), 5′-(tert-butyl)-[1,1′:3′,1″-terphenyl]-2′-amine (1 eq), tris(dibenzylideneacetone)dipalladium(0) (0.05 eq), tri-tert-butylphosphine (0.1 eq), and sodium tert-butoxide (3 eq) were dissolved in o-xylene and then stirred at 150° C. for 10 hours. After cooling, the resultant product was washed three times with ethyl acetate and water, and an organic layer obtained by separation was dried utilizing MgSO₄ and dried under reduced pressure. Intermediate Compound 29-3 was obtained by purification through column chromatography with MC and n-hexane. (Yield: 70%)

4) Synthesis of Intermediate Compound 29-4

Intermediate Compound 29-2 (1 eq), Intermediate Compound 29-3 (1 eq), tris(dibenzylideneacetone)dipalladium(0) (0.2 eq), tri-tert-butylphosphine (0.4 eq), and sodium tert-butoxide (3 eq) were dissolved in o-xylene and then stirred at 150° C. for 48 hours. After cooling, the resultant product was washed three times with ethyl acetate and water, and an organic layer obtained by separation was dried utilizing MgSO₄ and dried under reduced pressure. Intermediate Compound 29-4 was obtained by purification through column chromatography with MC and n-hexane. (Yield: 35%)

5) Synthesis of Compound 29

Intermediate Compound 29-4 (1 eq) was dissolved in ortho dichlorobenzene, cooled to 0° C., and then BBr₃ (5 eq) was slowly injected thereto dropwise in a nitrogen atmosphere. After completion of adding BBr₃, the temperature was raised to 150° C. and the resultant mixture was stirred for 24 hours. After cooling, triethylamine was slowly added dropwise to a flask containing the reactants to terminate the reaction, and ethyl alcohol was added to the reactants to cause precipitation and a solid was obtained therefrom by filtration. The obtained solid was purified through column chromatography with MC and n-hexane and then recrystallized utilizing toluene and acetone to obtain Compound 29. (Yield: 16%)

4) Synthesis of Compound 58

Polycyclic compound 58 according to an embodiment may be synthesized by, for example, a process of Reaction Formula 4.

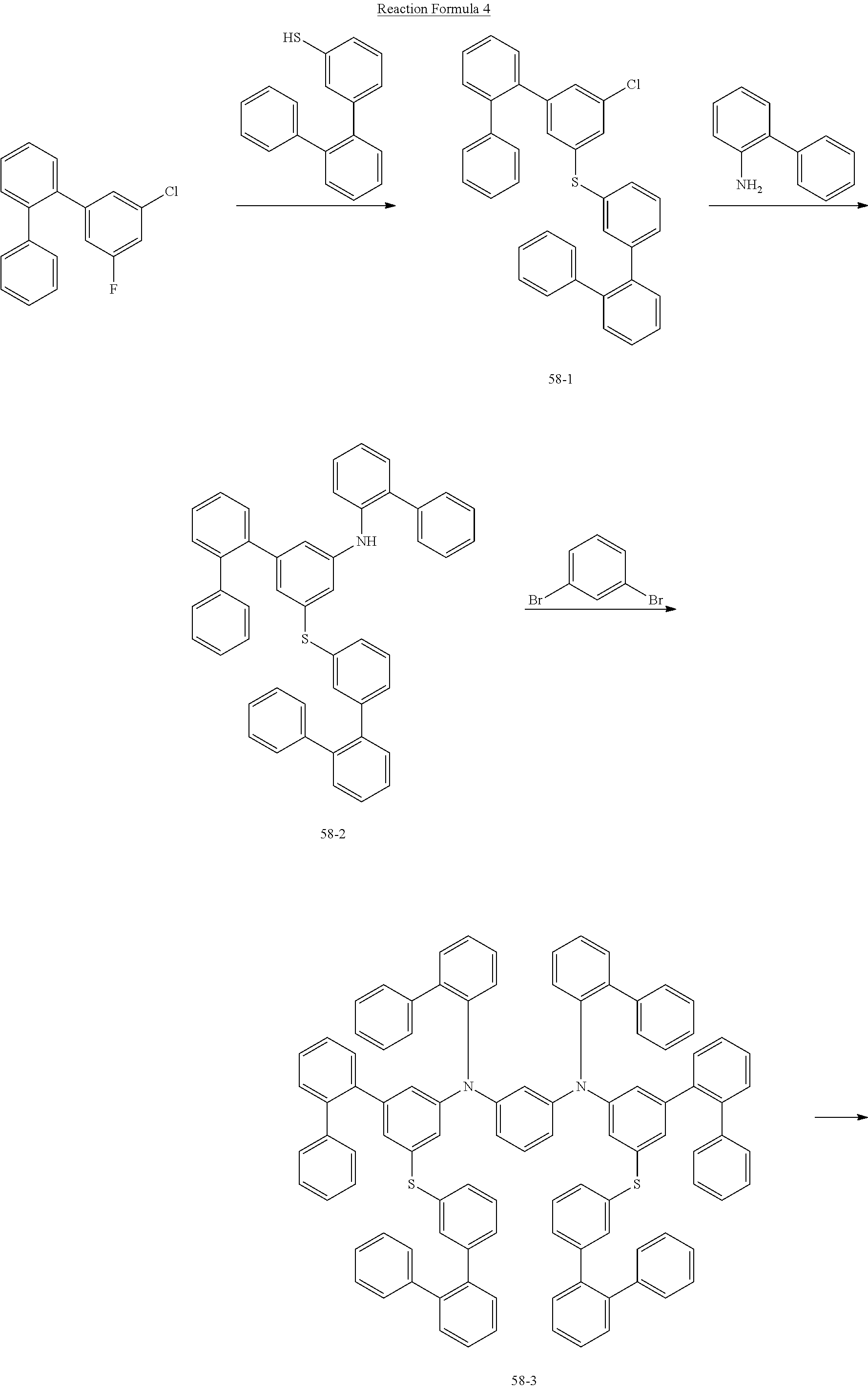

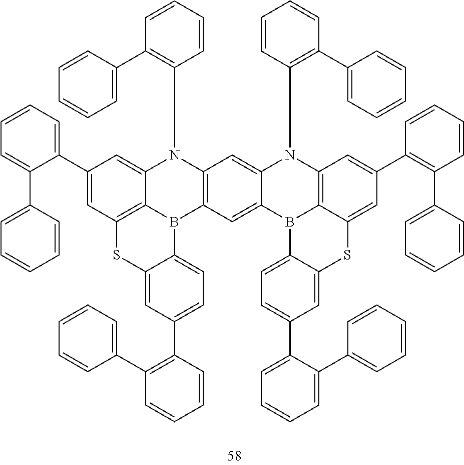 [SMILES: c1ccc(-c2ccccc2-c2ccc3c(c2)Sc2cc(-c4ccccc4-c4ccccc4)cc4c2B3c2cc3c(cc2N4c2ccccc2-c2ccccc2)N(c2ccccc2-c2ccccc2)c2cc(-c4ccccc4-c4ccccc4)cc4c2B3c2ccc(-c3ccccc3-c3ccccc3)cc2S4)cc1]

1) Synthesis of Intermediate Compound 58-1

3-chloro-5-fluoro-1,1′:2′,1″-terphenyl (1 eq), [1,1′:2′,1″-terphenyl]-3-thiol (1.4 eq), and K₃PO₄ (2 eq) were dissolved in DMF and then stirred at 160° C. for 17 hours. After cooling, a solvent was removed therefrom under reduced pressure, and the resultant product was washed three times with ethyl acetate and water, and an organic layer obtained by separation was dried utilizing MgSO₄ and dried under reduced pressure. Intermediate Compound 58-1 was obtained by purification through column chromatography with MC and n-hexane. (Yield: 52%)

2) Synthesis of Intermediate Compound 58-2

Intermediate Compound 58-1 (8 eq), [1,1′-biphenyl]-2-amine (1 eq), tris(dibenzylideneacetone)dipalladium(0) (0.05 eq), tri-tert-butylphosphine (0.1 eq), and sodium tert-butoxide (3 eq) were dissolved in toluene and then stirred at 110° C. for 8 hours. After cooling, the resultant product was washed three times with ethyl acetate and water, and an organic layer obtained by separation was dried utilizing MgSO₄ and dried under reduced pressure. Intermediate Compound 58-2 was obtained by purification through column chromatography with MC and n-hexane. (Yield: 73%)

3) Synthesis of Intermediate Compound 58-3

1,3-dibromobenzene (1 eq), Intermediate Compound 58-2 (2.1 eq), tris(dibenzylideneacetone)dipalladium(0) (0.05 eq), tri-tert-butylphosphine (0.1 eq), and sodium tert-butoxide (3 eq) were dissolved in toluene and then stirred at 110° C. for 12 hours. After cooling, the resultant product was washed three times with ethyl acetate and water, and an organic layer obtained by separation was dried utilizing MgSO₄ and dried under reduced pressure. Intermediate Compound 58-3 was obtained by purification through column chromatography with MC and n-hexane. (Yield: 69%)

4) Synthesis of Compound 58

Intermediate Compound 58-3 (1 eq) was dissolved in ortho dichlorobenzene, cooled to 0° C., and then BBr₃ (5 eq) was slowly injected thereto dropwise in a nitrogen atmosphere. After completion of adding BBr₃, the temperature was raised to 150° C. and the resultant mixture was stirred for 24 hours. After cooling, triethylamine was slowly added dropwise to a flask containing the reactants to terminate the reaction, and ethyl alcohol was added to the reactants to cause precipitation and a solid was obtained therefrom by filtration. The obtained solid was purified through column chromatography with MC and n-hexane and then recrystallized utilizing toluene and acetone to obtain Compound 58. (Yield: 23%)

(5) Synthesis of Compound 82

Polycyclic Compound 82 according to an embodiment may be synthesized by, for example, a process of Reaction Formula 5.

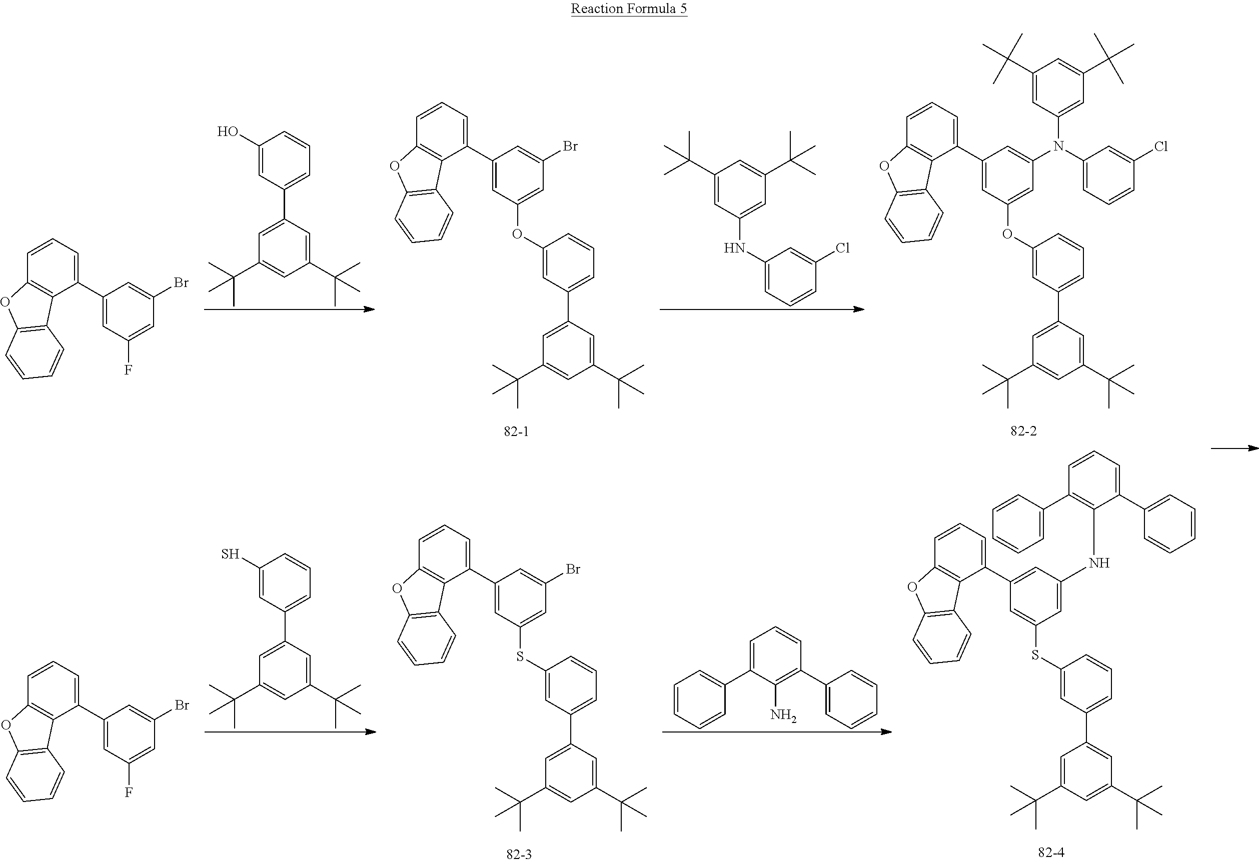

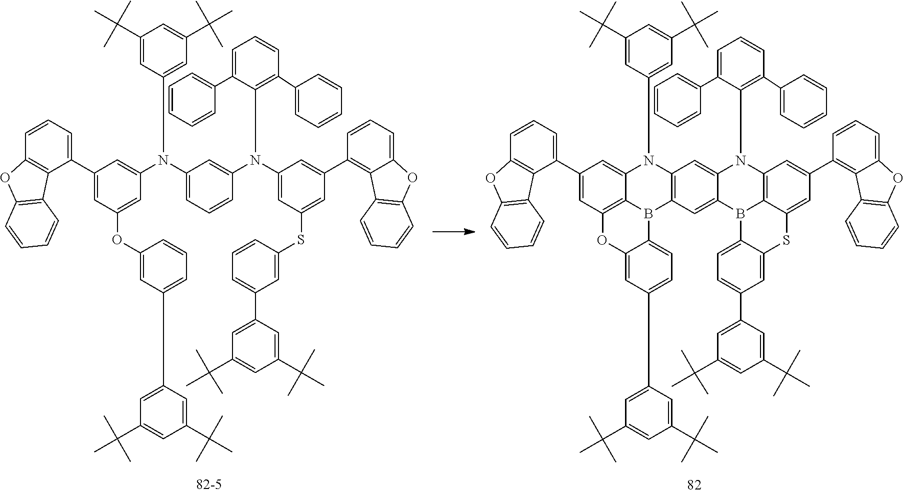 [SMILES: CC(C)(C)c1cc(-c2cccc(Oc3cc(-c4cccc5oc6ccccc6c45)cc(N(c4cccc(N(c5cc(Sc6cccc(-c7cc(C(C)(C)C)cc(C(C)(C)C)c7)c6)cc(-c6cccc7oc8ccccc8c67)c5)c5c(-c6ccccc6)cccc5-c5ccccc5)c4)c4cc(C(C)(C)C)cc(C(C)(C)C)c4)c3)c2)cc(C(C)(C)C)c1 ; CC(C)(C)c1cc(-c2ccc3c(c2)Oc2cc(-c4cccc5oc6ccccc6c45)cc4c2B3c2cc3c(cc2N4c2cc(C(C)(C)C)cc(C(C)(C)C)c2)N(c2c(-c4ccccc4)cccc2-c2ccccc2)c2cc(-c4cccc5oc6ccccc6c45)cc4c2B3c2ccc(-c3cc(C(C)(C)C)cc(C(C)(C)C)c3)cc2S4)cc(C(C)(C)C)c1]

1) Synthesis of Intermediate Compound 82-1

1-(3-bromo-5-fluorophenyl)dibenzo[b,d]furan (1 eq), 3′,5′-di-tert-butyl-[1,1′-biphenyl]-3-ol (1.1 eq), and K₃PO₄ (2 eq) were dissolved in DMF and then stirred at 160° C. for 12 hours. After cooling, a solvent was removed therefrom under reduced pressure, and the resultant product was washed three times with ethyl acetate and water, and an organic layer obtained by separation was dried utilizing MgSO₄ and dried under reduced pressure. Intermediate Compound 82-1 was obtained by purification through column chromatography with MC and n-hexane. (Yield: 74%)

2) Synthesis of Intermediate Compound 82-2

Intermediate Compound 82-1 (1 eq), 3,5-di-tert-butyl-N-(3-chlorophenyl)aniline (1 eq), tris(dibenzylideneacetone)dipalladium(0) (0.05 eq), tri-tert-butylphosphine (0.1 eq), and sodium tert-butoxide (3 eq) were dissolved in toluene and then stirred at 100° C. for 1 hour. After cooling, the resultant product was washed three times with ethyl acetate and water, and an organic layer obtained by separation was dried utilizing MgSO₄ and dried under reduced pressure. Intermediate Compound 82-2 was obtained by purification through column chromatography with MC and n-hexane. (Yield: 51%)

3) Synthesis of Intermediate Compound 82-3

1-(3-bromo-5-fluorophenyl)dibenzo[b,d]furan (1 eq), 3′,5′-di-tert-butyl-[1,1′-biphenyl]-3-thiol (1.2 eq), and K₃PO₄ (2 eq) were dissolved in DMF and then stirred at 160° C. for 12 hours. After cooling, a solvent was removed therefrom under reduced pressure, and the resultant product was washed three times with ethyl acetate and water, and an organic layer obtained by separation was dried utilizing MgSO₄ and dried under reduced pressure. Intermediate Compound 82-3 was obtained by purification through column chromatography with MC and n-hexane. (Yield: 51%)

4) Synthesis of Intermediate Compound 82-4

Intermediate Compound 82-3 (1 eq), [1,1′:3′,1″-terphenyl]-2′-amine (1 eq), tris(dibenzylideneacetone)dipalladium(0) (0.05 eq), tri-tert-butylphosphine (0.1 eq), and sodium tert-butoxide (3 eq) were dissolved in toluene and then stirred at 110° C. for 8 hours. After cooling, the resultant product was washed three times with ethyl acetate and water, and an organic layer obtained by separation was dried utilizing MgSO₄ and dried under reduced pressure. Intermediate Compound 82-4 was obtained by purification through column chromatography with MC and n-hexane. (Yield: 73%)

5) Synthesis of Intermediate Compound 82-5

Intermediate Compound 82-2 (1 eq), Intermediate Compound 82-4 (1 eq), tris(dibenzylideneacetone)dipalladium(0) (0.2 eq), tri-tert-butylphosphine (0.4 eq), and sodium tert-butoxide (3 eq) were dissolved in o-xylene and then stirred at 150° C. for 50 hours. After cooling, the resultant product was washed three times with ethyl acetate and water, and an organic layer obtained by separation was dried utilizing MgSO₄ and dried under reduced pressure. Intermediate Compound 82-5 was obtained by purification through column chromatography with MC and n-hexane. (Yield: 28%)

6) Synthesis of Compound 82

Intermediate Compound 82-5 (1 eq) was dissolved in ortho dichlorobenzene, cooled to 0° C., and then BBr₃ (5 eq) was slowly injected thereto dropwise in a nitrogen atmosphere. After completion of adding BBr₃, the temperature was raised to 150° C. and the resultant mixture was stirred for 24 hours. After cooling, triethylamine was slowly added dropwise to a flask containing the reactants to terminate the reaction, and ethyl alcohol was added to the reactants to cause precipitation and a solid was obtained therefrom by filtration. The obtained solid was purified through column chromatography with MC and n-hexane and then recrystallized utilizing toluene and acetone to obtain Compound 82. (Yield: 19%)

(6) Synthesis of Compound 105

Polycyclic Compound 105 according to an embodiment may be synthesized by, for example, a process of Reaction Formula 6.

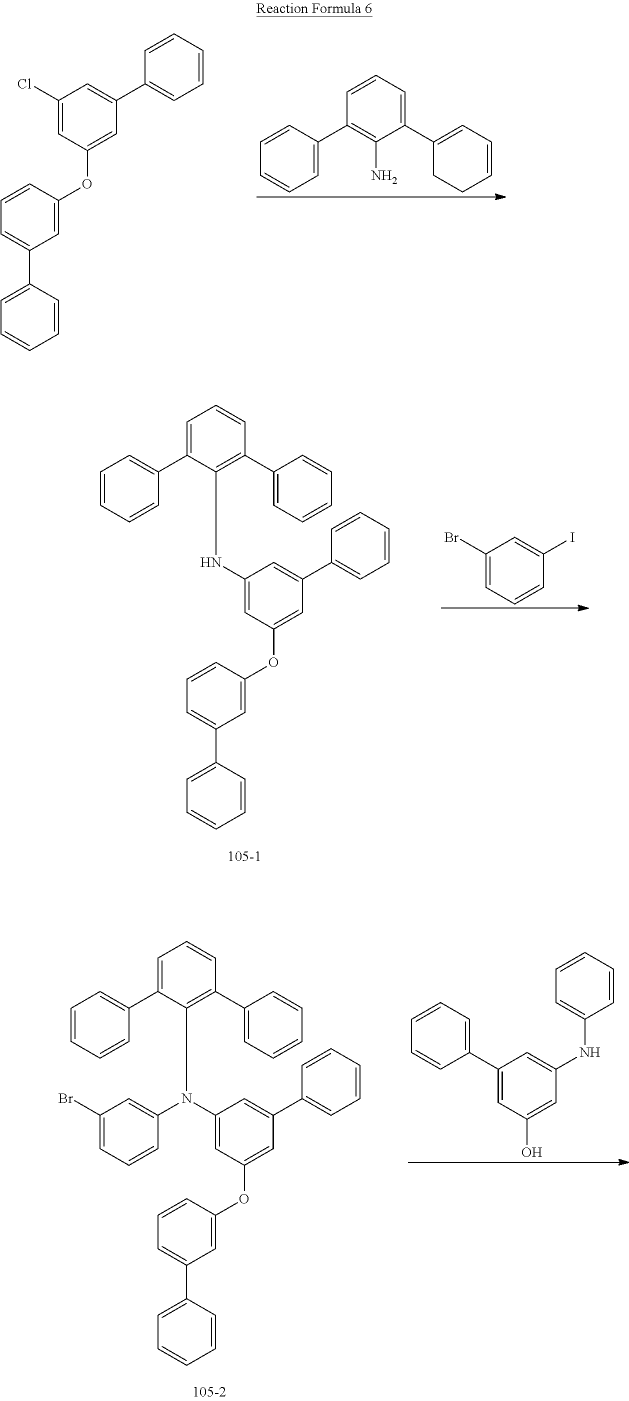 [SMILES: Clc1cc(Oc2cccc(-c3ccccc3)c2)cc(-c2ccccc2)c1 ; Nc1c(C2=CC=CCC2)cccc1-c1ccccc1 ; c1ccc(-c2cccc(Oc3cc(Nc4c(-c5ccccc5)cccc4-c4ccccc4)cc(-c4ccccc4)c3)c2)cc1 ; Brc1cccc(I)c1 ; Brc1cccc(N(c2cc(Oc3cccc(-c4ccccc4)c3)cc(-c3ccccc3)c2)c2c(-c3ccccc3)cccc2-c2ccccc2)c1 ; Oc1cc(Nc2ccccc2)cc(-c2ccccc2)c1]

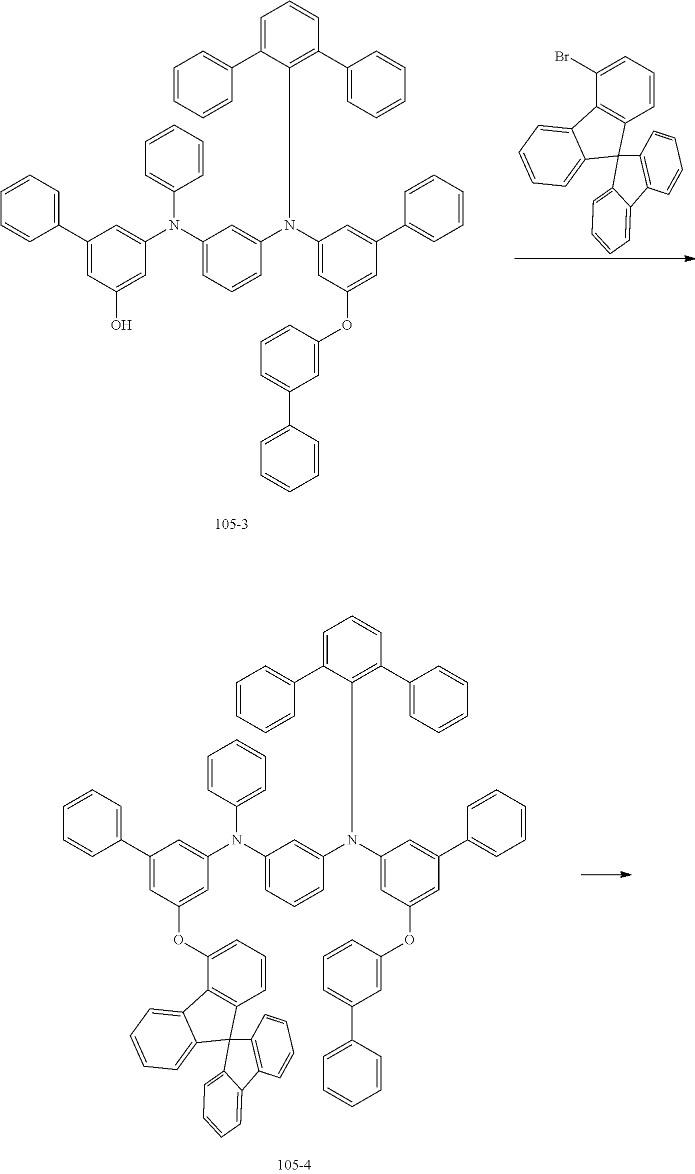 [SMILES: Oc1cc(-c2ccccc2)cc(N(c2ccccc2)c2cccc(N(c3cc(Oc4cccc(-c5ccccc5)c4)cc(-c4ccccc4)c3)c3c(-c4ccccc4)cccc3-c3ccccc3)c2)c1 ; Brc1cccc2c1-c1ccccc1C21c2ccccc2-c2ccccc21 ; c1ccc(-c2cccc(Oc3cc(-c4ccccc4)cc(N(c4cccc(N(c5ccccc5)c5cc(Oc6cccc7c6-c6ccccc6C76c7ccccc7-c7ccccc76)cc(-c6ccccc6)c5)c4)c4c(-c5ccccc5)cccc4-c4ccccc4)c3)c2)cc1]

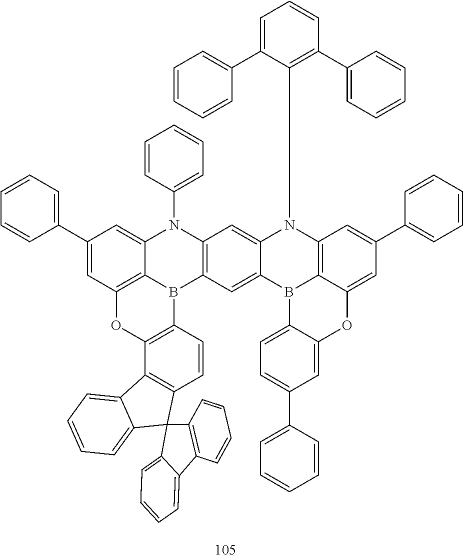 [SMILES: c1ccc(-c2ccc3c(c2)Oc2cc(-c4ccccc4)cc4c2B3c2cc3c(cc2N4c2c(-c4ccccc4)cccc2-c2ccccc2)N(c2ccccc2)c2cc(-c4ccccc4)cc4c2B3c2ccc3c(c2O4)-c2ccccc2C32c3ccccc3-c3ccccc32)cc1]

1) Synthesis of Intermediate Compound 105-1

3-([1,1′-biphenyl]-3-yloxy)-5-chloro-1,1′-biphenyl (1 eq), [1,1′:3′,1″-terphenyl]-2′-amine (1eq), tris(dibenzylideneacetone)dipalladium(0) (0.05 eq), tri-tert-butylphosphine (0.1 eq), and sodium tert-butoxide (3 eq) were dissolved in toluene and then stirred at 110° C. for 12 hours. After cooling, the resultant product was washed three times with ethyl acetate and water, and an organic layer obtained by separation was dried utilizing MgSO₄ and dried under reduced pressure. Intermediate Compound 105-1 was obtained by purification through column chromatography with MC and n-hexane. (Yield: 73%)

2) Synthesis of Intermediate Compound 105-2

Intermediate Compound 105-1 (1 eq), 1-bromo-3-iodobenzene (3 eq), tris(dibenzylideneacetone)dipalladium(0) (0.25 eq), tri-tert-butylphosphine (0.4 eq), and sodium tert-butoxide (3 eq) were dissolved in o-xylene and then stirred at 160° C. for 48 hours. After cooling, the resultant product was washed three times with ethyl acetate and water, and an organic layer obtained by separation was dried utilizing MgSO₄ and dried under reduced pressure. Intermediate Compound 105-2 was obtained by purification through column chromatography with MC and n-hexane. (Yield: 36%)

3) Synthesis of Intermediate Compound 105-3

Intermediate 105-2 (1 eq), 5-(phenylamino)-[1,1′-biphenyl]-3-ol (1 eq), tris(dibenzylideneacetone)dipalladium(0) (0.15 eq), tri-tert-butylphosphine (0.3 eq), and sodium tert-butoxide (3 eq) were dissolved in toluene and then stirred at 110° C. for 24 hours. After cooling, the resultant product was washed three times with ethyl acetate and water, and an organic layer obtained by separation was dried utilizing MgSO₄ and dried under reduced pressure. Intermediate Compound 105-3 was obtained by purification through column chromatography with MC and n-hexane. (Yield: 41%)

4) Synthesis of Intermediate Compound 105-4

Intermediate Compound 105-3 (1 eq), 4-bromo-9,9′-spirobi[fluorene] (1 eq), Cul (0.1 eq), 1,10-Phen. (0.1 eq), and K₂CO₃ (3 eq) were dissolved in DMF and then stirred at 160° C. for 12 hours. After cooling, a solvent was removed therefrom under reduced pressure, and the resultant product was washed three times with water, and an organic layer obtained by separation was dried utilizing MgSO₄ and dried under reduced pressure. Intermediate Compound 105-4 was obtained by purification through column chromatography with MC and n-hexane. (Yield: 68%)

5) Synthesis of Compound 105

Intermediate 105-5 (1 eq) was dissolved in ortho dichlorobenzene, cooled to 0° C., and then BBr₃ (5 eq) was slowly injected thereto dropwise in a nitrogen atmosphere. After completion of adding BBr₃, the temperature was raised to 150° C. and the resultant mixture was stirred for 49 hours. After cooling, triethylamine was slowly added dropwise to a flask containing the reactants to terminate the reaction, and ethyl alcohol was added to the reactants to cause precipitation and a solid was obtained therefrom by filtration. The obtained solid was purified through column chromatography with MC and n-hexane and then recrystallized utilizing toluene and acetone to obtain Compound 105. (Yield: 13%)

(7) Synthesis of Compound 107

Polycyclic Compound 107 according to an embodiment may be synthesized by, for example, a process of Reaction Formula 7.

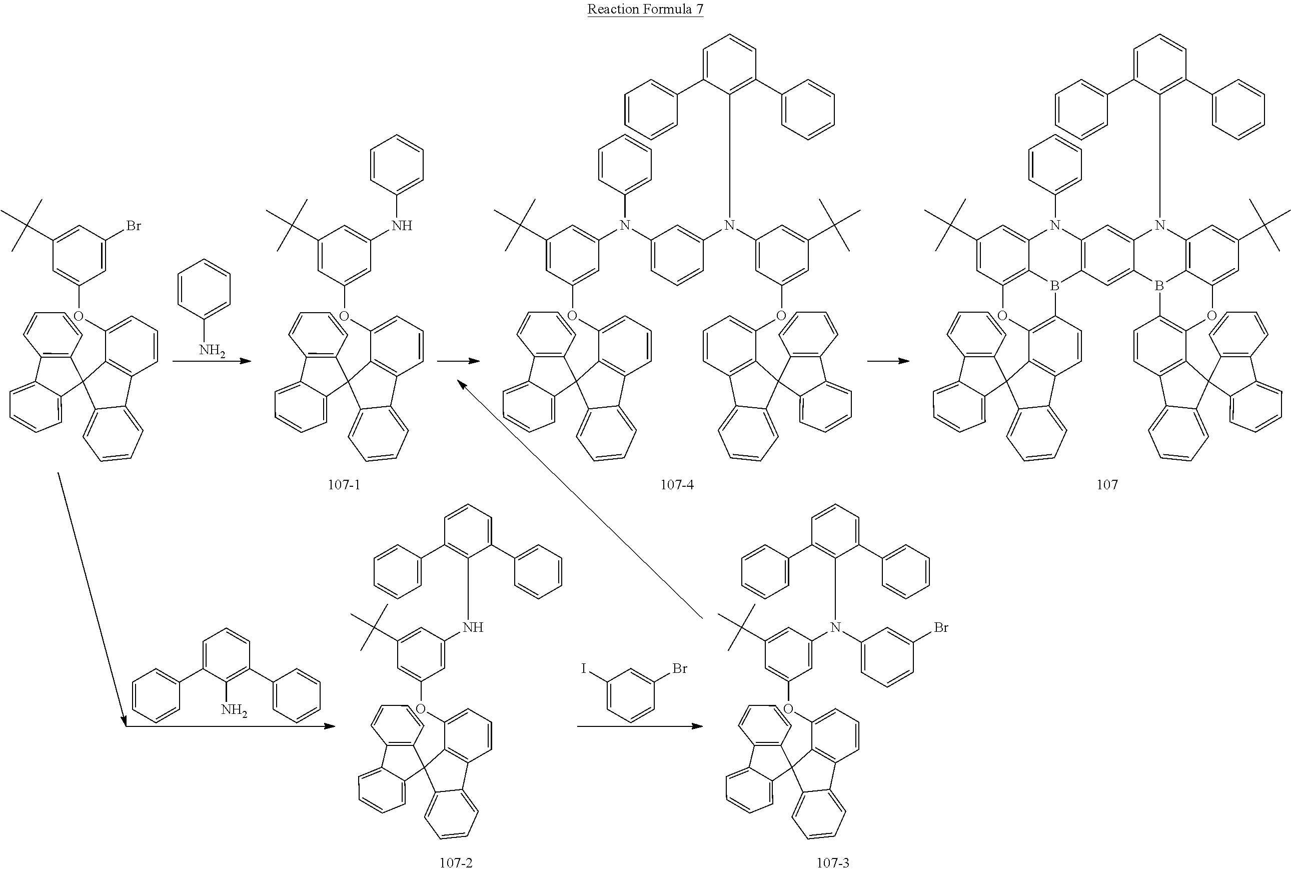

1) Synthesis of Intermediate Compound 107-1

1-(3-bromo-5-(tert-butyl)phenoxy)-9,9′-spirobi[fluorene] (1 eq), aniline (1.2 eq), tris(dibenzylideneacetone)dipalladium(0) (0.05 eq), tri-tert-butylphosphine (0.1 eq), and sodium tert-butoxide (3 eq) were dissolved in toluene and then stirred at 100° C. for 12 hours. After cooling, the resultant product was washed three times with ethyl acetate and water, and an organic layer obtained by separation was dried utilizing MgSO₄ and dried under reduced pressure. Intermediate Compound 107-1 was obtained by purification through column chromatography with MC and n-hexane. (Yield: 82%)

2) Synthesis of Intermediate Compound 107-2

1-(3-bromo-5-(tert-butyl)phenoxy)-9,9′-spirobi[fluorene] (1 eq), [1,1′:3′,1″-terphenyl]-2′-amine (1.1 eq), tris(dibenzylideneacetone)dipalladium(0) (0.05 eq), tri-tert-butylphosphine (0.1 eq), and sodium tert-butoxide (3 eq) were dissolved in toluene and then stirred at 100° C. for 12 hours. After cooling, the resultant product was washed three times with ethyl acetate and water, and an organic layer obtained by separation was dried utilizing MgSO₄ and dried under reduced pressure. Intermediate Compound 107-2 was obtained by purification through column chromatography with MC and n-hexane. (Yield: 76%)

3) Synthesis of Intermediate Compound 107-3

Intermediate Compound 107-2 (1 eq), 1-bromo-3-iodobenzene (3 eq), tris(dibenzylideneacetone)dipalladium(0) (0.2 eq), tri-tert-butylphosphine (0.4 eq), and sodium tert-butoxide (3 eq) were dissolved in o-xylene and then stirred at 160° C. for 48 hours. After cooling, the resultant product was washed three times with ethyl acetate and water, and an organic layer obtained by separation was dried utilizing MgSO₄ and dried under reduced pressure. Intermediate Compound 107-3 was obtained by purification through column chromatography with MC and n-hexane. (Yield: 31%)

4) Synthesis of Intermediate Compound 107-4

Intermediate Compound 107-1 (1 eq), Intermediate Compound 107-3 (1 eq), tris(dibenzylideneacetone)dipalladium(0) (0.1 eq), tri-tert-butylphosphine (0.2 eq), and sodium tert-butoxide (3 eq) were dissolved in toluene and then stirred at 110° C. for 48 hours. After cooling, the resultant product was washed three times with ethyl acetate and water, and an organic layer obtained by separation was dried utilizing MgSO₄ and dried under reduced pressure. Intermediate Compound 107-4 was obtained by purification through column chromatography with MC and n-hexane. (Yield: 70%)

5) Synthesis of Compound 107

Intermediate Compound 107-4 (1 eq) was dissolved in ortho dichlorobenzene, cooled to 0° C., and then BBr₃ (5 eq) was slowly injected thereto dropwise in a nitrogen atmosphere. After completion of adding BBr₃, the temperature was raised to 150° C. and the resultant mixture was stirred for 24 hours. After cooling, triethylamine was slowly added dropwise to a flask containing the reactants to terminate the reaction, and ethyl alcohol was added to the reactants to cause precipitation and a solid was obtained therefrom by filtration. The obtained solid was purified through column chromatography with MC and n-hexane and then recrystallized utilizing toluene and acetone to obtain Compound 107. (Yield: 10%)

TABLE 1

| Compound | NMR | Cal | Meas. |
|---|---|---|---|
| 6 | 10.41 (1H, s), 9.15-9.13 (1H, d), 9.11-9.08 (1H, | 1445.483 | 1445.478 |
| | d)7.91-7.76 (10H, m), 7.73-7.70 (2H, m), 7.61-7.39 | | |
| | (16H, m) | | |
| | 7.31-7.27 (6H, m), 7.22-7.17 (4H, m), 7.04-6.93 (10H, m) | | |
| | 6.73 (1H, s), 6.63 (1H, s), 6.52 (1H, s), 1.60 (18H, s), | | |
| | 1.42 (18H, s) | | |
| 14 | 10.38 (1H, s), 9.19-9.17 (1H, d), 9.15-9.12 (1H, | 1401.217 | 1401.211 |
| | d)7.99-7.93 (4H, m), 7.71-7.67 (2H, m), 7.62-7.55 | | |
| | (18H, m), 7.53-7.37 (20H, m), 7.35-7.31 (2H, t), | | |
| | 7.17-7.12 (5H, m), 7.05-7.02 (2H, d), 6.83-6.77 (1H, t), | | |
| | 6.73-6.70 (2H, s), 6.63-6.61 (2H, s), 6.53 (1H, s) | | |
| 29 | 10.36 (1H, s), 9.18-9.14 (1H, d), 9.10-9.07 (1H, | 1416.359 | 1416.347 |
| | d)8.11-8.07 (2H, m), 7.99-7.93 (1H, m), 7.62-7.56 (2H, m) | | |
| | 7.71-7.67 (2H, m), 7.60-7.55 (4H, d), 7.50-7.41 (4H, t) | | |
| | 7.62-7.45 (5H, m), 7.53-7.47 (2H, m), 7.45-7.36 (11H, m) | | |
| | 7.35-7.31 (2H, t), 7.25-7.20 (2H, m), 7.17-7.07 (5H, m) | | |
| | 7.05-7.02 (2H, d), 6.73-6.70 (2H, s), 6.63-6.61 (2H, s), | | |
| | 6.53 (1H, s), 1.57-1.54 (9H, m), 1.52-1.49 (9H, m), | | |
| | 1.41-1.38 (9H, s) | | |
| 58 | 10.44 (1H, s), 9.26-9.23 (1H, d), 9.21-9.18 (1H, d) | 1405.381 | 1405.374 |
| | 7.83-7.79 (12H, m), 7.71-7.67 (2H, m), 7.63-7.55 (4H, | | |
| | d), 7.53-7.42 (28H, m), 7.40-7.31 (4H, m), 7.16-7.12 | | |
| | (4H, d), 6.95-6.92 (2H, s), 6.80-6.72 (4H, t), 6.65-6.62 | | |
| | (2H, s), 6.62 (1H, s) | | |
| 82 | 10.48 (1H, s), 9.29-9.25 (1H, d), 9.20-9.17 (1H, d) | 1601.728 | 1601.721 |
| | 7.97-7.93 (2H, m), 7.82-7.78 (5H, m), 7.71-7.67 (1H, s), | | |
| | 7.63-7.55 (8H, d), 7.53-7.43 (8H, m) 7.41-7.36 (4H, m) | | |
| | 7.45-7.42 (3H, s) 7.40-7.37 (1H, s) 7.36-7.31 (2H, m) | | |
| | 7.17-7.12 (3H, m), 7.05-7.02 (2H, d), 6.99-6.91 (2H, d), | | |
| | 6.81-6.73 (3H, m), 6.69 (1H, s), 1.52-1.49 (36H, s), | | |
| | 1.46-1.43 (18H, s) | | |
| 105 | 10.41 (1H, s), 9.21-9.19 (1H, d), 9.17-9.14 (1H, d) | 1231.053 | 1231.046 |
| | 8.05-8.00 (3H, d), 7.70-7.65 (2H, m), 7.62-7.42 (27H, m), | | |
| | 7.39-7.31 (8H, m), 7.17-7.12 (5H, m), 7.05-7.02 (2H, | | |
| | d), 6.83-6.73 (3H, m), 6.69-6.66 (2H, s), 6.59 (1H, s), | | |
| 107 | 10.33 (1H, s), 9.13-9.11 (1H, d), 9.05-9.01 (1H, | 1353.260 | 1353.252 |
| | d)8.15-8.12 (2H, d), 8.05-8.00 (6H, d), 7.60-7.55 (4H, d) | | |
| | 7.50-7.41 (10H, m), 7.4-7.3 (14H, m), 7.17-7.12 (5H, m), | | |
| | 7.05-7.02 (2H, d) 6.83-6.77 (1H, t), 6.51 (1H, s) | | |
| | 6.41-6.36 (4H, d), 1.59 (18H, s), | | |

2. Manufacture and Evaluation of light emitting elements

(2) Manufacture of light emitting elements

Light emitting elements were manufactured utilizing Example Compounds and Comparative Example Compounds as respective dopants of respective emission layers.

In more detail, as an anode, a glass substrate having an ITO electrode (Corning, 15 Ω/cm², 1200 Å) formed thereon was cut to a size of about 50 mm×50 mm×0.7 mm, subjected to ultrasonic cleaning utilizing isopropyl alcohol for 5 minutes and pure water for 5 minutes and ultraviolet irradiation for 30 minutes, and then exposed to ozone for cleaning before being mounted on a vacuum deposition apparatus.

On the anode, a hole injection layer having a thickness of 300 A was formed through deposition of NPD, and on the hole injection layer, a hole transport layer having a thickness of 200 A was formed through deposition of H-1-1, and then on the hole transport layer, a light emitting auxiliary layer having a thickness of 100 A was formed through deposition of CzSi.

On the light emitting auxiliary layer, a host mixture, a phosphorescent sensitizer, and a dopant utilizing a respective Example or Comparative Example Compound were co-deposited at a weight ratio of 85:14:1 to form an emission layer having a thickness of 200 Å. As shown in Table 1, the host mixture was provided by mixing one of first hosts HT1, HT2, HT3, and HT4 and one of second hosts ETH85, ETH66, and ETH86 at a weight ratio of 5:5.

Thereafter, on the emission layer, a hole blocking layer having a thickness of 200 Å was formed through deposition of TSPO1; on the hole blocking layer, an electron transport layer having a thickness of 300 Å was formed through deposition of TPBI; on the electron transport layer, an electron injection layer having a thickness of 10 Å was formed through deposition of LiF; and on the electron injection layer, a cathode having a thickness of 3000 Å was formed through deposition of Al to complete the manufacture of a light emitting element.

### Example Compounds

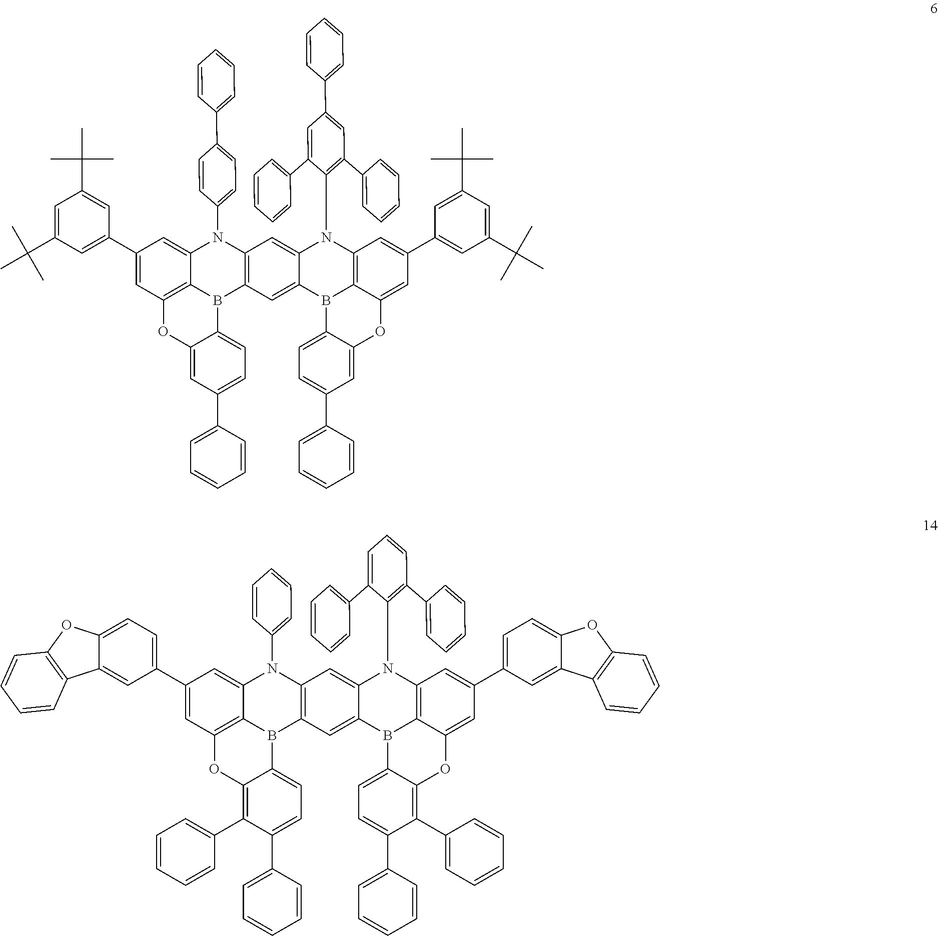 [SMILES: CC(C)(C)c1cc(-c2cc3c4c(c2)N(c2ccc(-c5ccccc5)cc2)c2cc5c(cc2B4c2ccc(-c4ccccc4)cc2O3)B2c3ccc(-c4ccccc4)cc3Oc3cc(-c4cc(C(C)(C)C)cc(C(C)(C)C)c4)cc(c32)N5c2c(-c3ccccc3)cc(-c3ccccc3)cc2-c2ccccc2)cc(C(C)(C)C)c1 ; c1ccc(-c2ccc3c(c2-c2ccccc2)Oc2cc(-c4ccc5oc6ccccc6c5c4)cc4c2B3c2cc3c(cc2N4c2ccccc2)N(c2c(-c4ccccc4)cccc2-c2ccccc2)c2cc(-c4ccc5oc6ccccc6c5c4)cc4c2B3c2ccc(-c3ccccc3)c(-c3ccccc3)c2O4)cc1]

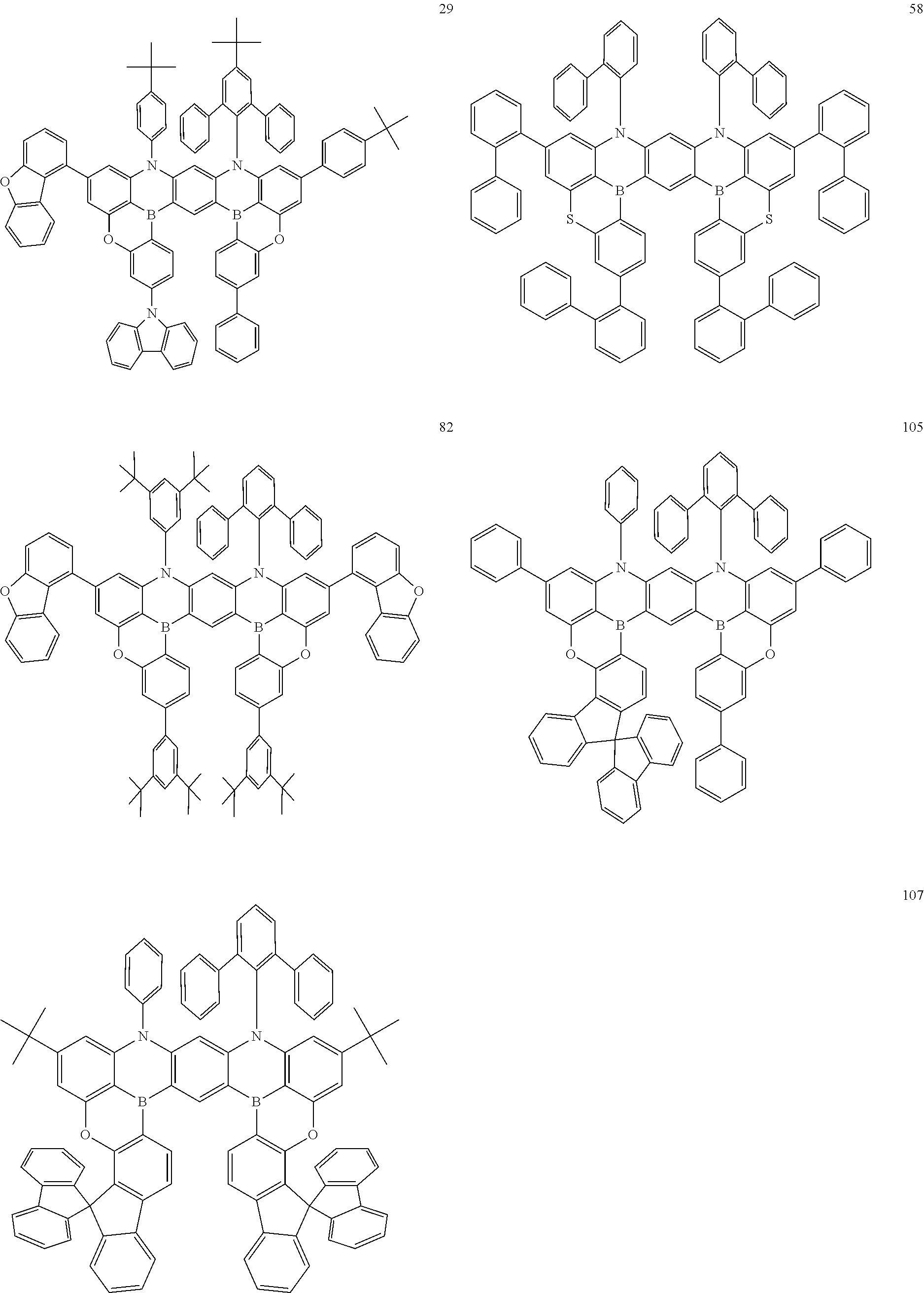

### Comparative Example Compounds

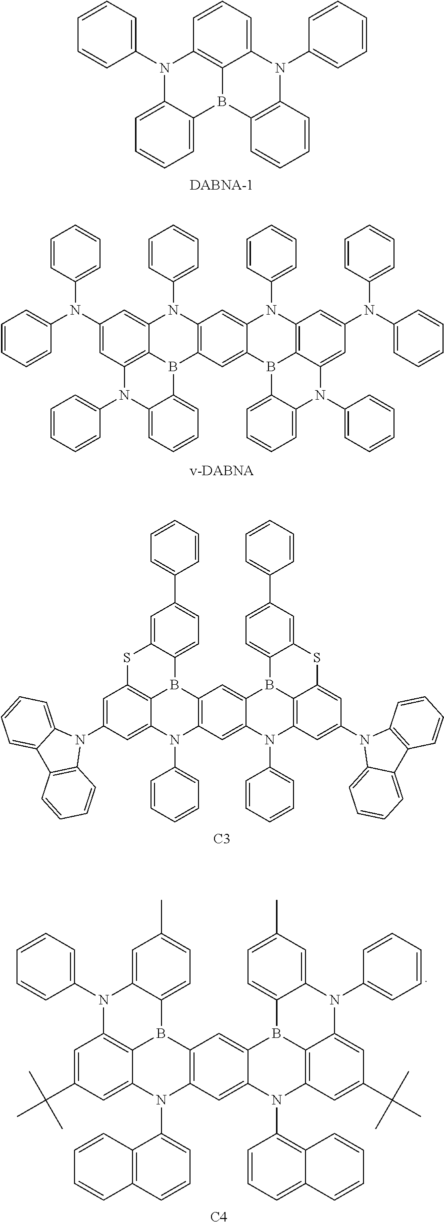

In Table 2, Comparative Example Compound DABNA-1 corresponds to Comparative Example Compound C1, and Comparative Example Compound v-DABNA corresponds to Comparative Example Compound C2.

The compounds utilized to manufacture the light emitting elements are as follows.

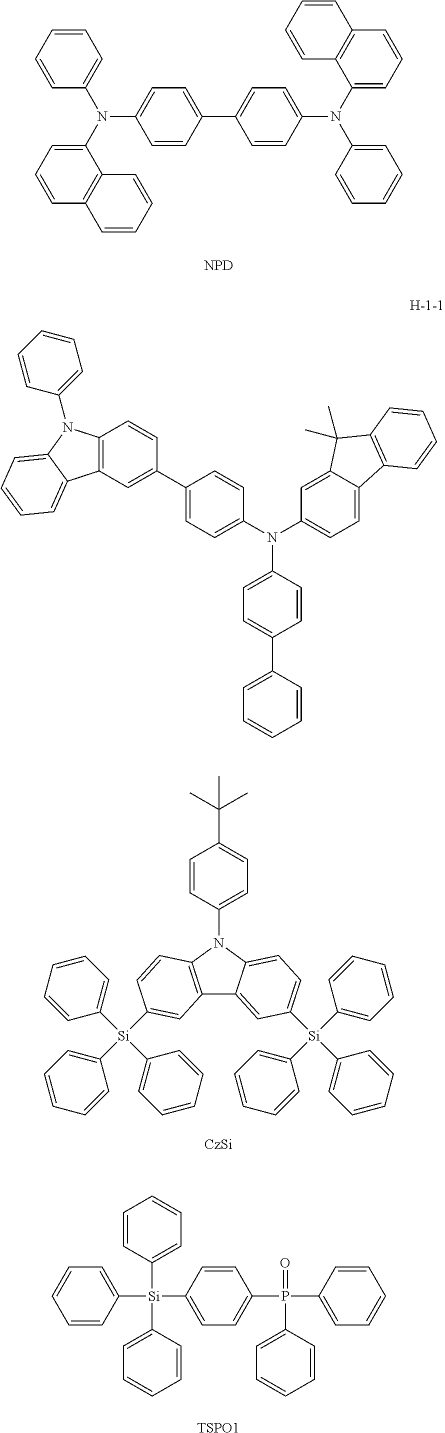

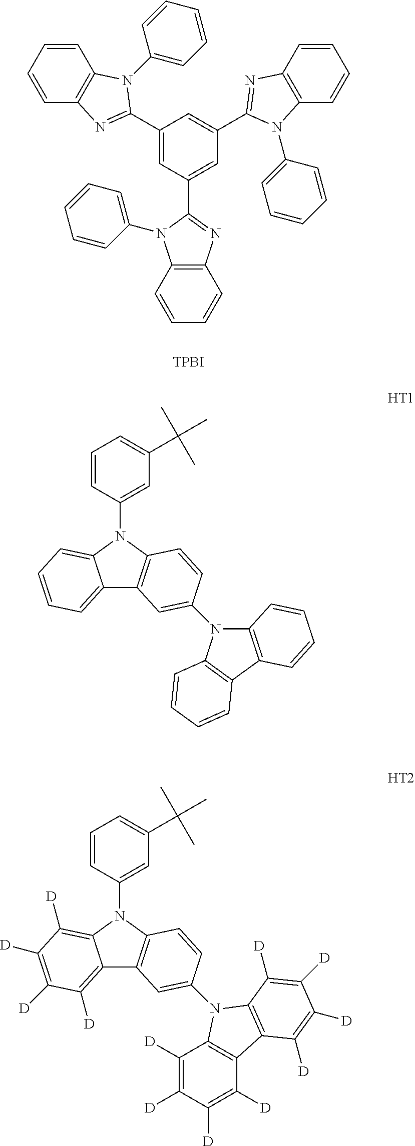

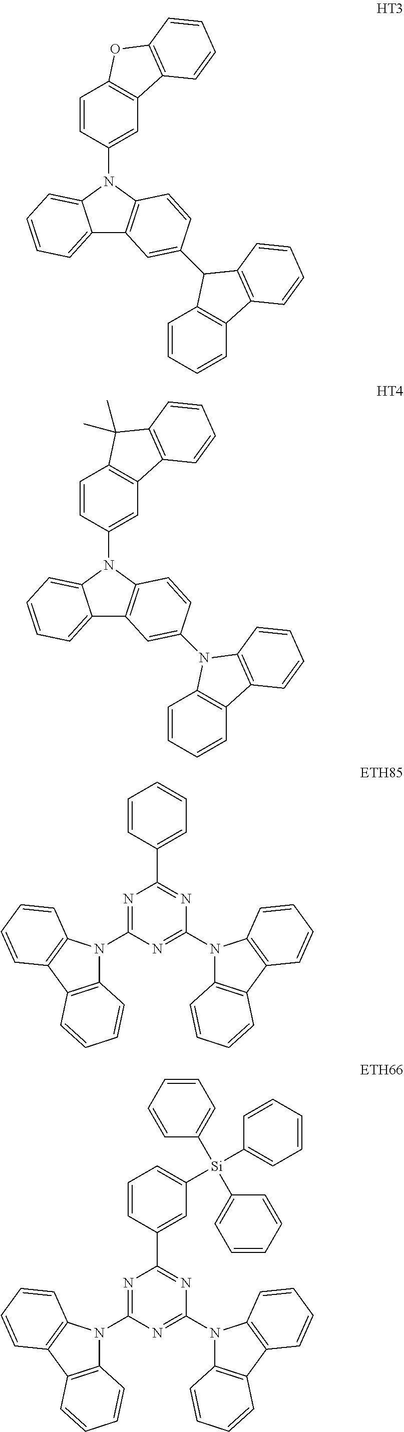

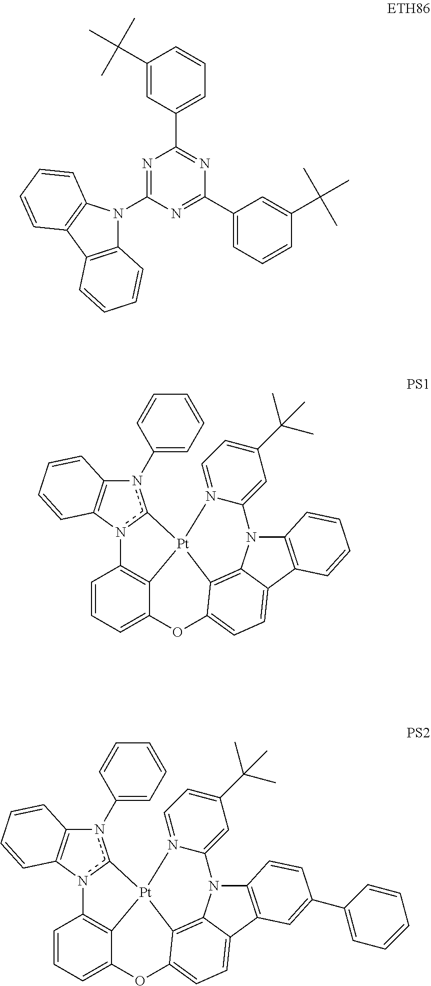

(2) Evaluation of light emitting elements

Driving voltage (V), light emitting efficiency (cd/A), light emitting wavelength (nm), and service life for the light emitting elements of Examples i to 17 and Comparative Examples 1 to 6 were evaluated and the results are shown in Table 2. In the characteristic evaluation results for the light emitting elements of Examples and Comparative Examples, driving voltage (V), light emitting efficiency (Cd/A), and light emitting wavelength were each measured utilizing Keithley MU 236 and a luminance meter PR650 at a current density of 1000 cd/m². A time taken for luminance to reach 95% with respect to an initial luminance was measured as the lifespan (%, T₉₅), and the relative lifespan was calculated with respect to Comparative Example 3 (e.g., utilizing the lifespan Comparative Example 3 as 1), and the results are shown for each.

TABLE 2

| | First | | | | | Light | |
|---|---|---|---|---|---|---|---|
| | host:Second | | | Driving | | emission | Relative |
| | host (mixing | Phosphorescent | | voltage | Efficiency | wavelength | Lifespan |
| Item | ratio = 5:5) | sensitizer | Dopant | (V) | (cd/A) | (Nm) | (T₉₅) |
| Example 1 | HT2/ETH66 | PS2 | Example | 4.1 | 27.3 | 459 | 6.1 |
| | | | Compound 6 | | | | |
| Example 2 | HT2/ETH66 | PS2 | Example | 4.3 | 28.0 | 460 | 6.6 |
| | | | Compound 14 | | | | |
| Example 3 | HT2/ETH66 | PS2 | Example | 4.2 | 26.5 | 458 | 5.3 |
| | | | Compound 29 | | | | |
| Example 4 | HT2/ETH66 | PS2 | Example | 4.2 | 27.0 | 460 | 5.0 |
| | | | Compound 58 | | | | |
| Example 5 | HT2/ETH66 | PS2 | Example | 4.2 | 26.1 | 460 | 5.3 |
| | | | Compound 82 | | | | |
| Example 6 | HT2/ETH66 | PS2 | Example | 4.1 | 26.8 | 458 | 6.7 |
| | | | Compound 105 | | | | |
| Example 7 | HT2/ETH66 | PS2 | Example | 4.2 | 27.4 | 460 | 6.5 |
| | | | Compound 107 | | | | |
| Example 8 | HT3/ETH86 | PS1 | Example | 4.1 | 26.5 | 460 | 5.6 |
| | | | Compound 6 | | | | |
| Example 9 | HT3/ETH86 | PS1 | Example | 4.0 | 26.8 | 462 | 5.5 |
| | | | Compound 14 | | | | |
| Example 10 | HT3/ETH86 | PS1 | Example | 4.1 | 27.2 | 462 | 6.1 |
| | | | Compound 82 | | | | |
| Example 11 | HT1/ETH86 | PS1 | Example | 4.2 | 27.1 | 460 | 6.9 |
| | | | Compound 58 | | | | |
| Example 12 | HT1/ETH86 | PS1 | Example | 4.2 | 26.7 | 461 | 6.1 |
| | | | Compound 105 | | | | |
| Example 13 | HT1/ETH86 | PS1 | Example | 4.3 | 26.8 | 459 | 6.0 |
| | | | Compound 107 | | | | |
| Example 14 | HT4/ETH85 | PS2 | Example | 4.3 | 26.4 | 461 | 6.1 |
| | | | Compound 6 | | | | |
| Example 15 | HT4/ETH85 | PS2 | Example | 4.2 | 26.1 | 460 | 5.7 |
| | | | Compound 29 | | | | |
| Example 16 | HT4/ETH85 | PS2 | Example | 4.2 | 26.8 | 461 | 6.4 |
| | | | Compound 82 | | | | |
| Example 17 | HT4/ETH85 | PS2 | Example | 4.0 | 27.1 | 461 | 5.9 |
| | | | Compound 107 | | | | |
| Comparative | HT2/ETH66 | x | Comparative | 5.5 | 12.8 | 458 | — |
| Example 1 | | | Example | | | | |
| | | | compound C1 | | | | |
| Comparative | HT2/ETH66 | x | Comparative | 5.3 | 22.1 | 468 | — |
| Example 2 | | | Example | | | | |
| | | | compound C2 | | | | |
| Comparative | HT2/ETH66 | PS2 | Comparative | 4.7 | 14.9 | 461 | 1.0 |
| Example 3 | | | Example | | | | |
| | | | compound C1 | | | | |
| Comparative | HT2/ETH66 | PS2 | Comparative | 4.4 | 24.2 | 465 | 3.1 |
| Example 4 | | | Example | | | | |
| | | | compound C2 | | | | |
| Comparative | HT2/ETH66 | PS2 | Comparative | 4.5 | 23.1 | 459 | 2.5 |
| Example 5 | | | Example | | | | |
| | | | compound C3 | | | | |
| Comparative | HT2/ETH66 | PS2 | Comparative | 4.7 | 21.9 | 468 | 2.3 |
| Example 6 | | | Example | | | | |
| | | | compound C4 | | | | |

Referring to the results of Table 2, the light emitting elements of Examples 1 to 17 (each including the corresponding polycyclic compound of an embodiment) each exhibited higher light emitting efficiency and longer lifespan than the light emitting elements of Comparative Examples 1 to 6.

The polycyclic compound of an embodiment may include a plate-shaped fused ring structure of nine rings that contains at least two boron atoms (B) as ring-forming atoms as a core, and substituents positioned para to the boron atoms at the core portion, thereby contributing to increasing efficiency and lifespan of a light emitting element when utilized as an emission layer material. In the polycyclic compound of an embodiment, substituents are positioned para to the boron atoms to allow pi (Π) electrons to be stably supplied to the boron atoms by conjugation or hyper conjugation, resulting in reduced electron deficiency, and accordingly, the boron atoms are less likely to be unstable. In the polycyclic compound of an embodiment, as hyper conjugation is prolonged, radicals may be stabilized in a wider space, thereby contributing to increasing the lifespan of a light emitting element.

In some embodiments, in the polycyclic compound of an embodiment, a benzene ring is further bonded and/or fused throughout the molecular structure, and the core portion includes a structure in which at least one oxygen atom or one sulfur atom is introduced, and the polycyclic compound of an embodiment may thus contribute to increased lifespan of a light emitting element when utilized as an emission layer material. In some embodiments, the polycyclic compound of an embodiment may include an oxygen atom and/or a sulfur atom that is introduced into a core portion to form a fused ring, thereby contributing to shortened wavelength of a light emitting element.

A light emitting element according to an embodiment includes a polycyclic compound according to an embodiment, and may thus exhibit high efficiency and long life characteristics.

A polycyclic compound according to an embodiment may be utilized as a light emitting material for achieving improved characteristics of a light emitting element with high efficiency and long lifespan.

As used herein, the term “and/or” includes any and all combinations of one or more of the associated listed items. Throughout the disclosure, the expression “at least one of a, b or c”, “at least one selected from a, b, and c”, “at least one selected from the group consisting of a, b, and c”, “at least one selected from among a, b, and c”, etc., indicates only a, only b, only c, both (e.g., simultaneously) a and b, both (e.g., simultaneously) a and c, both (e.g., simultaneously) b and c, all of a, b, and c, or variations thereof.

The use of “may” when describing embodiments of the present disclosure refers to “one or more embodiments of the present disclosure”. As used herein, the singular forms “a”, “an” and “the” are intended to include the plural forms as well, unless the context clearly indicates otherwise.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the present disclosure has been described with reference to a preferred embodiment of the present disclosure, it will be understood that the present disclosure should not be limited to these preferred embodiments but one or more suitable changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims, and equivalents thereof.

What is claimed is:

1. A light emitting element comprising:
a first electrode;
a second electrode on the first electrode; and
an emission layer between the first electrode and the second electrode,
wherein the emission layer comprises:
a first compound represented by Formula 1; and
at least one of a second compound represented by Formula HT, a third compound represented by Formula ET, or a fourth compound represented by Formula M-b: 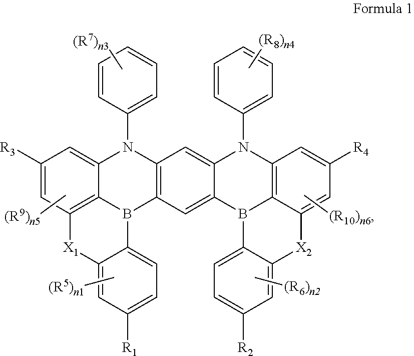
wherein in Formula 1,
one of X₁ or X₂ is O or S and the other one of X₁ or X₂ is NRₓ, O, or S,
Rₓ is a substituted or unsubstituted aryl group having 6 to 30 ring-forming carbon atoms, or a substituted or unsubstituted heteroaryl group having 2 to 30 ring-forming carbon atoms,
R₁ to R₄ are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, wherein when R₃ and R₄ are a substituted or unsubstituted carbazole group, the nitrogen atom of the carbazole group is not bonded to a benzene ring,
R₅ to R₈ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
R₉ and R₁₀ are each independently a hydrogen atom or a deuterium atom, or bonded to an adjacent group to form a ring,
n1 and n2 are each independently an integer of 0 to 3,
n3 and n4 are each independently an integer of 0 to 5, and
n5 and n6 are each independently an integer of 0 to 2; 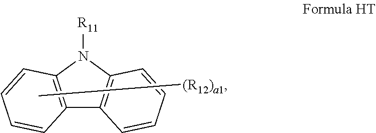
wherein in Formula HT,
a1 is an integer of 0 to 8, and
R₁₁ and R₁₂ are each independently a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms; 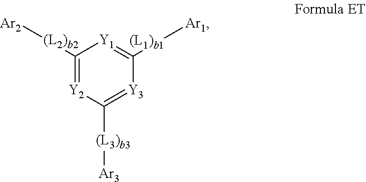
wherein in Formula ET,
at least one of Y₁ to Y₃ is N and any remainder thereof is CRₐ,
Rₐ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer of 0 to 10,
L₁ to L₃ are each independently a direct linkage, a substituted or unsubstituted arylene group having 6 to 30 ring-forming carbon atoms, or a substituted or unsubstituted heteroarylene group having 2 to 30 ring-forming carbon atoms, and
Ar₁ to Ar₃ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and 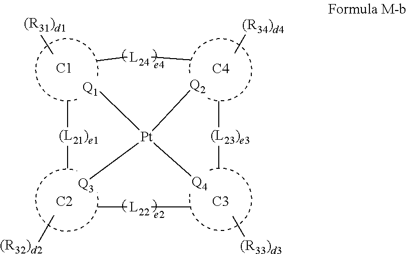
wherein in Formula M-b,
Q₁ to Q₄ are each independently C or N,
C1 to C4 are each independently a substituted or unsubstituted hydrocarbon ring group having 5 to 30 ring-forming carbon atoms, or a substituted or unsubstituted heterocycle having 2 to 30 ring-forming carbon atoms,
e1 to e4 are each independently 0 or 1,
L₂₁ to L₂₄ are each independently a direct linkage 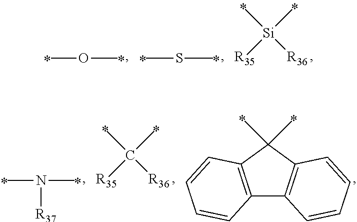
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
d1 to d4 are each independently an integer of 0 to 4, and
R₃₁ to R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

2. The light emitting element of claim 1, wherein the first compound represented by Formula 1 is represented by Formula 1-1 or Formula 1-2: 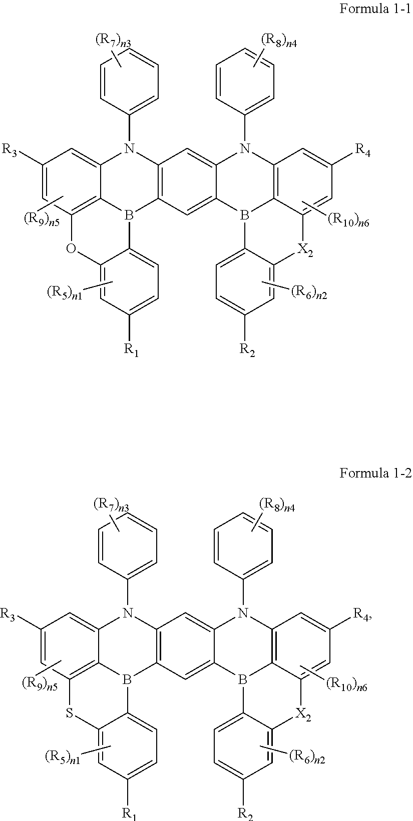
wherein in Formulas 1-1 and 1-2,
X₂ is NRₓ₁, O, or S,
Rₓ₁ is a substituted or unsubstituted aryl group having 6 to 30 ring-forming carbon atoms, or a substituted or unsubstituted heteroaryl group having 2 to 30 ring-forming carbon atoms, and
R₁ to R₁₀, and n1 to n6 are the same as respectively defined in Formula 1.

3. The light emitting element of claim 1, wherein the first compound represented by Formula 1 is represented by Formula 2: 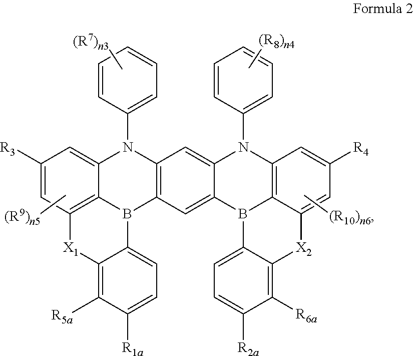
wherein in Formula 2,
R₁ₐ is a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to R₅ₐ to form a ring,
R₂ₐ is a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to R₆ₐ to form a ring,
R₅ₐ is a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to R₁ₐ to form a ring,
R₆ₐ is a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to R₂ₐ to form a ring, and
X₁, X₂, R₃, R₄, R₇ to R₁₀, and n3 to n6 are the same as respectively defined in Formula 1.

4. The light emitting element of claim 1, wherein the first compound represented by Formula 1 is represented by Formula 3: 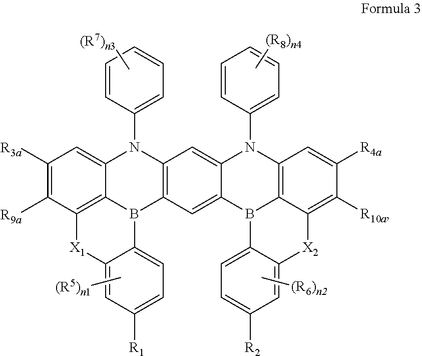
Formula 3
R₃ₐ is a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to R₉ₐ to form a ring,
R₄a is a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to R₁₀ₐ to form a ring,
R₉ₐ is a hydrogen atom or a deuterium atom, and/or bonded to R₃a to form a ring,
R₁₀ₐ is a hydrogen atom or a deuterium atom, and/or bonded to R₄ₐ to form a ring, and
X₁, X₂, R₁, R₂, R₅ to R₈, and n1 to n4 are the same as respectively defined in Formula 1.

5. The light emitting element of claim 1, wherein R₁ and R₂ are each independently represented by any one from among R-1 to R-7, and/or bonded to an adjacent group to form a ring represented by R-9, and
R₃ and R₄ are each independently represented by any one from among R-1 to R-5, and R-8, and/or bonded to an adjacent group to form a ring represented by R-9: 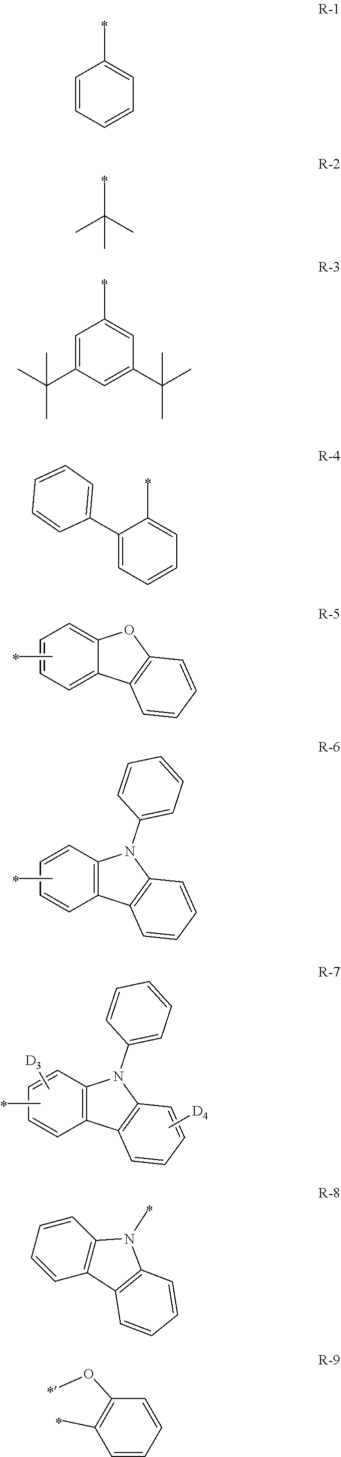
wherein in R-1 to R-9, “*-” is a site where R₁ to R₄ are linked to Formula 1, and
in R-9, “*′-” is a site where the adjacent group is linked to Formula 1.

6. The light emitting element of claim 1, wherein R₅ and R₆ are each independently a hydrogen atom, a deuterium atom, a substituted or unsubstituted t-butyl group, or a substituted or unsubstituted phenyl group, and/or bonded to an adjacent group to form a ring.

7. The light emitting element of claim 1, wherein the first compound represented by Formula 1 is represented by Formula 4: 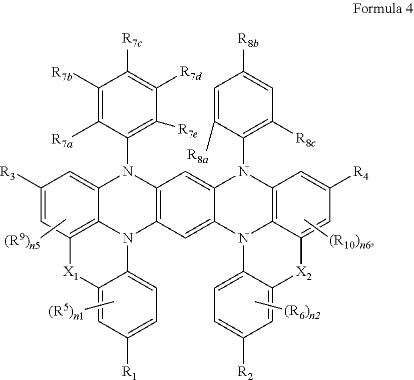
wherein in Formula 4,
R₇ₐ to R₇ₑ, and R₈ₐ to R_{8c} are each independently a hydrogen atom, a deuterium atom, a substituted or unsubstituted alkyl group having 1 to 6 carbon atoms, or a substituted or unsubstituted aryl group having 6 to 20 ring-forming carbon atoms, and
X₁, X₂, R₁ to R₆, R₉, R₁₀, n1, n2, n5, and n6 are the same as respectively defined in Formula 1.

8. The light emitting element of claim 7, wherein R₇ₐ to R₇ₑ, and R₈ₐ to R_{8c} are each independently a hydrogen atom, a deuterium atom, a substituted or unsubstituted t-butyl group, or a substituted or unsubstituted phenyl group.

9. The light emitting element of claim 1, wherein Rₓ is a substituted or unsubstituted phenyl group, or a substituted or unsubstituted biphenyl group.

10. The light emitting element of claim 1, wherein the emission layer is to emit blue light.

11. The light emitting element of claim 1, wherein the emission layer comprises the first compound, the second compound, and the third compound.

12. The light emitting element of claim 1, wherein the emission layer comprises the first compound, the second compound, the third compound, and the fourth compound.

13. The light emitting element of claim 1, wherein the first compound represented by Formula 1 is any one selected from among compounds of Compound Group 1:

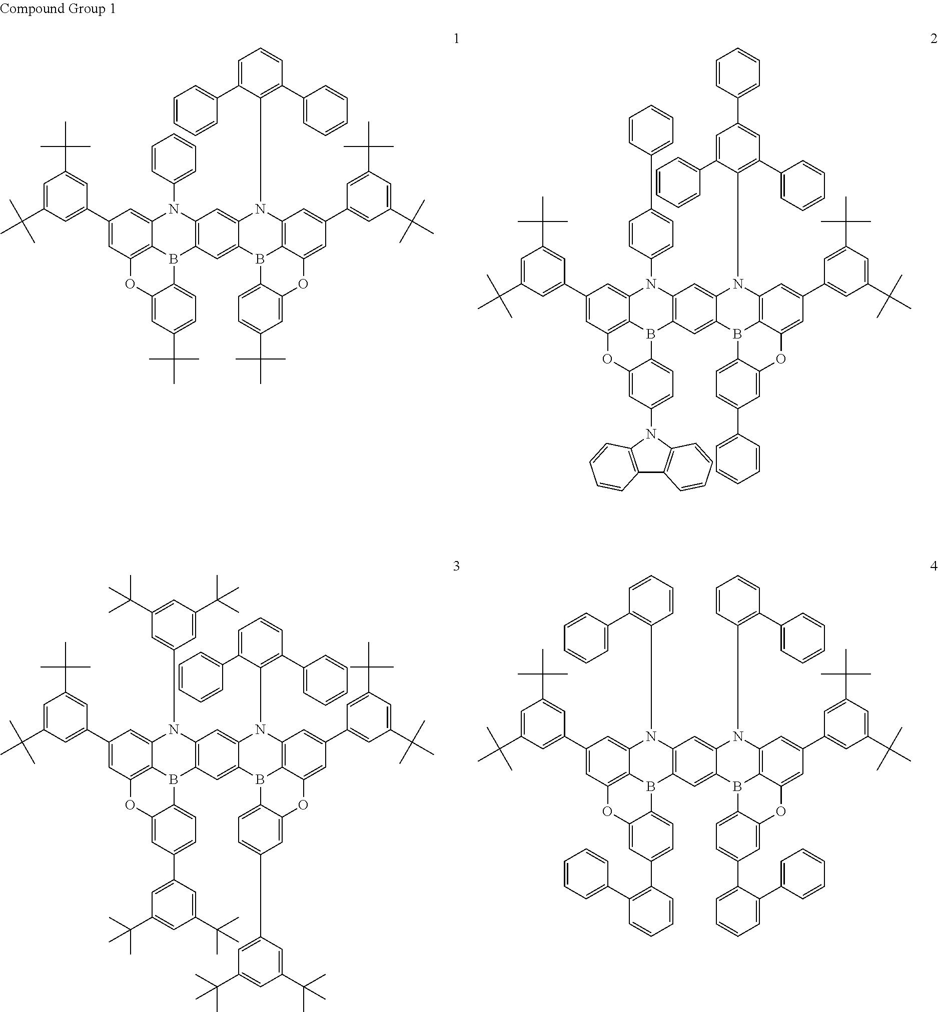

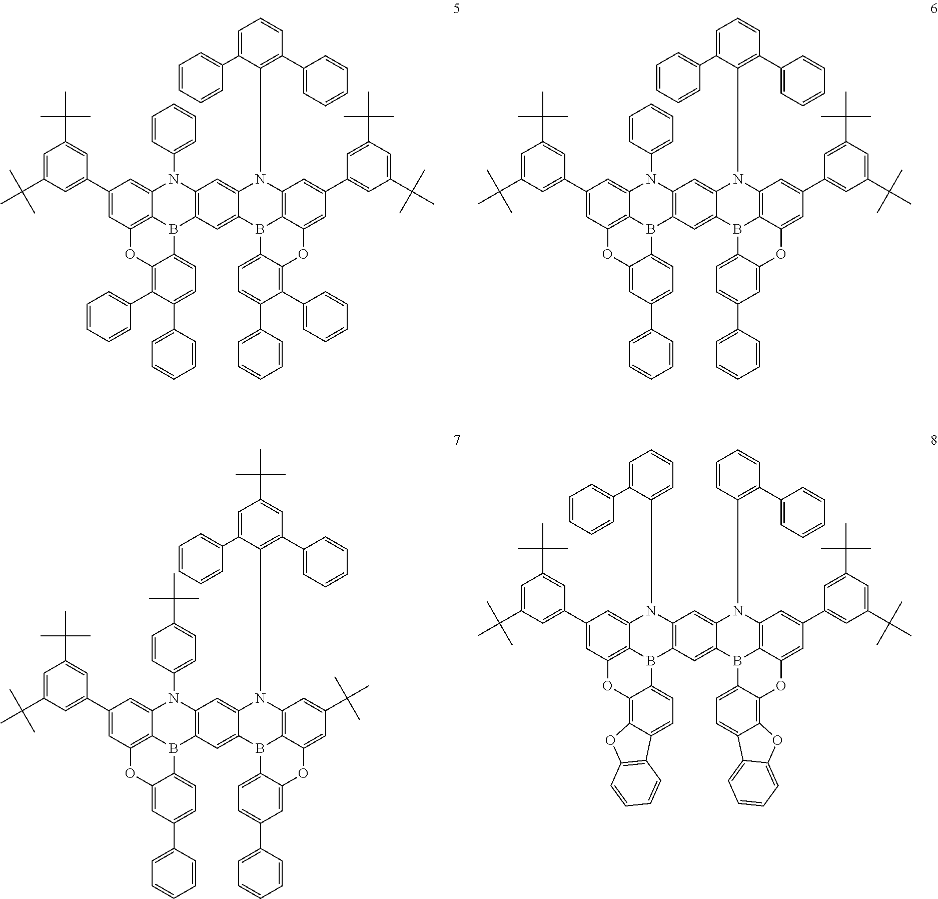

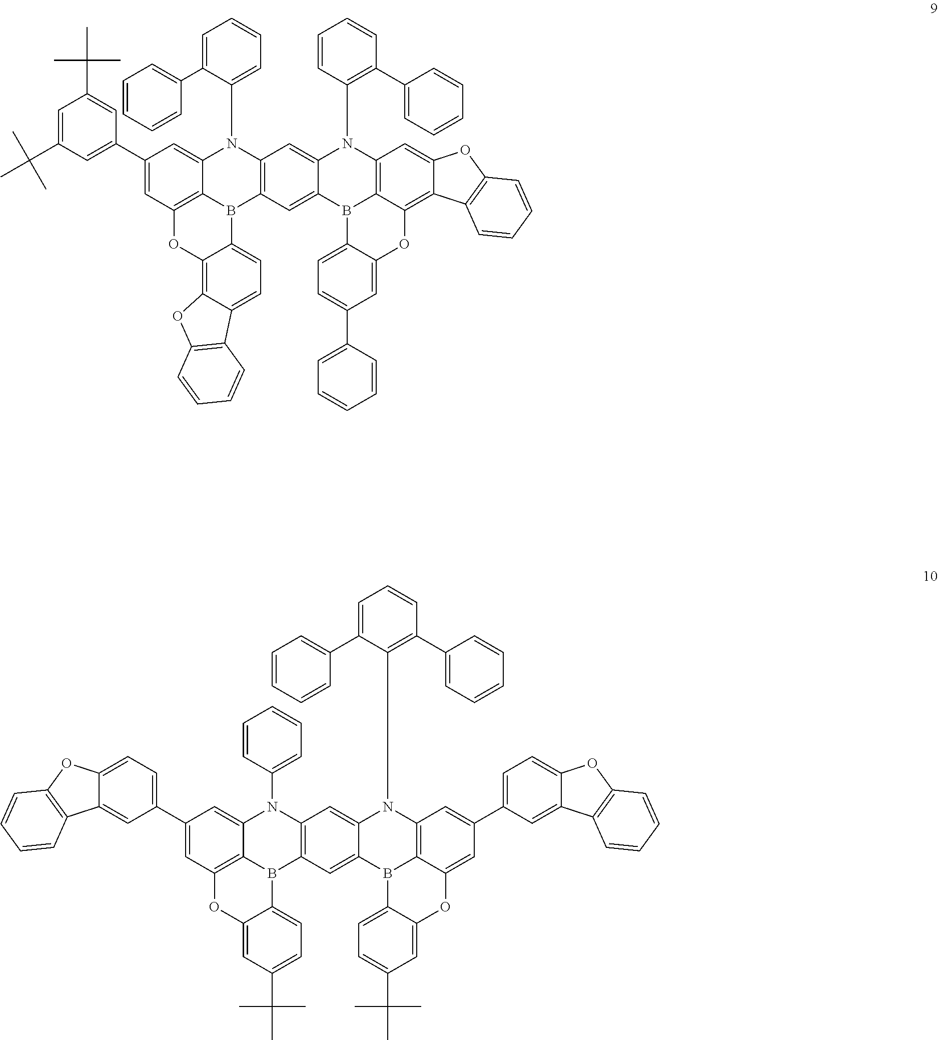 [SMILES: CC(C)(C)c1cc(-c2cc3c4c(c2)N(c2ccccc2-c2ccccc2)c2cc5c(cc2B4c2ccc4c(oc6ccccc64)c2O3)B2c3ccc(-c4ccccc4)cc3Oc3c2c(cc2oc4ccccc4c32)N5c2ccccc2-c2ccccc2)cc(C(C)(C)C)c1 ; CC(C)(C)c1ccc2c(c1)Oc1cc(-c3ccc4oc5ccccc5c4c3)cc3c1B2c1cc2c(cc1N3c1ccccc1)N(c1c(-c3ccccc3)cccc1-c1ccccc1)c1cc(-c3ccc4oc5ccccc5c4c3)cc3c1B2c1ccc(C(C)(C)C)cc1O3]

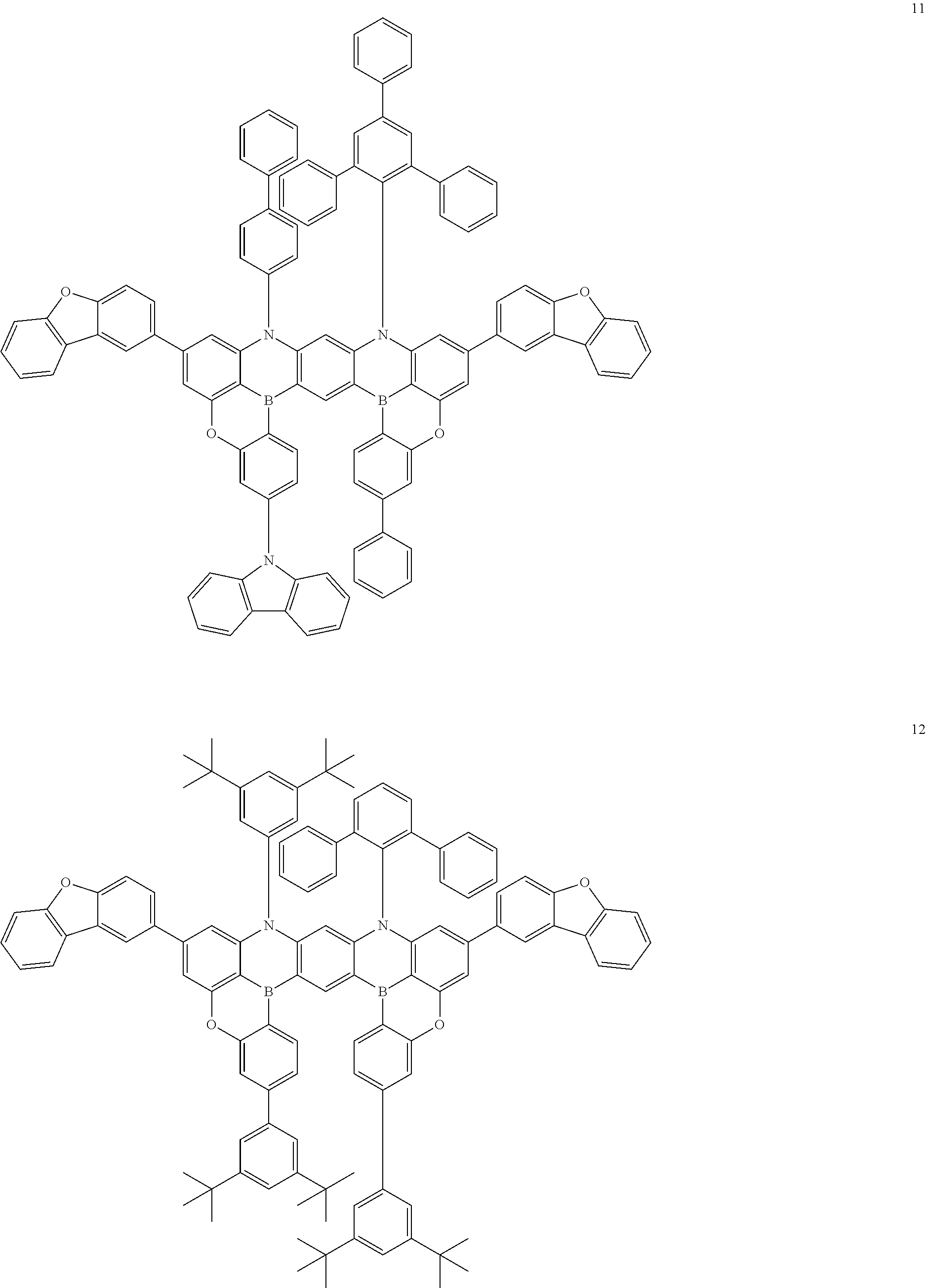 [SMILES: c1ccc(-c2ccc(N3c4cc5c(cc4B4c6ccc(-n7c8ccccc8c8ccccc87)cc6Oc6cc(-c7ccc8oc9ccccc9c8c7)cc3c64)B3c4ccc(-c6ccccc6)cc4Oc4cc(-c6ccc7oc8ccccc8c7c6)cc(c43)N5c3c(-c4ccccc4)cc(-c4ccccc4)cc3-c3ccccc3)cc2)cc1 ; CC(C)(C)c1cc(-c2ccc3c(c2)Oc2cc(-c4ccc5oc6ccccc6c5c4)cc4c2B3c2cc3c(cc2N4c2cc(C(C)(C)C)cc(C(C)(C)C)c2)N(c2c(-c4ccccc4)cccc2-c2ccccc2)c2cc(-c4ccc5oc6ccccc6c5c4)cc4c2B3c2ccc(-c3cc(C(C)(C)C)cc(C(C)(C)C)c3)cc2O4)cc(C(C)(C)C)c1]

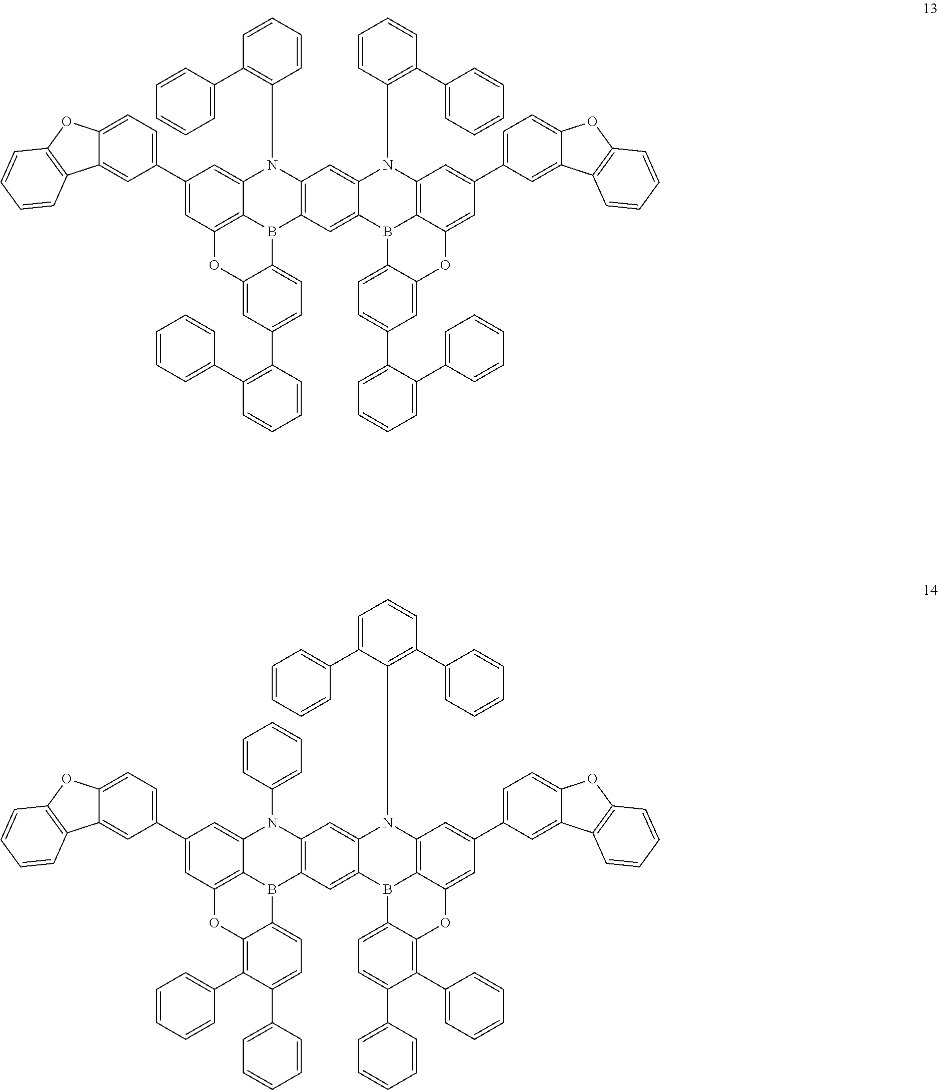 [SMILES: c1ccc(-c2ccccc2-c2ccc3c(c2)Oc2cc(-c4ccc5oc6ccccc6c5c4)cc4c2B3c2cc3c(cc2N4c2ccccc2-c2ccccc2)N(c2ccccc2-c2ccccc2)c2cc(-c4ccc5oc6ccccc6c5c4)cc4c2B3c2ccc(-c3ccccc3-c3ccccc3)cc2O4)cc1 ; c1ccc(-c2ccc3c(c2-c2ccccc2)Oc2cc(-c4ccc5oc6ccccc6c5c4)cc4c2B3c2cc3c(cc2N4c2ccccc2)N(c2c(-c4ccccc4)cccc2-c2ccccc2)c2cc(-c4ccc5oc6ccccc6c5c4)cc4c2B3c2ccc(-c3ccccc3)c(-c3ccccc3)c2O4)cc1]

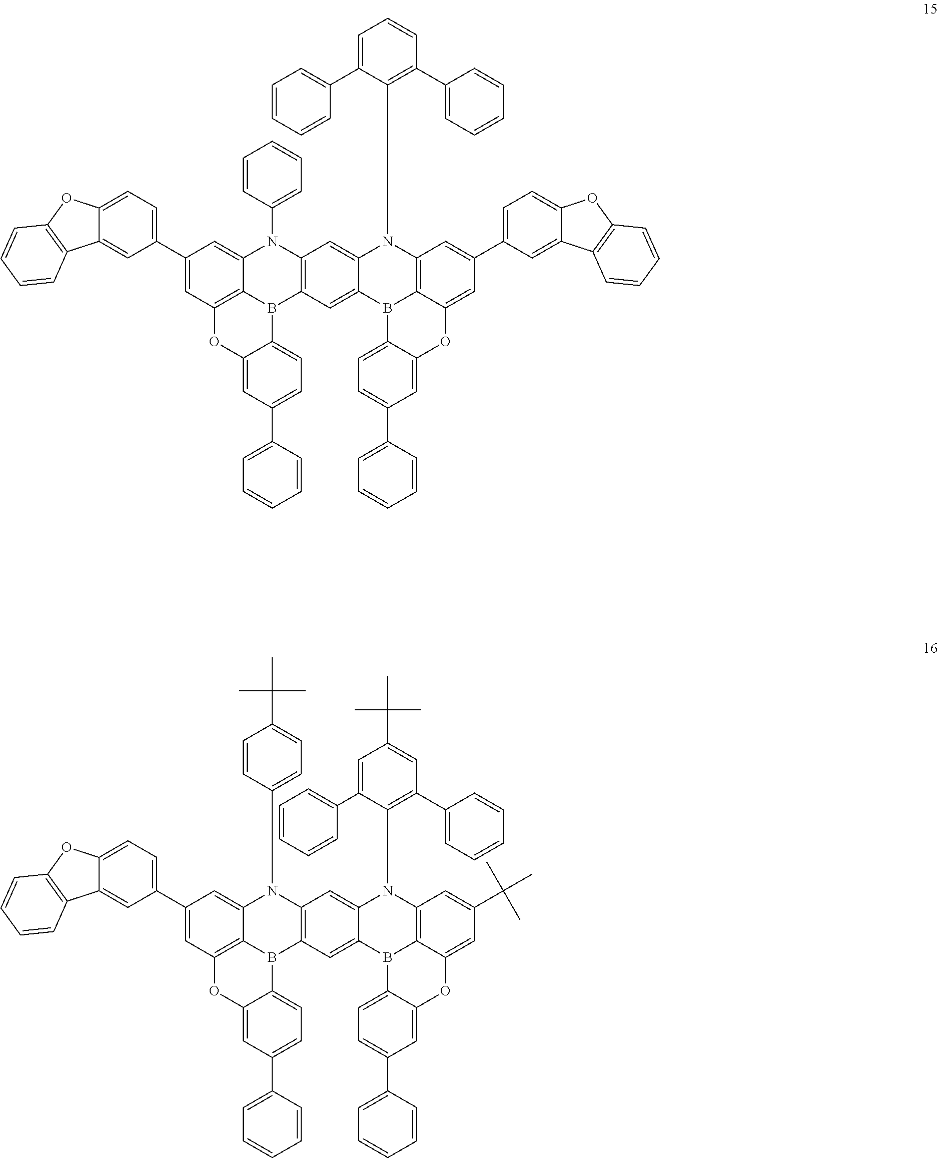 [SMILES: c1ccc(-c2ccc3c(c2)Oc2cc(-c4ccc5oc6ccccc6c5c4)cc4c2B3c2cc3c(cc2N4c2ccccc2)N(c2c(-c4ccccc4)cccc2-c2ccccc2)c2cc(-c4ccc5oc6ccccc6c5c4)cc4c2B3c2ccc(-c3ccccc3)cc2O4)cc1 ; CC(C)(C)c1ccc(N2c3cc4c(cc3B3c5ccc(-c6ccccc6)cc5Oc5cc(-c6ccc7oc8ccccc8c7c6)cc2c53)B2c3ccc(-c5ccccc5)cc3Oc3cc(C(C)(C)C)cc(c32)N4c2c(-c3ccccc3)cc(C(C)(C)C)cc2-c2ccccc2)cc1]

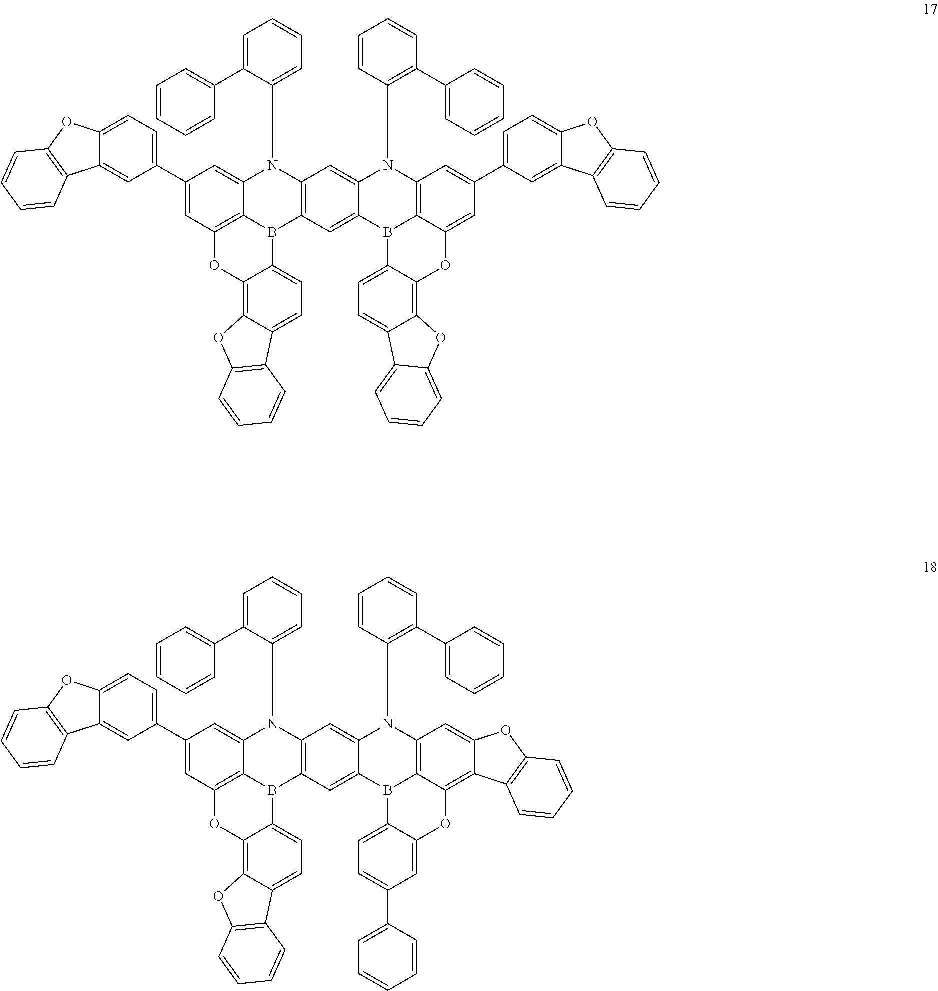 [SMILES: c1ccc(-c2ccccc2N2c3cc4c(cc3B3c5ccc6c(oc7ccccc76)c5Oc5cc(-c6ccc7oc8ccccc8c7c6)cc2c53)B2c3ccc5c(oc6ccccc65)c3Oc3cc(-c5ccc6oc7ccccc7c6c5)cc(c32)N4c2ccccc2-c2ccccc2)cc1 ; c1ccc(-c2ccc3c(c2)Oc2c4c(cc5oc6ccccc6c25)N(c2ccccc2-c2ccccc2)c2cc5c(cc2B34)B2c3ccc4c(oc6ccccc64)c3Oc3cc(-c4ccc6oc7ccccc7c6c4)cc(c32)N5c2ccccc2-c2ccccc2)cc1]

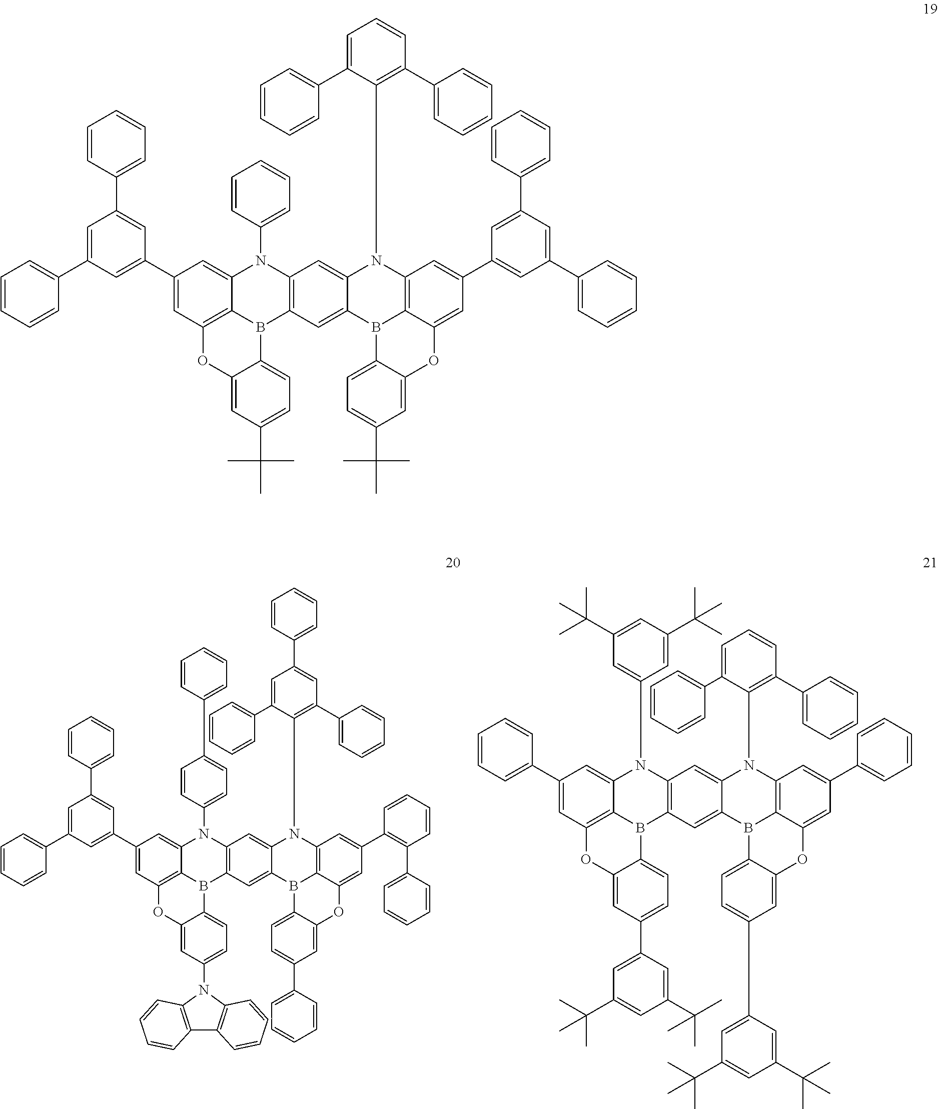

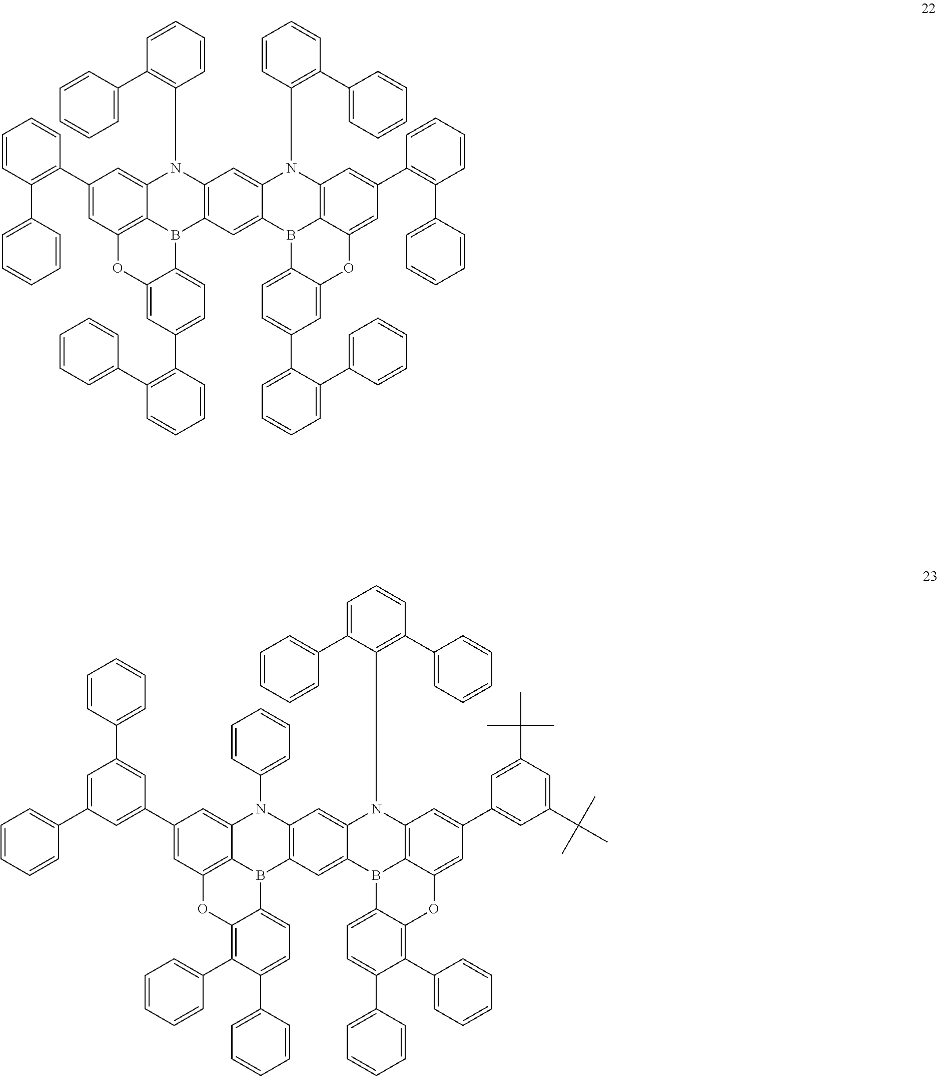 [SMILES: c1ccc(-c2ccccc2-c2ccc3c(c2)Oc2cc(-c4ccccc4-c4ccccc4)cc4c2B3c2cc3c(cc2N4c2ccccc2-c2ccccc2)N(c2ccccc2-c2ccccc2)c2cc(-c4ccccc4-c4ccccc4)cc4c2B3c2ccc(-c3ccccc3-c3ccccc3)cc2O4)cc1 ; CC(C)(C)c1cc(-c2cc3c4c(c2)N(c2c(-c5ccccc5)cccc2-c2ccccc2)c2cc5c(cc2B4c2ccc(-c4ccccc4)c(-c4ccccc4)c2O3)B2c3ccc(-c4ccccc4)c(-c4ccccc4)c3Oc3cc(-c4cc(-c6ccccc6)cc(-c6ccccc6)c4)cc(c32)N5c2ccccc2)cc(C(C)(C)C)c1]

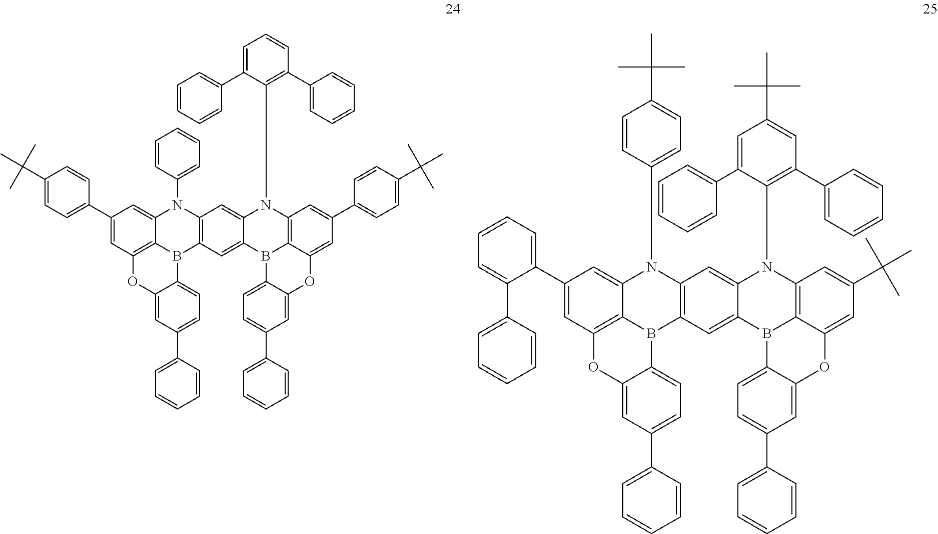 [SMILES: CC(C)(C)c1ccc(-c2cc3c4c(c2)N(c2ccccc2)c2cc5c(cc2B4c2ccc(-c4ccccc4)cc2O3)B2c3ccc(-c4ccccc4)cc3Oc3cc(-c4ccc(C(C)(C)C)cc4)cc(c32)N5c2c(-c3ccccc3)cccc2-c2ccccc2)cc1 ; CC(C)(C)c1ccc(N2c3cc4c(cc3B3c5ccc(-c6ccccc6)cc5Oc5cc(-c6ccccc6-c6ccccc6)cc2c53)B2c3ccc(-c5ccccc5)cc3Oc3cc(C(C)(C)C)cc(c32)N4c2c(-c3ccccc3)cc(C(C)(C)C)cc2-c2ccccc2)cc1]

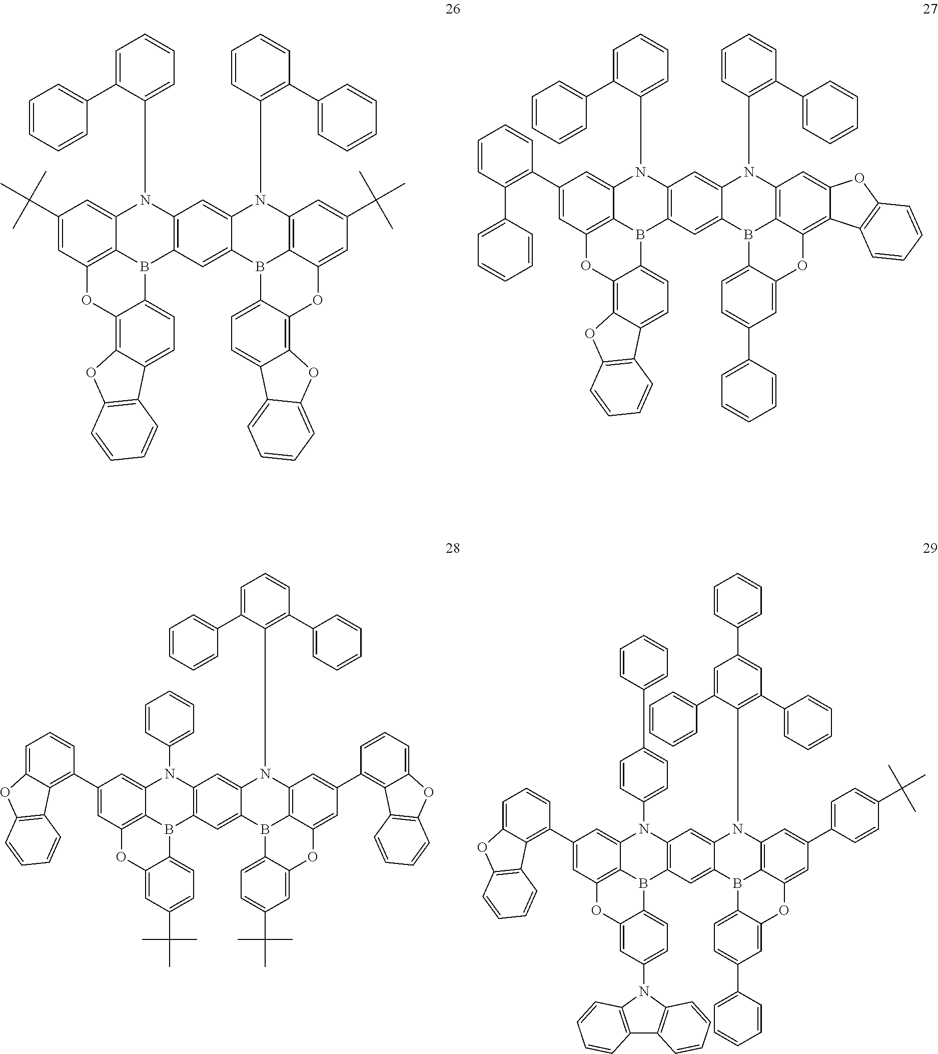

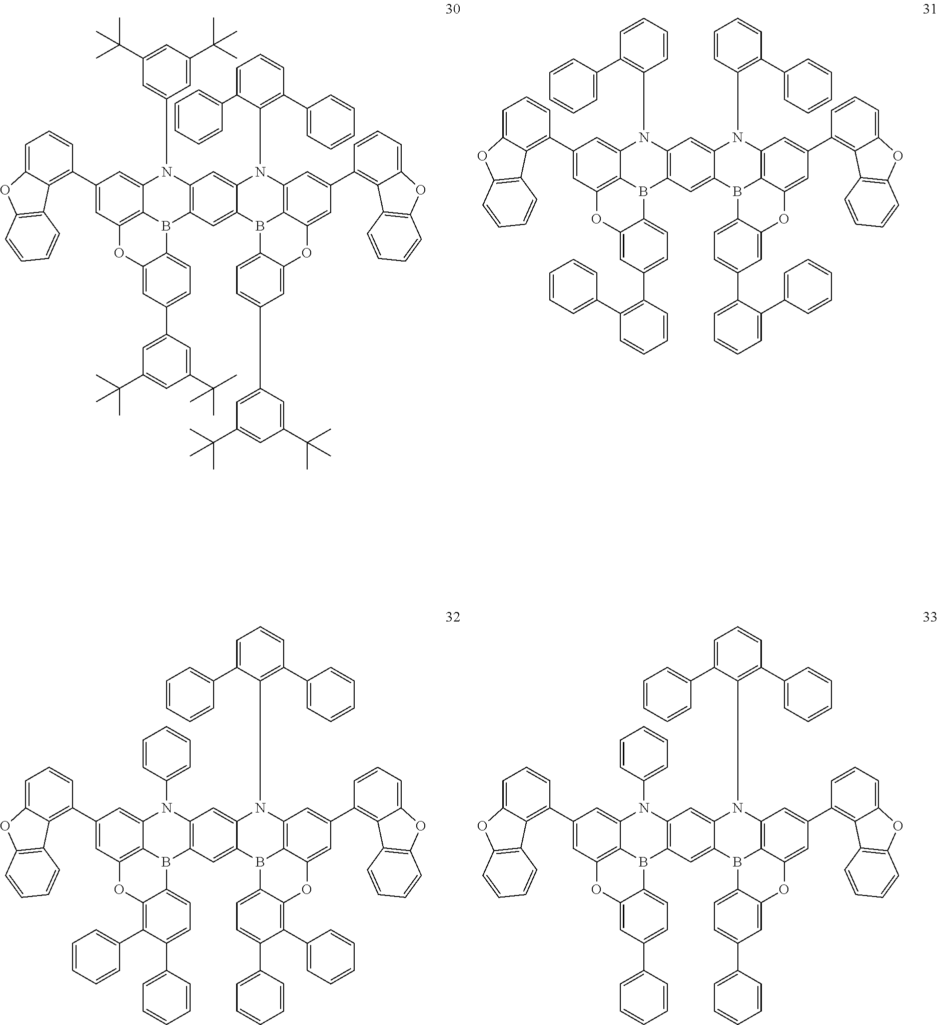

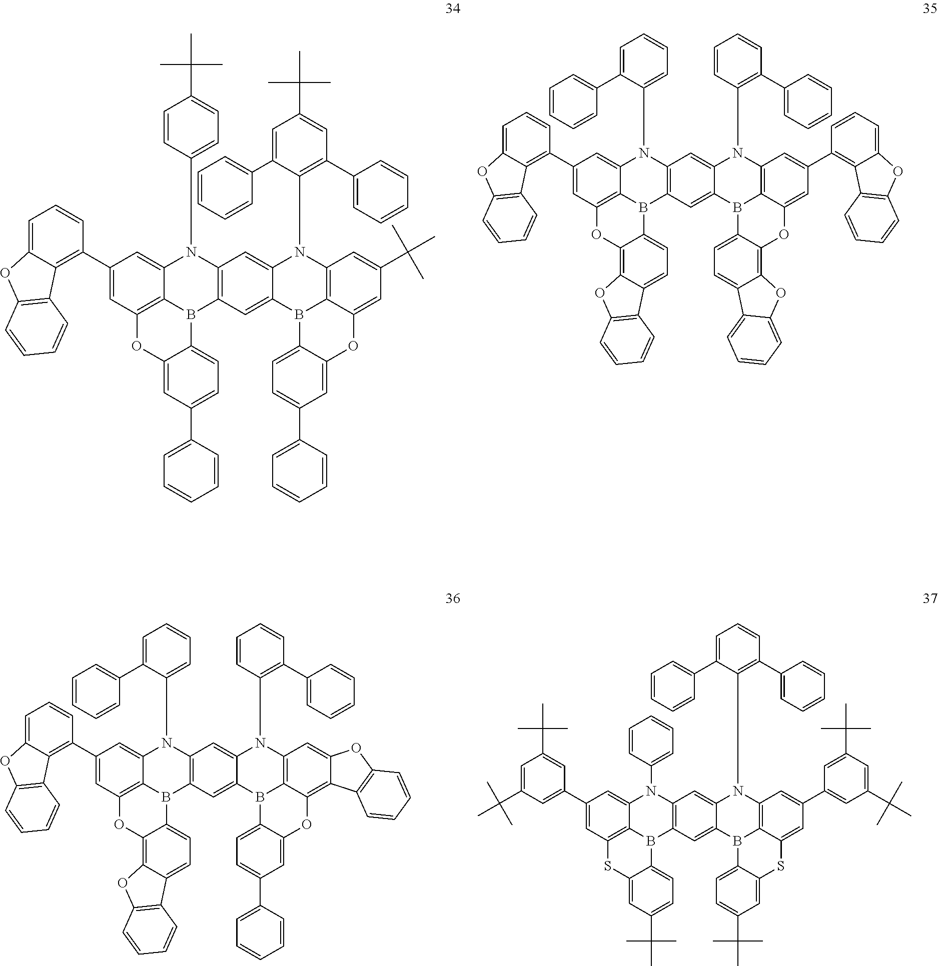

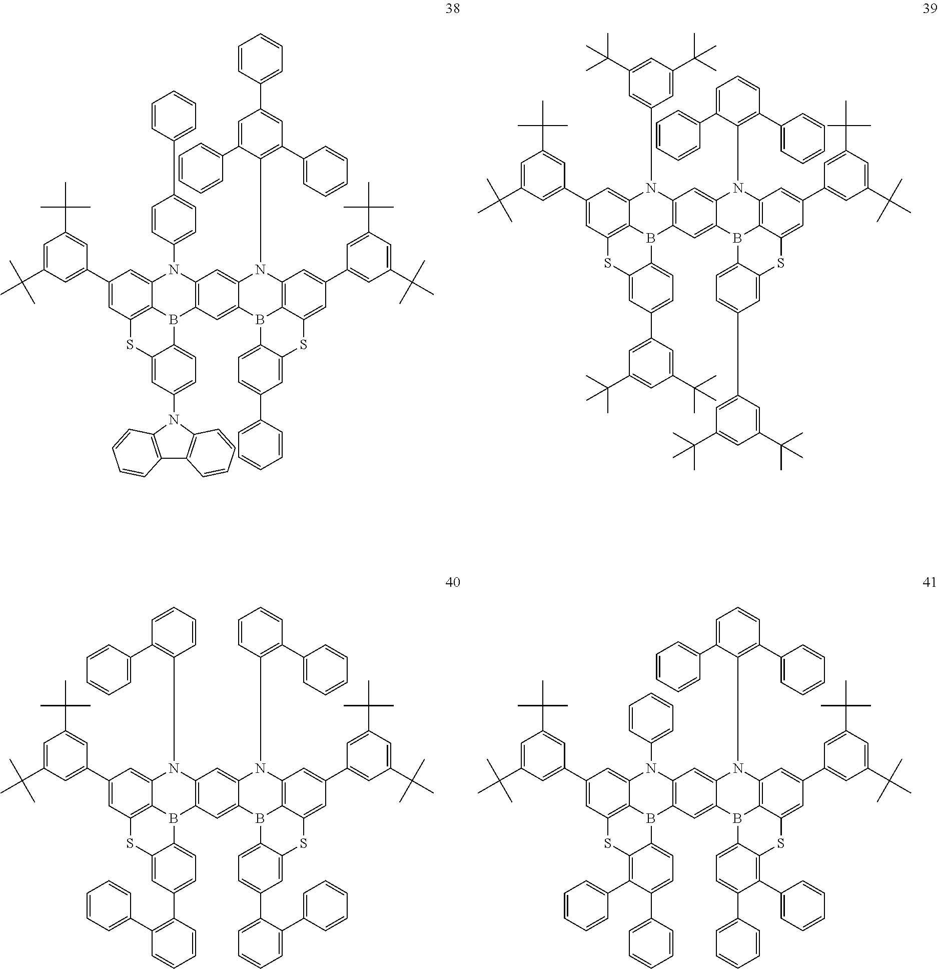

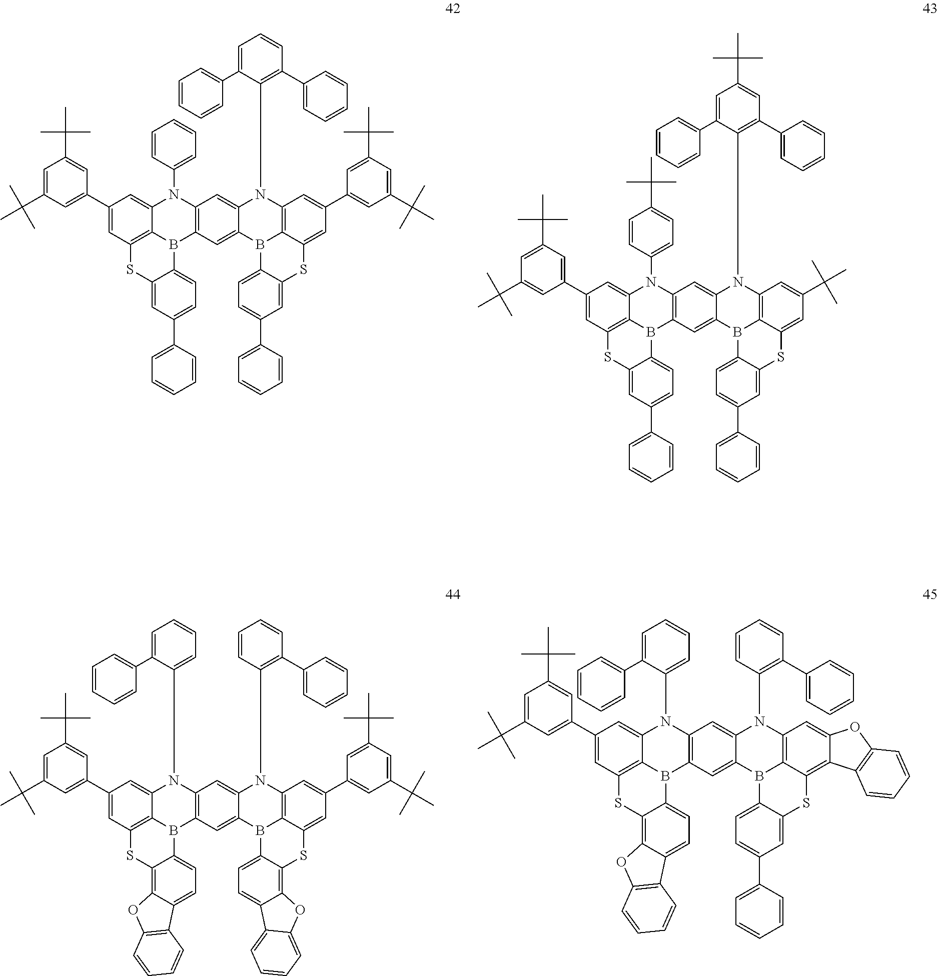

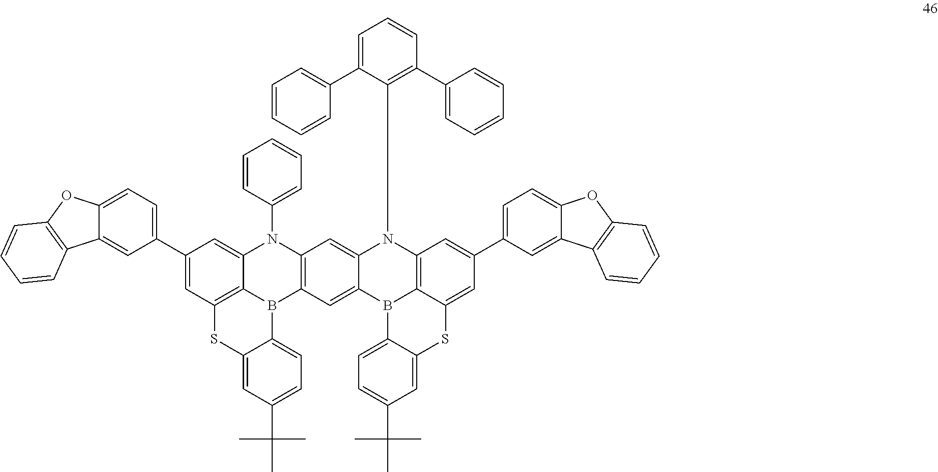 [SMILES: CC(C)(C)c1ccc2c(c1)Sc1cc(-c3ccc4oc5ccccc5c4c3)cc3c1B2c1cc2c(cc1N3c1ccccc1)N(c1c(-c3ccccc3)cccc1-c1ccccc1)c1cc(-c3ccc4oc5ccccc5c4c3)cc3c1B2c1ccc(C(C)(C)C)cc1S3]

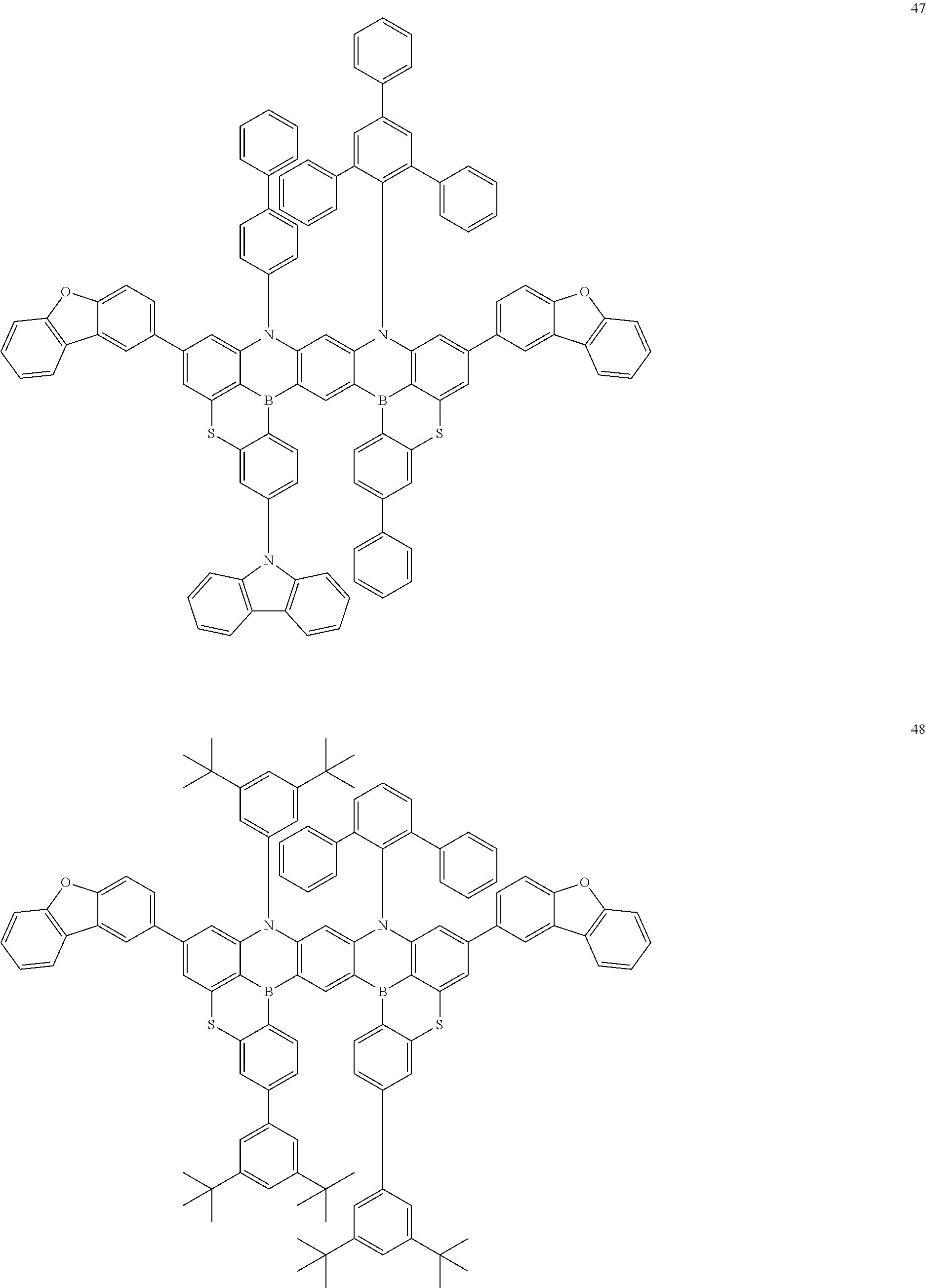 [SMILES: c1ccc(-c2ccc(N3c4cc5c(cc4B4c6ccc(-n7c8ccccc8c8ccccc87)cc6Sc6cc(-c7ccc8oc9ccccc9c8c7)cc3c64)B3c4ccc(-c6ccccc6)cc4Sc4cc(-c6ccc7oc8ccccc8c7c6)cc(c43)N5c3c(-c4ccccc4)cc(-c4ccccc4)cc3-c3ccccc3)cc2)cc1 ; CC(C)(C)c1cc(-c2ccc3c(c2)Sc2cc(-c4ccc5oc6ccccc6c5c4)cc4c2B3c2cc3c(cc2N4c2cc(C(C)(C)C)cc(C(C)(C)C)c2)N(c2c(-c4ccccc4)cccc2-c2ccccc2)c2cc(-c4ccc5oc6ccccc6c5c4)cc4c2B3c2ccc(-c3cc(C(C)(C)C)cc(C(C)(C)C)c3)cc2S4)cc(C(C)(C)C)c1]

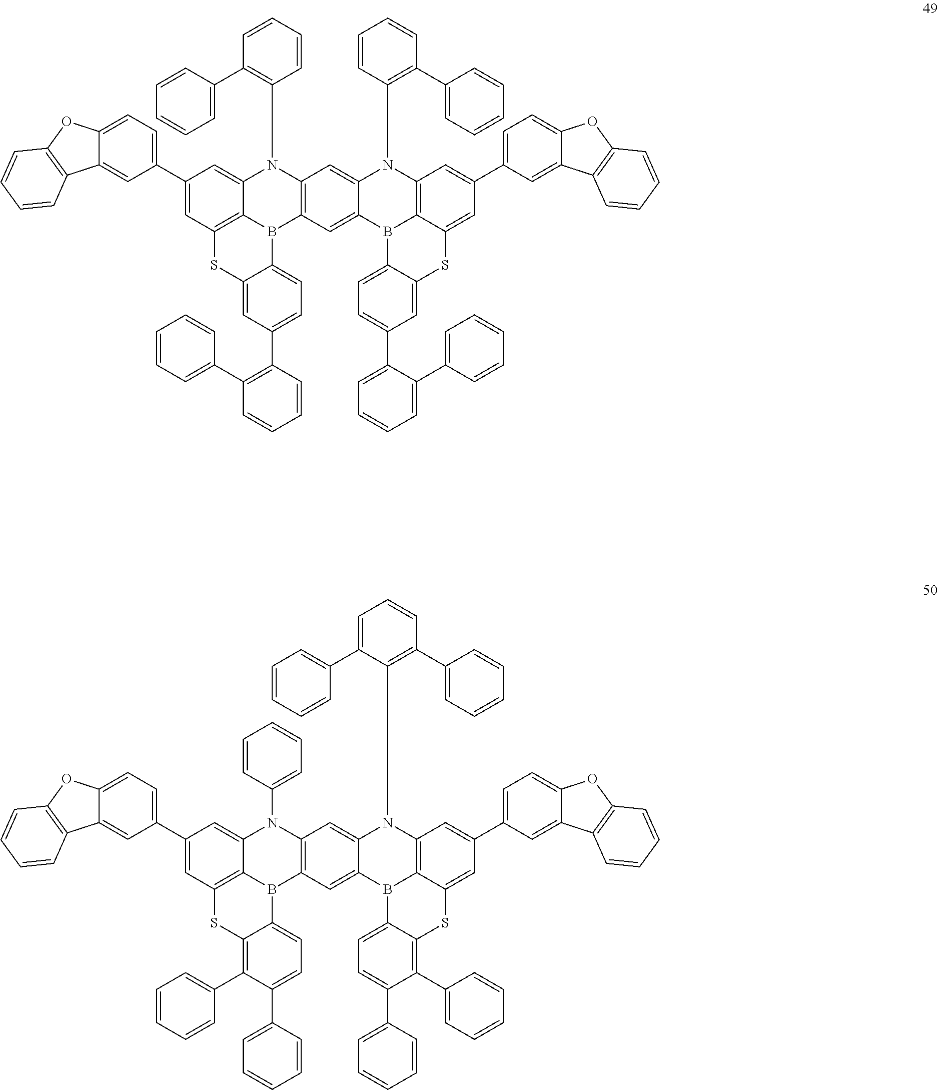 [SMILES: c1ccc(-c2ccccc2-c2ccc3c(c2)Sc2cc(-c4ccc5oc6ccccc6c5c4)cc4c2B3c2cc3c(cc2N4c2ccccc2-c2ccccc2)N(c2ccccc2-c2ccccc2)c2cc(-c4ccc5oc6ccccc6c5c4)cc4c2B3c2ccc(-c3ccccc3-c3ccccc3)cc2S4)cc1 ; c1ccc(-c2ccc3c(c2-c2ccccc2)Sc2cc(-c4ccc5oc6ccccc6c5c4)cc4c2B3c2cc3c(cc2N4c2ccccc2)N(c2c(-c4ccccc4)cccc2-c2ccccc2)c2cc(-c4ccc5oc6ccccc6c5c4)cc4c2B3c2ccc(-c3ccccc3)c(-c3ccccc3)c2S4)cc1]

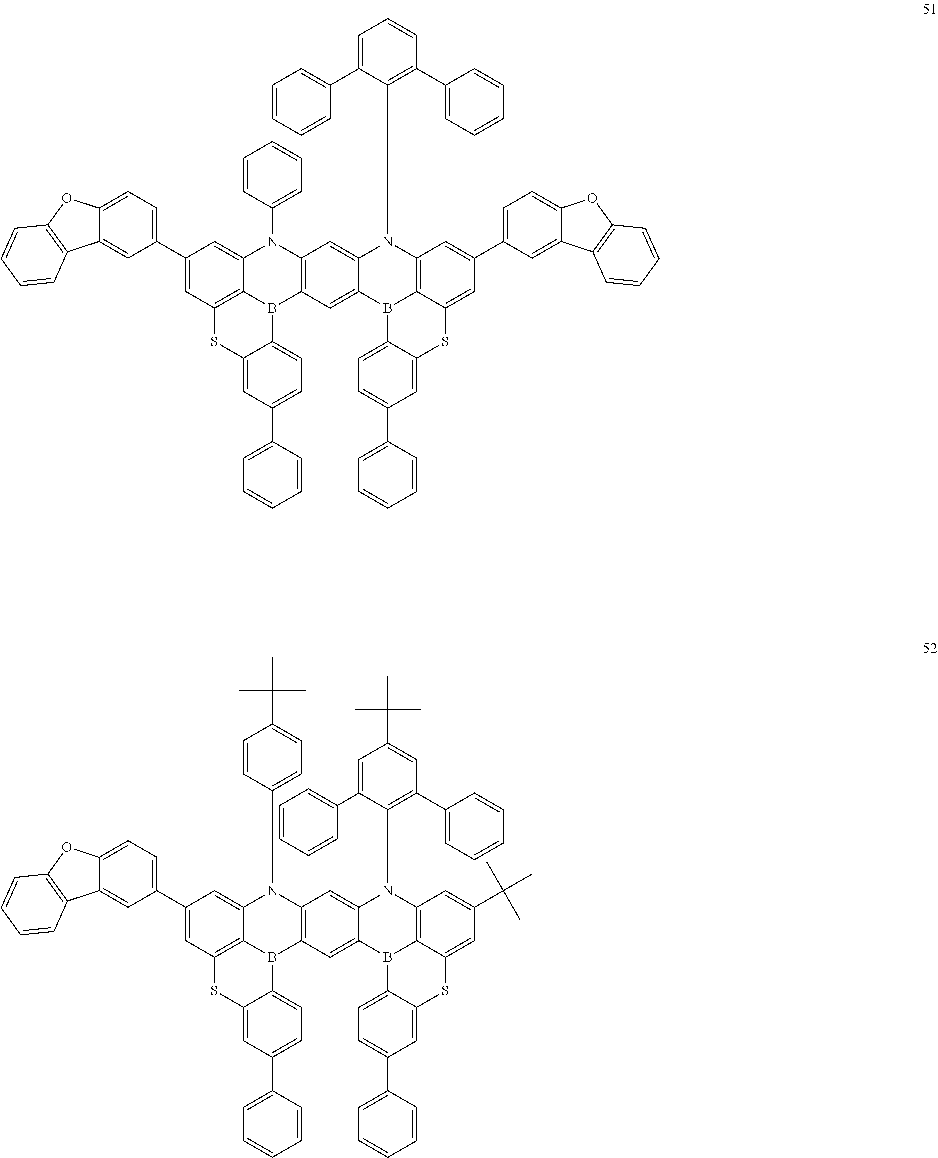 [SMILES: c1ccc(-c2ccc3c(c2)Sc2cc(-c4ccc5oc6ccccc6c5c4)cc4c2B3c2cc3c(cc2N4c2ccccc2)N(c2c(-c4ccccc4)cccc2-c2ccccc2)c2cc(-c4ccc5oc6ccccc6c5c4)cc4c2B3c2ccc(-c3ccccc3)cc2S4)cc1 ; CC(C)(C)c1ccc(N2c3cc4c(cc3B3c5ccc(-c6ccccc6)cc5Sc5cc(-c6ccc7oc8ccccc8c7c6)cc2c53)B2c3ccc(-c5ccccc5)cc3Sc3cc(C(C)(C)C)cc(c32)N4c2c(-c3ccccc3)cc(C(C)(C)C)cc2-c2ccccc2)cc1]

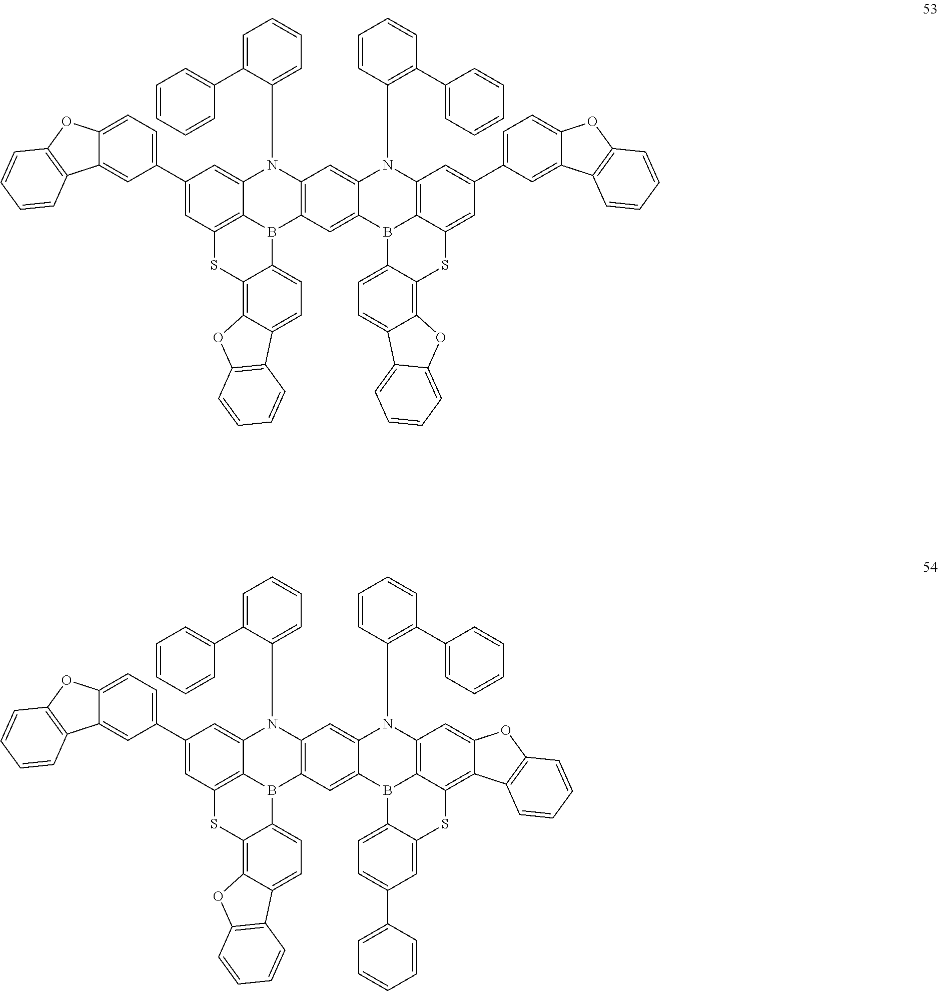 [SMILES: c1ccc(-c2ccccc2N2c3cc4c(cc3B3c5ccc6c(oc7ccccc76)c5Sc5cc(-c6ccc7oc8ccccc8c7c6)cc2c53)B2c3ccc5c(oc6ccccc65)c3Sc3cc(-c5ccc6oc7ccccc7c6c5)cc(c32)N4c2ccccc2-c2ccccc2)cc1 ; c1ccc(-c2ccc3c(c2)Sc2c4c(cc5oc6ccccc6c25)N(c2ccccc2-c2ccccc2)c2cc5c(cc2B34)B2c3ccc4c(oc6ccccc64)c3Sc3cc(-c4ccc6oc7ccccc7c6c4)cc(c32)N5c2ccccc2-c2ccccc2)cc1]

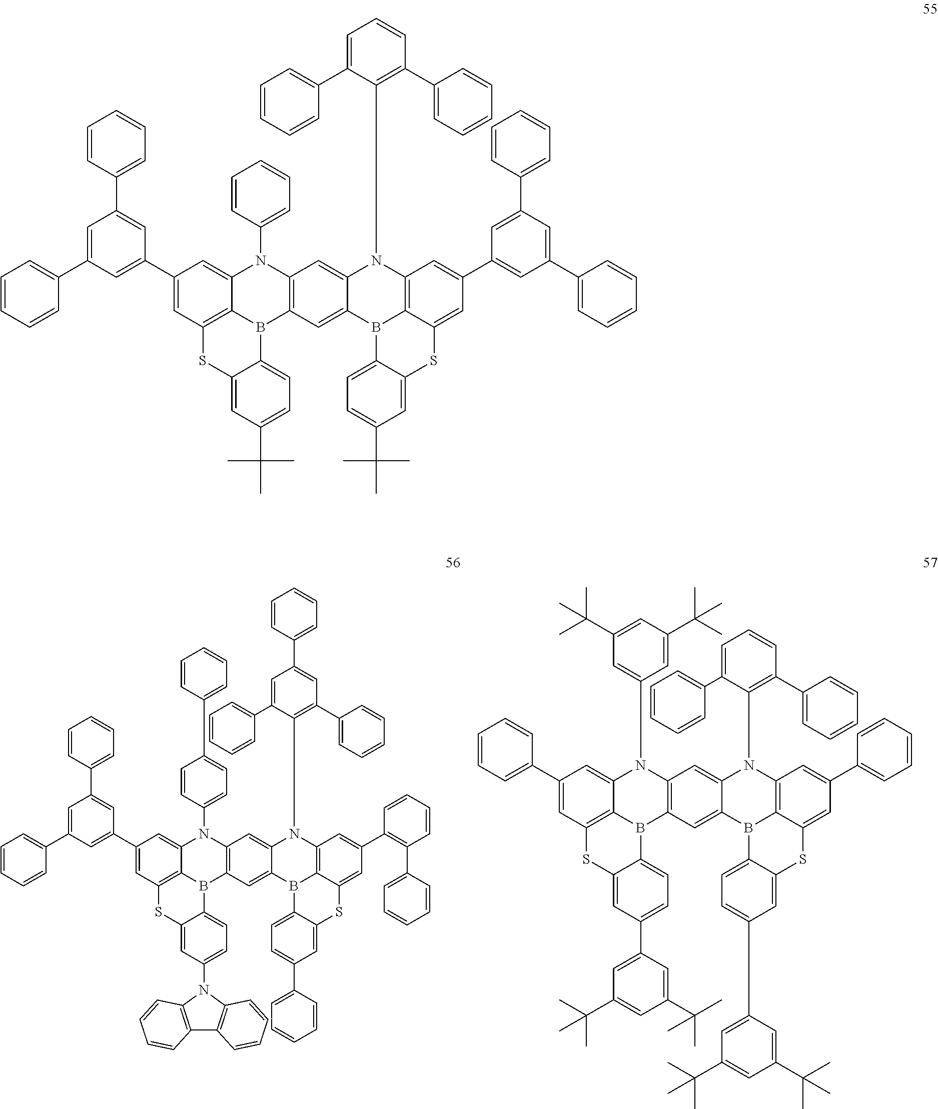

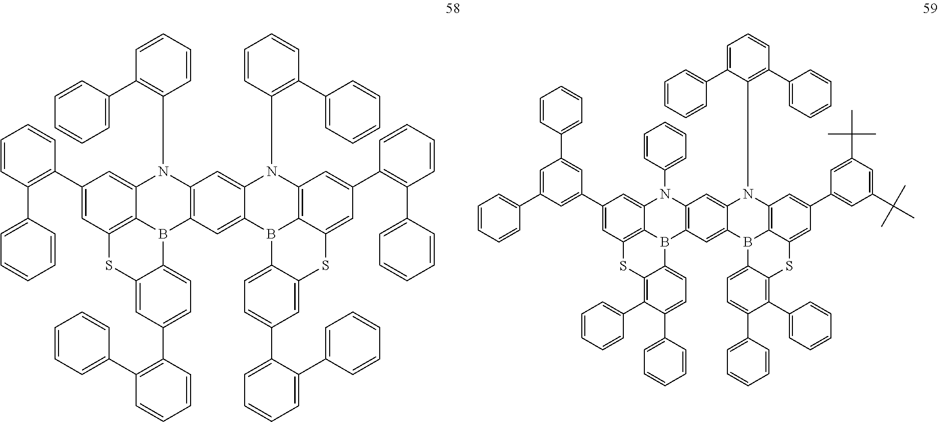 [SMILES: c1ccc(-c2ccccc2-c2ccc3c(c2)Sc2cc(-c4ccccc4-c4ccccc4)cc4c2B3c2cc3c(cc2N4c2ccccc2-c2ccccc2)N(c2ccccc2-c2ccccc2)c2cc(-c4ccccc4-c4ccccc4)cc4c2B3c2ccc(-c3ccccc3-c3ccccc3)cc2S4)cc1 ; CC(C)(C)c1cc(-c2cc3c4c(c2)N(c2c(-c5ccccc5)cccc2-c2ccccc2)c2cc5c(cc2B4c2ccc(-c4ccccc4)c(-c4ccccc4)c2S3)B2c3ccc(-c4ccccc4)c(-c4ccccc4)c3Sc3cc(-c4cc(-c6ccccc6)cc(-c6ccccc6)c4)cc(c32)N5c2ccccc2)cc(C(C)(C)C)c1]

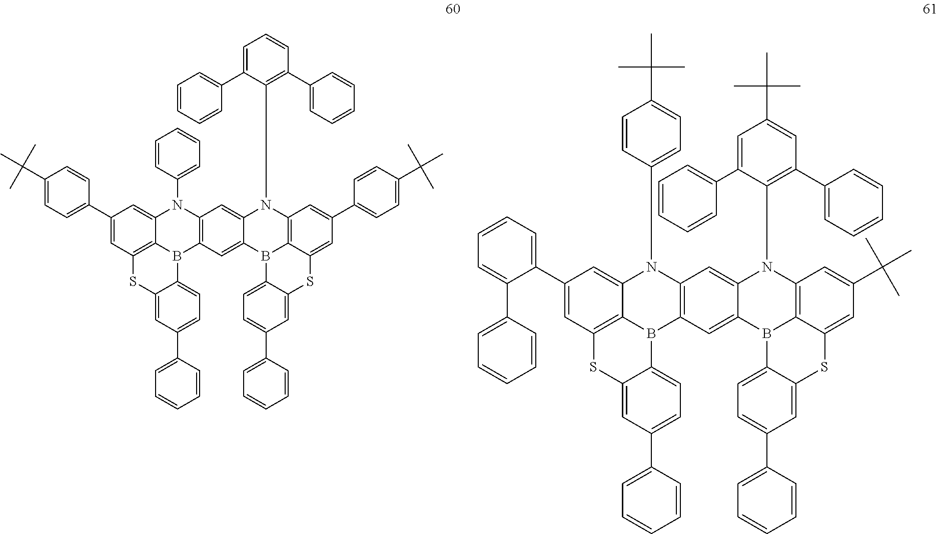 [SMILES: CC(C)(C)c1ccc(-c2cc3c4c(c2)N(c2ccccc2)c2cc5c(cc2B4c2ccc(-c4ccccc4)cc2S3)B2c3ccc(-c4ccccc4)cc3Sc3cc(-c4ccc(C(C)(C)C)cc4)cc(c32)N5c2c(-c3ccccc3)cccc2-c2ccccc2)cc1 ; CC(C)(C)c1ccc(N2c3cc4c(cc3B3c5ccc(-c6ccccc6)cc5Sc5cc(-c6ccccc6-c6ccccc6)cc2c53)B2c3ccc(-c5ccccc5)cc3Sc3cc(C(C)(C)C)cc(c32)N4c2c(-c3ccccc3)cc(C(C)(C)C)cc2-c2ccccc2)cc1]

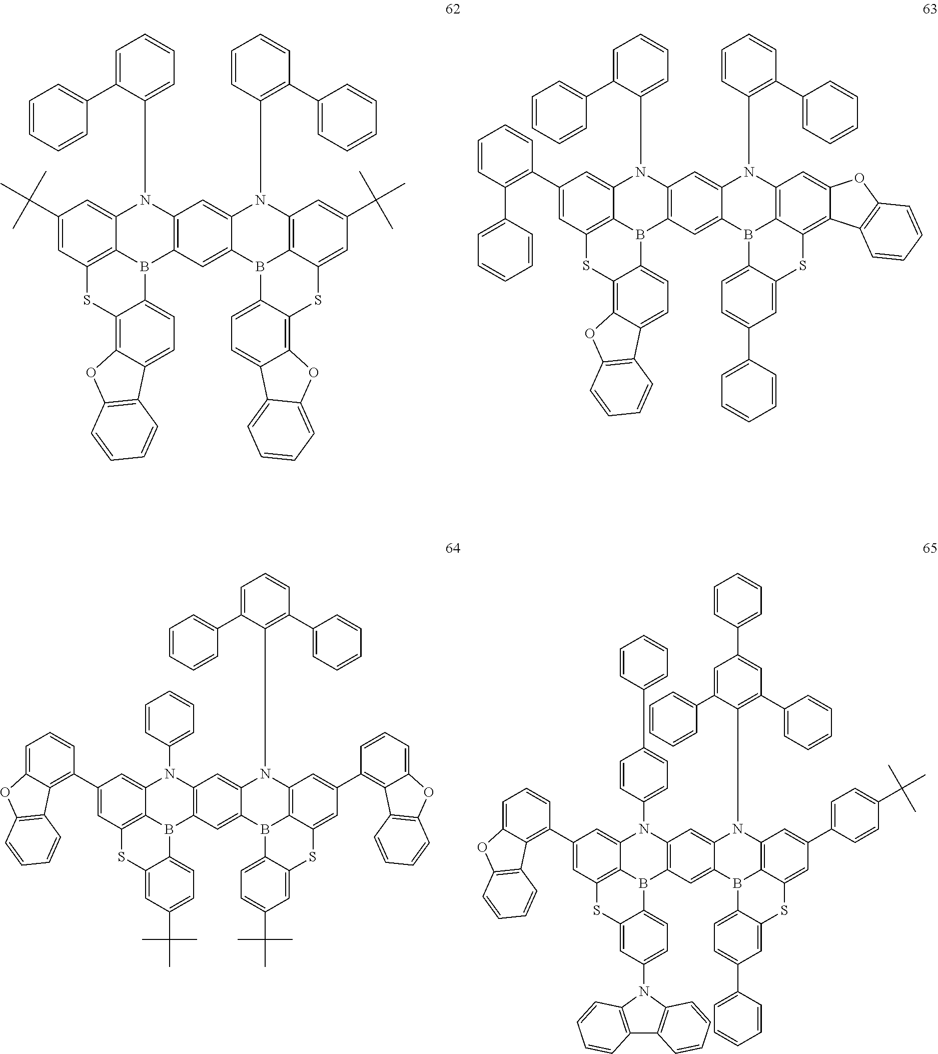

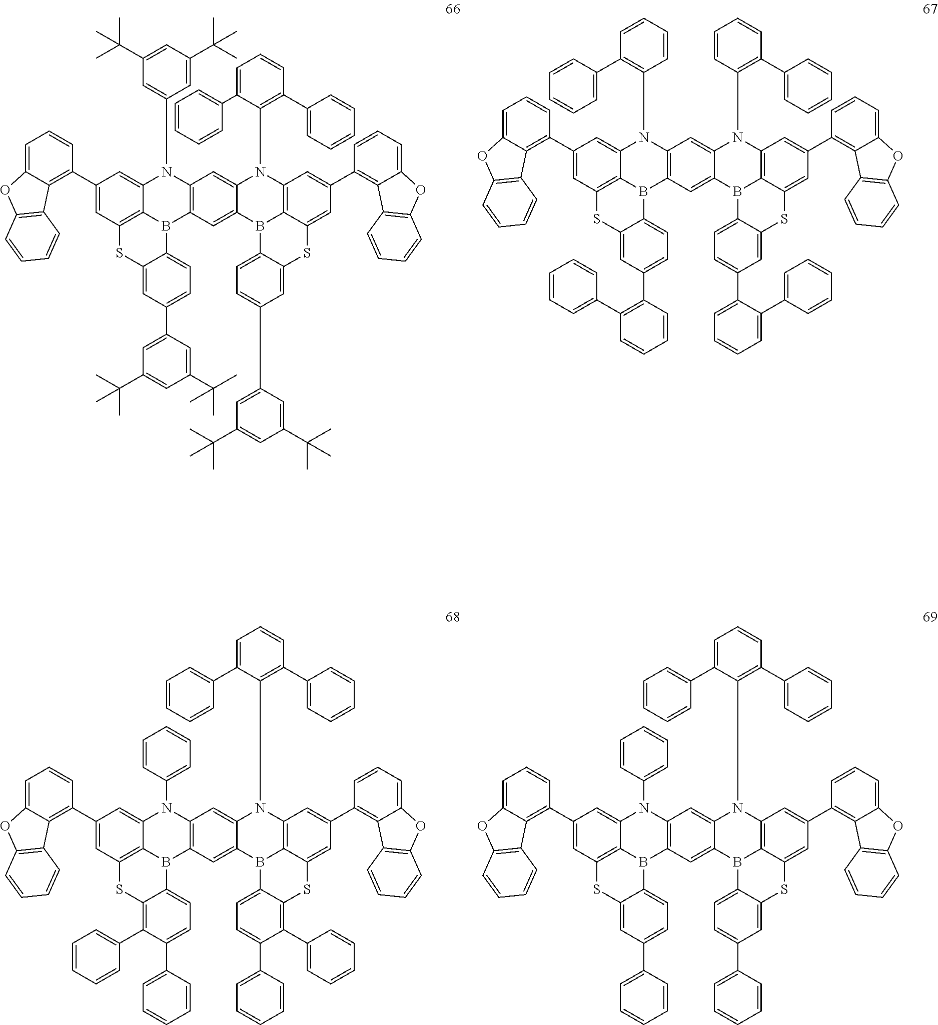

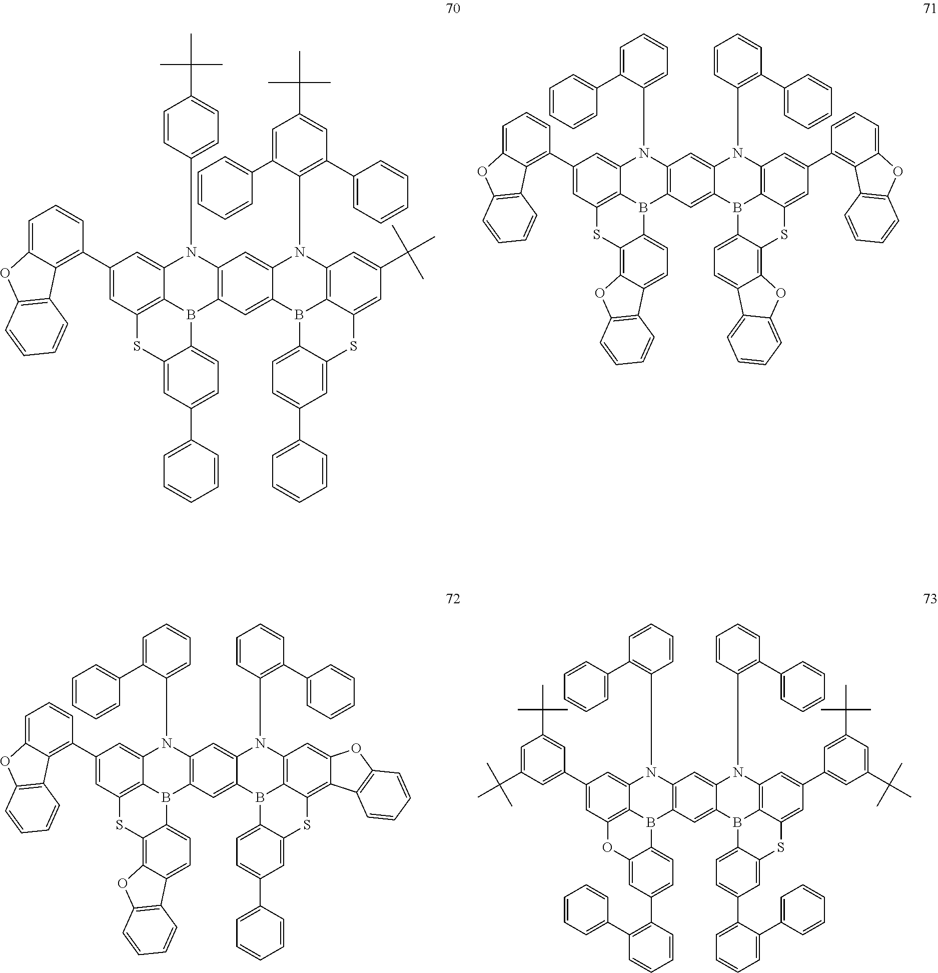

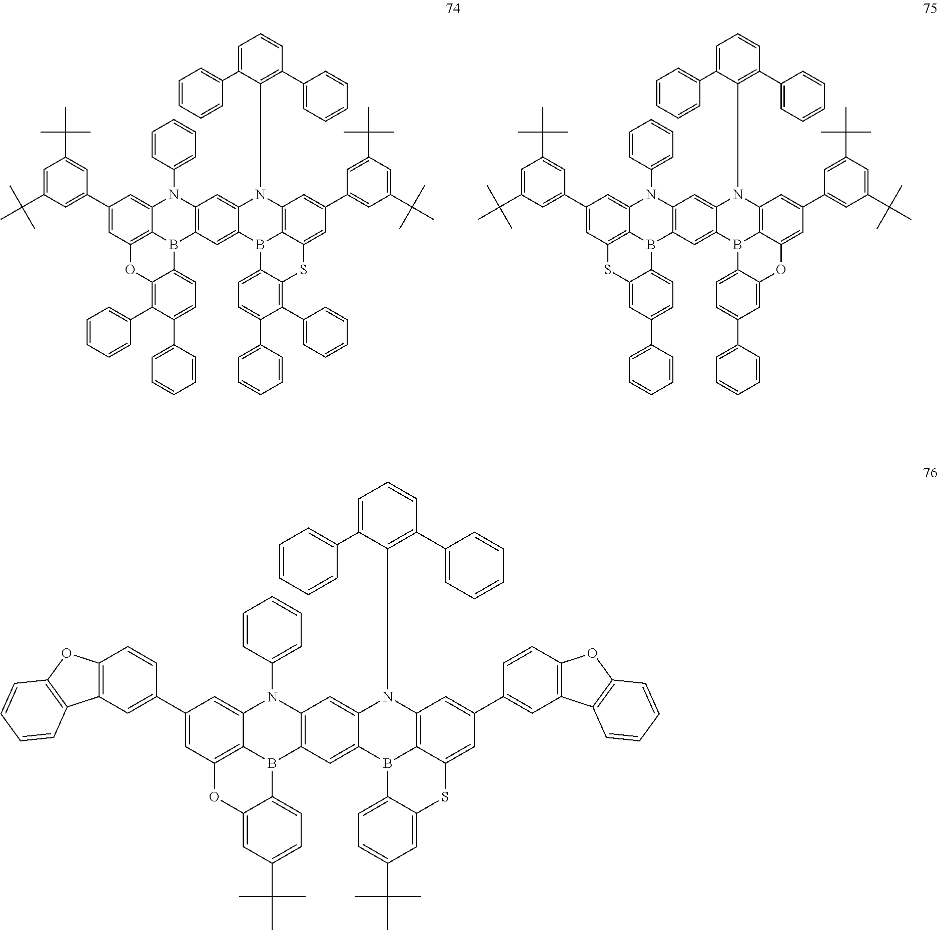

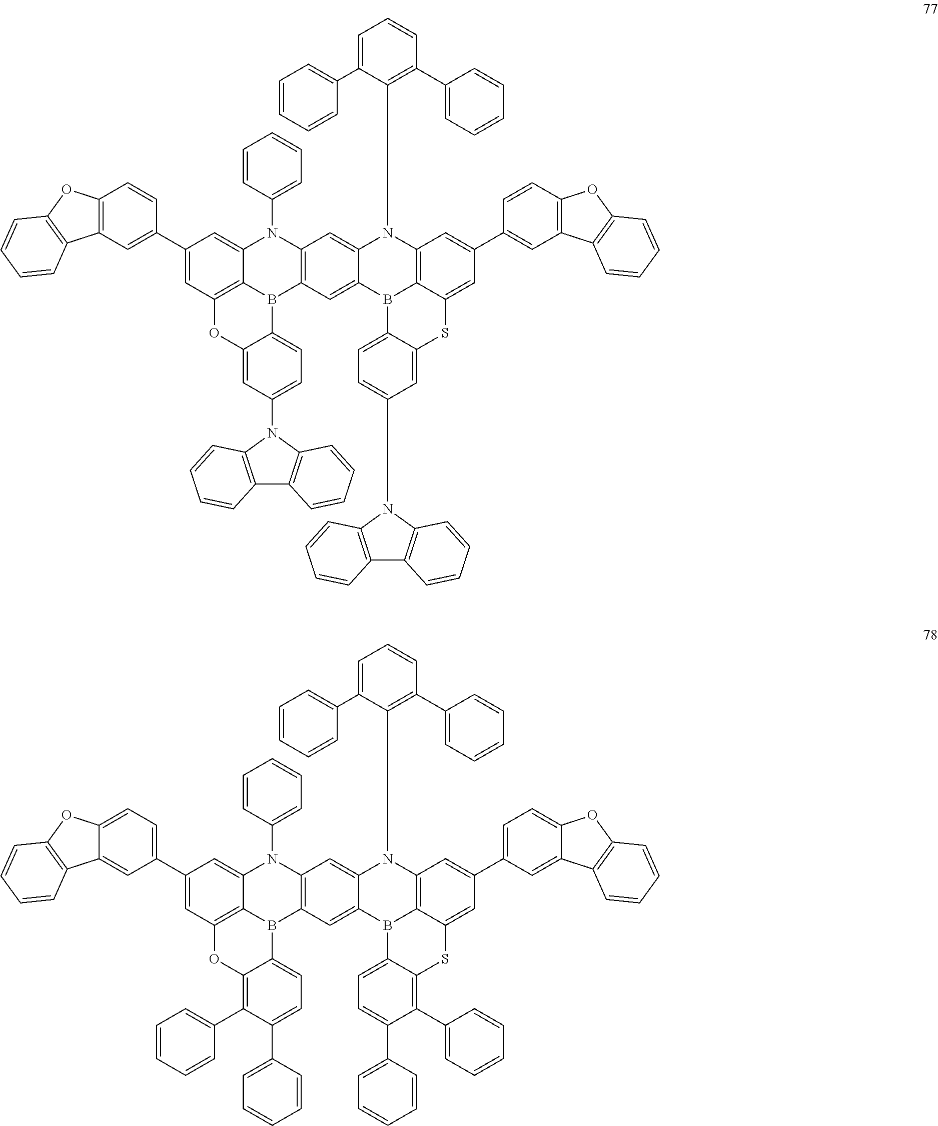 [SMILES: c1ccc(-c2cccc(-c3ccccc3)c2N2c3cc4c(cc3B3c5ccc(-n6c7ccccc7c7ccccc76)cc5Sc5cc(-c6ccc7oc8ccccc8c7c6)cc2c53)B2c3ccc(-n5c6ccccc6c6ccccc65)cc3Oc3cc(-c5ccc6oc7ccccc7c6c5)cc(c32)N4c2ccccc2)cc1 ; c1ccc(-c2ccc3c(c2-c2ccccc2)Oc2cc(-c4ccc5oc6ccccc6c5c4)cc4c2B3c2cc3c(cc2N4c2ccccc2)N(c2c(-c4ccccc4)cccc2-c2ccccc2)c2cc(-c4ccc5oc6ccccc6c5c4)cc4c2B3c2ccc(-c3ccccc3)c(-c3ccccc3)c2S4)cc1]

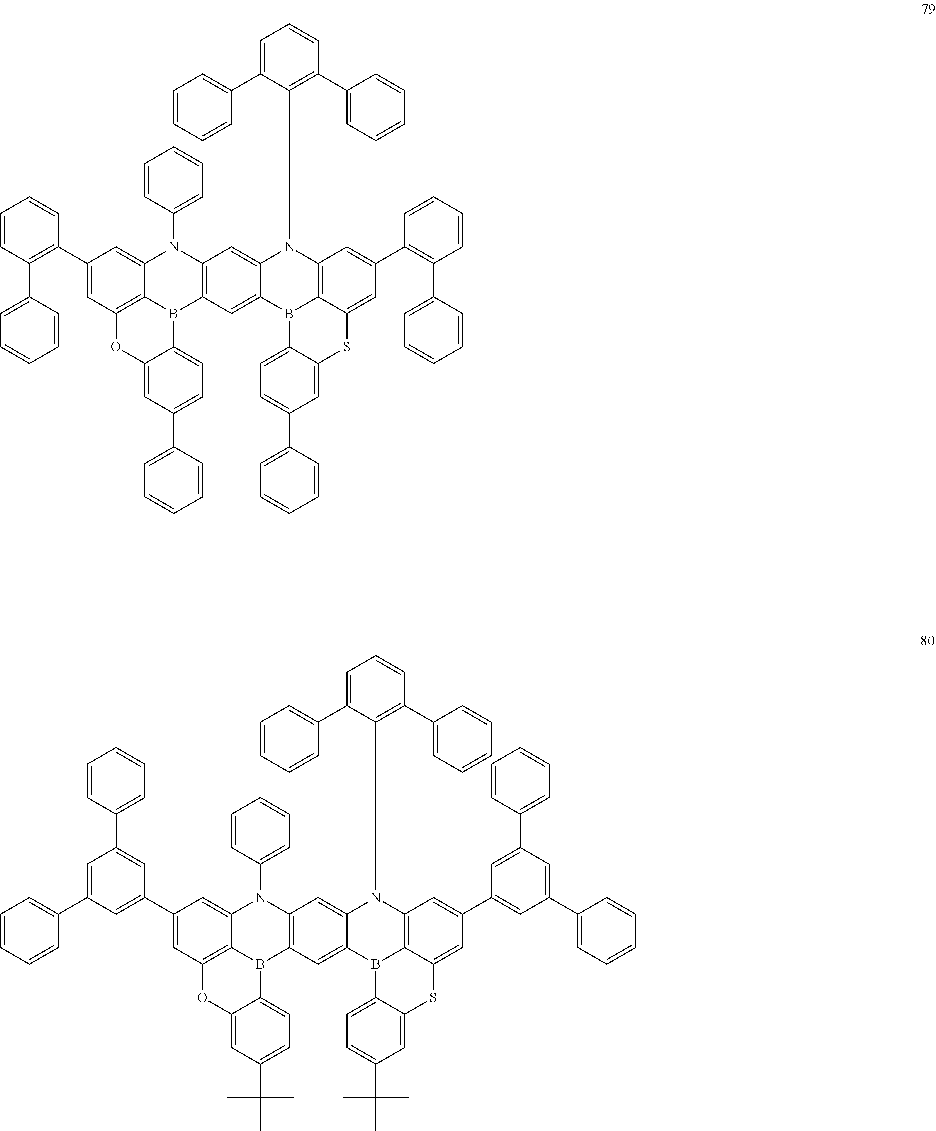 [SMILES: c1ccc(-c2ccc3c(c2)Oc2cc(-c4ccccc4-c4ccccc4)cc4c2B3c2cc3c(cc2N4c2ccccc2)N(c2c(-c4ccccc4)cccc2-c2ccccc2)c2cc(-c4ccccc4-c4ccccc4)cc4c2B3c2ccc(-c3ccccc3)cc2S4)cc1 ; CC(C)(C)c1ccc2c(c1)Oc1cc(-c3cc(-c4ccccc4)cc(-c4ccccc4)c3)cc3c1B2c1cc2c(cc1N3c1ccccc1)N(c1c(-c3ccccc3)cccc1-c1ccccc1)c1cc(-c3cc(-c4ccccc4)cc(-c4ccccc4)c3)cc3c1B2c1ccc(C(C)(C)C)cc1S3]

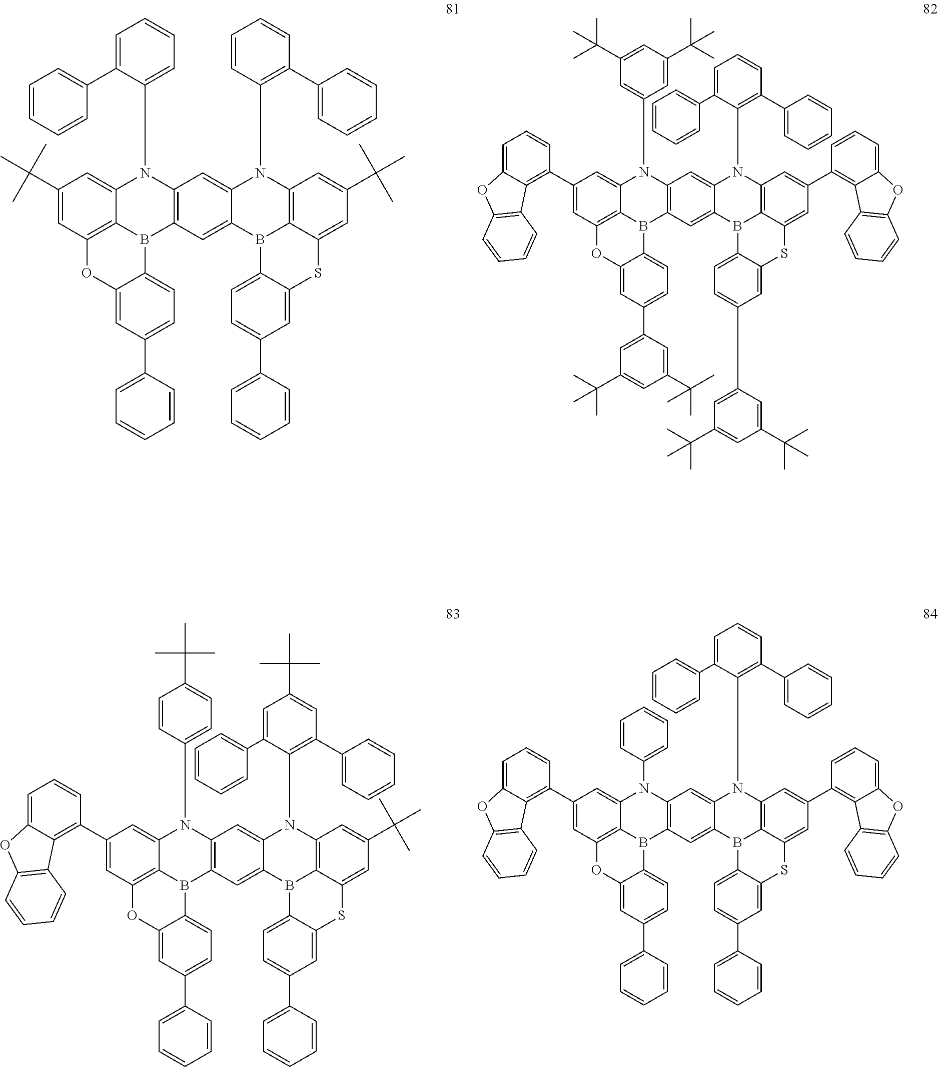

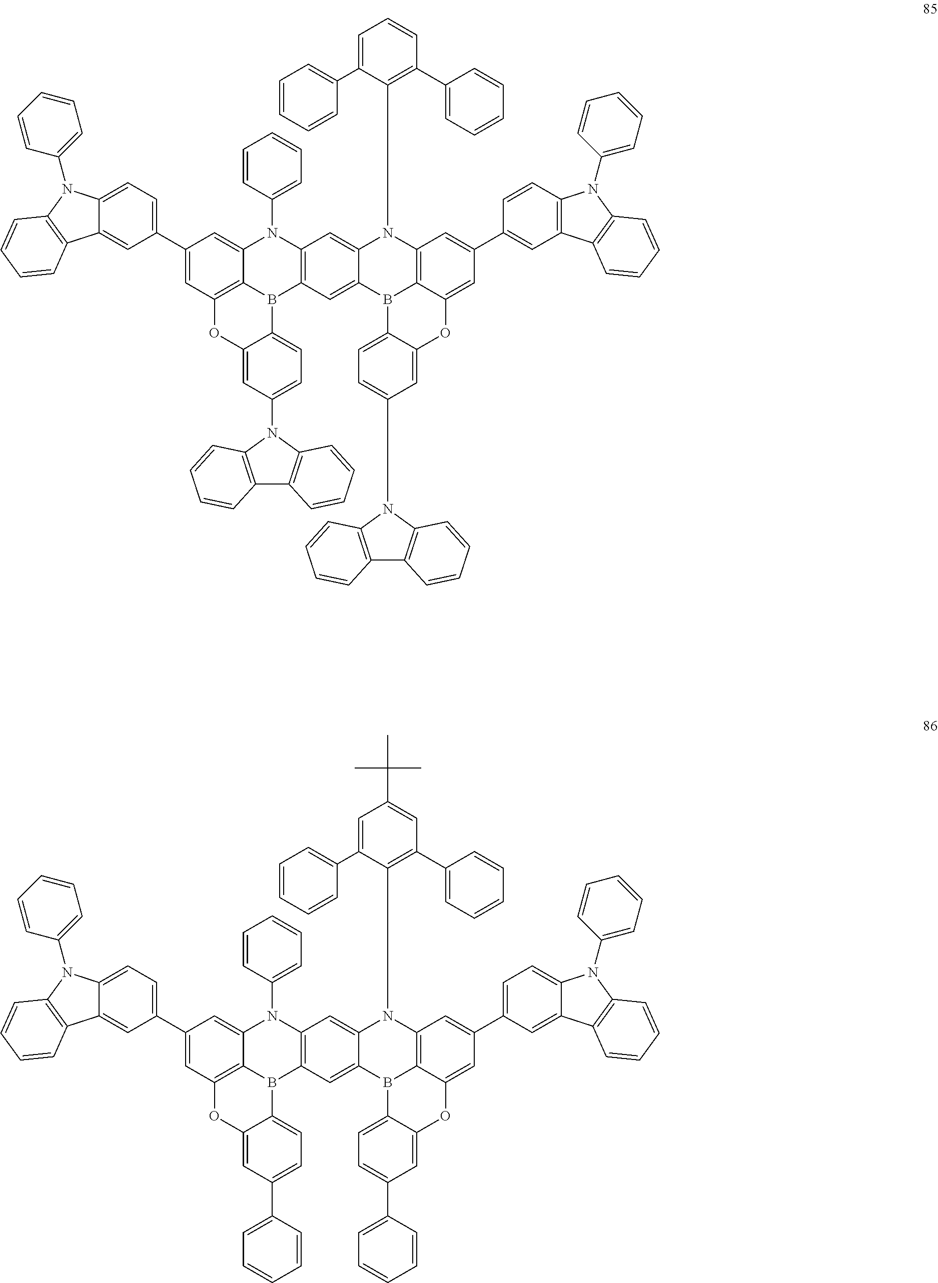 [SMILES: c1ccc(-c2cccc(-c3ccccc3)c2N2c3cc4c(cc3B3c5ccc(-n6c7ccccc7c7ccccc76)cc5Oc5cc(-c6ccc7c(c6)c6ccccc6n7-c6ccccc6)cc2c53)B2c3ccc(-n5c6ccccc6c6ccccc65)cc3Oc3cc(-c5ccc6c(c5)c5ccccc5n6-c5ccccc5)cc(c32)N4c2ccccc2)cc1 ; CC(C)(C)c1cc(-c2ccccc2)c(N2c3cc4c(cc3B3c5ccc(-c6ccccc6)cc5Oc5cc(-c6ccc7c(c6)c6ccccc6n7-c6ccccc6)cc2c53)B2c3ccc(-c5ccccc5)cc3Oc3cc(-c5ccc6c(c5)c5ccccc5n6-c5ccccc5)cc(c32)N4c2ccccc2)c(-c2ccccc2)c1]

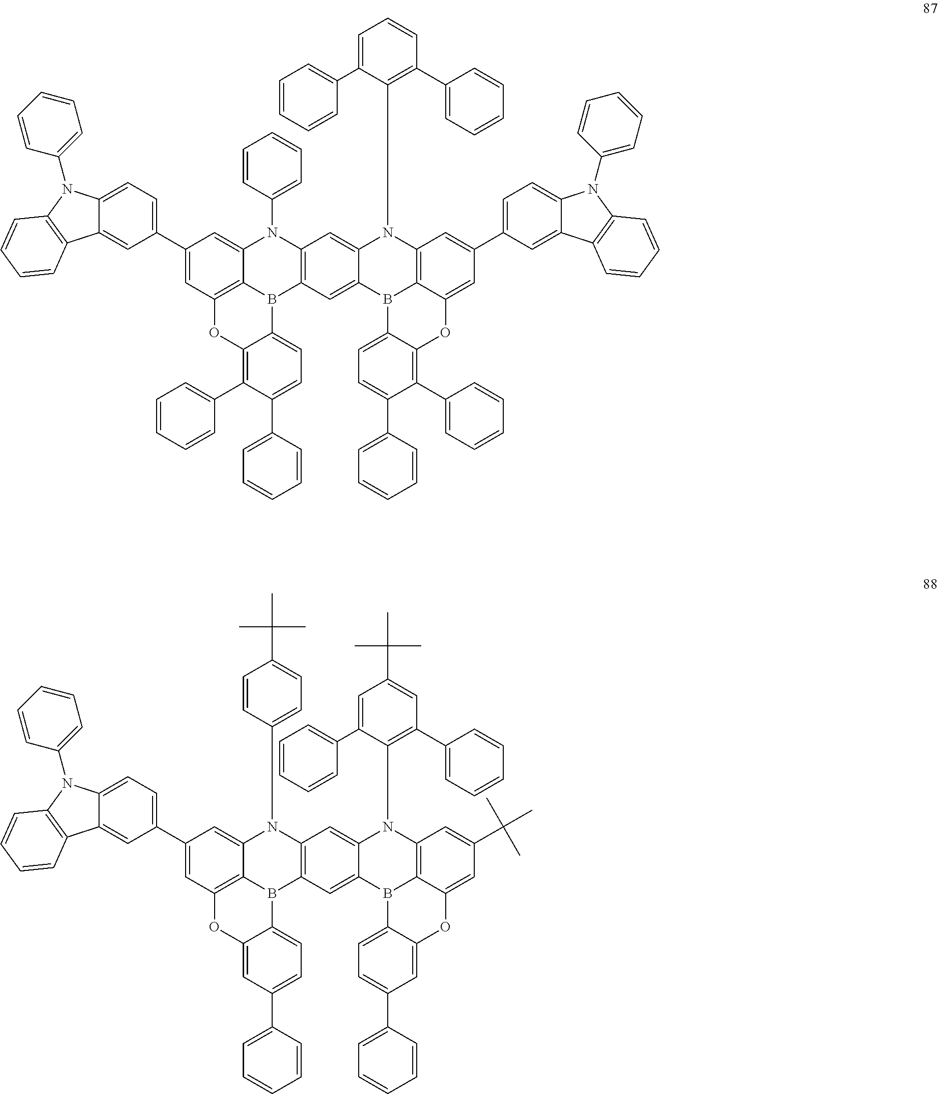 [SMILES: c1ccc(-c2ccc3c(c2-c2ccccc2)Oc2cc(-c4ccc5c(c4)c4ccccc4n5-c4ccccc4)cc4c2B3c2cc3c(cc2N4c2ccccc2)N(c2c(-c4ccccc4)cccc2-c2ccccc2)c2cc(-c4ccc5c(c4)c4ccccc4n5-c4ccccc4)cc4c2B3c2ccc(-c3ccccc3)c(-c3ccccc3)c2O4)cc1 ; CC(C)(C)c1ccc(N2c3cc4c(cc3B3c5ccc(-c6ccccc6)cc5Oc5cc(-c6ccc7c(c6)c6ccccc6n7-c6ccccc6)cc2c53)B2c3ccc(-c5ccccc5)cc3Oc3cc(C(C)(C)C)cc(c32)N4c2c(-c3ccccc3)cc(C(C)(C)C)cc2-c2ccccc2)cc1]

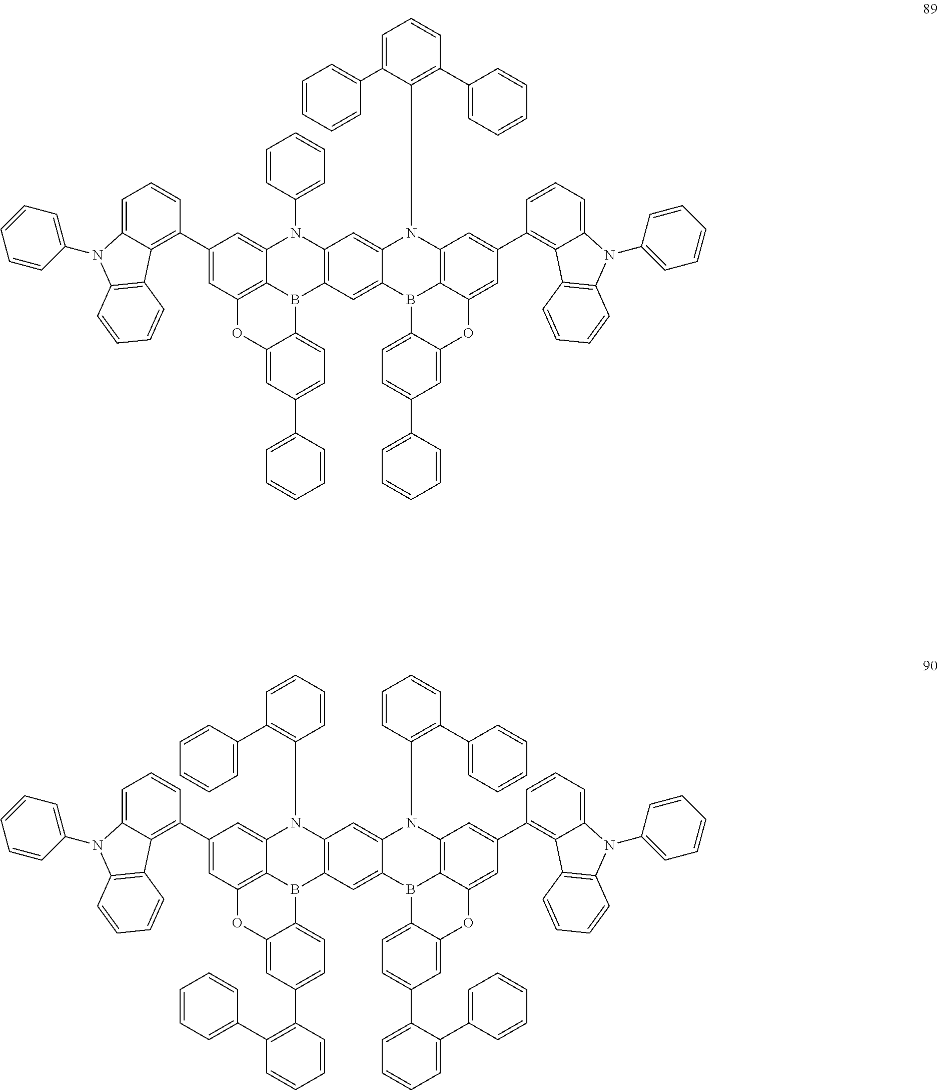

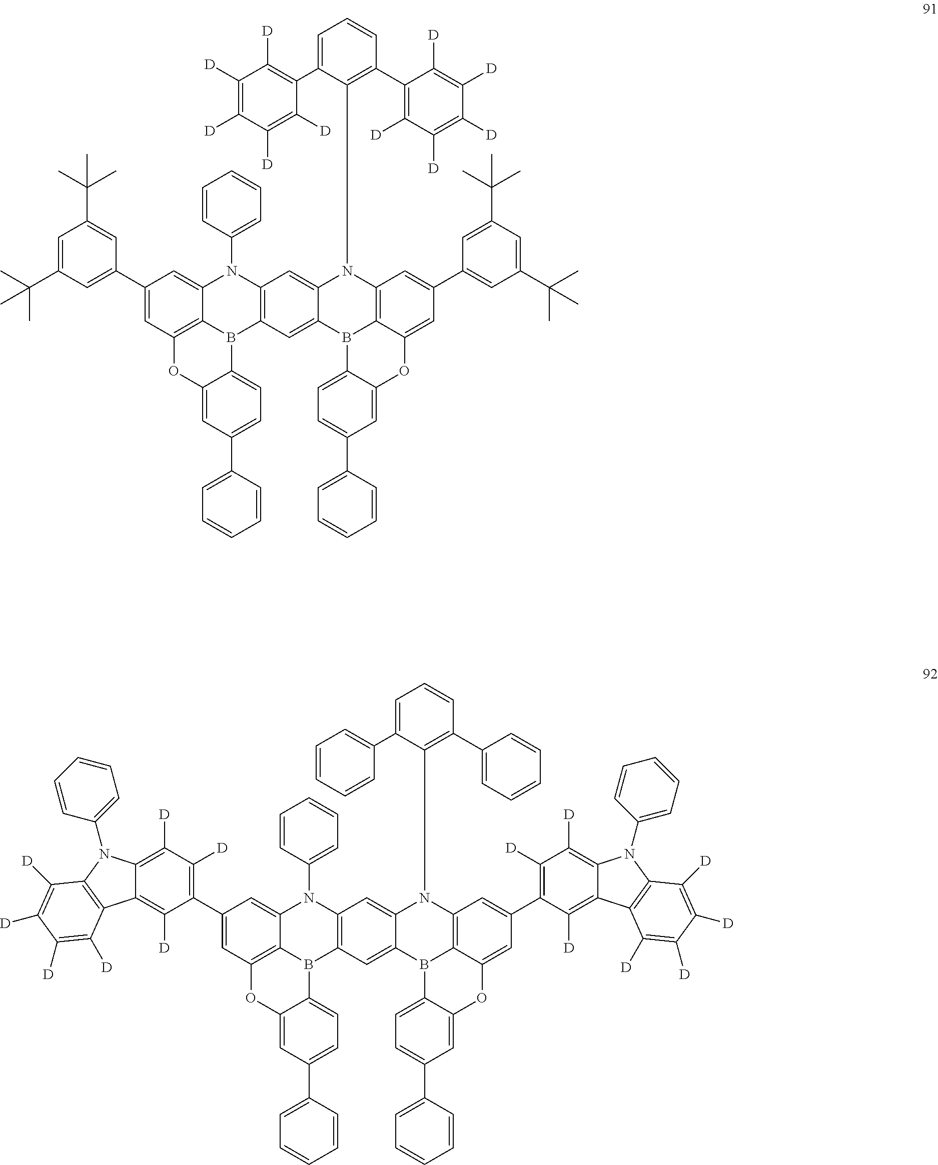

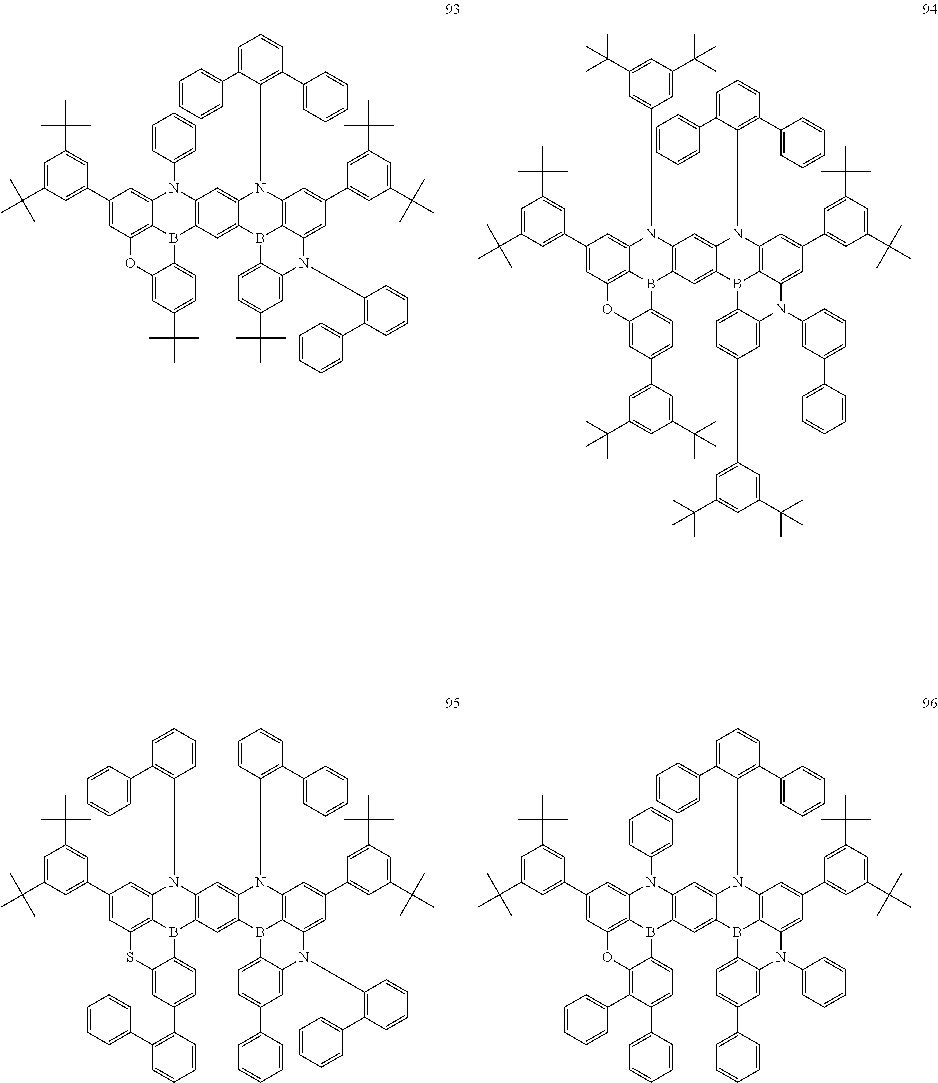

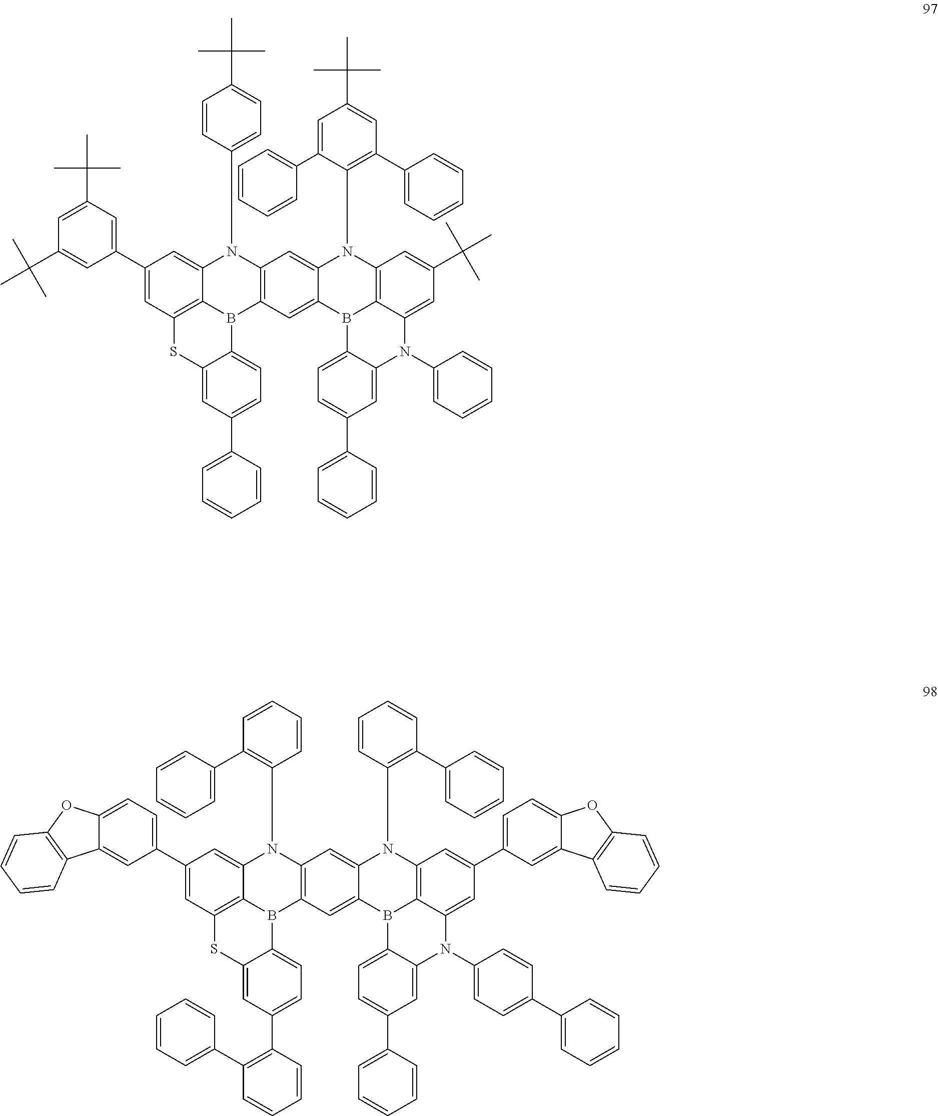 [SMILES: CC(C)(C)c1ccc(N2c3cc4c(cc3B3c5ccc(-c6ccccc6)cc5Sc5cc(-c6cc(C(C)(C)C)cc(C(C)(C)C)c6)cc2c53)B2c3ccc(-c5ccccc5)cc3N(c3ccccc3)c3cc(C(C)(C)C)cc(c32)N4c2c(-c3ccccc3)cc(C(C)(C)C)cc2-c2ccccc2)cc1 ; c1ccc(-c2ccc(N3c4cc(-c5ccccc5)ccc4B4c5cc6c(cc5N(c5ccccc5-c5ccccc5)c5cc(-c7ccc8oc9ccccc9c8c7)cc3c54)N(c3ccccc3-c3ccccc3)c3cc(-c4ccc5oc7ccccc7c5c4)cc4c3B6c3ccc(-c5ccccc5-c5ccccc5)cc3S4)cc2)cc1]

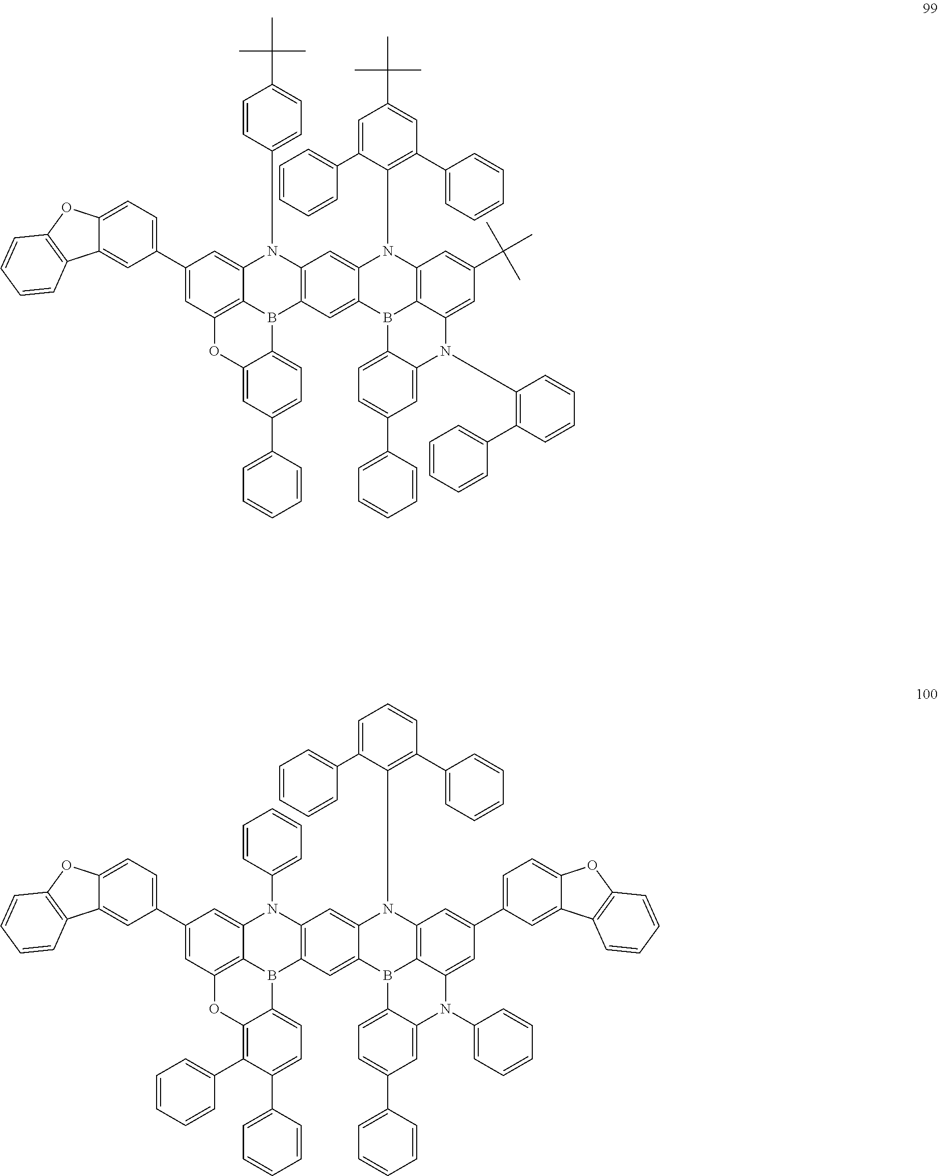 [SMILES: CC(C)(C)c1ccc(N2c3cc4c(cc3B3c5ccc(-c6ccccc6)cc5Oc5cc(-c6ccc7oc8ccccc8c7c6)cc2c53)B2c3ccc(-c5ccccc5)cc3N(c3ccccc3-c3ccccc3)c3cc(C(C)(C)C)cc(c32)N4c2c(-c3ccccc3)cc(C(C)(C)C)cc2-c2ccccc2)cc1 ; c1ccc(-c2ccc3c(c2)N(c2ccccc2)c2cc(-c4ccc5oc6ccccc6c5c4)cc4c2B3c2cc3c(cc2N4c2c(-c4ccccc4)cccc2-c2ccccc2)N(c2ccccc2)c2cc(-c4ccc5oc6ccccc6c5c4)cc4c2B3c2ccc(-c3ccccc3)c(-c3ccccc3)c2O4)cc1]

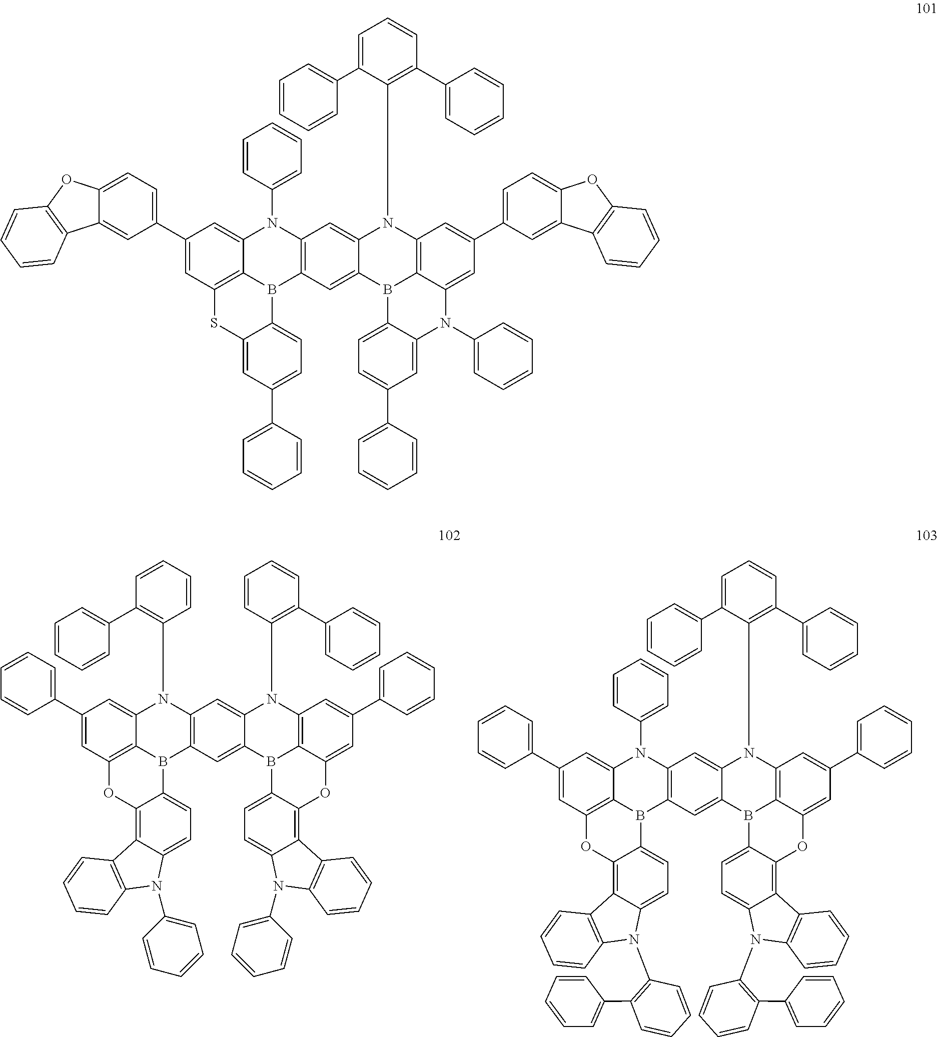

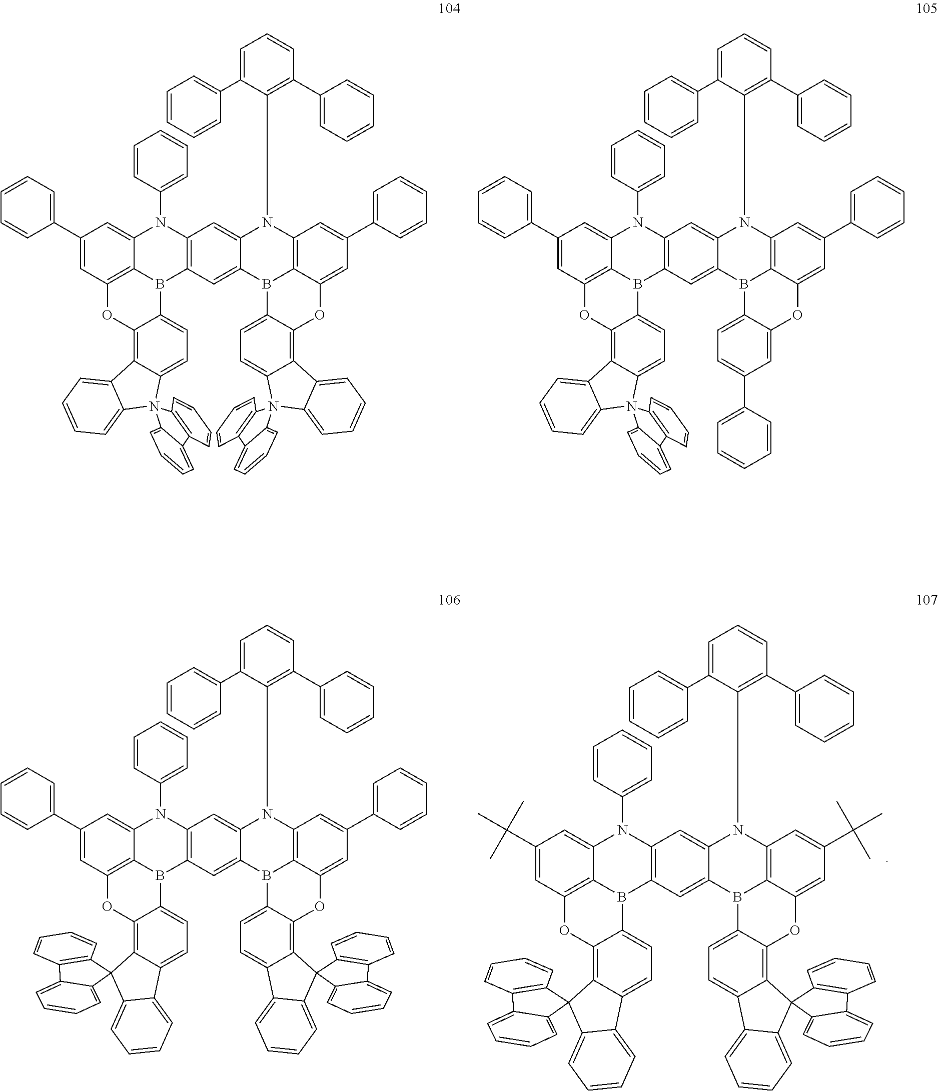

14. A polycyclic compound represented by Formula 1: 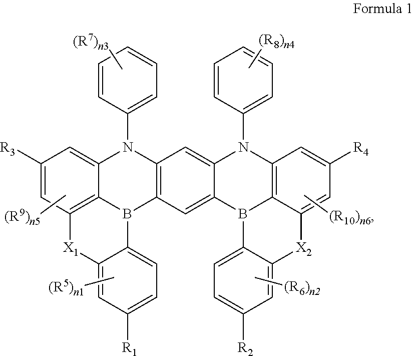
wherein in Formula 1,
one of X₁, or X₂ is O or S and the other one of X₁, or X₂ is NR_{X}, O, or S,
R_{X} is a substituted or unsubstituted aryl group having 6 to 30 ring-forming carbon atoms, or a substituted or unsubstituted heteroaryl group having 2 to 30 ring-forming carbon atoms,
R₁ to R₄ are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, wherein when R₃ and R₄ are a substituted or unsubstituted carbazole group, the nitrogen atom of the carbazole group is not bonded to a benzene ring,
R₅ to R₈ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
R₉ and R₁₀ are each independently a hydrogen atom or a deuterium atom, or bonded to an adjacent group to form a ring,
n1 and n2 are each independently an integer of 0 to 3,
n3 and n4 are each independently an integer of 0 to 5, and
n5 and n6 are each independently an integer of 0 to 2.

15. The polycyclic compound of claim 14, wherein the first compound represented by Formula 1 is represented by Formula 1-1 or Formula 1-2: 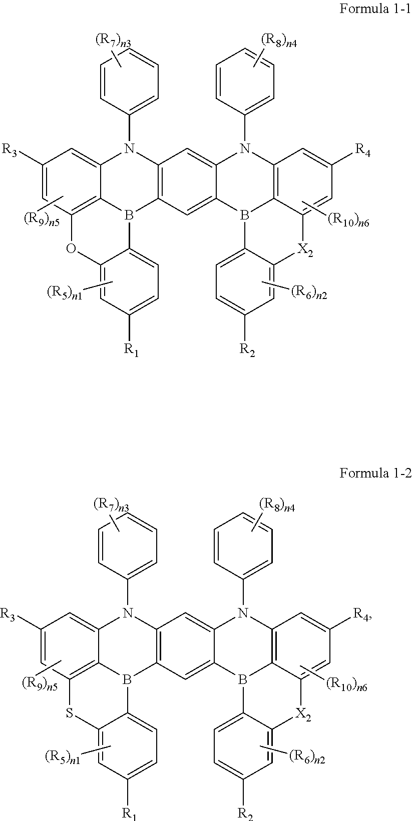
wherein in Formulas 1-1 and 1-2,
X₂ is NRₓ₁, O, or S,
Rₓ₁ is a substituted or unsubstituted aryl group having 6 to 30 ring-forming carbon atoms, or a substituted or unsubstituted heteroaryl group having 2 to 30 ring-forming carbon atoms, and
R₁ to R₁₀, and n1 to n6 are the same as respectively defined in Formula 1.

16. The polycyclic compound of claim 14, wherein the first compound represented by Formula 1 is represented by Formula 2: 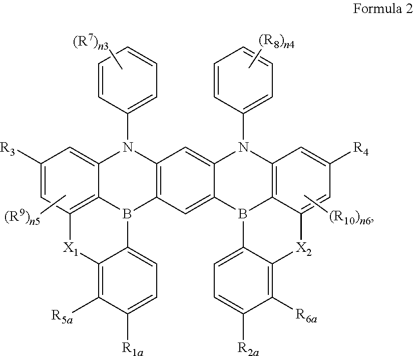
wherein in Formula 2,
R₁ₐ is a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to R₅ₐ to form a ring,
R₂ₐ is a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to R₆ₐ to form a ring,
R₅ₐ is a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to R₁ₐ to form a ring,
R₆ₐ is a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to R₂ₐ to form a ring, and
X₁, X₂, R₃, R₄, R₇ to R₁₀, and n3 to n6 are the same as respectively defined in Formula 1.

17. The polycyclic compound of claim 14, wherein the first compound represented by Formula 1 is represented by Formula 3: 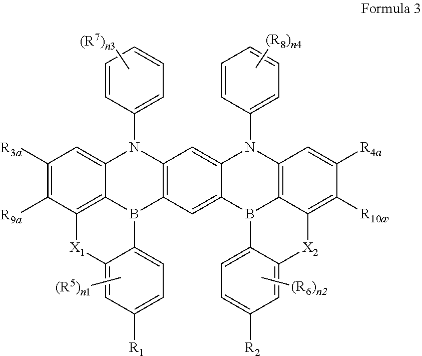
wherein in Formula 3,
R₃ₐ is a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to R₉ₐ to form a ring,
R₄a is a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to R₁₀ₐ to form a ring,
R₉ₐ is a hydrogen atom or a deuterium atom, and/or bonded to R₃a to form a ring,
R₁₀ₐ is a hydrogen atom or a deuterium atom, and/or bonded to R₄ₐ to form a ring, and
X₁, X₂, R₁, R₂, R₅ to R₈, and n1 to n4 are the same as respectively defined in Formula 1.

18. The polycyclic compound of claim 14, wherein R₁ and R₂ are each independently represented by any one from among R-1 to R-7, and/or bonded to an adjacent group to form a ring represented by R-9, and
R₃ and R₄ are each independently represented by any one selected from among R-1 to R-5, and R-8, and/or bonded to an adjacent group to form a ring represented by R-9: 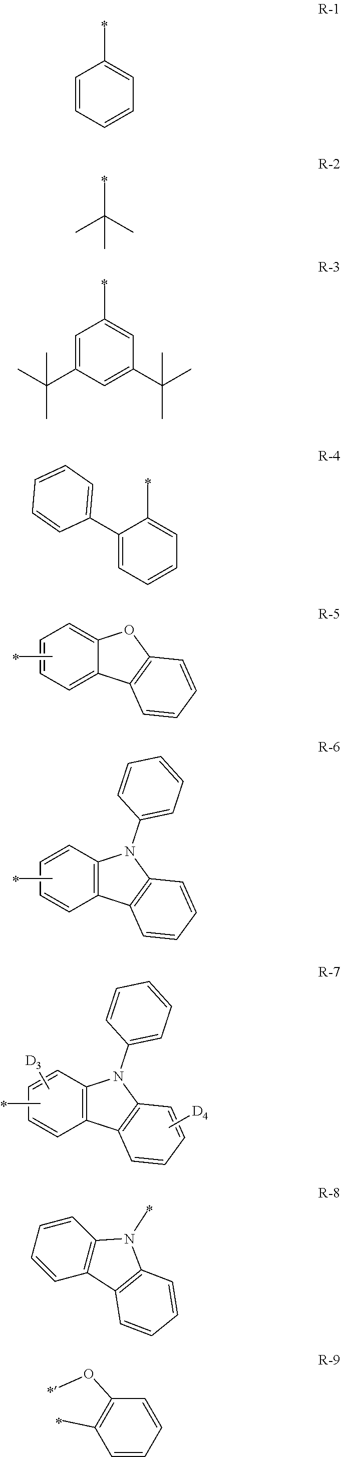
wherein in R-1 to R-9, “*′-” is a site where R₁ to R₄ are linked to Formula 1, and
in R-9, “*′-” is a site where the adjacent group is linked to Formula 1.

19. The polycyclic compound of claim 14, wherein the first compound represented by Formula 1 is represented by Formula 4: 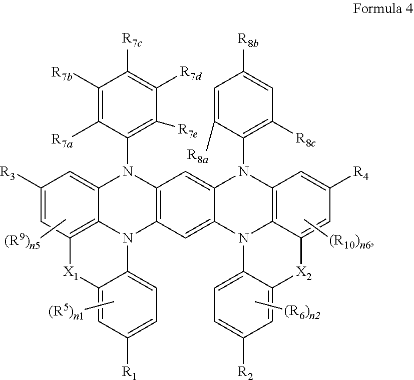
wherein in Formula 4,
R₇ₐ to R₇ₑ, and R₈ₐ to R_{8c} are each independently a hydrogen atom, a deuterium atom, a substituted or unsubstituted alkyl group having 1 to 6 carbon atoms, or a substituted or unsubstituted aryl group having 6 to 20 ring-forming carbon atoms, and
X₁, X₂, R₁ to R₆, R₉, R₁₀, n1, n2, n5, and n6 are the same as respectively defined in Formula 1.

20. The polycyclic compound of claim 14, wherein the first compound represented by Formula 1 is any one selected from among compounds of Compound Group 1: 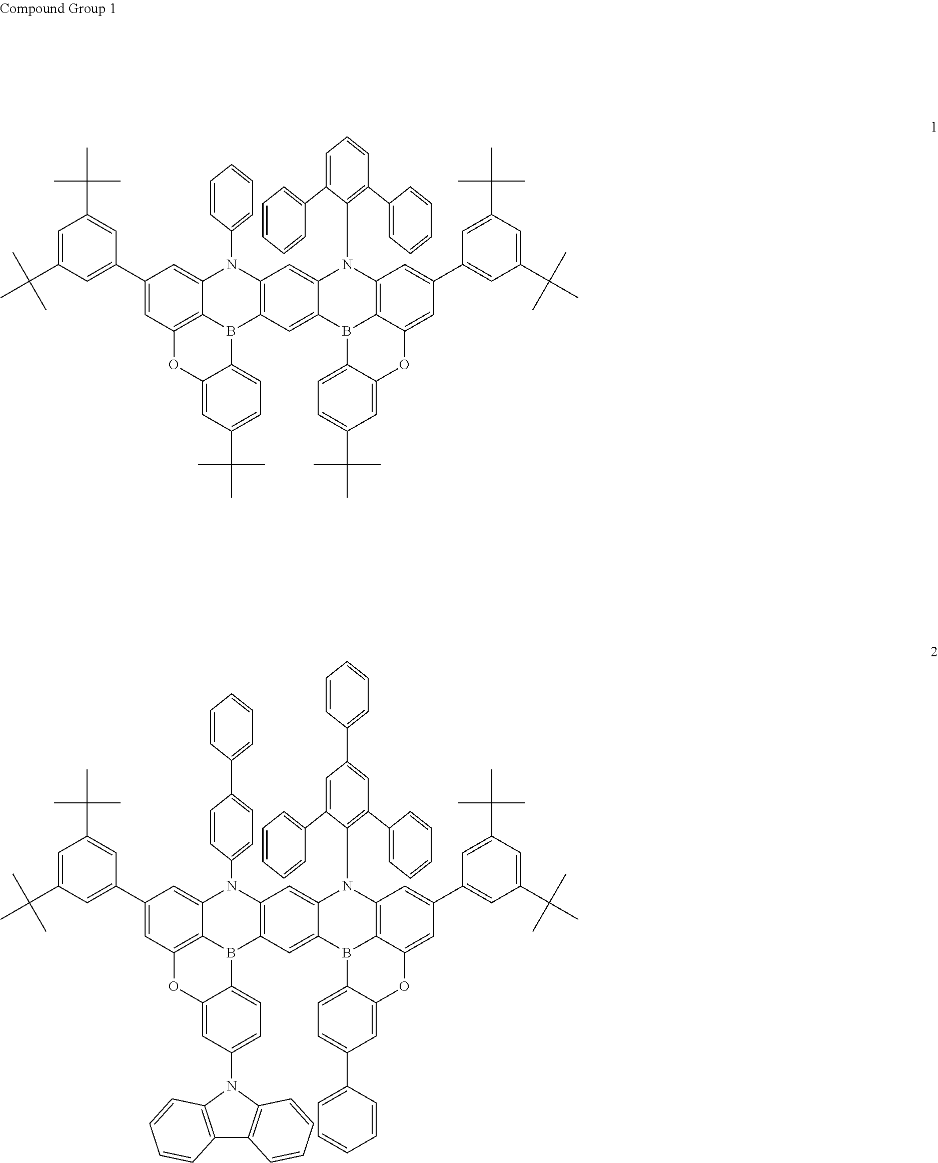 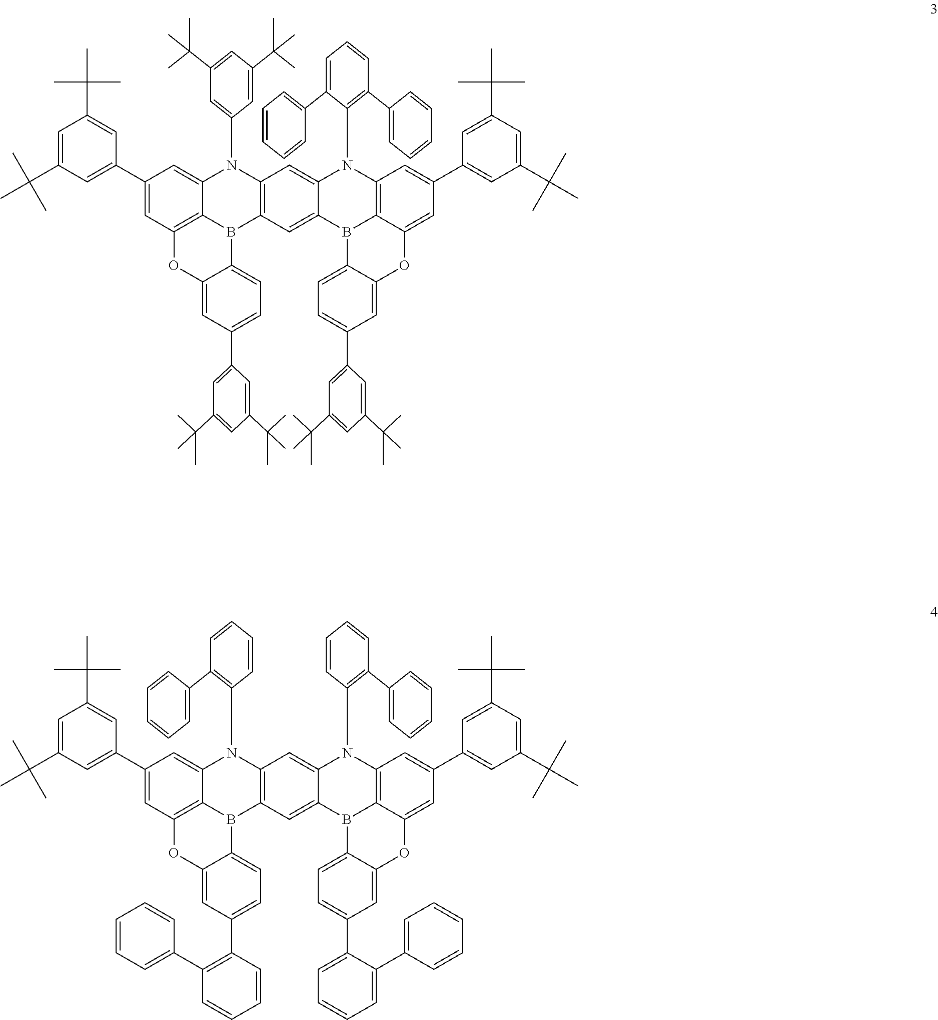 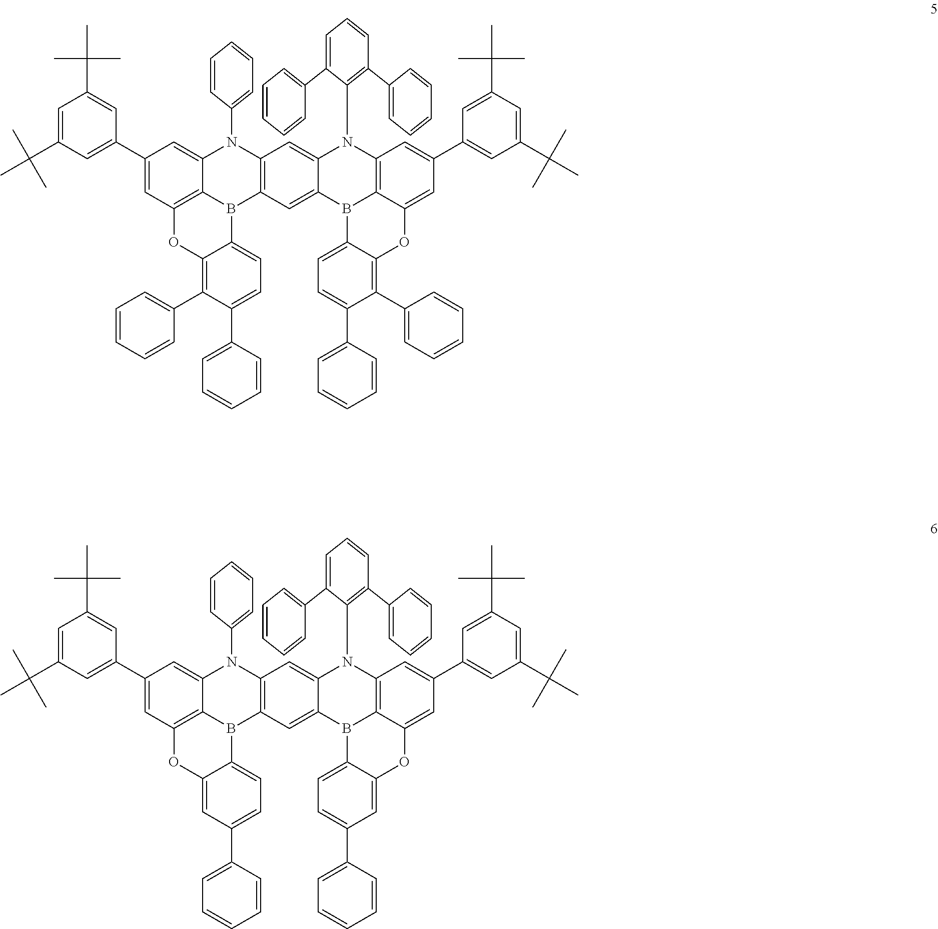 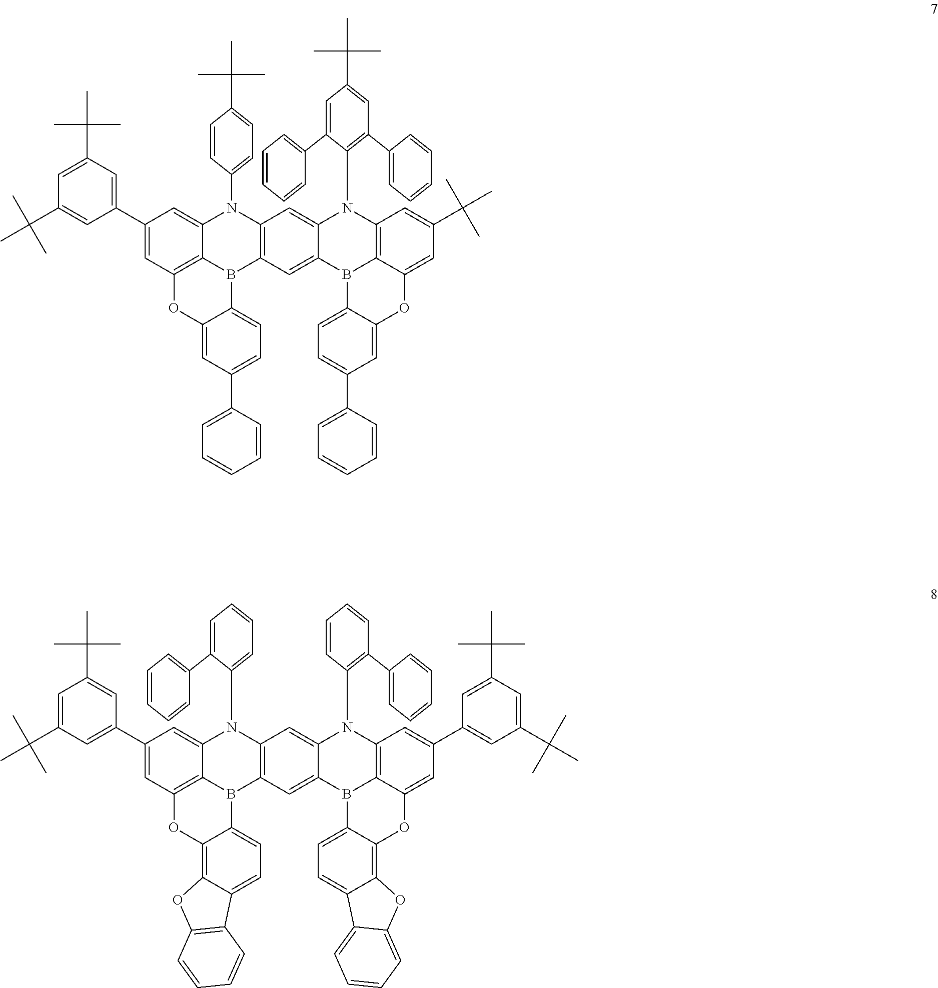 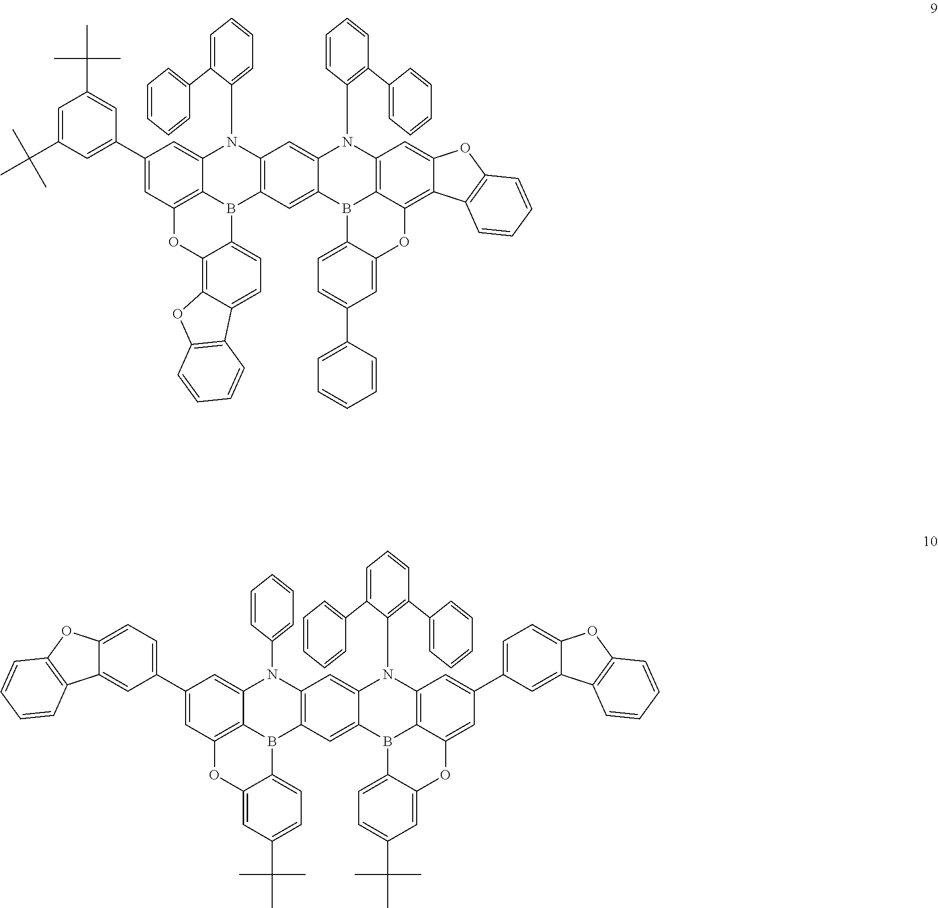 [SMILES: CC(C)(C)c1cc(-c2cc3c4c(c2)N(c2ccccc2-c2ccccc2)c2cc5c(cc2B4c2ccc4c(oc6ccccc64)c2O3)B2c3ccc(-c4ccccc4)cc3Oc3c2c(cc2oc4ccccc4c32)N5c2ccccc2-c2ccccc2)cc(C(C)(C)C)c1 ; CC(C)(C)c1ccc2c(c1)Oc1cc(-c3ccc4oc5ccccc5c4c3)cc3c1B2c1cc2c(cc1N3c1ccccc1)N(c1c(-c3ccccc3)cccc1-c1ccccc1)c1cc(-c3ccc4oc5ccccc5c4c3)cc3c1B2c1ccc(C(C)(C)C)cc1O3] 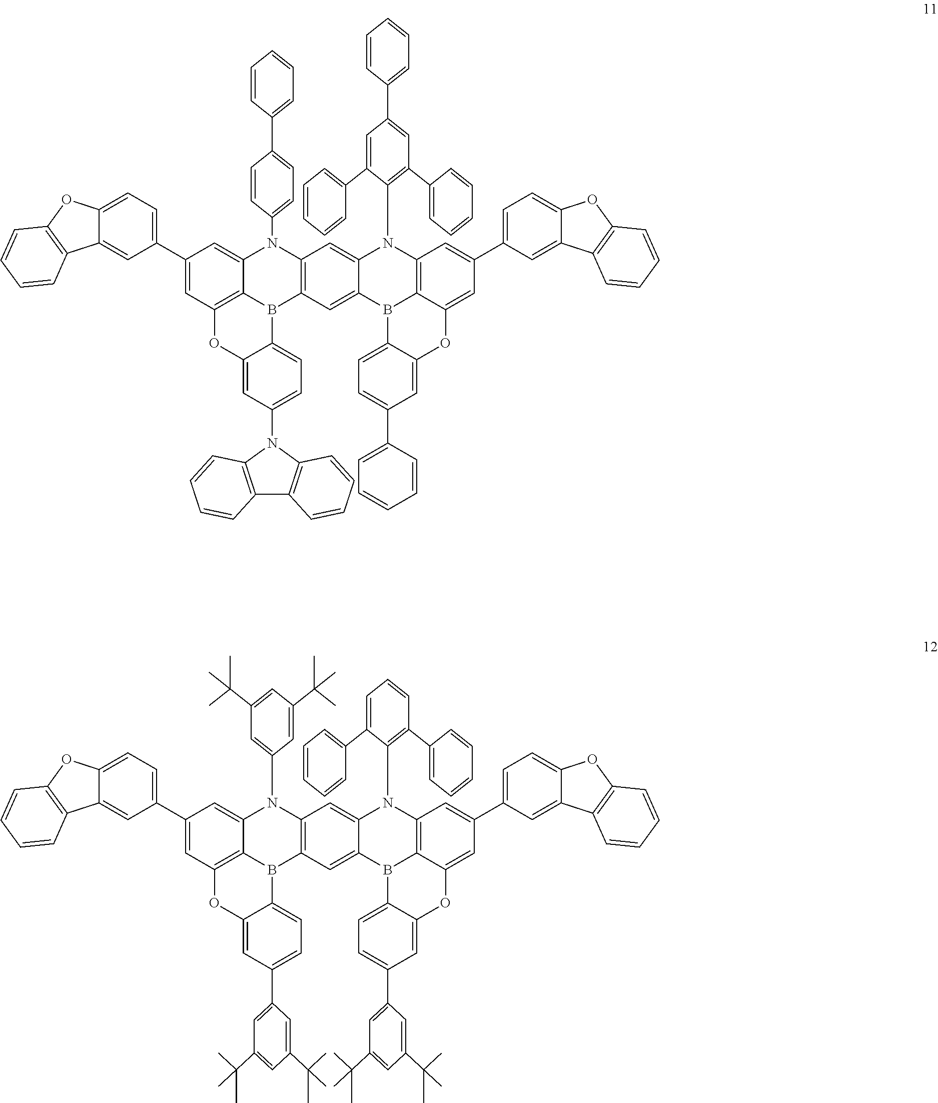 [SMILES: c1ccc(-c2ccc(N3c4cc5c(cc4B4c6ccc(-n7c8ccccc8c8ccccc87)cc6Oc6cc(-c7ccc8oc9ccccc9c8c7)cc3c64)B3c4ccc(-c6ccccc6)cc4Oc4cc(-c6ccc7oc8ccccc8c7c6)cc(c43)N5c3c(-c4ccccc4)cc(-c4ccccc4)cc3-c3ccccc3)cc2)cc1 ; CC(C)(C)c1cc(-c2ccc3c(c2)Oc2cc(-c4ccc5oc6ccccc6c5c4)cc4c2B3c2cc3c(cc2N4c2cc(C(C)(C)C)cc(C(C)(C)C)c2)N(c2c(-c4ccccc4)cccc2-c2ccccc2)c2cc(-c4ccc5oc6ccccc6c5c4)cc4c2B3c2ccc(-c3cc(C(C)(C)C)cc(C(C)(C)C)c3)cc2O4)cc(C(C)(C)C)c1] 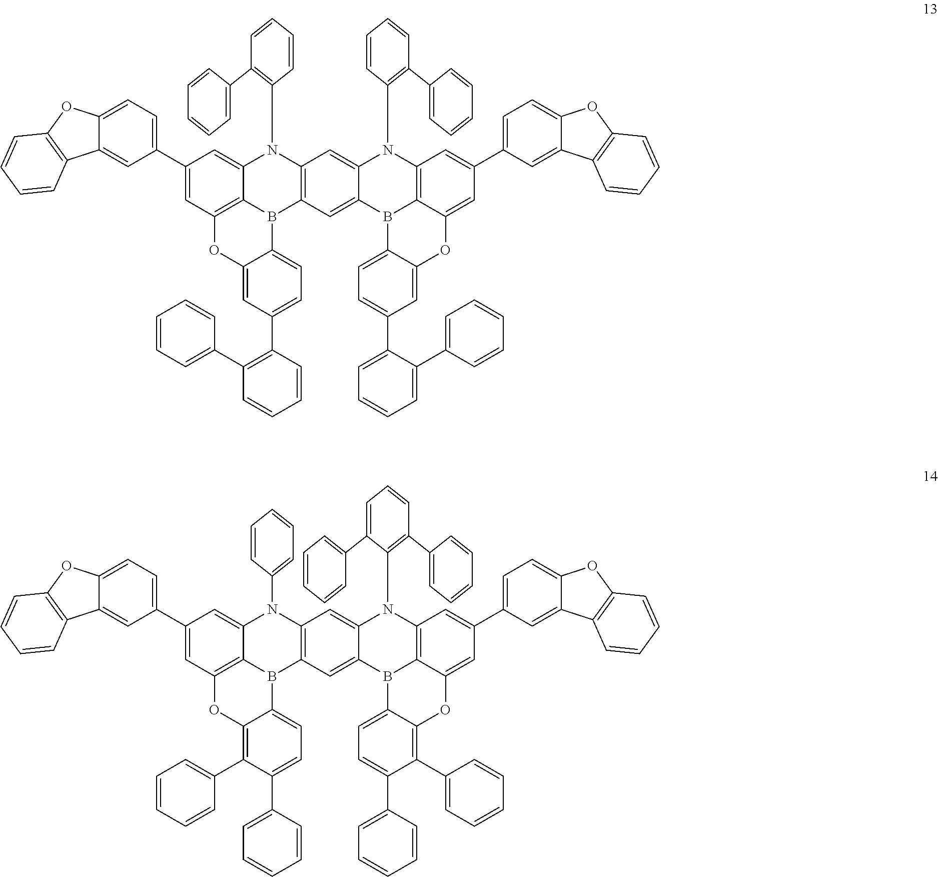 [SMILES: c1ccc(-c2ccccc2-c2ccc3c(c2)Oc2cc(-c4ccc5oc6ccccc6c5c4)cc4c2B3c2cc3c(cc2N4c2ccccc2-c2ccccc2)N(c2ccccc2-c2ccccc2)c2cc(-c4ccc5oc6ccccc6c5c4)cc4c2B3c2ccc(-c3ccccc3-c3ccccc3)cc2O4)cc1 ; c1ccc(-c2ccc3c(c2-c2ccccc2)Oc2cc(-c4ccc5oc6ccccc6c5c4)cc4c2B3c2cc3c(cc2N4c2ccccc2)N(c2c(-c4ccccc4)cccc2-c2ccccc2)c2cc(-c4ccc5oc6ccccc6c5c4)cc4c2B3c2ccc(-c3ccccc3)c(-c3ccccc3)c2O4)cc1] 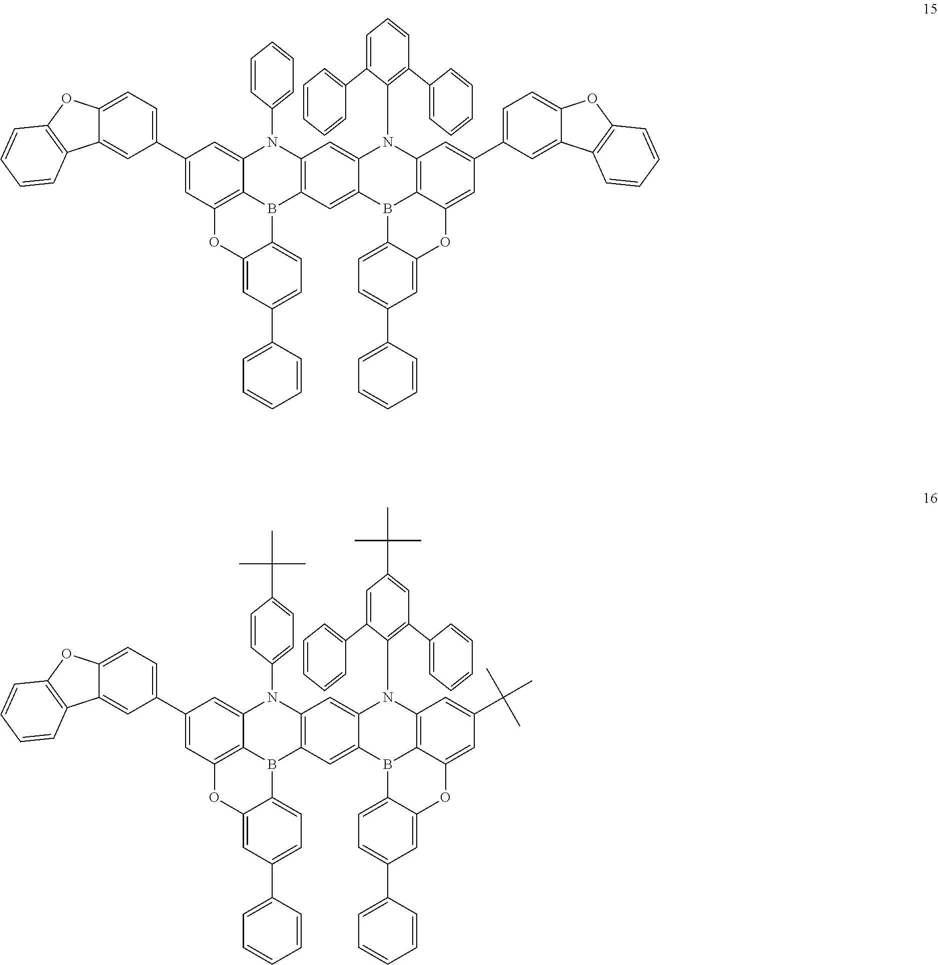 [SMILES: c1ccc(-c2ccc3c(c2)Oc2cc(-c4ccc5oc6ccccc6c5c4)cc4c2B3c2cc3c(cc2N4c2ccccc2)N(c2c(-c4ccccc4)cccc2-c2ccccc2)c2cc(-c4ccc5oc6ccccc6c5c4)cc4c2B3c2ccc(-c3ccccc3)cc2O4)cc1 ; CC(C)(C)c1ccc(N2c3cc4c(cc3B3c5ccc(-c6ccccc6)cc5Oc5cc(-c6ccc7oc8ccccc8c7c6)cc2c53)B2c3ccc(-c5ccccc5)cc3Oc3cc(C(C)(C)C)cc(c32)N4c2c(-c3ccccc3)cc(C(C)(C)C)cc2-c2ccccc2)cc1] 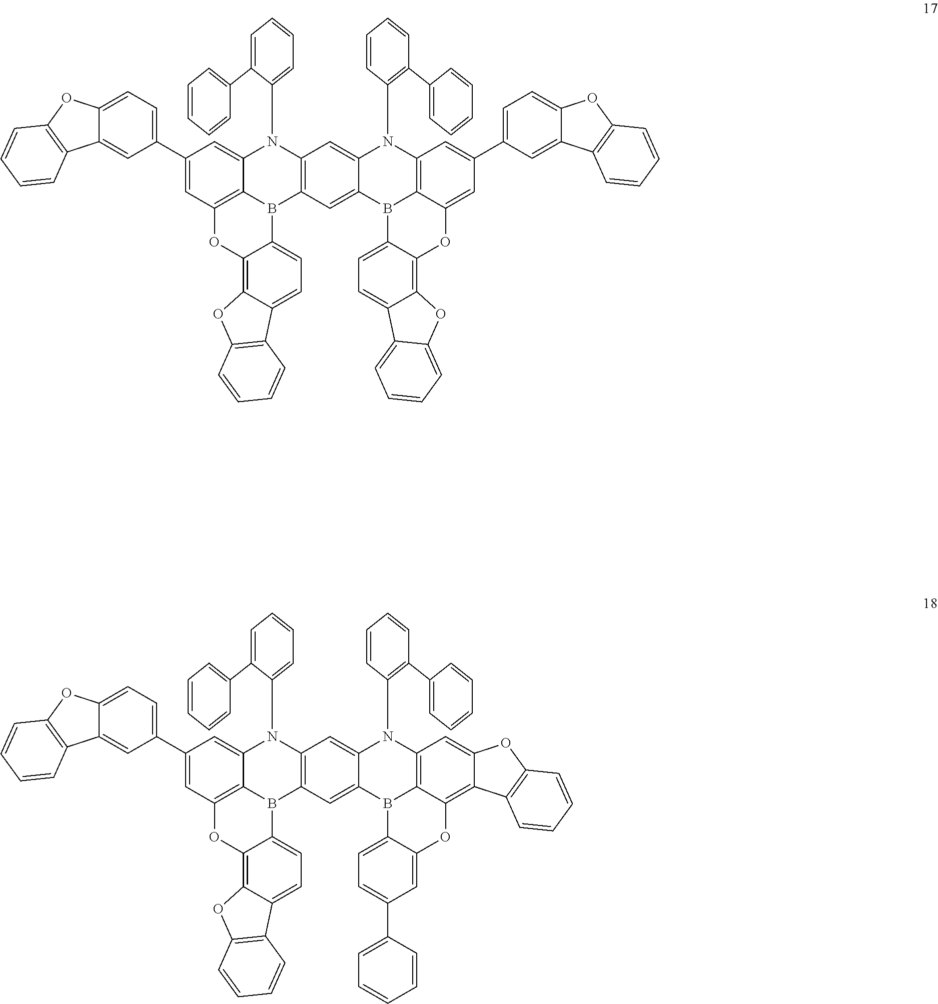 [SMILES: c1ccc(-c2ccccc2N2c3cc4c(cc3B3c5ccc6c(oc7ccccc76)c5Oc5cc(-c6ccc7oc8ccccc8c7c6)cc2c53)B2c3ccc5c(oc6ccccc65)c3Oc3cc(-c5ccc6oc7ccccc7c6c5)cc(c32)N4c2ccccc2-c2ccccc2)cc1 ; c1ccc(-c2ccc3c(c2)Oc2c4c(cc5oc6ccccc6c25)N(c2ccccc2-c2ccccc2)c2cc5c(cc2B34)B2c3ccc4c(oc6ccccc64)c3Oc3cc(-c4ccc6oc7ccccc7c6c4)cc(c32)N5c2ccccc2-c2ccccc2)cc1] 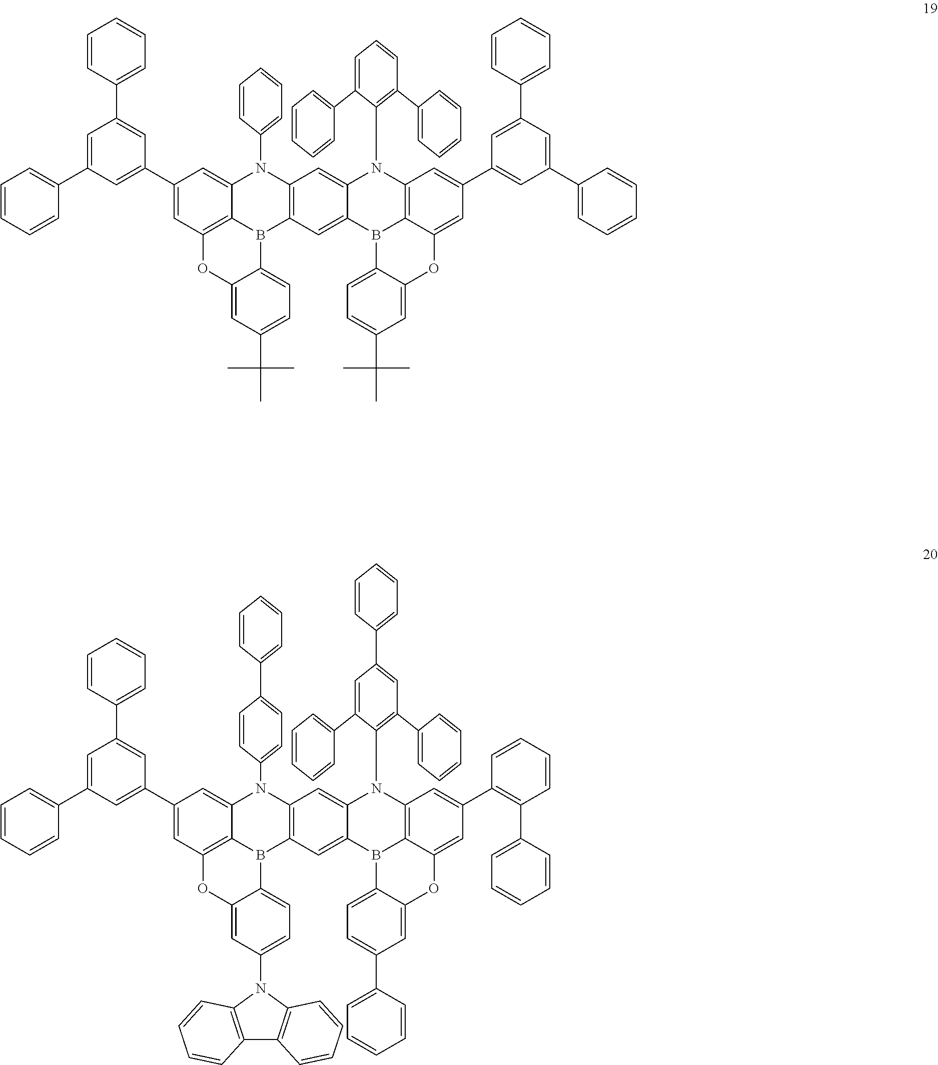 [SMILES: CC(C)(C)c1ccc2c(c1)Oc1cc(-c3cc(-c4ccccc4)cc(-c4ccccc4)c3)cc3c1B2c1cc2c(cc1N3c1ccccc1)N(c1c(-c3ccccc3)cccc1-c1ccccc1)c1cc(-c3cc(-c4ccccc4)cc(-c4ccccc4)c3)cc3c1B2c1ccc(C(C)(C)C)cc1O3 ; c1ccc(-c2ccc(N3c4cc5c(cc4B4c6ccc(-n7c8ccccc8c8ccccc87)cc6Oc6cc(-c7cc(-c8ccccc8)cc(-c8ccccc8)c7)cc3c64)B3c4ccc(-c6ccccc6)cc4Oc4cc(-c6ccccc6-c6ccccc6)cc(c43)N5c3c(-c4ccccc4)cc(-c4ccccc4)cc3-c3ccccc3)cc2)cc1] 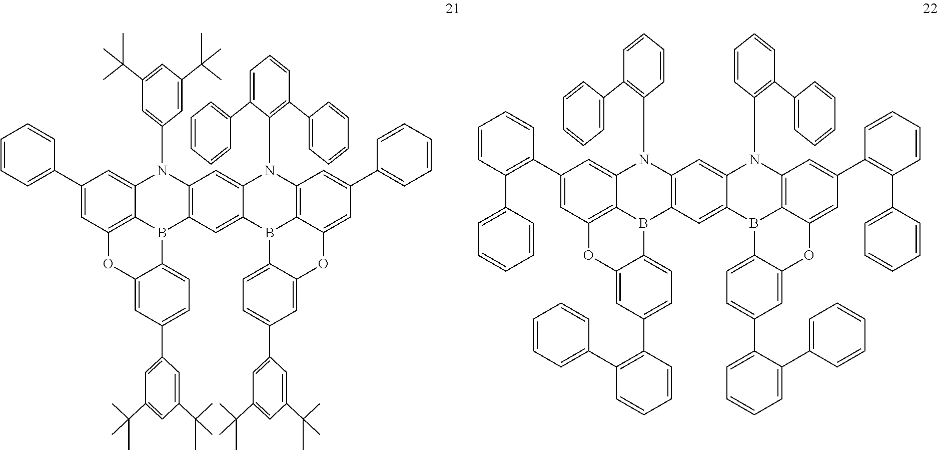 [SMILES: CC(C)(C)c1cc(-c2ccc3c(c2)Oc2cc(-c4ccccc4)cc4c2B3c2cc3c(cc2N4c2cc(C(C)(C)C)cc(C(C)(C)C)c2)N(c2c(-c4ccccc4)cccc2-c2ccccc2)c2cc(-c4ccccc4)cc4c2B3c2ccc(-c3cc(C(C)(C)C)cc(C(C)(C)C)c3)cc2O4)cc(C(C)(C)C)c1 ; c1ccc(-c2ccccc2-c2ccc3c(c2)Oc2cc(-c4ccccc4-c4ccccc4)cc4c2B3c2cc3c(cc2N4c2ccccc2-c2ccccc2)N(c2ccccc2-c2ccccc2)c2cc(-c4ccccc4-c4ccccc4)cc4c2B3c2ccc(-c3ccccc3-c3ccccc3)cc2O4)cc1] 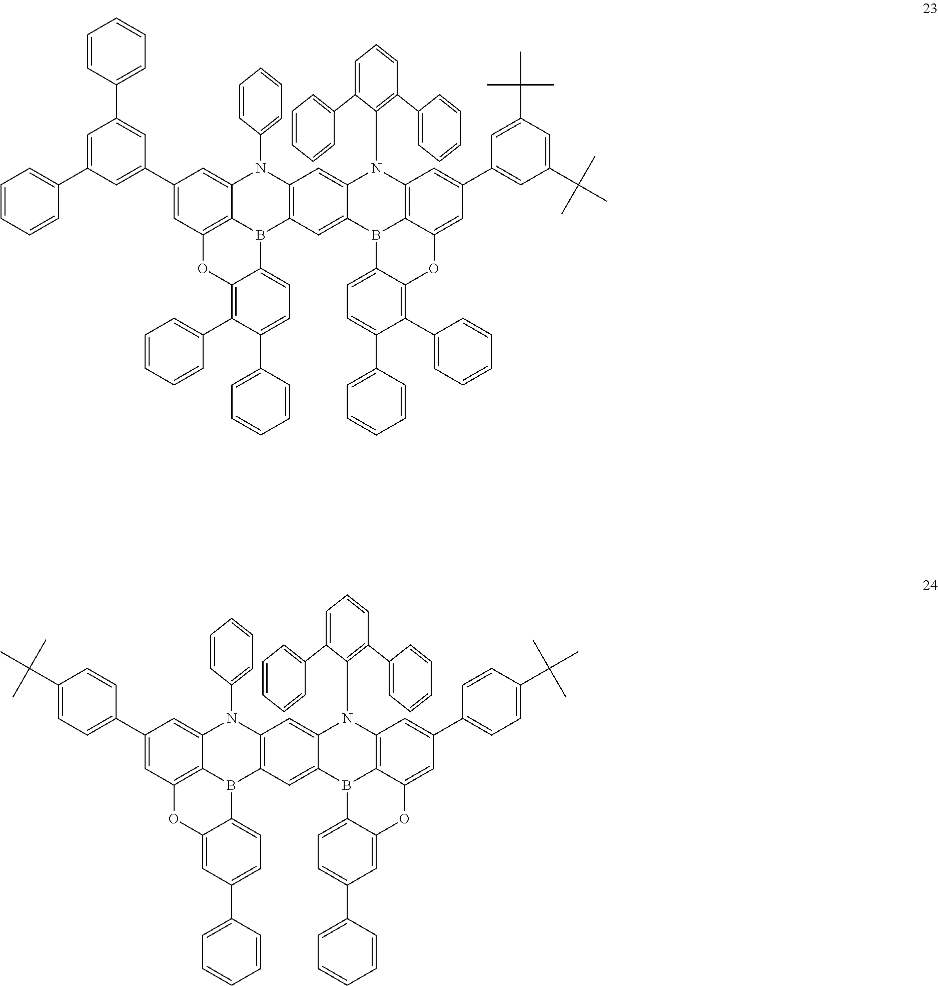 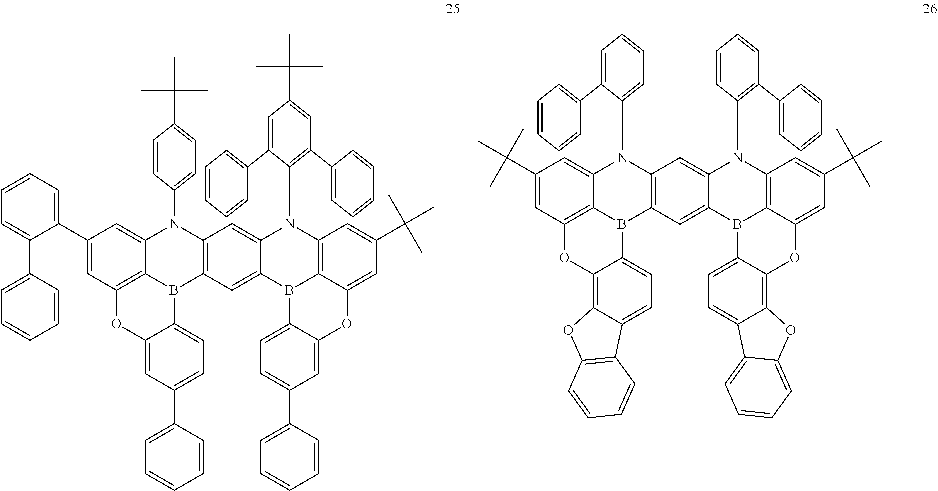 [SMILES: CC(C)(C)c1ccc(N2c3cc4c(cc3B3c5ccc(-c6ccccc6)cc5Oc5cc(-c6ccccc6-c6ccccc6)cc2c53)B2c3ccc(-c5ccccc5)cc3Oc3cc(C(C)(C)C)cc(c32)N4c2c(-c3ccccc3)cc(C(C)(C)C)cc2-c2ccccc2)cc1 ; CC(C)(C)c1cc2c3c(c1)N(c1ccccc1-c1ccccc1)c1cc4c(cc1B3c1ccc3c(oc5ccccc53)c1O2)B1c2ccc3c(oc5ccccc53)c2Oc2cc(C(C)(C)C)cc(c21)N4c1ccccc1-c1ccccc1] 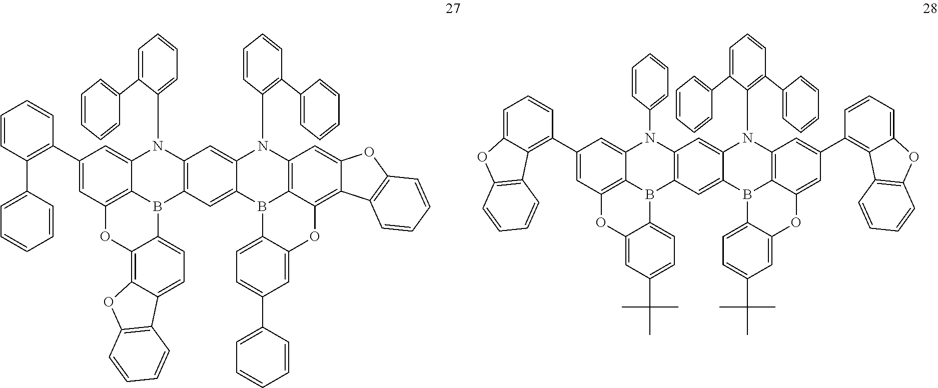 [SMILES: c1ccc(-c2ccc3c(c2)Oc2c4c(cc5oc6ccccc6c25)N(c2ccccc2-c2ccccc2)c2cc5c(cc2B34)B2c3ccc4c(oc6ccccc64)c3Oc3cc(-c4ccccc4-c4ccccc4)cc(c32)N5c2ccccc2-c2ccccc2)cc1 ; CC(C)(C)c1ccc2c(c1)Oc1cc(-c3cccc4oc5ccccc5c34)cc3c1B2c1cc2c(cc1N3c1ccccc1)N(c1c(-c3ccccc3)cccc1-c1ccccc1)c1cc(-c3cccc4oc5ccccc5c34)cc3c1B2c1ccc(C(C)(C)C)cc1O3] 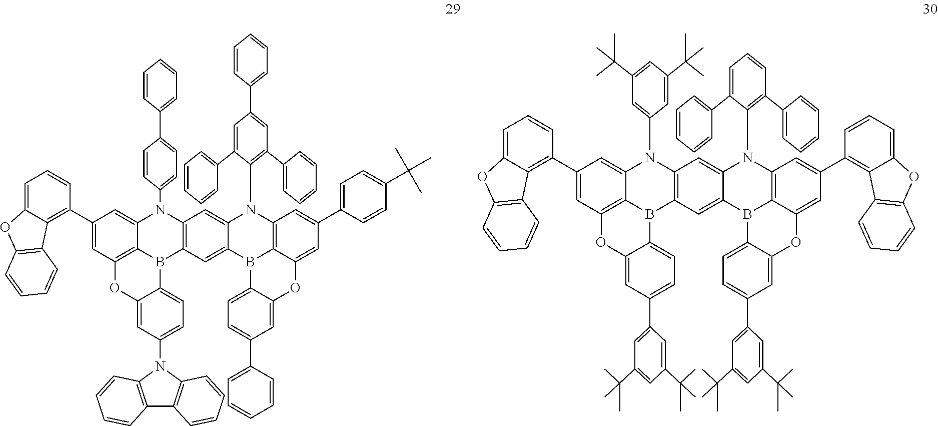 [SMILES: CC(C)(C)c1ccc(-c2cc3c4c(c2)N(c2c(-c5ccccc5)cc(-c5ccccc5)cc2-c2ccccc2)c2cc5c(cc2B4c2ccc(-c4ccccc4)cc2O3)B2c3ccc(-n4c6ccccc6c6ccccc64)cc3Oc3cc(-c4cccc6oc7ccccc7c46)cc(c32)N5c2ccc(-c3ccccc3)cc2)cc1 ; CC(C)(C)c1cc(-c2ccc3c(c2)Oc2cc(-c4cccc5oc6ccccc6c45)cc4c2B3c2cc3c(cc2N4c2cc(C(C)(C)C)cc(C(C)(C)C)c2)N(c2c(-c4ccccc4)cccc2-c2ccccc2)c2cc(-c4cccc5oc6ccccc6c45)cc4c2B3c2ccc(-c3cc(C(C)(C)C)cc(C(C)(C)C)c3)cc2O4)cc(C(C)(C)C)c1] 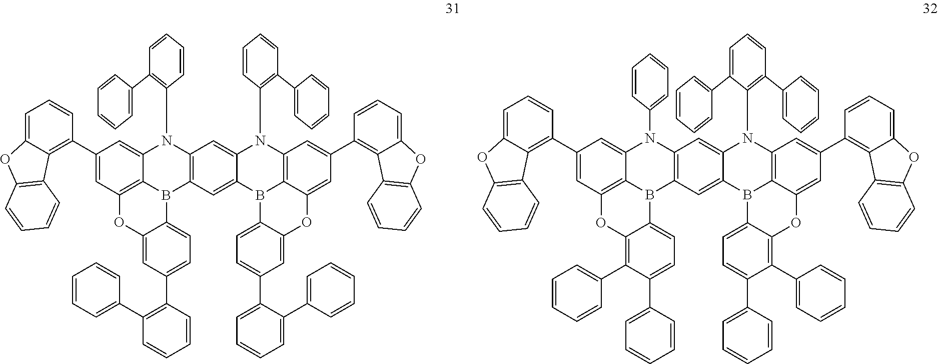 [SMILES: c1ccc(-c2ccccc2-c2ccc3c(c2)Oc2cc(-c4cccc5oc6ccccc6c45)cc4c2B3c2cc3c(cc2N4c2ccccc2-c2ccccc2)N(c2ccccc2-c2ccccc2)c2cc(-c4cccc5oc6ccccc6c45)cc4c2B3c2ccc(-c3ccccc3-c3ccccc3)cc2O4)cc1 ; c1ccc(-c2ccc3c(c2-c2ccccc2)Oc2cc(-c4cccc5oc6ccccc6c45)cc4c2B3c2cc3c(cc2N4c2ccccc2)N(c2c(-c4ccccc4)cccc2-c2ccccc2)c2cc(-c4cccc5oc6ccccc6c45)cc4c2B3c2ccc(-c3ccccc3)c(-c3ccccc3)c2O4)cc1] 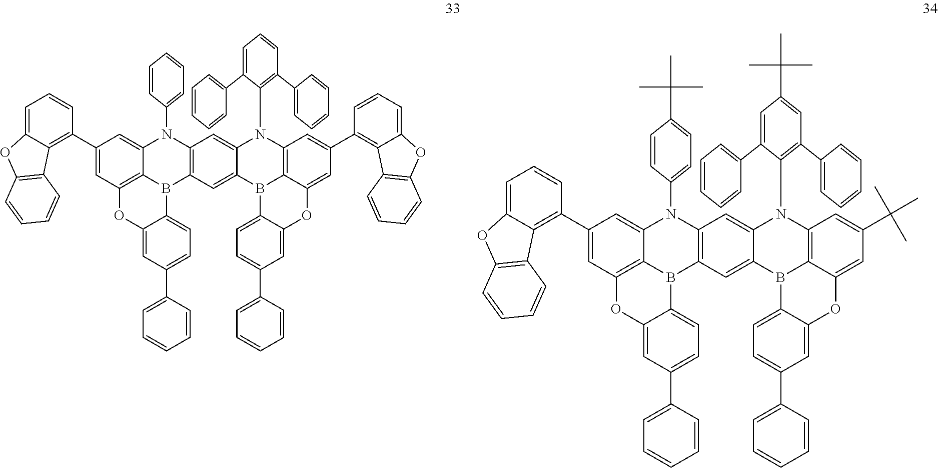 [SMILES: c1ccc(-c2ccc3c(c2)Oc2cc(-c4cccc5oc6ccccc6c45)cc4c2B3c2cc3c(cc2N4c2ccccc2)N(c2c(-c4ccccc4)cccc2-c2ccccc2)c2cc(-c4cccc5oc6ccccc6c45)cc4c2B3c2ccc(-c3ccccc3)cc2O4)cc1 ; CC(C)(C)c1ccc(N2c3cc4c(cc3B3c5ccc(-c6ccccc6)cc5Oc5cc(-c6cccc7oc8ccccc8c67)cc2c53)B2c3ccc(-c5ccccc5)cc3Oc3cc(C(C)(C)C)cc(c32)N4c2c(-c3ccccc3)cc(C(C)(C)C)cc2-c2ccccc2)cc1] 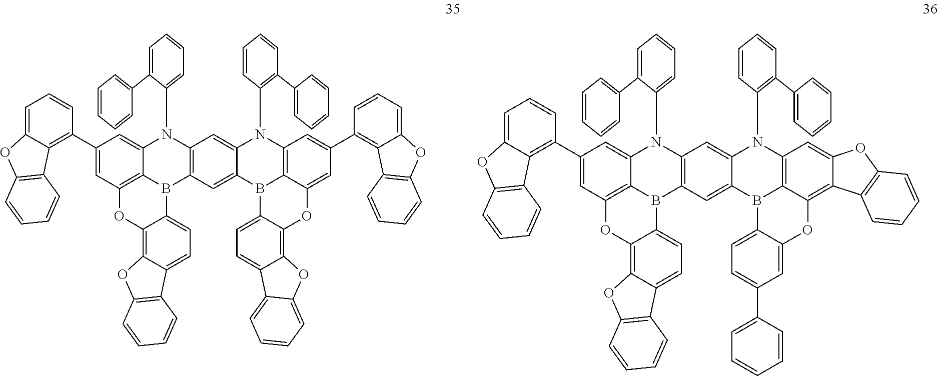 [SMILES: c1ccc(-c2ccccc2N2c3cc4c(cc3B3c5ccc6c(oc7ccccc76)c5Oc5cc(-c6cccc7oc8ccccc8c67)cc2c53)B2c3ccc5c(oc6ccccc65)c3Oc3cc(-c5cccc6oc7ccccc7c56)cc(c32)N4c2ccccc2-c2ccccc2)cc1 ; c1ccc(-c2ccc3c(c2)Oc2c4c(cc5oc6ccccc6c25)N(c2ccccc2-c2ccccc2)c2cc5c(cc2B34)B2c3ccc4c(oc6ccccc64)c3Oc3cc(-c4cccc6oc7ccccc7c46)cc(c32)N5c2ccccc2-c2ccccc2)cc1] 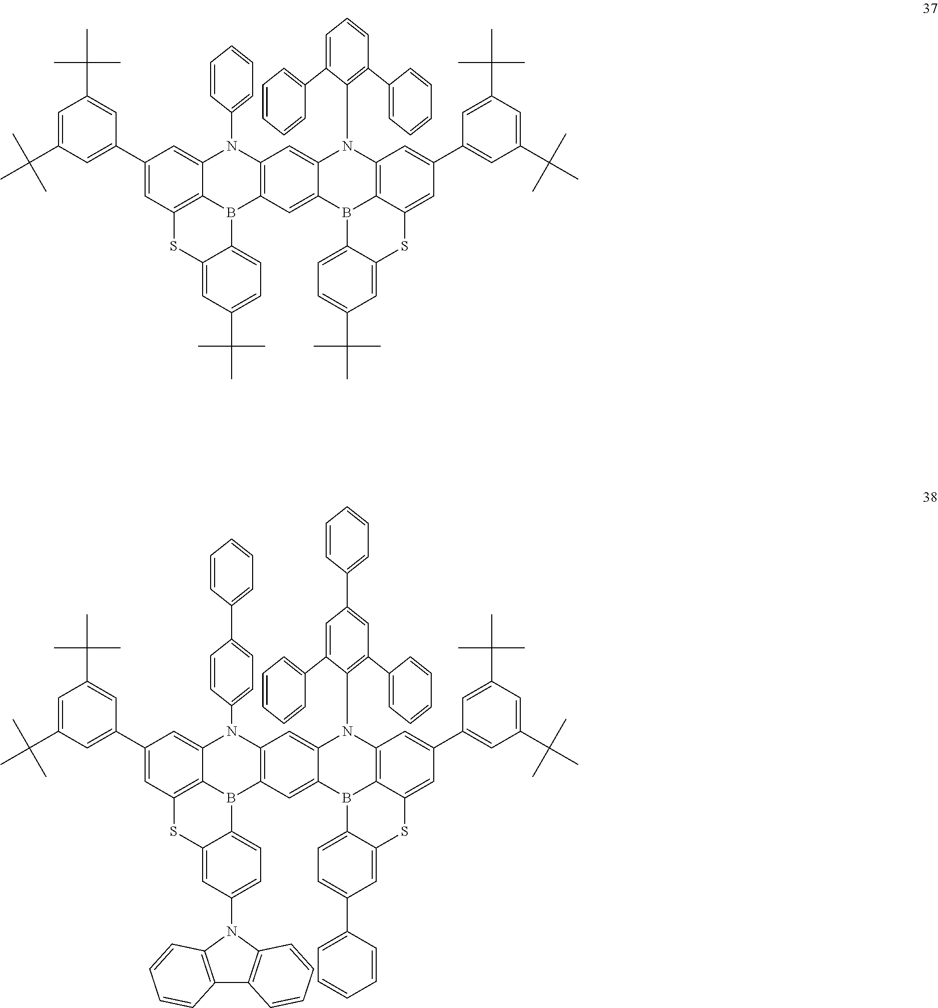 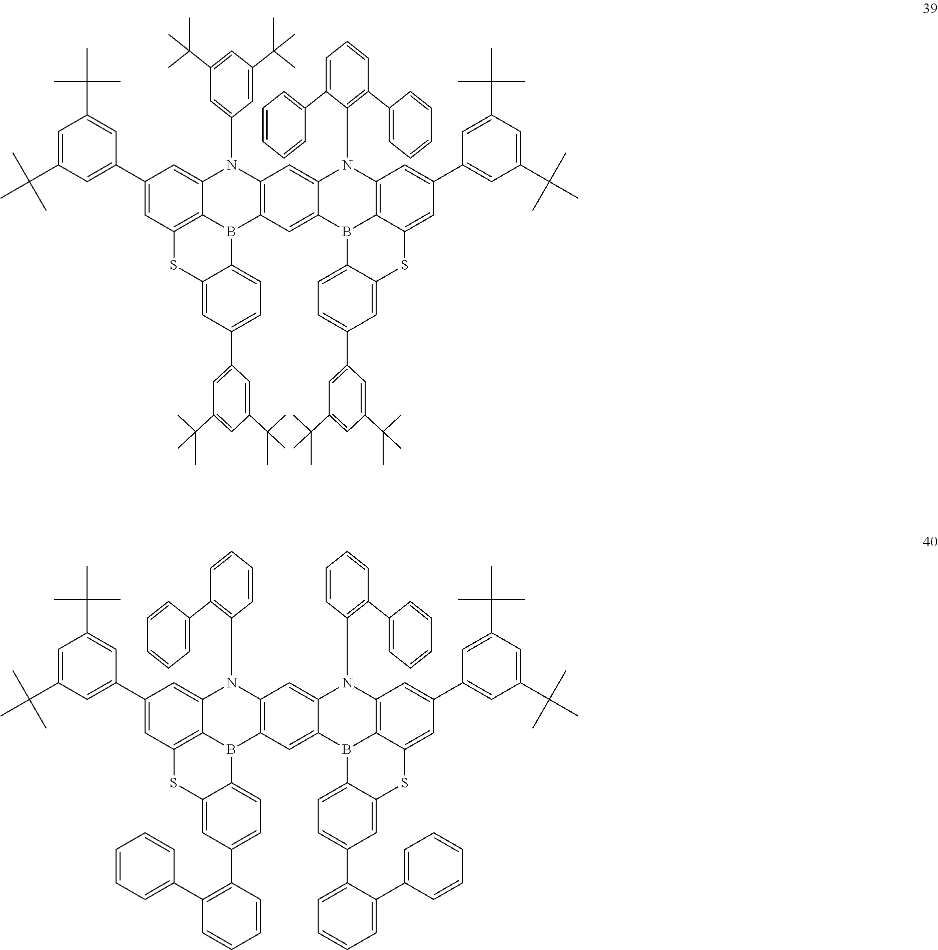 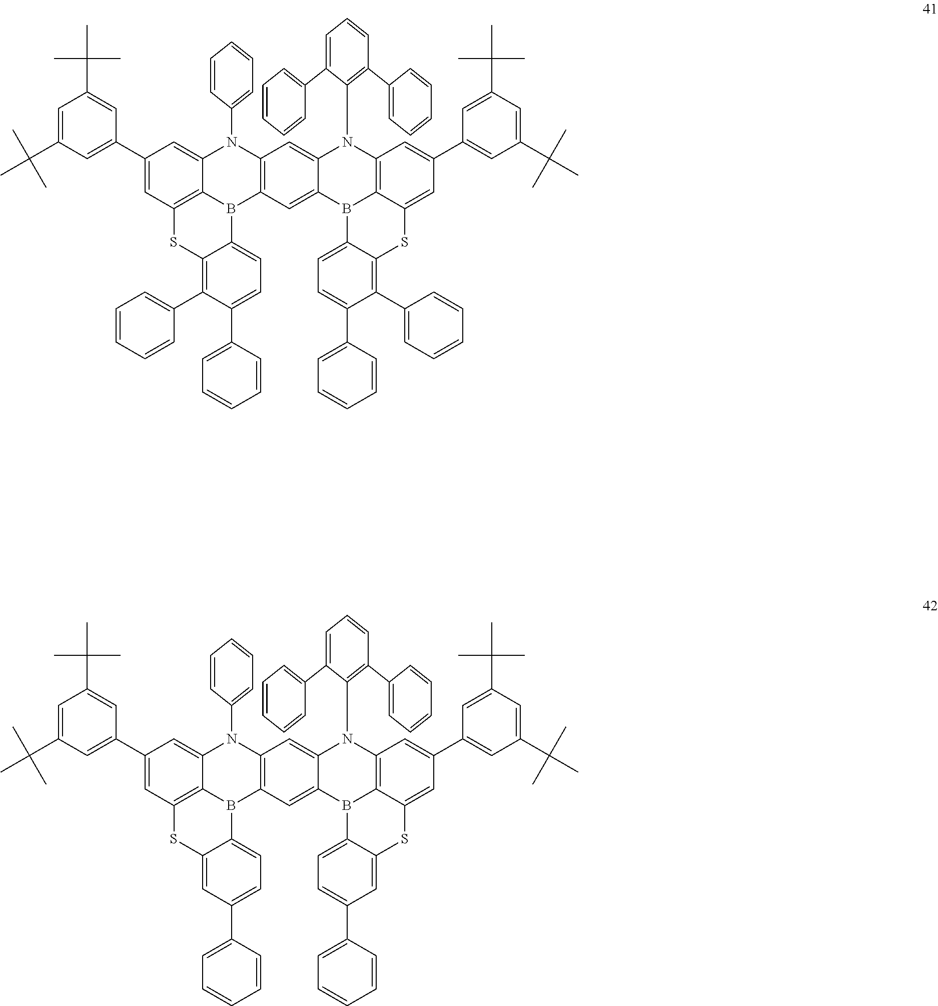 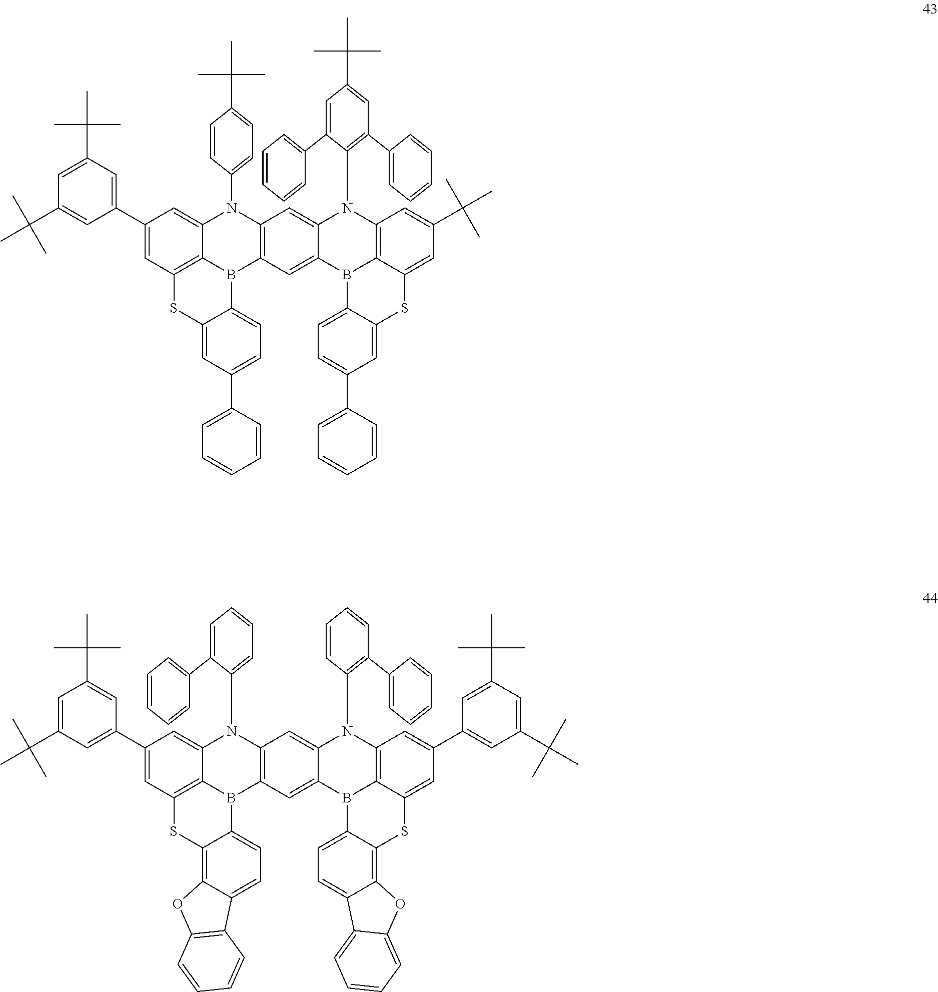 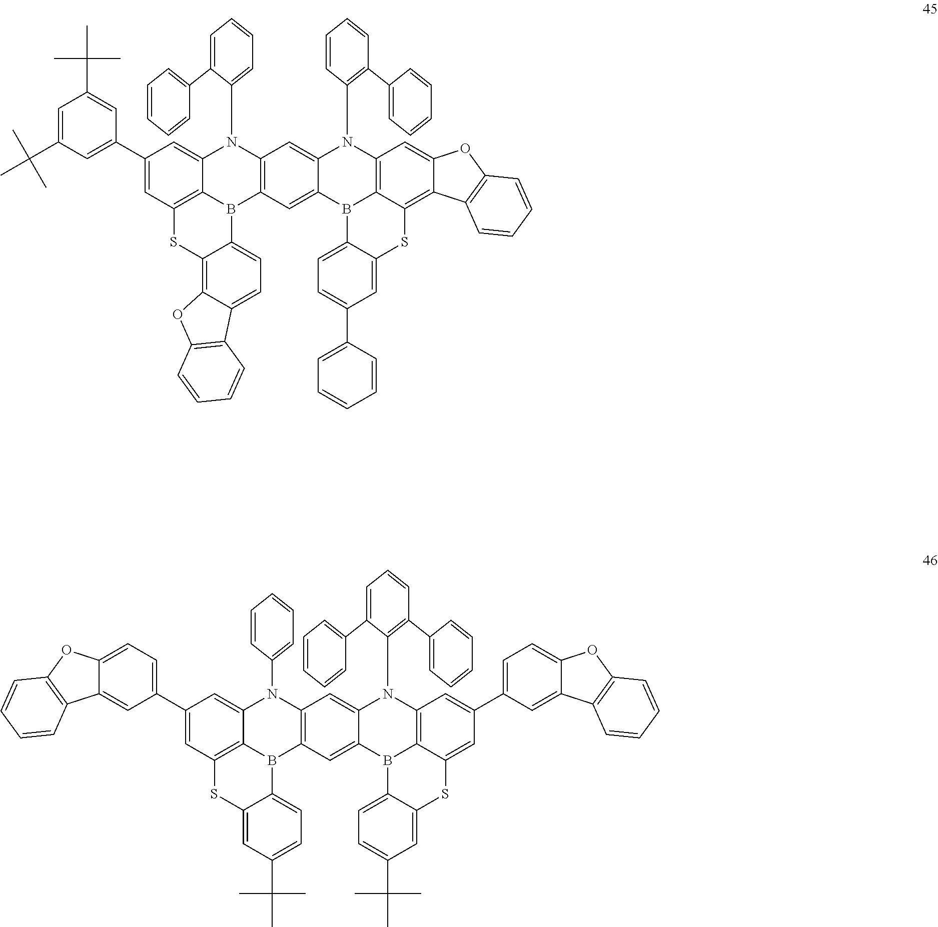 [SMILES: CC(C)(C)c1cc(-c2cc3c4c(c2)N(c2ccccc2-c2ccccc2)c2cc5c(cc2B4c2ccc4c(oc6ccccc64)c2S3)B2c3ccc(-c4ccccc4)cc3Sc3c2c(cc2oc4ccccc4c32)N5c2ccccc2-c2ccccc2)cc(C(C)(C)C)c1 ; CC(C)(C)c1ccc2c(c1)Sc1cc(-c3ccc4oc5ccccc5c4c3)cc3c1B2c1cc2c(cc1N3c1ccccc1)N(c1c(-c3ccccc3)cccc1-c1ccccc1)c1cc(-c3ccc4oc5ccccc5c4c3)cc3c1B2c1ccc(C(C)(C)C)cc1S3] 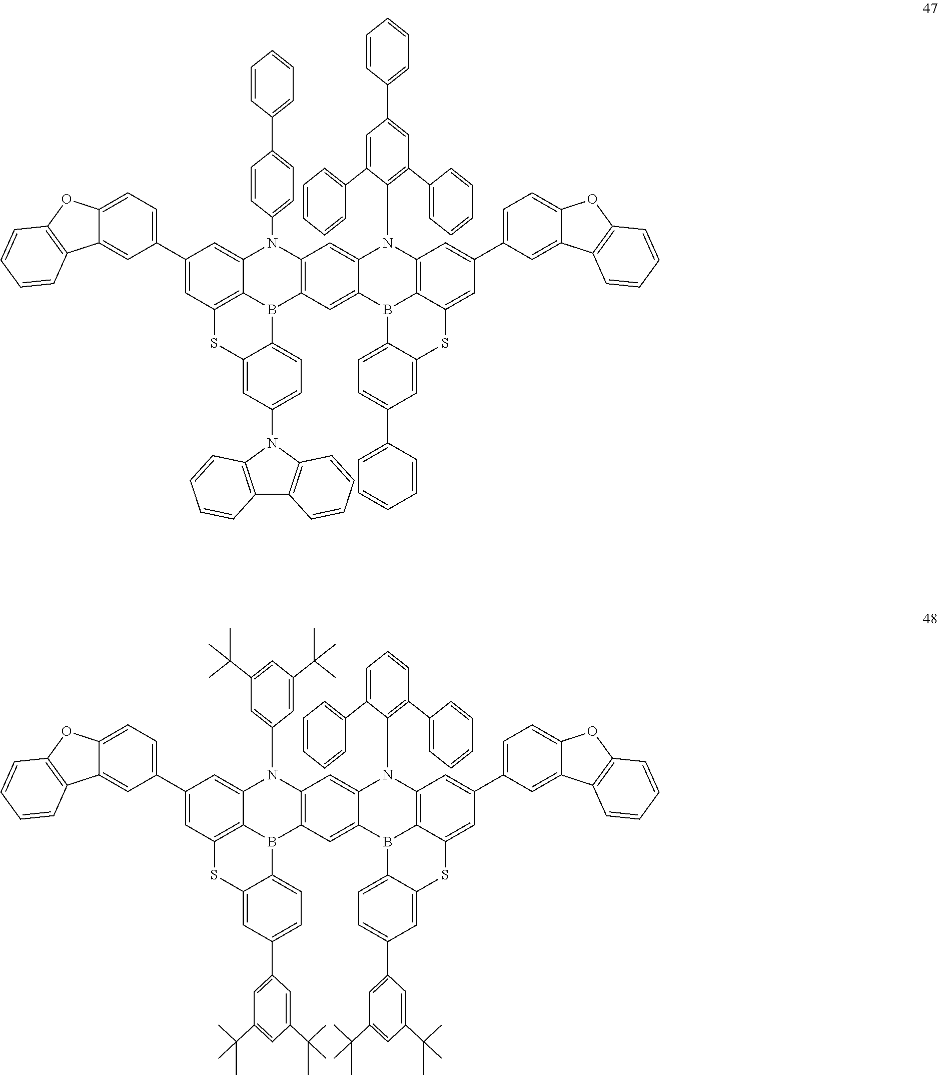 [SMILES: c1ccc(-c2ccc(N3c4cc5c(cc4B4c6ccc(-n7c8ccccc8c8ccccc87)cc6Sc6cc(-c7ccc8oc9ccccc9c8c7)cc3c64)B3c4ccc(-c6ccccc6)cc4Sc4cc(-c6ccc7oc8ccccc8c7c6)cc(c43)N5c3c(-c4ccccc4)cc(-c4ccccc4)cc3-c3ccccc3)cc2)cc1 ; CC(C)(C)c1cc(-c2ccc3c(c2)Sc2cc(-c4ccc5oc6ccccc6c5c4)cc4c2B3c2cc3c(cc2N4c2cc(C(C)(C)C)cc(C(C)(C)C)c2)N(c2c(-c4ccccc4)cccc2-c2ccccc2)c2cc(-c4ccc5oc6ccccc6c5c4)cc4c2B3c2ccc(-c3cc(C(C)(C)C)cc(C(C)(C)C)c3)cc2S4)cc(C(C)(C)C)c1] 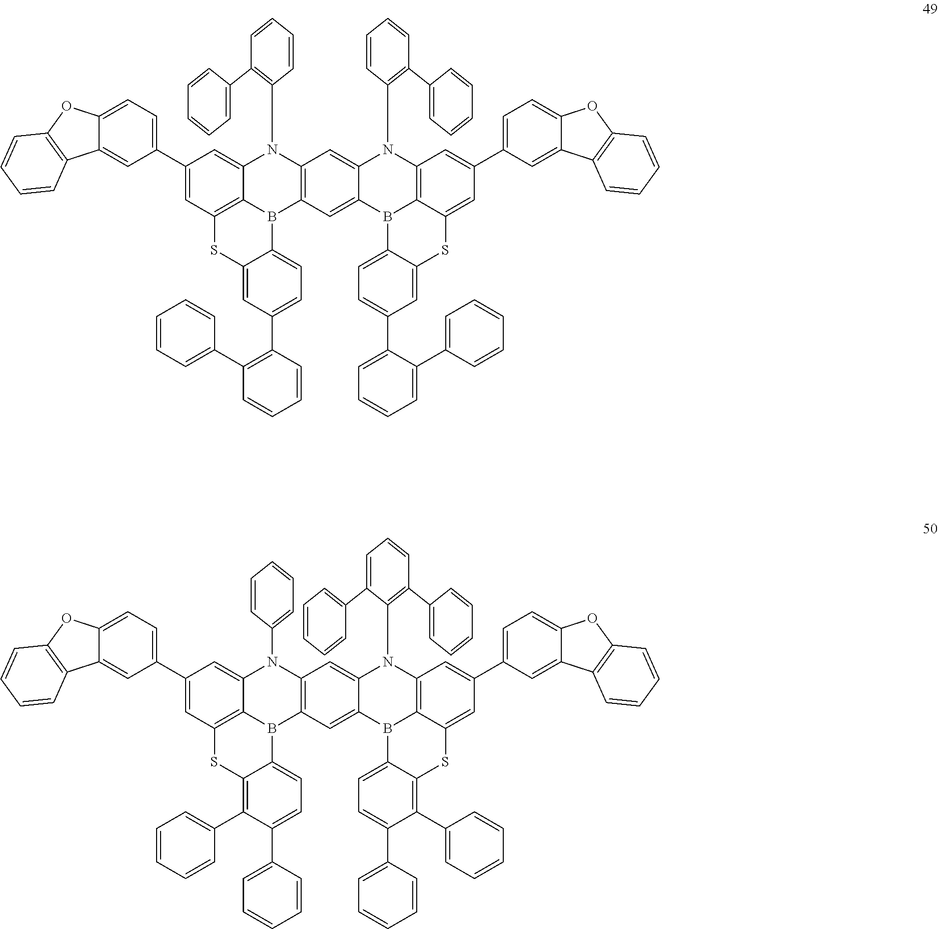 [SMILES: c1ccc(-c2ccccc2-c2ccc3c(c2)Sc2cc(-c4ccc5oc6ccccc6c5c4)cc4c2B3c2cc3c(cc2N4c2ccccc2-c2ccccc2)N(c2ccccc2-c2ccccc2)c2cc(-c4ccc5oc6ccccc6c5c4)cc4c2B3c2ccc(-c3ccccc3-c3ccccc3)cc2S4)cc1 ; c1ccc(-c2ccc3c(c2-c2ccccc2)Sc2cc(-c4ccc5oc6ccccc6c5c4)cc4c2B3c2cc3c(cc2N4c2ccccc2)N(c2c(-c4ccccc4)cccc2-c2ccccc2)c2cc(-c4ccc5oc6ccccc6c5c4)cc4c2B3c2ccc(-c3ccccc3)c(-c3ccccc3)c2S4)cc1] 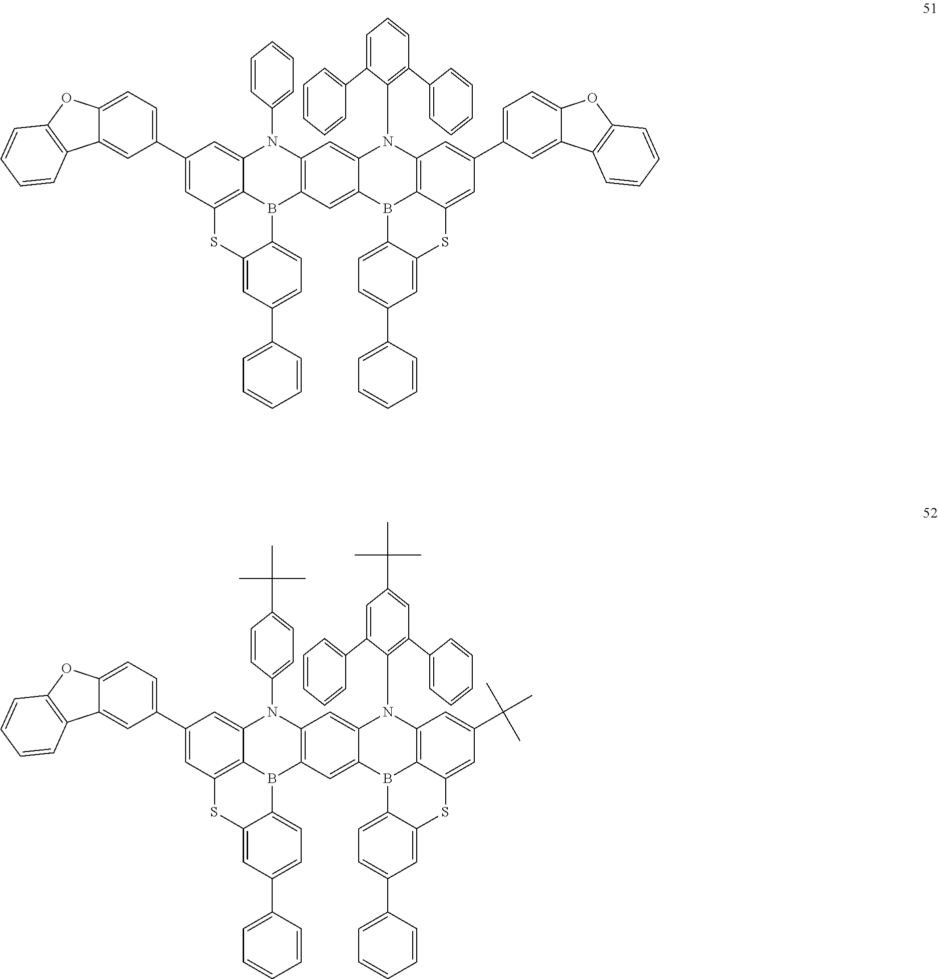 [SMILES: c1ccc(-c2ccc3c(c2)Sc2cc(-c4ccc5oc6ccccc6c5c4)cc4c2B3c2cc3c(cc2N4c2ccccc2)N(c2c(-c4ccccc4)cccc2-c2ccccc2)c2cc(-c4ccc5oc6ccccc6c5c4)cc4c2B3c2ccc(-c3ccccc3)cc2S4)cc1 ; CC(C)(C)c1ccc(N2c3cc4c(cc3B3c5ccc(-c6ccccc6)cc5Sc5cc(-c6ccc7oc8ccccc8c7c6)cc2c53)B2c3ccc(-c5ccccc5)cc3Sc3cc(C(C)(C)C)cc(c32)N4c2c(-c3ccccc3)cc(C(C)(C)C)cc2-c2ccccc2)cc1] 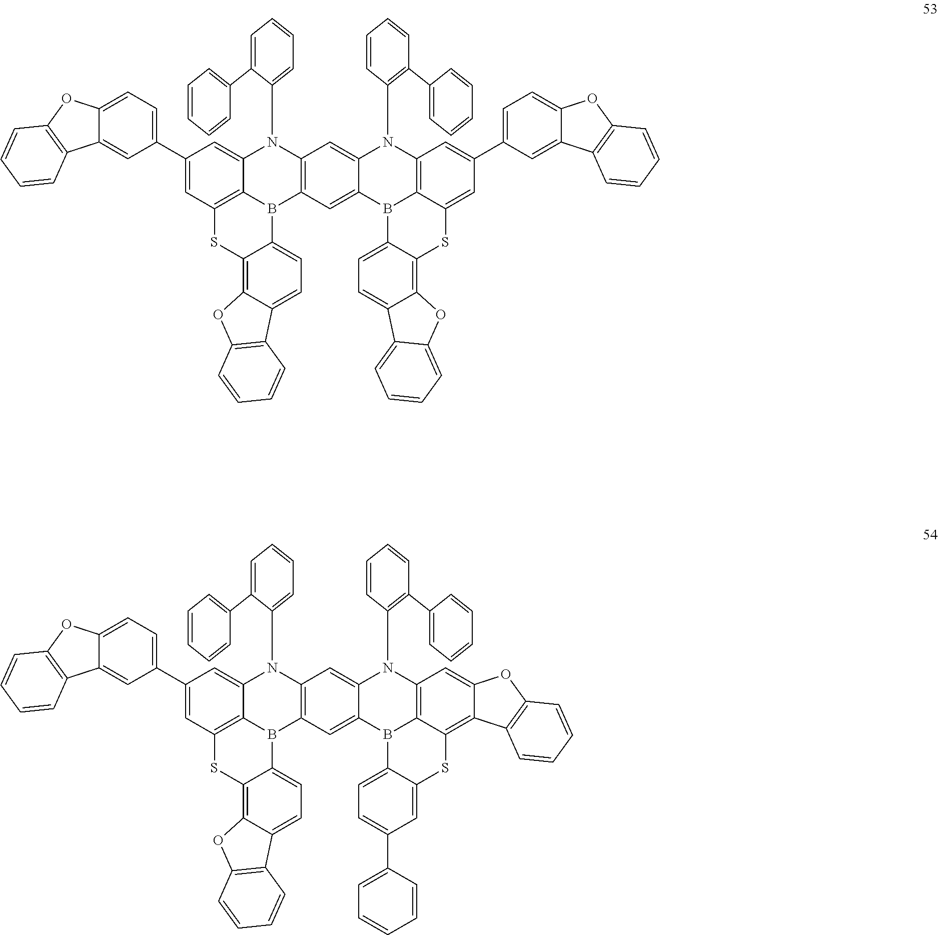 [SMILES: c1ccc(-c2ccccc2N2c3cc4c(cc3B3c5ccc6c(oc7ccccc76)c5Sc5cc(-c6ccc7oc8ccccc8c7c6)cc2c53)B2c3ccc5c(oc6ccccc65)c3Sc3cc(-c5ccc6oc7ccccc7c6c5)cc(c32)N4c2ccccc2-c2ccccc2)cc1 ; c1ccc(-c2ccc3c(c2)Sc2c4c(cc5oc6ccccc6c25)N(c2ccccc2-c2ccccc2)c2cc5c(cc2B34)B2c3ccc4c(oc6ccccc64)c3Sc3cc(-c4ccc6oc7ccccc7c6c4)cc(c32)N5c2ccccc2-c2ccccc2)cc1] 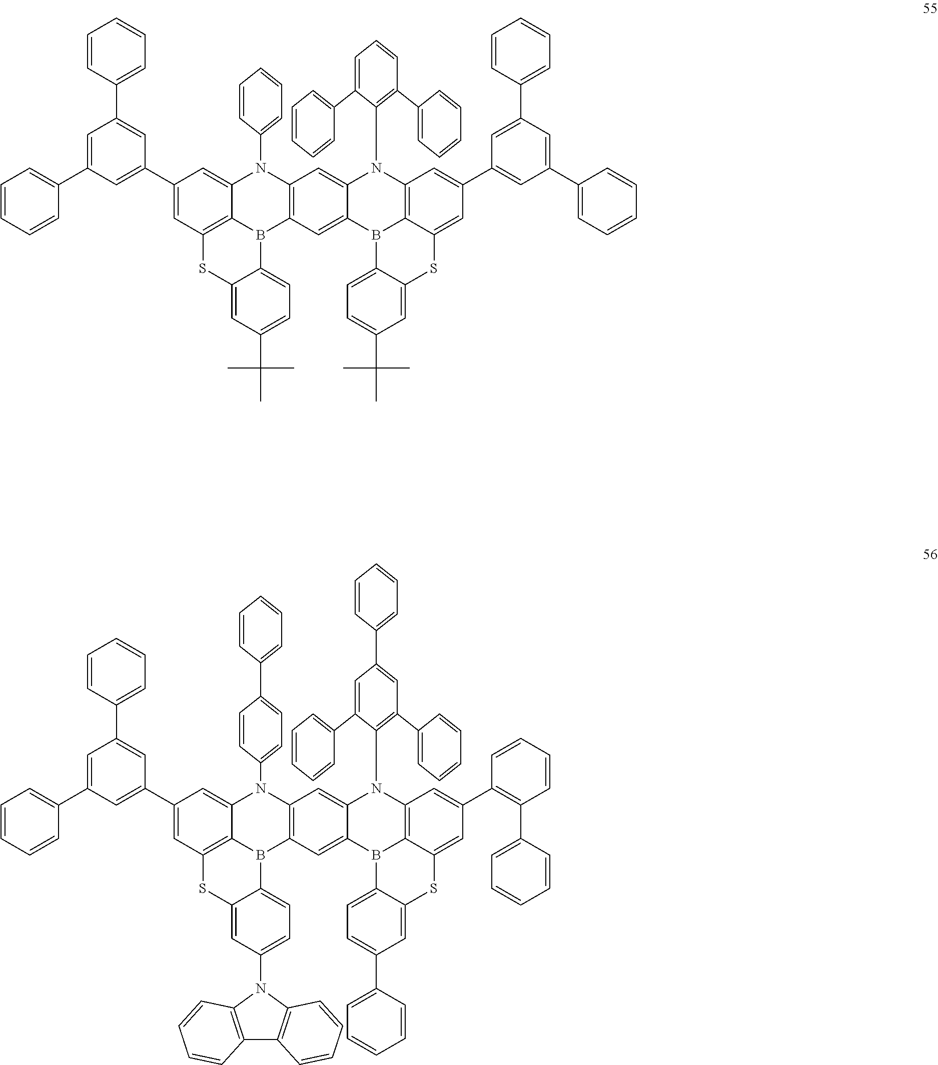 [SMILES: CC(C)(C)c1ccc2c(c1)Sc1cc(-c3cc(-c4ccccc4)cc(-c4ccccc4)c3)cc3c1B2c1cc2c(cc1N3c1ccccc1)N(c1c(-c3ccccc3)cccc1-c1ccccc1)c1cc(-c3cc(-c4ccccc4)cc(-c4ccccc4)c3)cc3c1B2c1ccc(C(C)(C)C)cc1S3 ; c1ccc(-c2ccc(N3c4cc5c(cc4B4c6ccc(-n7c8ccccc8c8ccccc87)cc6Sc6cc(-c7cc(-c8ccccc8)cc(-c8ccccc8)c7)cc3c64)B3c4ccc(-c6ccccc6)cc4Sc4cc(-c6ccccc6-c6ccccc6)cc(c43)N5c3c(-c4ccccc4)cc(-c4ccccc4)cc3-c3ccccc3)cc2)cc1] 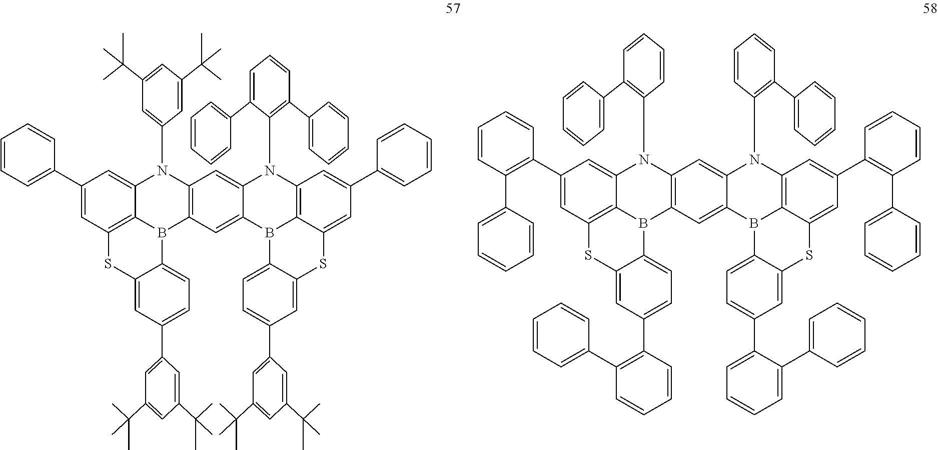 [SMILES: CC(C)(C)c1cc(-c2ccc3c(c2)Sc2cc(-c4ccccc4)cc4c2B3c2cc3c(cc2N4c2cc(C(C)(C)C)cc(C(C)(C)C)c2)N(c2c(-c4ccccc4)cccc2-c2ccccc2)c2cc(-c4ccccc4)cc4c2B3c2ccc(-c3cc(C(C)(C)C)cc(C(C)(C)C)c3)cc2S4)cc(C(C)(C)C)c1 ; c1ccc(-c2ccccc2-c2ccc3c(c2)Sc2cc(-c4ccccc4-c4ccccc4)cc4c2B3c2cc3c(cc2N4c2ccccc2-c2ccccc2)N(c2ccccc2-c2ccccc2)c2cc(-c4ccccc4-c4ccccc4)cc4c2B3c2ccc(-c3ccccc3-c3ccccc3)cc2S4)cc1] 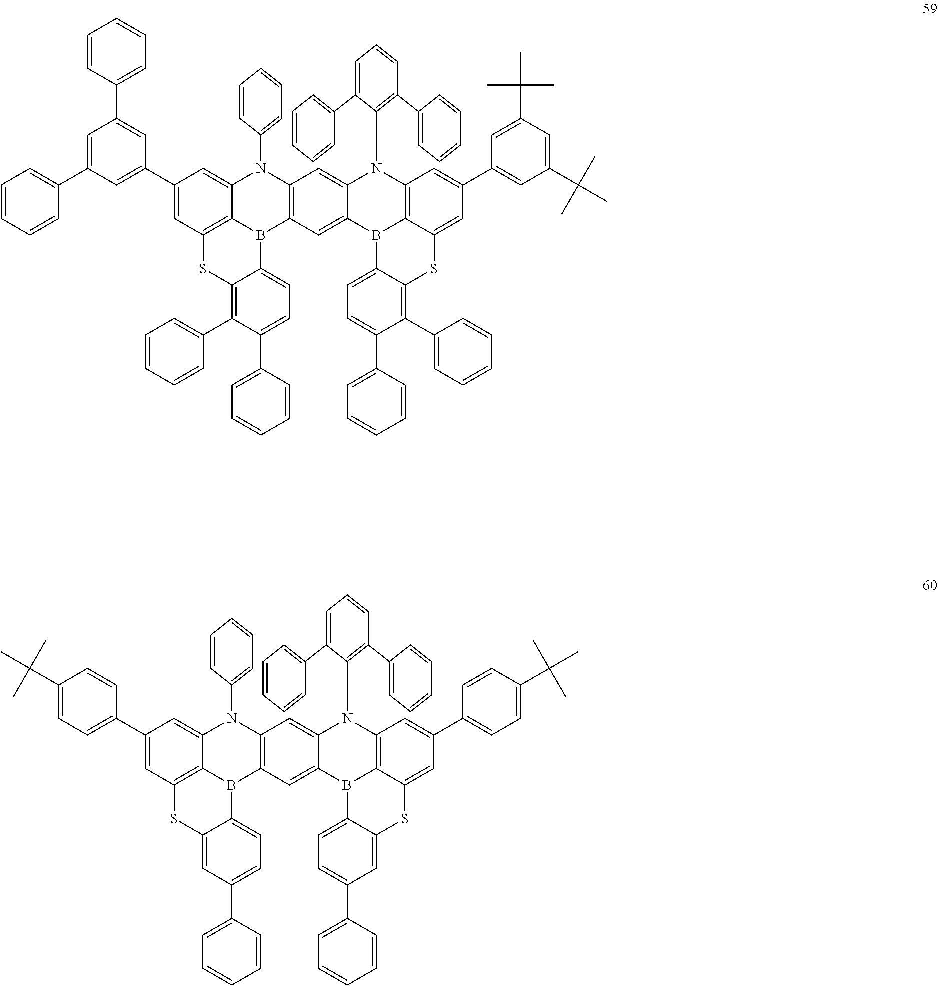 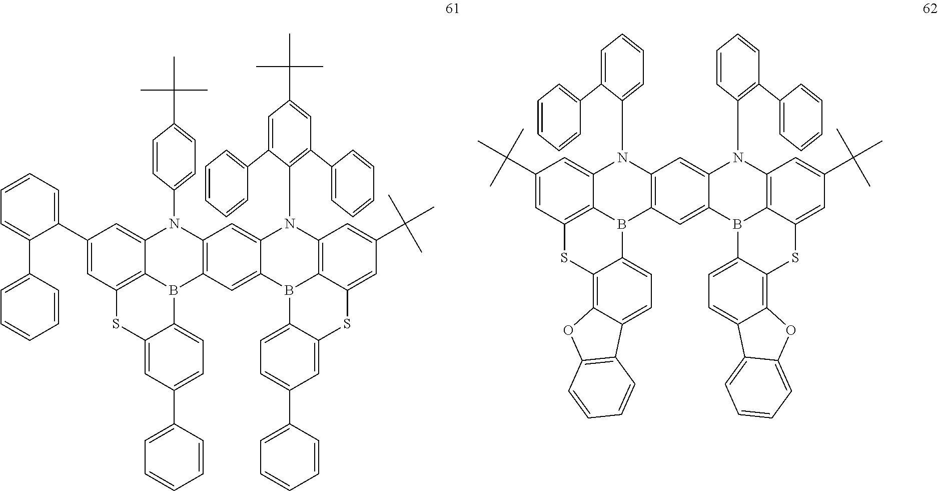 [SMILES: CC(C)(C)c1ccc(N2c3cc4c(cc3B3c5ccc(-c6ccccc6)cc5Sc5cc(-c6ccccc6-c6ccccc6)cc2c53)B2c3ccc(-c5ccccc5)cc3Sc3cc(C(C)(C)C)cc(c32)N4c2c(-c3ccccc3)cc(C(C)(C)C)cc2-c2ccccc2)cc1 ; CC(C)(C)c1cc2c3c(c1)N(c1ccccc1-c1ccccc1)c1cc4c(cc1B3c1ccc3c(oc5ccccc53)c1S2)B1c2ccc3c(oc5ccccc53)c2Sc2cc(C(C)(C)C)cc(c21)N4c1ccccc1-c1ccccc1] 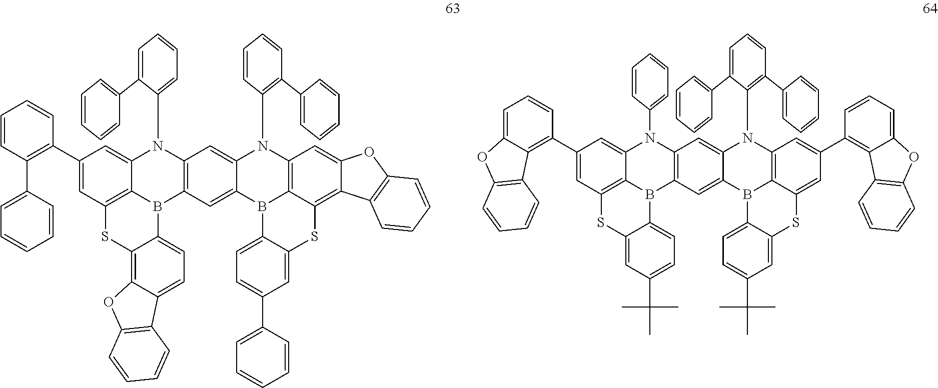 [SMILES: c1ccc(-c2ccc3c(c2)Sc2c4c(cc5oc6ccccc6c25)N(c2ccccc2-c2ccccc2)c2cc5c(cc2B34)B2c3ccc4c(oc6ccccc64)c3Sc3cc(-c4ccccc4-c4ccccc4)cc(c32)N5c2ccccc2-c2ccccc2)cc1 ; CC(C)(C)c1ccc2c(c1)Sc1cc(-c3cccc4oc5ccccc5c34)cc3c1B2c1cc2c(cc1N3c1ccccc1)N(c1c(-c3ccccc3)cccc1-c1ccccc1)c1cc(-c3cccc4oc5ccccc5c34)cc3c1B2c1ccc(C(C)(C)C)cc1S3] 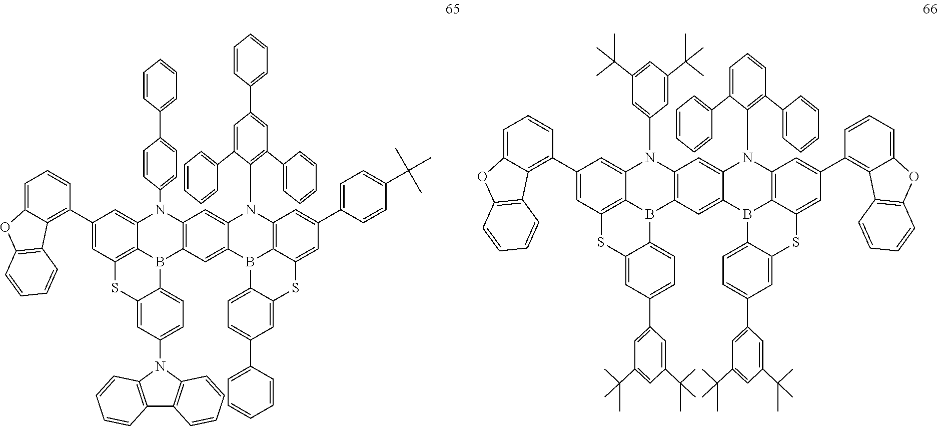 [SMILES: CC(C)(C)c1ccc(-c2cc3c4c(c2)N(c2c(-c5ccccc5)cc(-c5ccccc5)cc2-c2ccccc2)c2cc5c(cc2B4c2ccc(-c4ccccc4)cc2S3)B2c3ccc(-n4c6ccccc6c6ccccc64)cc3Sc3cc(-c4cccc6oc7ccccc7c46)cc(c32)N5c2ccc(-c3ccccc3)cc2)cc1 ; CC(C)(C)c1cc(-c2ccc3c(c2)Sc2cc(-c4cccc5oc6ccccc6c45)cc4c2B3c2cc3c(cc2N4c2cc(C(C)(C)C)cc(C(C)(C)C)c2)N(c2c(-c4ccccc4)cccc2-c2ccccc2)c2cc(-c4cccc5oc6ccccc6c45)cc4c2B3c2ccc(-c3cc(C(C)(C)C)cc(C(C)(C)C)c3)cc2S4)cc(C(C)(C)C)c1] 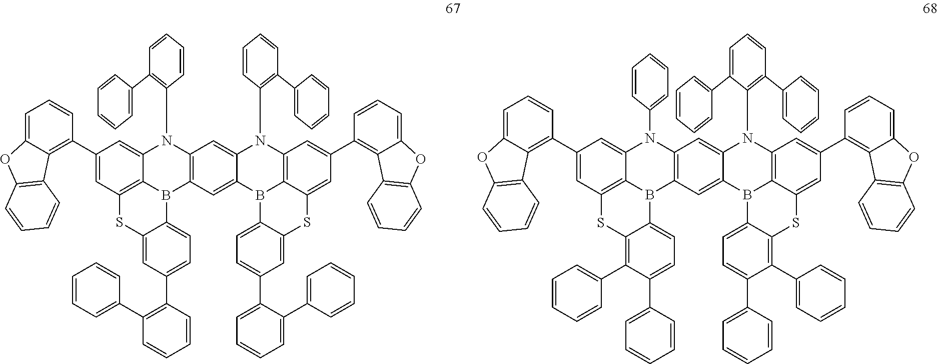 [SMILES: c1ccc(-c2ccccc2-c2ccc3c(c2)Sc2cc(-c4cccc5oc6ccccc6c45)cc4c2B3c2cc3c(cc2N4c2ccccc2-c2ccccc2)N(c2ccccc2-c2ccccc2)c2cc(-c4cccc5oc6ccccc6c45)cc4c2B3c2ccc(-c3ccccc3-c3ccccc3)cc2S4)cc1 ; c1ccc(-c2ccc3c(c2-c2ccccc2)Sc2cc(-c4cccc5oc6ccccc6c45)cc4c2B3c2cc3c(cc2N4c2ccccc2)N(c2c(-c4ccccc4)cccc2-c2ccccc2)c2cc(-c4cccc5oc6ccccc6c45)cc4c2B3c2ccc(-c3ccccc3)c(-c3ccccc3)c2S4)cc1] 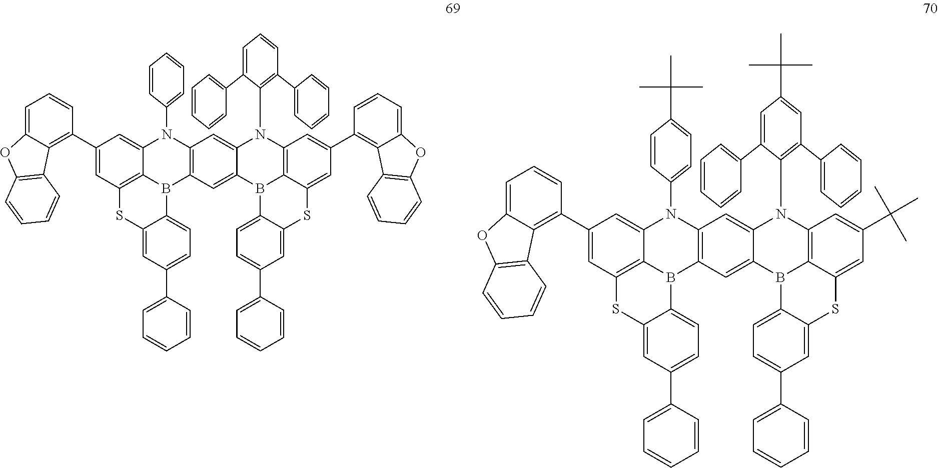 [SMILES: c1ccc(-c2ccc3c(c2)Sc2cc(-c4cccc5oc6ccccc6c45)cc4c2B3c2cc3c(cc2N4c2ccccc2)N(c2c(-c4ccccc4)cccc2-c2ccccc2)c2cc(-c4cccc5oc6ccccc6c45)cc4c2B3c2ccc(-c3ccccc3)cc2S4)cc1 ; CC(C)(C)c1ccc(N2c3cc4c(cc3B3c5ccc(-c6ccccc6)cc5Sc5cc(-c6cccc7oc8ccccc8c67)cc2c53)B2c3ccc(-c5ccccc5)cc3Sc3cc(C(C)(C)C)cc(c32)N4c2c(-c3ccccc3)cc(C(C)(C)C)cc2-c2ccccc2)cc1] 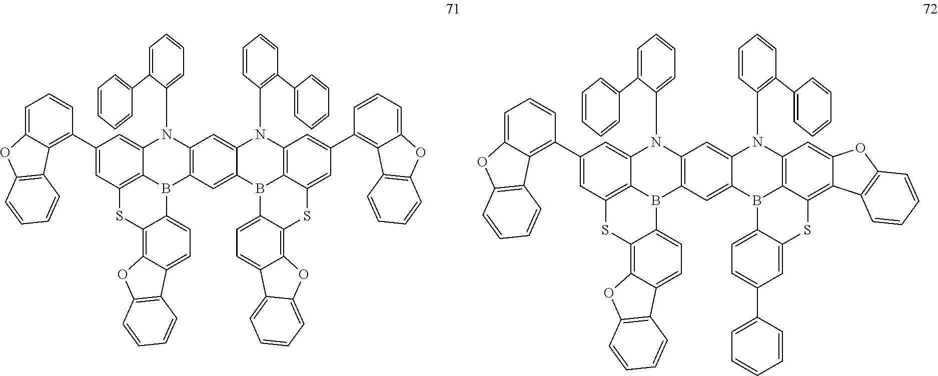 [SMILES: c1ccc(-c2ccccc2N2c3cc4c(cc3B3c5ccc6c(oc7ccccc76)c5Sc5cc(-c6cccc7oc8ccccc8c67)cc2c53)B2c3ccc5c(oc6ccccc65)c3Sc3cc(-c5cccc6oc7ccccc7c56)cc(c32)N4c2ccccc2-c2ccccc2)cc1 ; c1ccc(-c2ccc3c(c2)Sc2c4c(cc5oc6ccccc6c25)N(c2ccccc2-c2ccccc2)c2cc5c(cc2B34)B2c3ccc4c(oc6ccccc64)c3Sc3cc(-c4cccc6oc7ccccc7c46)cc(c32)N5c2ccccc2-c2ccccc2)cc1] 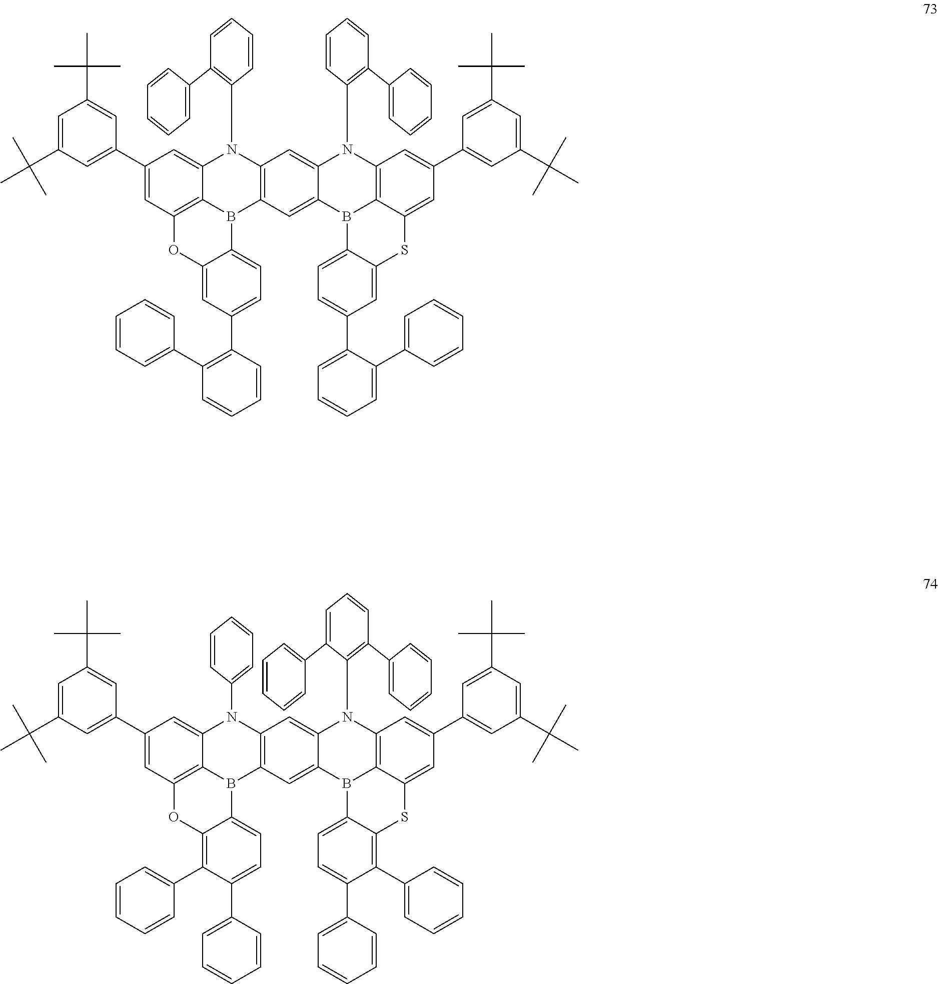 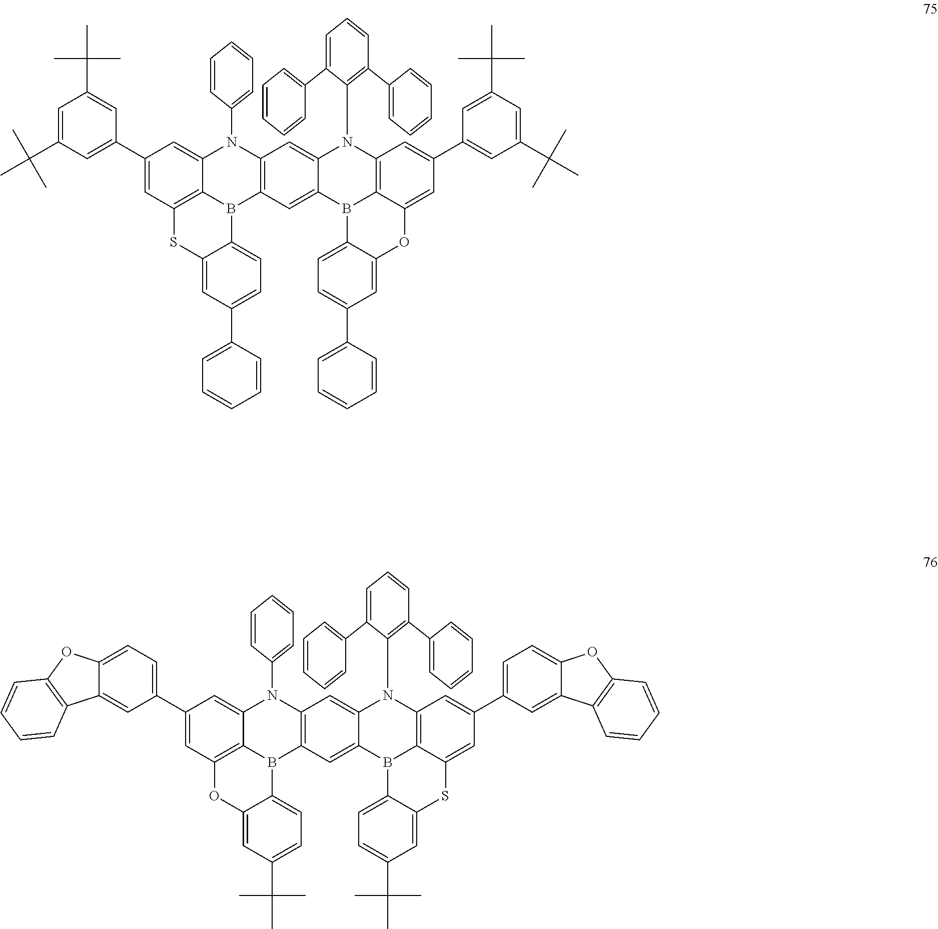 [SMILES: CC(C)(C)c1cc(-c2cc3c4c(c2)N(c2c(-c5ccccc5)cccc2-c2ccccc2)c2cc5c(cc2B4c2ccc(-c4ccccc4)cc2O3)B2c3ccc(-c4ccccc4)cc3Sc3cc(-c4cc(C(C)(C)C)cc(C(C)(C)C)c4)cc(c32)N5c2ccccc2)cc(C(C)(C)C)c1 ; CC(C)(C)c1ccc2c(c1)Oc1cc(-c3ccc4oc5ccccc5c4c3)cc3c1B2c1cc2c(cc1N3c1ccccc1)N(c1c(-c3ccccc3)cccc1-c1ccccc1)c1cc(-c3ccc4oc5ccccc5c4c3)cc3c1B2c1ccc(C(C)(C)C)cc1S3] 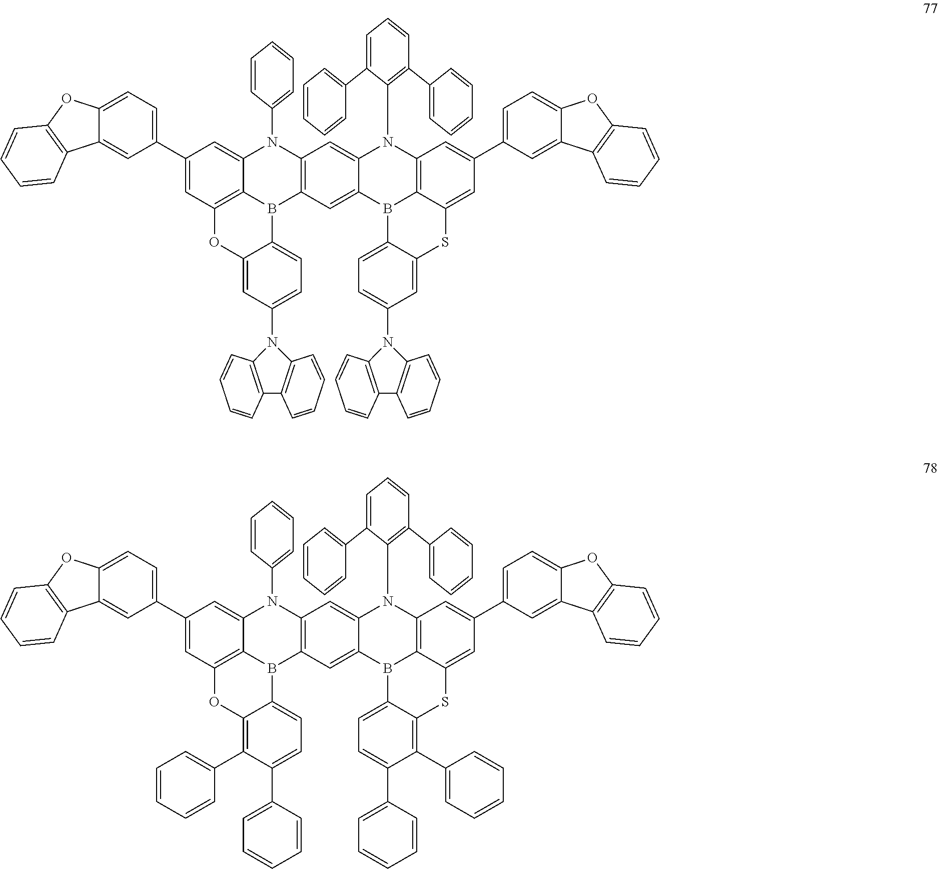 [SMILES: c1ccc(-c2cccc(-c3ccccc3)c2N2c3cc4c(cc3B3c5ccc(-n6c7ccccc7c7ccccc76)cc5Sc5cc(-c6ccc7oc8ccccc8c7c6)cc2c53)B2c3ccc(-n5c6ccccc6c6ccccc65)cc3Oc3cc(-c5ccc6oc7ccccc7c6c5)cc(c32)N4c2ccccc2)cc1 ; c1ccc(-c2ccc3c(c2-c2ccccc2)Oc2cc(-c4ccc5oc6ccccc6c5c4)cc4c2B3c2cc3c(cc2N4c2ccccc2)N(c2c(-c4ccccc4)cccc2-c2ccccc2)c2cc(-c4ccc5oc6ccccc6c5c4)cc4c2B3c2ccc(-c3ccccc3)c(-c3ccccc3)c2S4)cc1] 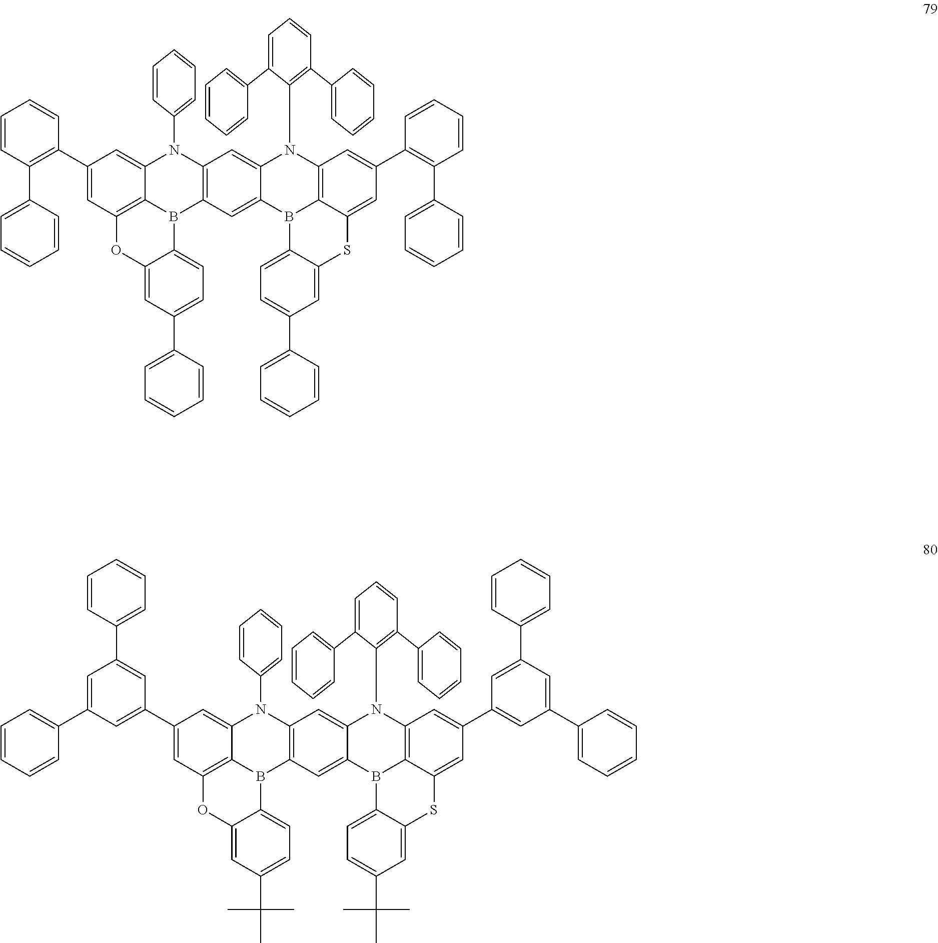 [SMILES: c1ccc(-c2ccc3c(c2)Oc2cc(-c4ccccc4-c4ccccc4)cc4c2B3c2cc3c(cc2N4c2ccccc2)N(c2c(-c4ccccc4)cccc2-c2ccccc2)c2cc(-c4ccccc4-c4ccccc4)cc4c2B3c2ccc(-c3ccccc3)cc2S4)cc1 ; CC(C)(C)c1ccc2c(c1)Oc1cc(-c3cc(-c4ccccc4)cc(-c4ccccc4)c3)cc3c1B2c1cc2c(cc1N3c1ccccc1)N(c1c(-c3ccccc3)cccc1-c1ccccc1)c1cc(-c3cc(-c4ccccc4)cc(-c4ccccc4)c3)cc3c1B2c1ccc(C(C)(C)C)cc1S3] 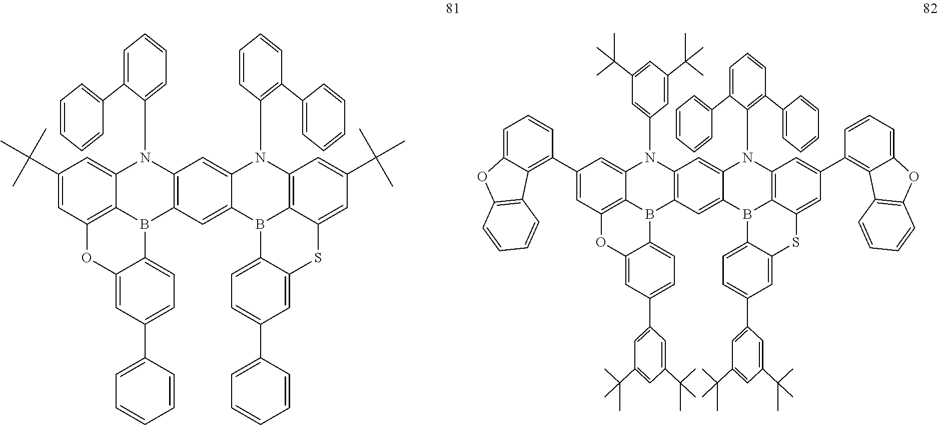 [SMILES: CC(C)(C)c1cc2c3c(c1)N(c1ccccc1-c1ccccc1)c1cc4c(cc1B3c1ccc(-c3ccccc3)cc1O2)B1c2ccc(-c3ccccc3)cc2Sc2cc(C(C)(C)C)cc(c21)N4c1ccccc1-c1ccccc1 ; CC(C)(C)c1cc(-c2ccc3c(c2)Oc2cc(-c4cccc5oc6ccccc6c45)cc4c2B3c2cc3c(cc2N4c2cc(C(C)(C)C)cc(C(C)(C)C)c2)N(c2c(-c4ccccc4)cccc2-c2ccccc2)c2cc(-c4cccc5oc6ccccc6c45)cc4c2B3c2ccc(-c3cc(C(C)(C)C)cc(C(C)(C)C)c3)cc2S4)cc(C(C)(C)C)c1] 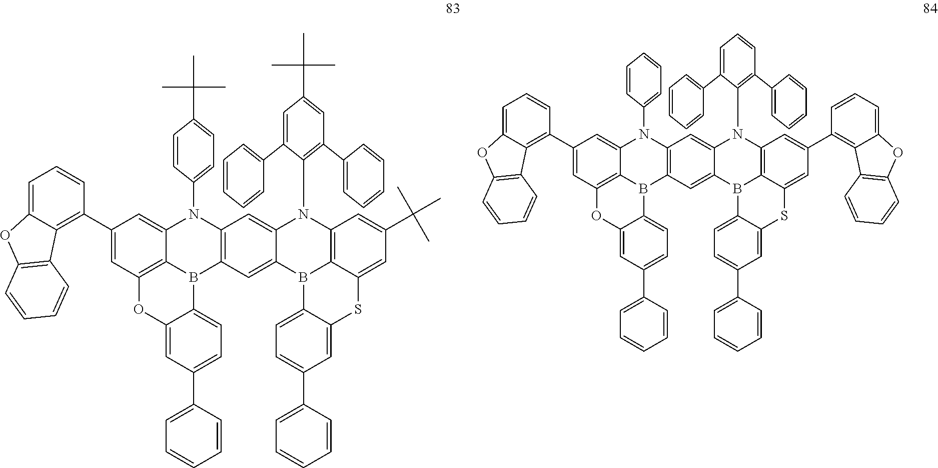 [SMILES: CC(C)(C)c1ccc(N2c3cc4c(cc3B3c5ccc(-c6ccccc6)cc5Oc5cc(-c6cccc7oc8ccccc8c67)cc2c53)B2c3ccc(-c5ccccc5)cc3Sc3cc(C(C)(C)C)cc(c32)N4c2c(-c3ccccc3)cc(C(C)(C)C)cc2-c2ccccc2)cc1 ; c1ccc(-c2ccc3c(c2)Oc2cc(-c4cccc5oc6ccccc6c45)cc4c2B3c2cc3c(cc2N4c2ccccc2)N(c2c(-c4ccccc4)cccc2-c2ccccc2)c2cc(-c4cccc5oc6ccccc6c45)cc4c2B3c2ccc(-c3ccccc3)cc2S4)cc1] 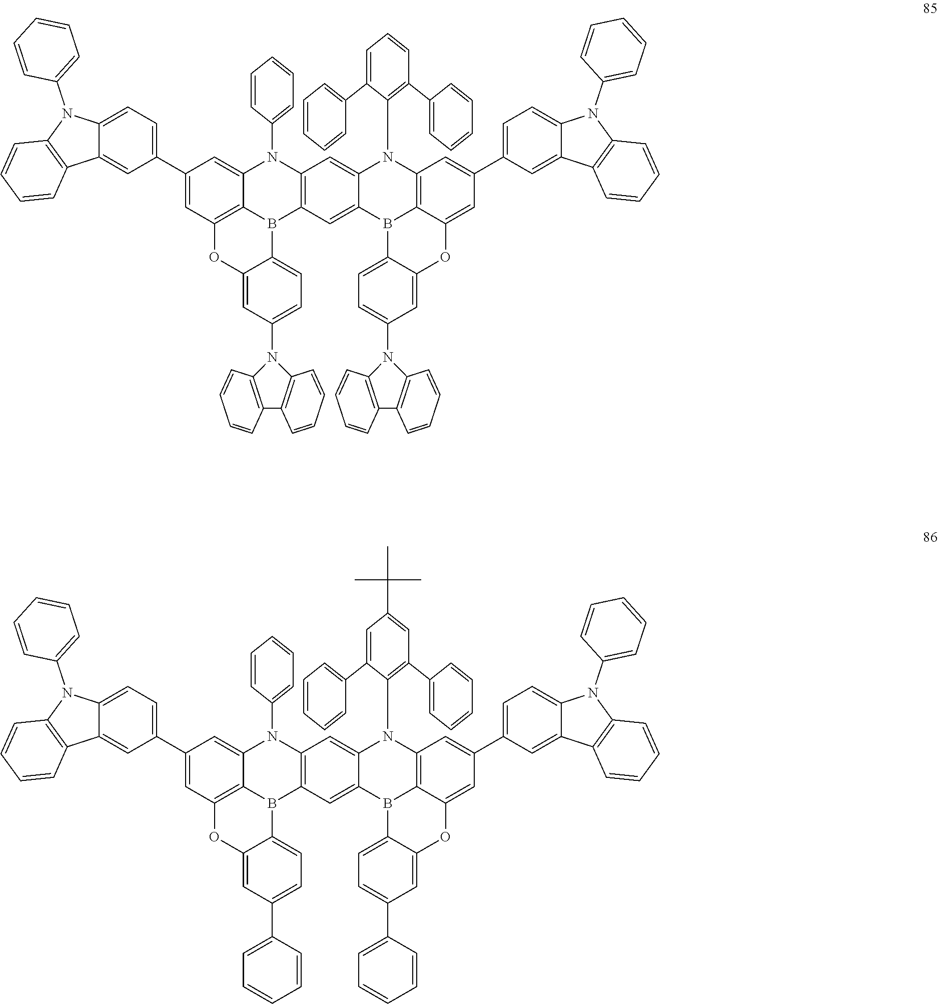 [SMILES: c1ccc(-c2cccc(-c3ccccc3)c2N2c3cc4c(cc3B3c5ccc(-n6c7ccccc7c7ccccc76)cc5Oc5cc(-c6ccc7c(c6)c6ccccc6n7-c6ccccc6)cc2c53)B2c3ccc(-n5c6ccccc6c6ccccc65)cc3Oc3cc(-c5ccc6c(c5)c5ccccc5n6-c5ccccc5)cc(c32)N4c2ccccc2)cc1 ; CC(C)(C)c1cc(-c2ccccc2)c(N2c3cc4c(cc3B3c5ccc(-c6ccccc6)cc5Oc5cc(-c6ccc7c(c6)c6ccccc6n7-c6ccccc6)cc2c53)B2c3ccc(-c5ccccc5)cc3Oc3cc(-c5ccc6c(c5)c5ccccc5n6-c5ccccc5)cc(c32)N4c2ccccc2)c(-c2ccccc2)c1] 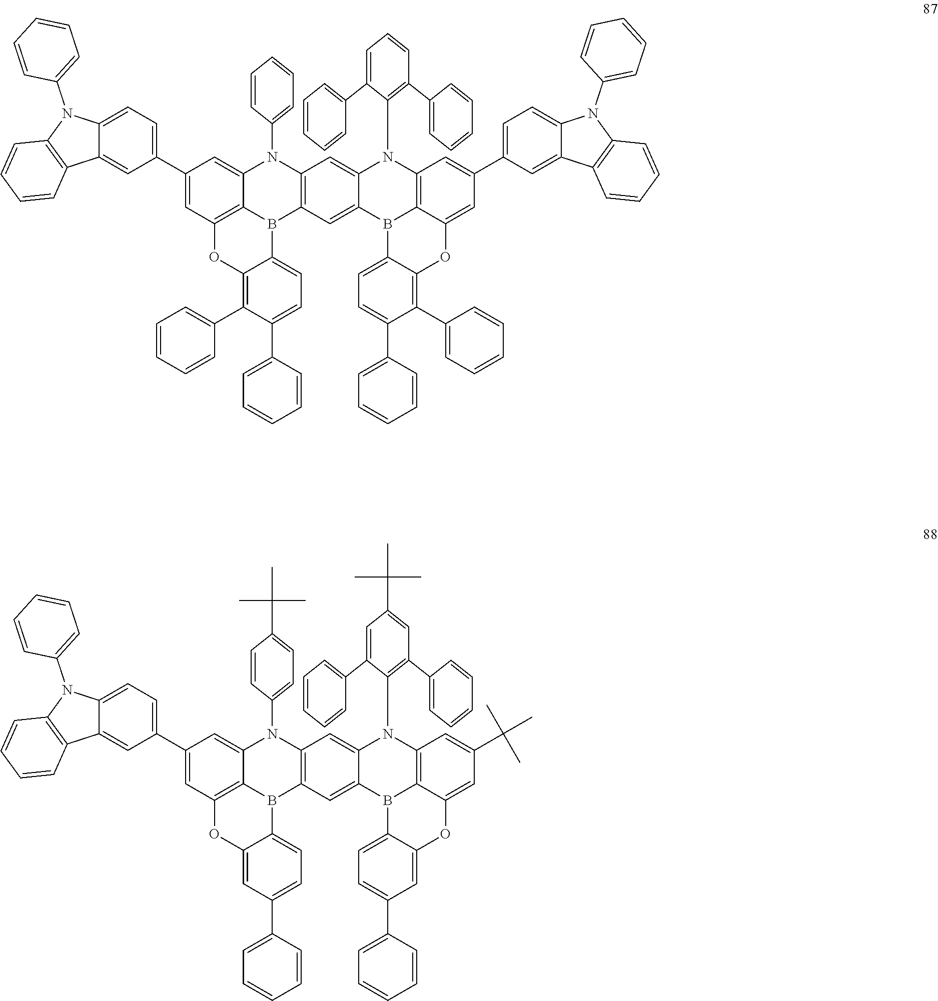 [SMILES: c1ccc(-c2ccc3c(c2-c2ccccc2)Oc2cc(-c4ccc5c(c4)c4ccccc4n5-c4ccccc4)cc4c2B3c2cc3c(cc2N4c2ccccc2)N(c2c(-c4ccccc4)cccc2-c2ccccc2)c2cc(-c4ccc5c(c4)c4ccccc4n5-c4ccccc4)cc4c2B3c2ccc(-c3ccccc3)c(-c3ccccc3)c2O4)cc1 ; CC(C)(C)c1ccc(N2c3cc4c(cc3B3c5ccc(-c6ccccc6)cc5Oc5cc(-c6ccc7c(c6)c6ccccc6n7-c6ccccc6)cc2c53)B2c3ccc(-c5ccccc5)cc3Oc3cc(C(C)(C)C)cc(c32)N4c2c(-c3ccccc3)cc(C(C)(C)C)cc2-c2ccccc2)cc1] 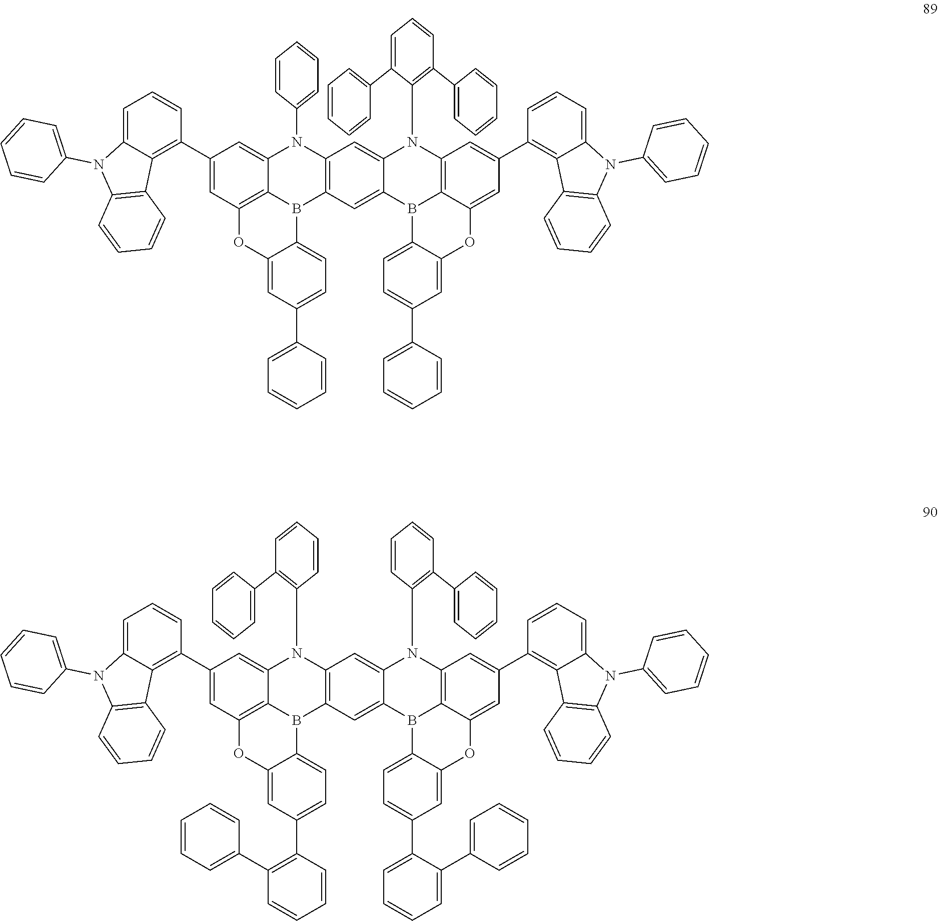 [SMILES: c1ccc(-c2ccc3c(c2)Oc2cc(-c4cccc5c4c4ccccc4n5-c4ccccc4)cc4c2B3c2cc3c(cc2N4c2ccccc2)N(c2c(-c4ccccc4)cccc2-c2ccccc2)c2cc(-c4cccc5c4c4ccccc4n5-c4ccccc4)cc4c2B3c2ccc(-c3ccccc3)cc2O4)cc1 ; c1ccc(-c2ccccc2-c2ccc3c(c2)Oc2cc(-c4cccc5c4c4ccccc4n5-c4ccccc4)cc4c2B3c2cc3c(cc2N4c2ccccc2-c2ccccc2)N(c2ccccc2-c2ccccc2)c2cc(-c4cccc5c4c4ccccc4n5-c4ccccc4)cc4c2B3c2ccc(-c3ccccc3-c3ccccc3)cc2O4)cc1] 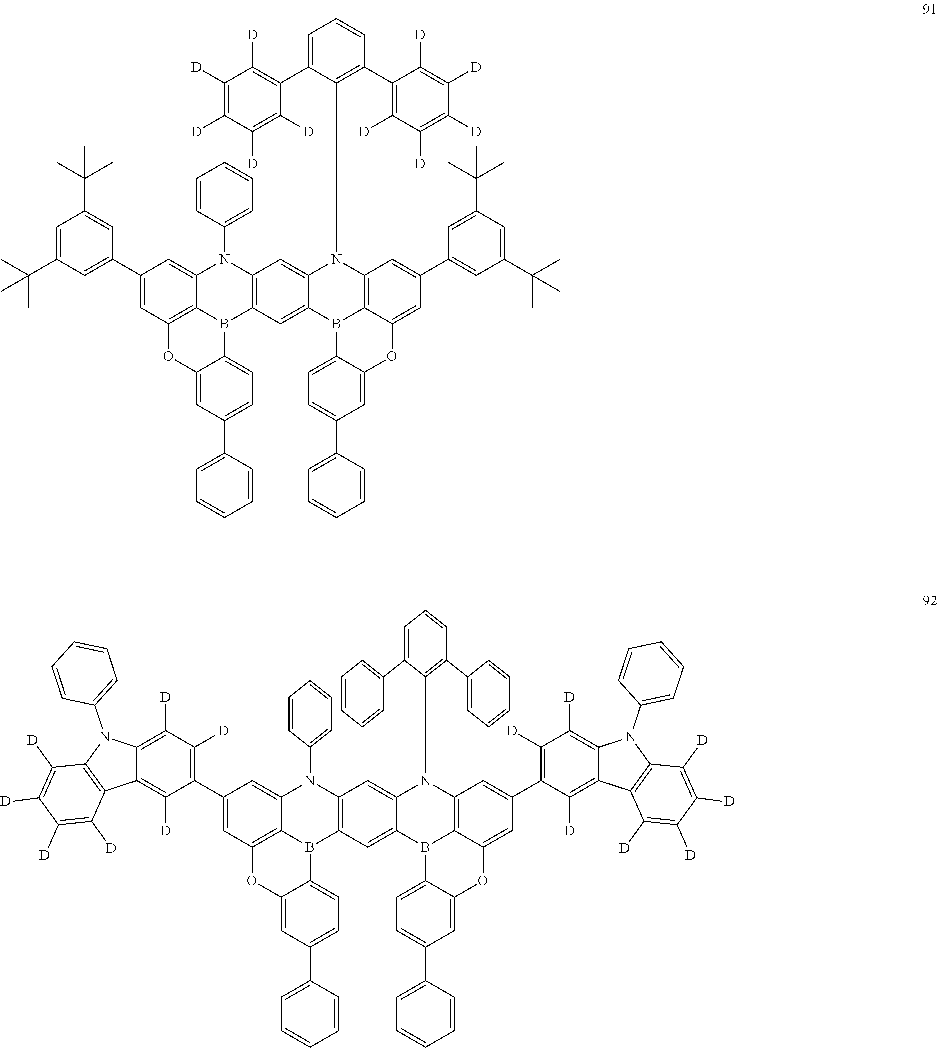 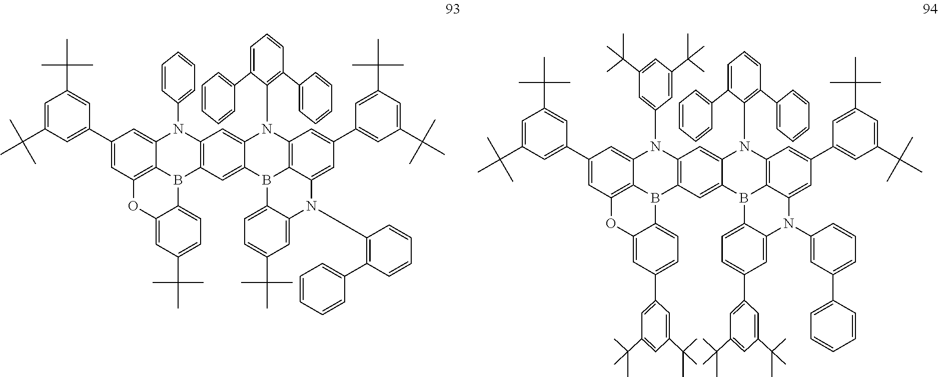 [SMILES: CC(C)(C)c1cc(-c2cc3c4c(c2)N(c2ccccc2)c2cc5c(cc2B4c2ccc(C(C)(C)C)cc2O3)B2c3ccc(C(C)(C)C)cc3N(c3ccccc3-c3ccccc3)c3cc(-c4cc(C(C)(C)C)cc(C(C)(C)C)c4)cc(c32)N5c2c(-c3ccccc3)cccc2-c2ccccc2)cc(C(C)(C)C)c1 ; CC(C)(C)c1cc(-c2ccc3c(c2)Oc2cc(-c4cc(C(C)(C)C)cc(C(C)(C)C)c4)cc4c2B3c2cc3c(cc2N4c2cc(C(C)(C)C)cc(C(C)(C)C)c2)N(c2c(-c4ccccc4)cccc2-c2ccccc2)c2cc(-c4cc(C(C)(C)C)cc(C(C)(C)C)c4)cc4c2B3c2ccc(-c3cc(C(C)(C)C)cc(C(C)(C)C)c3)cc2N4c2cccc(-c3ccccc3)c2)cc(C(C)(C)C)c1] 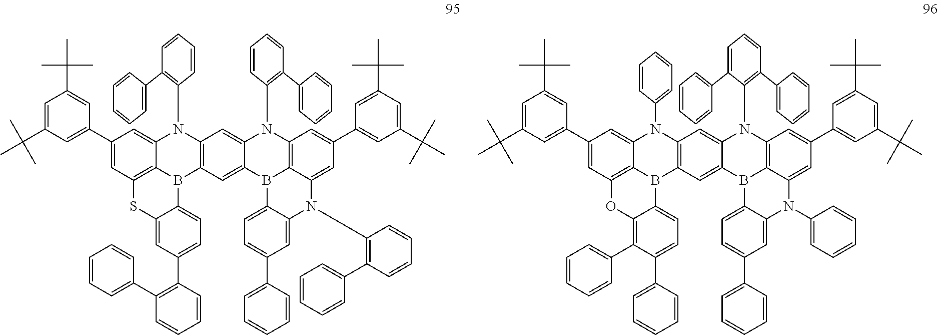 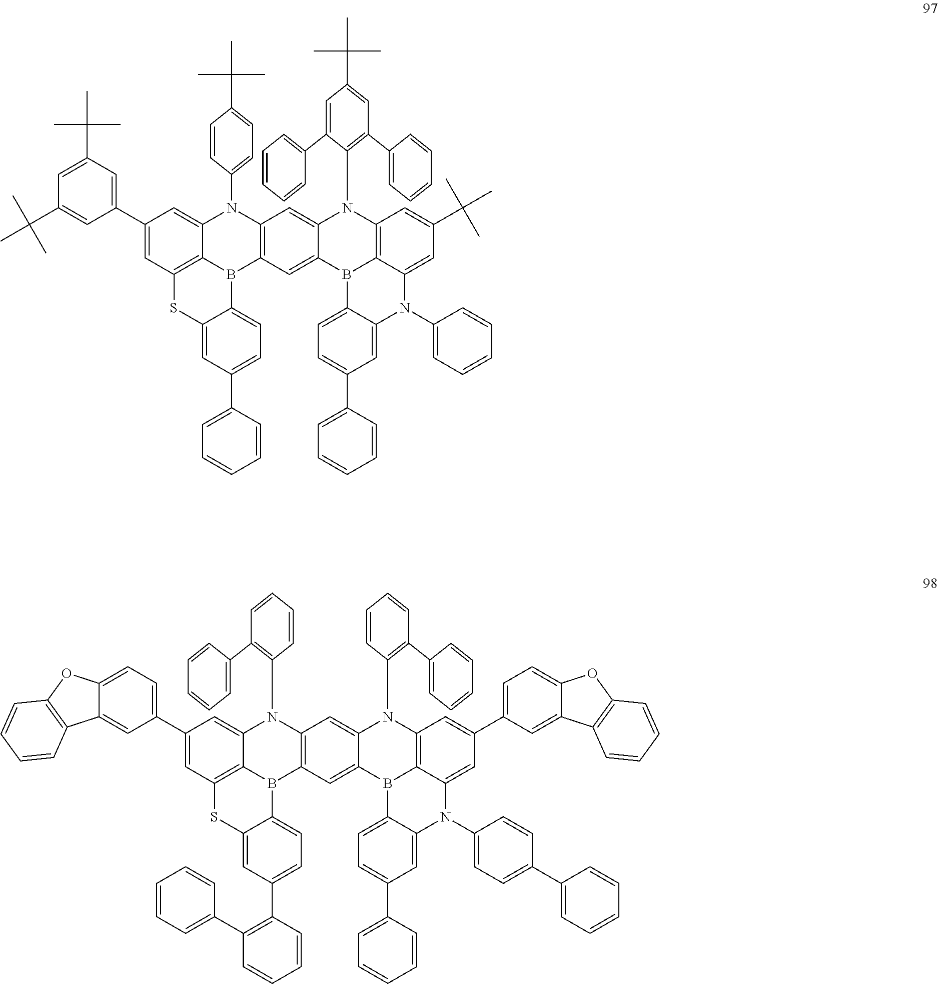 [SMILES: CC(C)(C)c1ccc(N2c3cc4c(cc3B3c5ccc(-c6ccccc6)cc5Sc5cc(-c6cc(C(C)(C)C)cc(C(C)(C)C)c6)cc2c53)B2c3ccc(-c5ccccc5)cc3N(c3ccccc3)c3cc(C(C)(C)C)cc(c32)N4c2c(-c3ccccc3)cc(C(C)(C)C)cc2-c2ccccc2)cc1 ; c1ccc(-c2ccc(N3c4cc(-c5ccccc5)ccc4B4c5cc6c(cc5N(c5ccccc5-c5ccccc5)c5cc(-c7ccc8oc9ccccc9c8c7)cc3c54)N(c3ccccc3-c3ccccc3)c3cc(-c4ccc5oc7ccccc7c5c4)cc4c3B6c3ccc(-c5ccccc5-c5ccccc5)cc3S4)cc2)cc1] 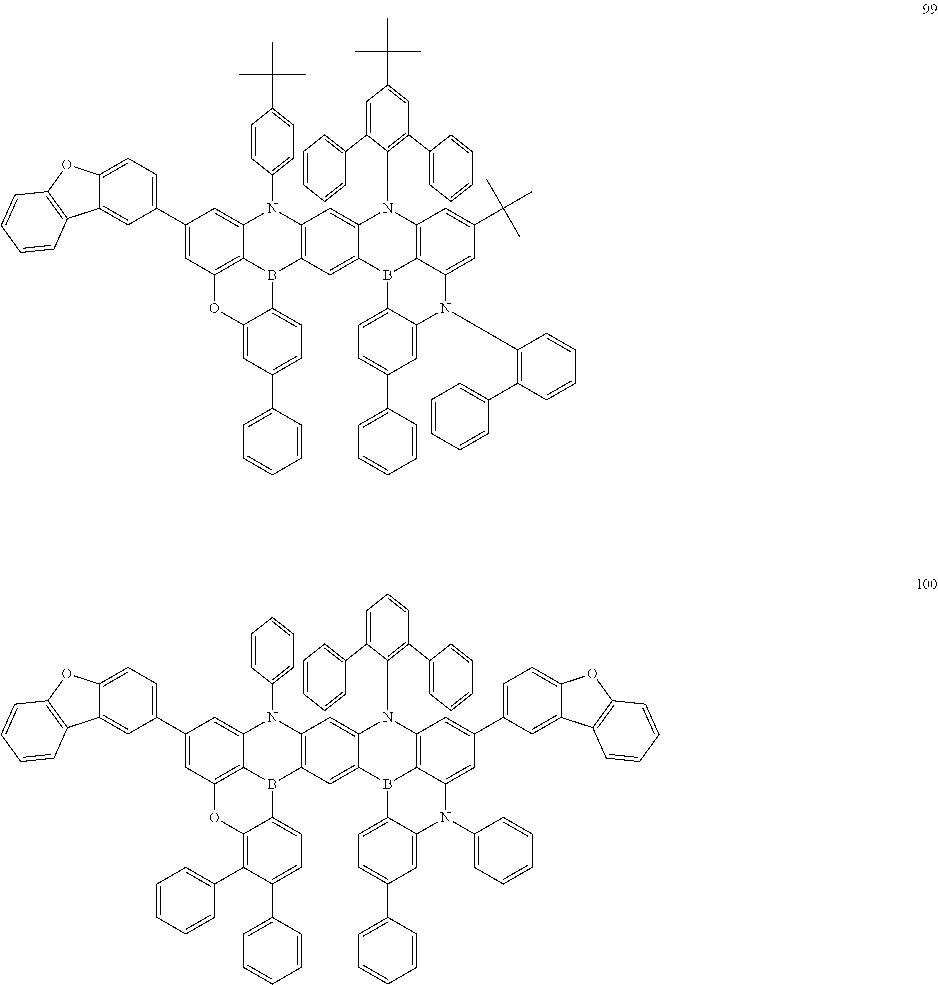 [SMILES: CC(C)(C)c1ccc(N2c3cc4c(cc3B3c5ccc(-c6ccccc6)cc5Oc5cc(-c6ccc7oc8ccccc8c7c6)cc2c53)B2c3ccc(-c5ccccc5)cc3N(c3ccccc3-c3ccccc3)c3cc(C(C)(C)C)cc(c32)N4c2c(-c3ccccc3)cc(C(C)(C)C)cc2-c2ccccc2)cc1 ; c1ccc(-c2ccc3c(c2)N(c2ccccc2)c2cc(-c4ccc5oc6ccccc6c5c4)cc4c2B3c2cc3c(cc2N4c2c(-c4ccccc4)cccc2-c2ccccc2)N(c2ccccc2)c2cc(-c4ccc5oc6ccccc6c5c4)cc4c2B3c2ccc(-c3ccccc3)c(-c3ccccc3)c2O4)cc1] 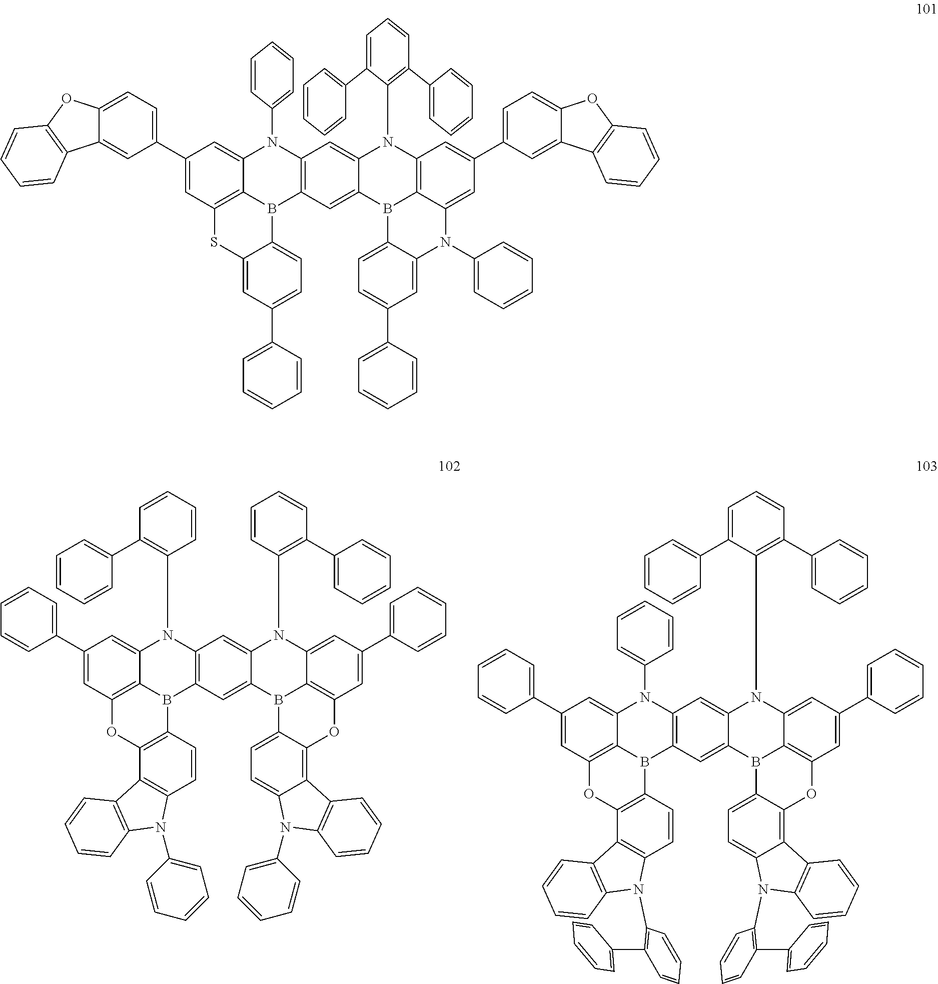 [chemical structure]
